(19) United States
(12) Patent Application Publication
(10) Pub. No.: US 2026/0090186 A1
(43) Pub. Date: Mar. 26, 2026

(54) LIGHT-EMITTING ELEMENT, HETERO COMPOUND FOR LIGHT-EMITTING ELEMENT, AND ELECTRONIC APPARATUS INCLUDING THE LIGHT-EMITTING ELEMENT

(71) Applicant: Samsung Display Co., Ltd., Yongin-si (KR)

(72) Inventors: HYEONGMIN KIM, Yongin-si (KR); JANG YEOL BAEK, Yongin-si (KR); HEECHOON AHN, Yongin-si (KR); HYUNAH UM, Yongin-si (KR); Juhui YUN, Yongin-si (KR); YESEUL LEE, Yongin-si (KR)

(21) Appl. No.: 19/296,805

(22) Filed: Aug. 11, 2025

(30) Foreign Application Priority Data
Sep. 26, 2024 (KR) 10-2024-0131177

(51) Int. Cl. H10K 50/11; C09K 11/06; H10K 59/38; H10K 85/30; H10K 85/40; H10K 85/60; H10K 102/00

(52) U.S. Cl. CPC H10K 50/11; C09K 11/06; H10K 59/38; H10K 85/342; H10K 85/346; H10K 85/40; H10K 85/626; H10K 85/633; H10K 85/636; H10K 85/654; H10K 85/6572; H10K 85/6574; H10K 85/6576; C09K 2211/1029; H10K 2102/331

(57) ABSTRACT

A light-emitting element, including a first electrode, a second electrode opposite to the first electrode, and at least one functional layer between the first electrode and the second electrode is provided. The at least one functional layer includes a hetero compound represented by Formula 1.

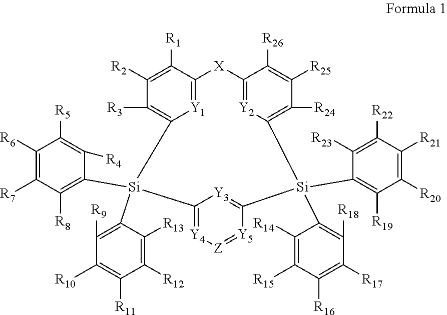

### CROSS-REFERENCE TO RELATED APPLICATION

This application claims priority to and the benefit of Korean Patent Application No. 10-2024-0131177, filed on Sep. 26, 2024, in the Korean Intellectual Property Office, the entire disclosure of which is incorporated herein by reference.

### BACKGROUND

One or more aspects of embodiments of the present disclosure herein relate to a light-emitting element, a hetero compound used for the light-emitting element, and an electronic apparatus including the light-emitting element.

An electronic apparatus includes a display device that displays an image. Recently, as image display devices, luminescence display devices have been actively developed. The luminescence display devices are unlike a liquid display device and are so-called “self-luminous” type (kind) display devices that recombine holes and electrons in the emission layer injected, respectively, from a first electrode and a second electrode. The display device then emits light from emission materials in the emission layer to achieve display, (e.g., of an image).

In the application of the light-emitting element to a display device, improvements in low-driving voltage, high luminous efficiency and long lifespan of the light-emitting element are required, and development of materials for the light-emitting elements that may stably achieve the requirements is consistently desired or required.

### SUMMARY

One or more aspects of embodiments of the present disclosure provide a light-emitting element having enhanced or improved luminous efficiency and element lifespan.

One or more aspects of embodiments of the present disclosure provide a hetero compound, which may enhance or improve luminous efficiency and element lifespan of the light-emitting element.

One or more aspects of embodiments of the present disclosure provide an electronic apparatus having suitable or excellent display quality by including the light-emitting element having improved luminous efficiency and lifespan.

However, it should be noted that these objectives are merely examples, and the scope of the disclosure is not limited to the herein-mentioned aspects. Rather, other objectives of one or more embodiments of the present disclosure will be apparent to those skilled in the art from the following descriptions.

Additional aspects of one or more embodiments will be set forth in part in the description which follows and, in part, will be apparent from the description, or may be learned by practice of the presented embodiments.

One or more embodiments of the present disclosure provide a light-emitting element including a first electrode, a second electrode opposite to the first electrode, and at least one functional layer between the first electrode and the second electrode and including (containing) a first compound represented by Formula 1.

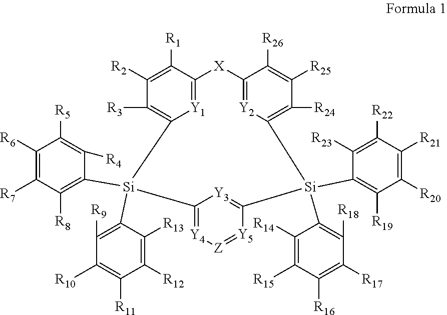

In Formula 1, X may be NAr₁ or O, Z may be CR₂₇ or N, Y₁ to Y₅ may each independently be CR₂₈ or N, Ar₁ may be a substituted or unsubstituted aryl group having 6 to 30 ring-forming carbons, a substituted or unsubstituted heteroaryl group having 2 to 30 ring-forming carbons, or may be bonded (bind) to an adjacent group to form a ring, R₁ to R₂₈ may each independently be a hydrogen atom, a deuterium atom, a cyano group, a substituted or unsubstituted silyl group, a substituted or unsubstituted alkyl group having 1 to 20 carbons, a substituted or unsubstituted cycloalkyl group having 3 to 20 ring-forming carbons, a substituted or unsubstituted hetero cycloalkyl group having 3 to 20 ring-forming carbons, a substituted or unsubstituted alkenyl group having 2 to 20 carbons, a substituted or unsubstituted cycloalkenyl group having 3 to 20 ring-forming carbons, a substituted or unsubstituted hetero cycloalkenyl group having 3 to 20 ring-forming carbons, a substituted or unsubstituted aryl group having 6 to 30 ring-forming carbons, a substituted or unsubstituted heteroaryl group having 2 to 30 ring-forming carbons, or may be bonded (bind) to an adjacent group to form a ring.

In one or more embodiments, the at least one functional layer may include a hole transport region on the first electrode; an emission layer on the hole transport region, and an electron transport region between the emission layer and the second electrode.

In one or more embodiments, the emission layer may be a phosphorescent emission layer comprising a host and a dopant, the host may be the first compound.

In one or more embodiments, the emission layer may include the first compound, and a second compound represented by Formula M-a.

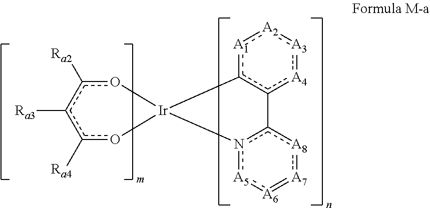

In Formula M-a, A₁ to A₈ may each independently be CRₐ₁ or N, Rₐ₁ to Rₐ₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, a substituted or unsubstituted heteroaryl group having 2 to 30 ring-forming carbons, or may be bonded (bind) to an adjacent group to form a ring, m may be 0 or 1, n may be 2 or 3, when (if) m is 0, n may be 3, and when (if) m is 1, n may be 2.

In one or more embodiments, the first compound represented by Formula 1 may be represented by (e.g., any one of) Formula 1-1 or Formula 1-2.

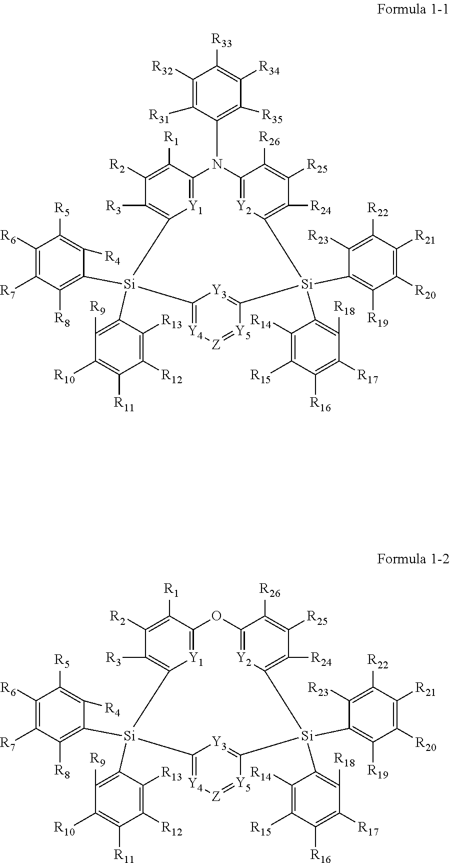

In Formula 1-1 and Formula 1-2, R₃₁ to R₃₅ may each independently be a hydrogen atom, a deuterium atom, a cyano group, a substituted or unsubstituted silyl group, a substituted or unsubstituted alkyl group having 1 to 20 carbons, a substituted or unsubstituted cycloalkyl group having 3 to 20 ring-forming carbons, a substituted or unsubstituted hetero cycloalkyl group having 3 to 20 ring-forming carbons, a substituted or unsubstituted alkenyl group having 2 to 20 carbons, a substituted or unsubstituted cycloalkenyl group having 3 to 20 ring-forming carbons, a substituted or unsubstituted hetero cycloalkenyl group having 3 to 20 ring-forming carbons, a substituted or unsubstituted aryl group having 6 to 30 ring-forming carbons, a substituted or unsubstituted heteroaryl group having 2 to 30 ring-forming carbons, or may be bonded (bind) to an adjacent group to form a ring.

In Formula 1-1 and Formula 1-2, Z, Y₁ to Y₅, and R₁ to R₂₆ may be as defined in Formula 1.

In one or more embodiments, the first compound represented by Formula 1 may be represented by (e.g., any one of) Formula 2-1 or Formula 2-2.

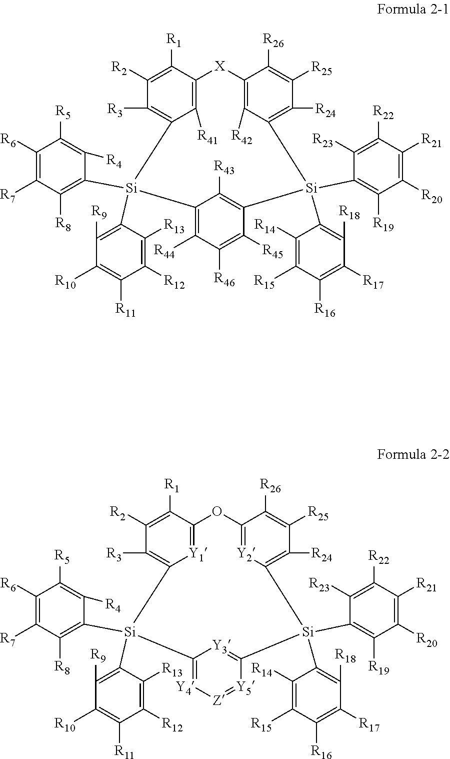

In Formula 2-1 and Formula 2-2, R₄₁ to R₄₆ may each independently be a hydrogen atom, a deuterium atom, or a substituted or unsubstituted carbazole group, at least any one selected from among Y₁′ to Y₅′, and Z′ may be N, and the rest (any remaining Y₁′ to Y₅′, and Z′) may each independently be CR₄₇, R₄₇ may be a hydrogen atom, or a deuterium atom. In Formula 2-1 and Formula 2-2, the descriptions in Formula 1 may be similarly applied for X, and R₁ to R₂₆.

In one or more embodiments, the first compound represented by Formula 1 may be represented by any one selected from among Formula 3-1 to Formula 3-3.

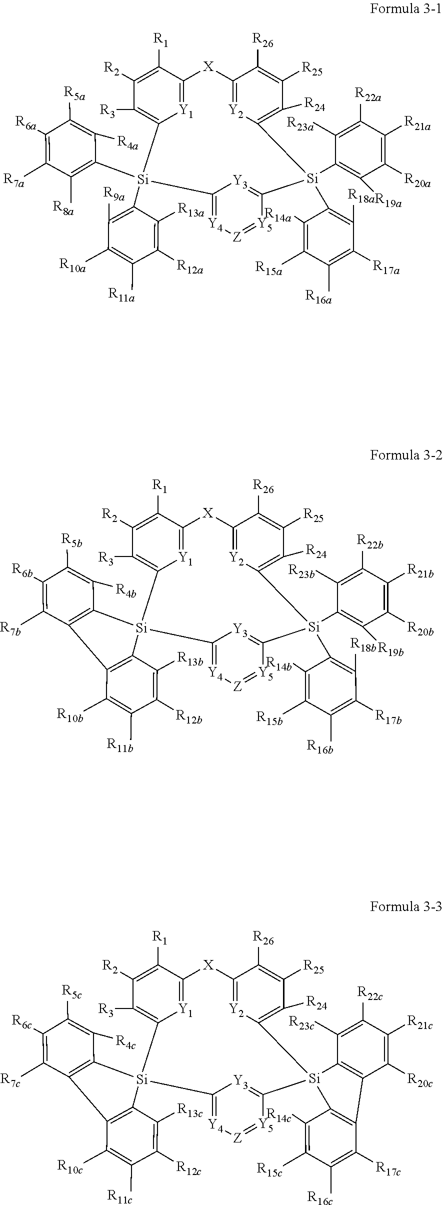

In Formula 3-1, R₄ₐ to R₂₃ₐ may each independently be a hydrogen atom, a deuterium atom, or a substituted or unsubstituted carbazole group, in Formula 3-2, R_{4b} to R_{7b}, R_{10b} to R_{13b}, and R_{14b} to R_{23b} may each independently be a hydrogen atom, a deuterium atom, or a substituted or unsubstituted carbazole group, and in Formula 3-3, R_{4c} to R_{7c}, R_{10c} to R_{13c}, R_{14c} to R_{17c}, and R_{20c} to R_{23c} may each independently be a hydrogen atom, a deuterium atom, or a substituted or unsubstituted carbazole group.

In Formula 3-1 to Formula 3-3, the descriptions in Formula 1 may be similarly applied for X, Z, Y₁ to Y₅, R₁ to R₃, and R₂₄ to R₂₆.

In one or more embodiments, the first compound represented by Formula 1 may be represented by any one selected from among Formula 4-1 to Formula 4-3.

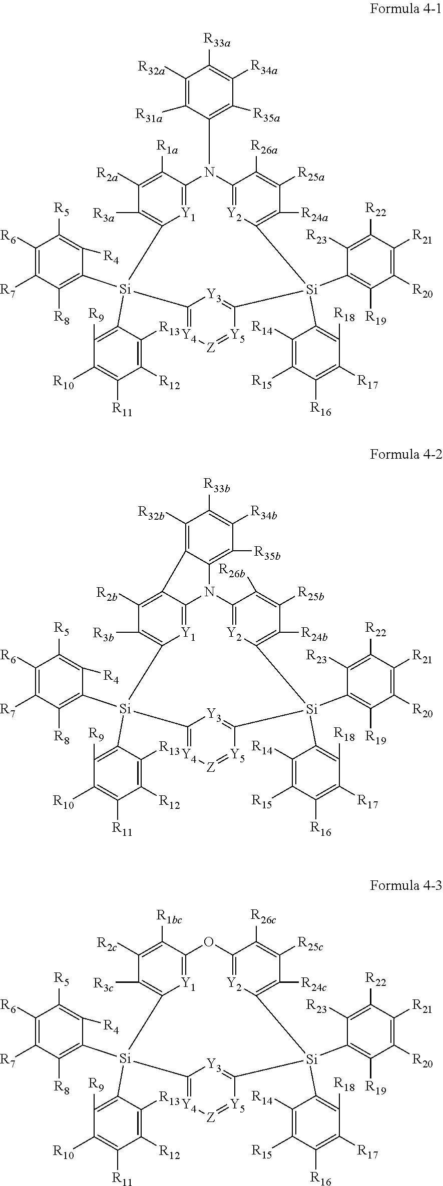

In Formula 4-1, R₁ₐ to R₃ₐ, R₂₄ₐ to R₂₆ₐ, and R₃₁ₐ to R₃₅ₐ may each independently be a hydrogen atom, a deuterium atom, or a substituted or unsubstituted carbazole group, in Formula 4-2, R_{2b}, R_{3b}, R_{24b} to R_{26b}, and R_{32b} to R_{35b} may each independently be a hydrogen atom, a deuterium atom, or a substituted or unsubstituted carbazole group, in Formula 4-3, R_{1c} to R_{3c}, and R_{24c} to R_{26c} may each independently be a hydrogen atom, a deuterium atom, or a substituted or unsubstituted carbazole group.

In Formula 4-1 to Formula 4-3, the descriptions in Formula 1 may be similarly applied for Z, Y₁ to Y₅, and R₄ to R₂₃.

In one or more embodiments, the first compound represented by Formula 1 may include at least one selected from among compounds in Compound Group 1.

In one or more embodiments of the present disclosure, a display device includes a base layer, a circuit layer on the base layer, and a display element layer on the circuit layer and including a light-emitting element, where the light-emitting element includes a first electrode, a second electrode facing the first electrode, and at least one functional layer between the first electrode and the second electrode, and the at least one functional layer includes (contains) a first compound represented by Formula 1.

In one or more embodiments, the light-emitting element may further include a capping layer on the second electrode, and the capping layer may have a refractive index of at least about 1.6 (or greater) for light in wavelength range of about 550 nanometer (nm) to about 660 nm.

In one or more embodiments, the display may further include a light control layer on the display element layer and including a quantum dot, where the light-emitting element may be to emit a first color light, and the light control layer may include a first light control part including (containing) a first quantum dot that converts the first color light into a second color light in a longer wavelength region than the first color light (e.g., a wavelength region of the second color light maybe longer than a wavelength region of the first color light), a second light control part including (containing) a second quantum dot that converts the first color light into a third color light in a longer wavelength region than the first color light and the second color light (e.g., a wavelength region of the third color light being longer than a wavelength region of the first color light and the wavelength region of the second color light), and a third light control part configured to transmit the first color light.

In one or more embodiments, the display device may further include a color filter layer on the light control layer, where the color filter layer may include a first filter configured to transmit the second color light, a second filter configured to transmit the third color light, and a third filter configured to transmit the first color light.

In one or more embodiments of the present disclosure, a hetero compound is represented by Formula 1.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1 is a plan view of a display device according to one or more embodiments of the present disclosure;

FIG. 2 is a cross-sectional view of a display device according to one or more embodiments of the present disclosure;

FIG. 3 is a cross-sectional view schematically illustrating a light-emitting element according to one or more embodiments of the present disclosure;

FIG. 4 is a cross-sectional view schematically illustrating a light-emitting element according to one or more embodiments of the present disclosure;

FIG. 5 is a cross-sectional view schematically illustrating a light-emitting element according to one or more embodiments of the present disclosure;

FIG. 6 is a cross-sectional view schematically illustrating a light-emitting element according to one or more embodiments of the present disclosure;

FIG. 7 and FIG. 8 are each independently a cross-sectional view of a display device according to one or more embodiments of the present disclosure;

FIG. 9 is a cross-sectional view illustrating a display device according to one or more embodiments of the present disclosure;

FIG. 10 is a cross-sectional view illustrating a display device according to one or more embodiments of the present disclosure; and

FIG. 11 is a view illustrating an inside of a vehicle in which a display device according to one or more embodiments is disposed.

FIG. 12 is a perspective view showing an electronic apparatus according to one or more embodiments;

FIG. 13 is an exploded perspective view showing an electronic apparatus according to one or more embodiments;

FIG. 14 is a block diagram of an electronic apparatus according to one or more embodiments;

FIG. 15 is a diagram showing an electronic apparatus according to one or more embodiments; and

FIG. 16 is a diagram showing an electronic apparatus according to one or more embodiments.

### DETAILED DESCRIPTION

Reference will now be made in more detail to embodiments, examples of which are illustrated in the accompanying drawings. Because the present disclosure may be modified in one or more suitable manners and have many forms, specific embodiments will be illustrated in the drawings and described in detail in the following detailed description. It should be understood, however, that it is not intended to limit the present disclosure to the particular forms disclosed, but rather, is intended to cover all modifications, equivalents, and alternatives falling within the spirit and scope of the present disclosure. Rather, these embodiments are provided so that this disclosure will be thorough and complete, and will fully convey the scope of the present disclosure to those skilled in the art. Accordingly, the embodiments are merely described herein, by referring to the figures, to explain aspects of example embodiments of the present description.

When explaining each of drawings, like reference numbers are used for referring to like elements. In the accompanying drawings, the dimensions of each structure are exaggeratingly illustrated for clarity of the present disclosure. It will be understood that, although the terms “first,” “second,” and/or the like, may be used herein to describe one or more suitable components, these components should not be limited by these terms. These terms are only used to distinguish one component from another. For example, a first component could be termed a second component, and, similarly, a second component could be termed a first component, without departing from the scope of example embodiments of the present disclosure.

As used herein, the singular forms, “a,” “an,” and “the” are intended to include the plural forms as well, unless the context clearly indicates otherwise.

In the present application, it will be understood that the terms “include,” “includes”, “including”, “have,” “has”, “having,” “comprise”, “comprises”, “comprising”, and/or the like, as used herein, specify the presence of features, numbers, steps, operations, component, parts, or combinations thereof disclosed in the specification, but do not exclude the possibility of presence or addition of one or more other features, numbers, steps, operations, component, parts, or combinations thereof.

In the present application, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “below”, “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be above the other part, or under the other part as well. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Throughout the disclosure, the expression “at least one of a, b or c” indicates: only a, only b, only c; both (e.g., simultaneously) a and b; both (e.g., simultaneously) a and c; both (e.g., simultaneously) b and c; all of a, b, and c; or variations thereof. The phrase “A and/or B” is used herein to select only A, select only B, or select both A and B. The phrase “at least one of A or B” is used to select only A, select only B, or select both A and B.

The term “and/or” includes all combinations of one or more components that may be defined by associated components.

Unless otherwise defined, all terms (including chemical, technical terms and scientific terms) used in the present specification have the same meaning as commonly understood by those skilled in the art to which the present disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

When a certain embodiment may be implemented differently, a specific process order may be different from the described order. For example, two consecutively described processes may be performed substantially at the same time or may be performed in an order opposite to the described order.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

As used herein, the phrase “consisting essentially of” indicates that any additional components will not materially affect the chemical, physical, optical or electrical properties of the semiconductor film.

### Definitions

In the specification, the term “substituted or unsubstituted” may refer to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified herein may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In some embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the embodiment of the present disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but the embodiment of the present disclosure is not limited thereto.

In the specification, a heterocycloalkyl group may refer to a cyclic hydrocarbon group including at least one heteroatom selected from N, O, P, and S as a ring-forming atom. The number of carbons in the heterocycloalkyl group is 3 to 30, 3 to 20, or 3 to 10. Examples of the heterocycloalkyl groups may include tetrahydrofuran, tetrahydrophenyl, and/or the like, but the embodiment of the present disclosure is not limited thereto.

In the specification, an alkenyl group means (refers to) a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but the embodiment of the present disclosure is not limited thereto.

In the specification, a cycloalkenyl group means (refers to) a cyclic alkenyl group having at least one carbon double bond in the ring but not having aromaticity. The number of carbons in the cycloalkenyl group is 3 to 30, 3 to 20, or 3 to 10. Examples of the cycloalkenyl group may include cyclopentenyl, cyclohexenyl, cycloheptenyl, and/or the like, but the embodiment of the present disclosure is not limited thereto.

In the specification, a heterocycloalkenyl group means (refers to) a cyclic alkenyl group including at least one heteroatom selected from N, O, P, and S as a ring-forming atom. The number of carbons in the heterocycloalkenyl group is 3 to 30, 3 to 20, or 3 to 10. Examples of the heterocycloalkenyl group may include a 2,3-dihydrofuran group, a 2,3-dihydrothiophene group, and/or the like, but the embodiment of the present disclosure is not limited thereto.

In the specification, an alkynyl group means (refers to) a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, and/or the like, but are not limited thereto.

In the specification, the hydrocarbon ring group means (refers to) any functional group or substituent derived from an aliphatic hydrocarbon ring. The hydrocarbon ring group may be a saturated hydrocarbon ring group having 5 to 20 ring-forming carbon atoms.

In the specification, an aryl group means (refers to) any functional group or substituent derived from an aromatic hydrocarbon ring. The aryl group may be a monocyclic aryl group or a polycyclic aryl group. The number of ring-forming carbon atoms in the aryl group may be 6 to 60, 6 to 50, 6 to 40, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

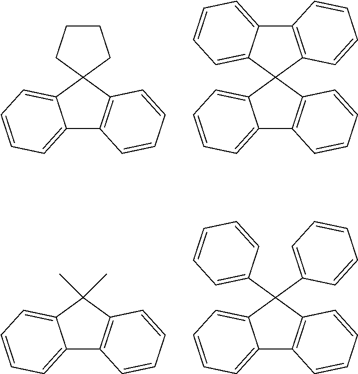

The heterocyclic group herein means (refers to) any functional group or substituent derived from a ring including (containing) at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may include (contain) at least one of B, O, N, P, Si or S as a heteroatom. If (e.g., when) the heterocyclic group includes (contains) two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 60, 2 to 50, 2 to 40, 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiment of the present disclosure is not limited thereto.

In the specification, the heteroaryl group may include (contain) at least one of B, O, N, P, Si, or S as a heteroatom. If (e.g., when) the heteroaryl group includes (contains) two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 50, 2 to 40, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but the embodiment of the present disclosure is not limited thereto.

In the specification, the preceding description of the aryl group may be applied to an arylene group except that the arylene group is a divalent group. The preceding description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but the embodiment of the present disclosure is not limited thereto.

In the specification, the germanium group includes an alkylgermanium group and an arylgermanium group. Examples of germanium group may include a trimethylgermanium group, triethylgermanium group, a t-butyldimethylgermanium group, a vinyldimethylgermanium group, a propyldimethylgermanium group, a triphenylgermanium group, a tribiphenylgermanium group, a diphenylgermanium group, a phenyl germanium group, and/or the like, but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

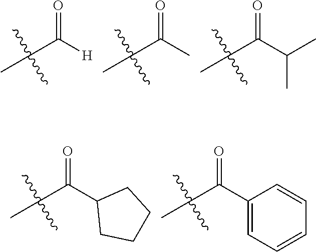

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined herein. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined herein. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but the embodiment of the present disclosure is not limited thereto.

The boron group herein may refer to that a boron atom is bonded to the alkyl group or the aryl group as defined herein. The boron group includes an alkyl boron group and an aryl boron group. Examples of the boron group may include a dimethylboron group, a trimethylboron group, a t-butyldimethylboron group, a diphenylboron group, a phenylboron group, and/or the like, but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, and/or the like, but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described herein.

In the specification, the aryl group among an aryloxy group, an arylthio group, an arylsulfoxy group, an arylamino group, an arylboron group, an arylsilyl group, an arylamine group is the same as the examples of the aryl group described herein.

In the specification, a direct linkage may refer to a single bond.

In the specification,

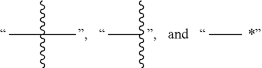

refer to a position to be connected.

Hereinafter, embodiments of the present disclosure will be described with reference to the accompanying drawings.

### Display Device

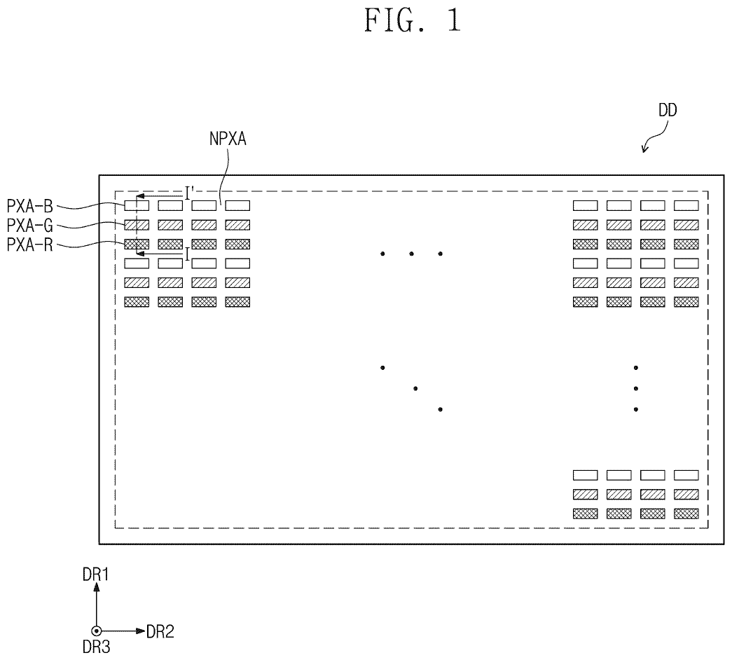

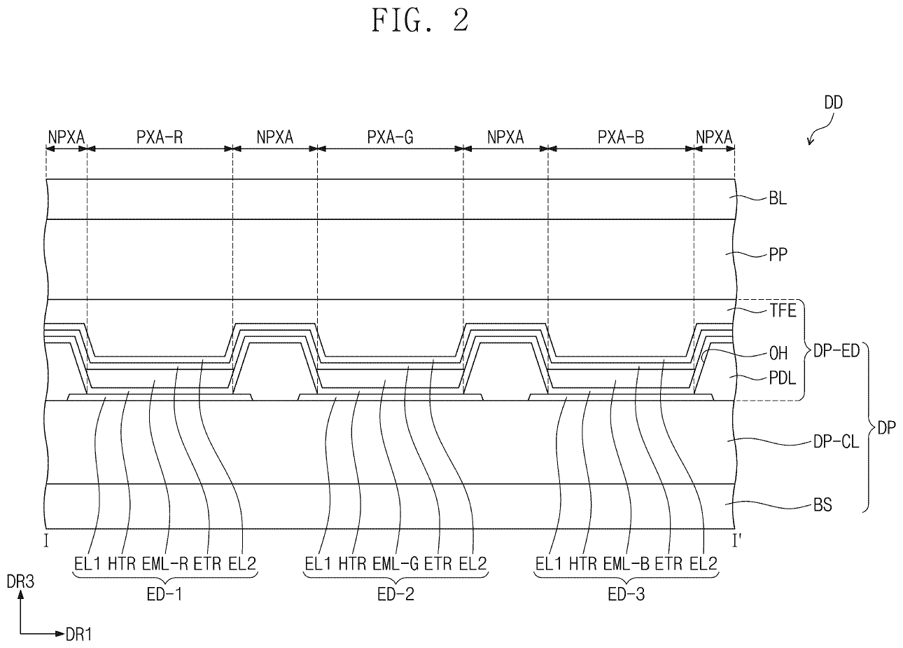

FIG. 1 is a plan view illustrating one or more embodiments of a display device DD. FIG. 2 is a cross-sectional view of the display device DD of the embodiment. FIG. 2 is a cross-sectional view illustrating a part taken along line I-I′ of FIG. 1.

The display device DD may include a display panel DP and an optical layer PP on the display panel DP. The display panel DP includes light emitting elements ED-1, ED-2, and ED-3. The display device DD may include a plurality of light emitting elements ED-1, ED-2, and ED-3. The optical layer PP may be on the display panel DP to control reflected light in the display panel DP due to external light. The optical layer PP may include, for example, a polarization layer or a color filter layer. Unlike the configuration illustrated in the drawing, the optical layer PP may not be included (be omitted) from the display device DD of one or more embodiments.

A base substrate BL may be on the optical layer PP. The base substrate BL may be a member which provides a base surface on which the optical layer PP arranged. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike the configuration illustrated, in one or more embodiments, the base substrate BL may not be included (be omitted).

The display device DD according to one or more embodiments may further include a filling layer. The filling layer (may be between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting elements ED-1, ED-2, and ED-3 between portions of the pixel defining film PDL, and an encapsulation layer TFE on the light emitting elements ED-1, ED-2, and ED-3.

The base layer BS may be a member which provides a base surface on which the display device layer DP-ED is arranged. The base layer BS may be a glass substrate, a metal substrate, a plastic substrate, and/or the like. However, the embodiment is not limited thereto, and the base layer BS may be an inorganic layer, an organic layer, or a composite material layer.

In one or more embodiments, the circuit layer DP-CL is on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display device layer DP-ED.

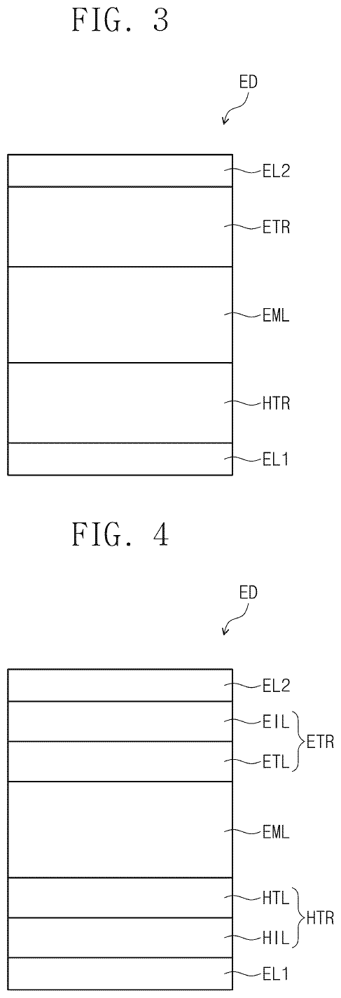

Each of the light emitting elements ED-1, ED-2, and ED-3 may have a structure of each light emitting element ED of embodiments according to FIGS. 3 to 6, which will be described in more detail elsewhere herein. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates one or more embodiments in which the emission layers EML-R, EML-G, and EML-B of the light emitting elements ED-1, ED-2, and ED-3 are in openings OH defined in the pixel defining film PDL, and the hole transport region HTR, the electron transport region ETR, and the second electrode EL2 are provided as a common layer in the entire light emitting elements ED-1, ED-2, and ED-3. However, the embodiment of the present disclosure is not limited thereto, and unlike the configuration illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in one or more embodiments may be provided by being patterned in an inkjet printing method.

The encapsulation layer TFE may cover the light emitting elements ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be on the second electrode EL2 and may be filling the opening OH.

Referring to FIGS. 1 and 2, the display device DD may include one or more non-light emitting region(s) NPXA and also include light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced and/or apart (e.g., spaced apart or separated) from each other on a plane (e.g., in a plan view).

Each of the light emitting regions PXA-R, PXA-G, and PXA-B may be a region divided (i.e., defined) by the pixel defining film PDL. The non-light emitting areas NPXA may be areas between the adjacent light emitting areas PXA-R, PXA-G, and PXA-B, which correspond to the pixel defining film PDL. In the specification, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3 may be in openings OH defined in the pixel defining film PDL and separated from each other.

The light emitting regions PXA-R, PXA-G, and PXA-B may be divided (i.e., defined) into a plurality of groups according to the color of light generated from the light emitting elements ED-1, ED-2, and ED-3. In the display device DD of one or more embodiments illustrated in FIGS. 1 and 2, three light emitting regions PXA-R, PXA-G, and PXA-B, which are to emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display device DD according to one or more embodiments, the plurality of light emitting elements ED-1, ED-2 and ED-3 may be to emit light beams having wavelengths different from each other. For example, in one or more embodiments, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, one or more embodiments of the present disclosure are not limited thereto, and the first to third light emitting elements ED-1, ED-2, and ED-3 may be to emit light beams in substantially the same wavelength range or at least one light emitting element may be to emit a light beam in a wavelength range different from the others. For example, the first to third light emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B each may be arranged along the second directional axis DR2. In some embodiments, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2.

An arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display device DD. For example, the arrangement form of the light emitting regions PXA-R, PXA-G, and PXA-B may be a PENTILE© arrangement form or a Diamond Pixel™ arrangement form, PENTILE© and Diamond Pixel^{T}M are registered trademarks owned by Samsung Display Co., Ltd.

In some embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but the embodiment of the present disclosure is not limited thereto.

Hereinafter, FIG. 3 to FIG. 6 are cross-sectional views schematically illustrating a light-emitting element according to one or more embodiments. The light-emitting element ED according to one or more embodiments may include a first electrode EL1, a second electrode EL2 facing the first electrode EL1, and at least one functional electrode between the first electrode EL1 and the second electrode EL2. The light-emitting element ED according to one or more embodiments may include a hetero compound according to one or more embodiments to be described later in the at least one functional layer.

The light-emitting element ED may include, as at least one functional layer, a hole transport region HTR, an emission layer EML, an electron transport region ETR, and/or the like, which are sequentially stacked. For example, the light-emitting element ED according to one or more embodiments may include a first electrode EL1, a hole transport region HTR, an emission layer EML, an electron transport region ETR, and a second electrode EL2, which are sequentially stacked.

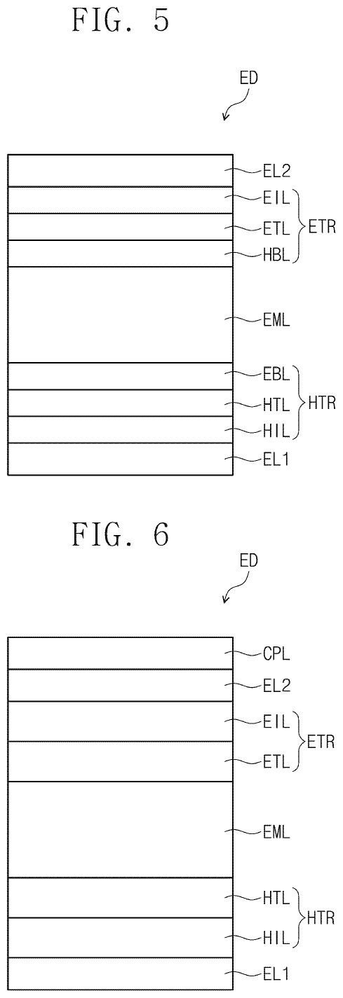

FIG. 4, compared to FIG. 3, illustrates a cross-sectional view of a light-emitting element ED in which the hole transport region HTR includes a hole injection layer HIL, and a hole transport layer HTL, and the electron transport region ETR includes an electron injection layer EIL and an electron transport layer ETL. In some embodiments, compared to FIG. 3, FIG. 5 illustrates a cross-sectional view of a light-emitting element ED in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. Compared to FIG. 4, FIG. 6 illustrates a cross-sectional view of a light-emitting element ED that includes a capping layer CPL on the second electrode EL2.

The light-emitting element ED may include (contain) a hetero compound according to one or more embodiments, to be described later, in at least one functional layer included in the light-emitting element ED. For example, an emission layer EML may include (contain) the hetero compound according to one or more embodiments, to be described later. However, one or more embodiments of the present disclosure is not limited thereto. In addition to the emission layer EML, the light-emitting element ED according to one or more embodiments may include (contain) the hetero compound according to one or more embodiments, to be described later, in the hole transport region HTR or the electron transport region ETR, which is one of a plurality of functional layers between the first electrode EL1 and the second electrode EL2, or may include (contain) the hetero compound according to one or more embodiments, to be described later, in the capping layer CPL on the second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

If (e.g., when) the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). If (e.g., when) the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). Alternatively, the first electrode EL1 may have a multilayer structure including a reflective film or a transflective film formed of the herein-described materials, and a transparent conductive film formed of ITO, IZO, ZnO, ITZO, and/or the like. For example, the first electrode EL1 may have a three-layer structure of ITO/Ag/ITO, but the embodiment of the present disclosure is not limited thereto. In some embodiments, the embodiment of the present disclosure is not limited thereto, and the first electrode EL1 may include the herein-described metal materials, combinations of at least two metal materials of the herein-described metal materials, oxides of the herein-described metal materials, and/or the like. The thickness of the first electrode EL1 may be from about 700 angstrom (Å) to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but the embodiment of the present disclosure is not limited thereto.

The hole transport region HTR may be formed using one or more suitable methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1:

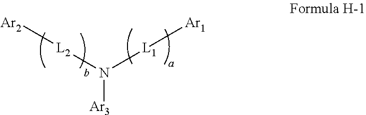

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. When a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. Alternatively, the compound represented by Formula H-2 may be a diamine compound in which at least one selected from among Ar₁ to Ar₃ includes the amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among the compounds in Compound Group H. However, the compounds listed in Compound Group H are examples, and the compounds represented by Formula H-1 are not limited to those represented by Compound Group H:

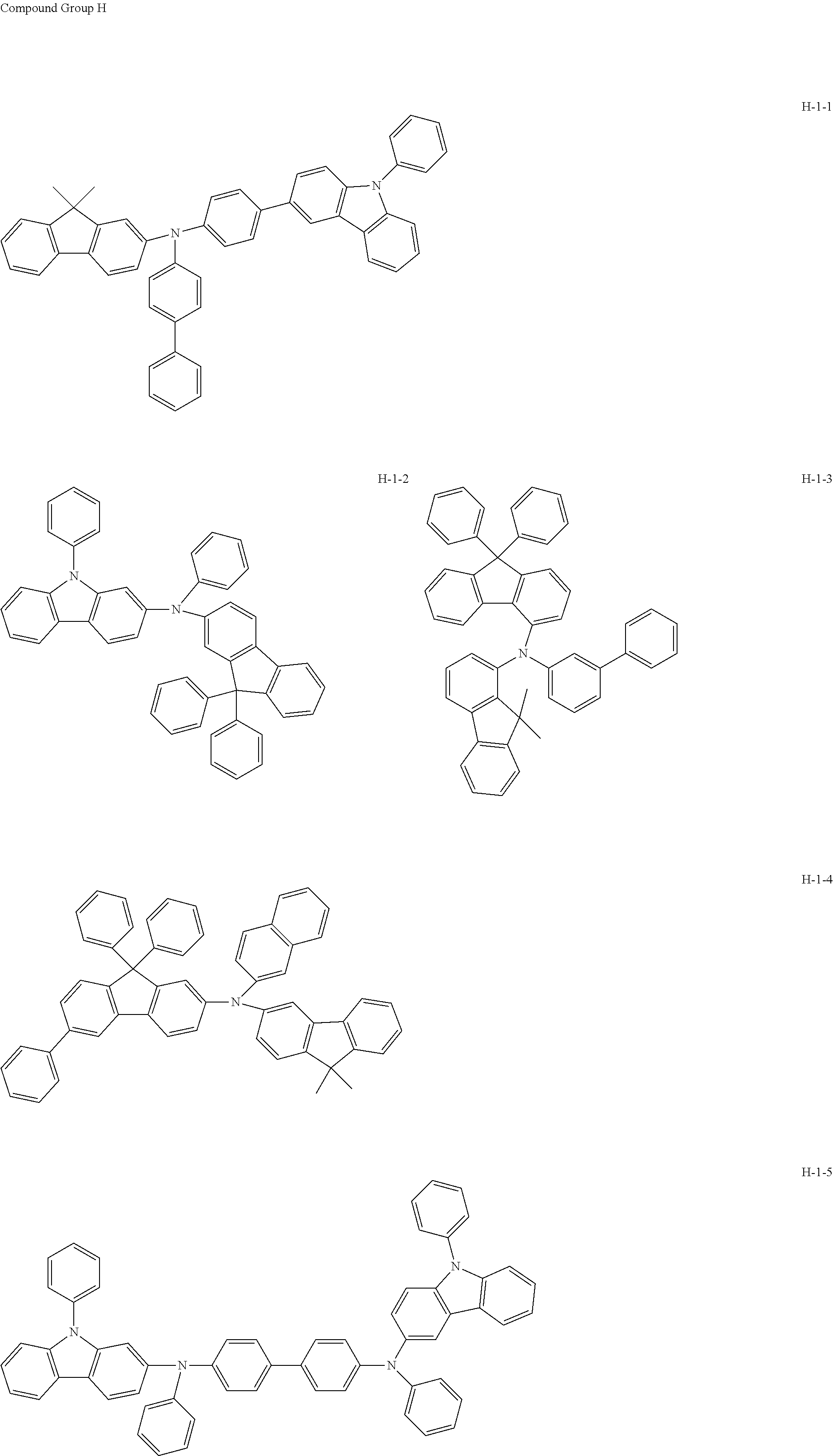 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

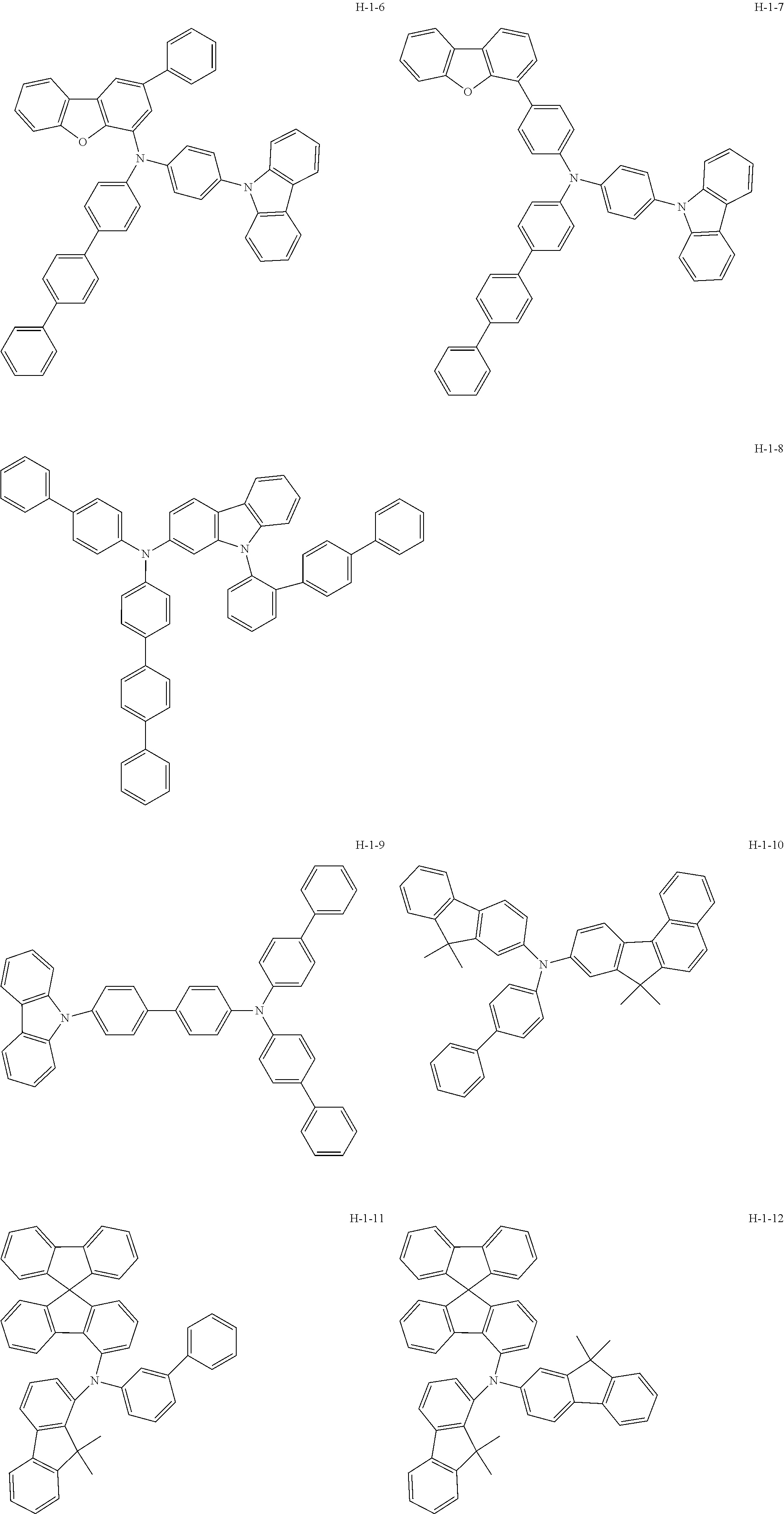

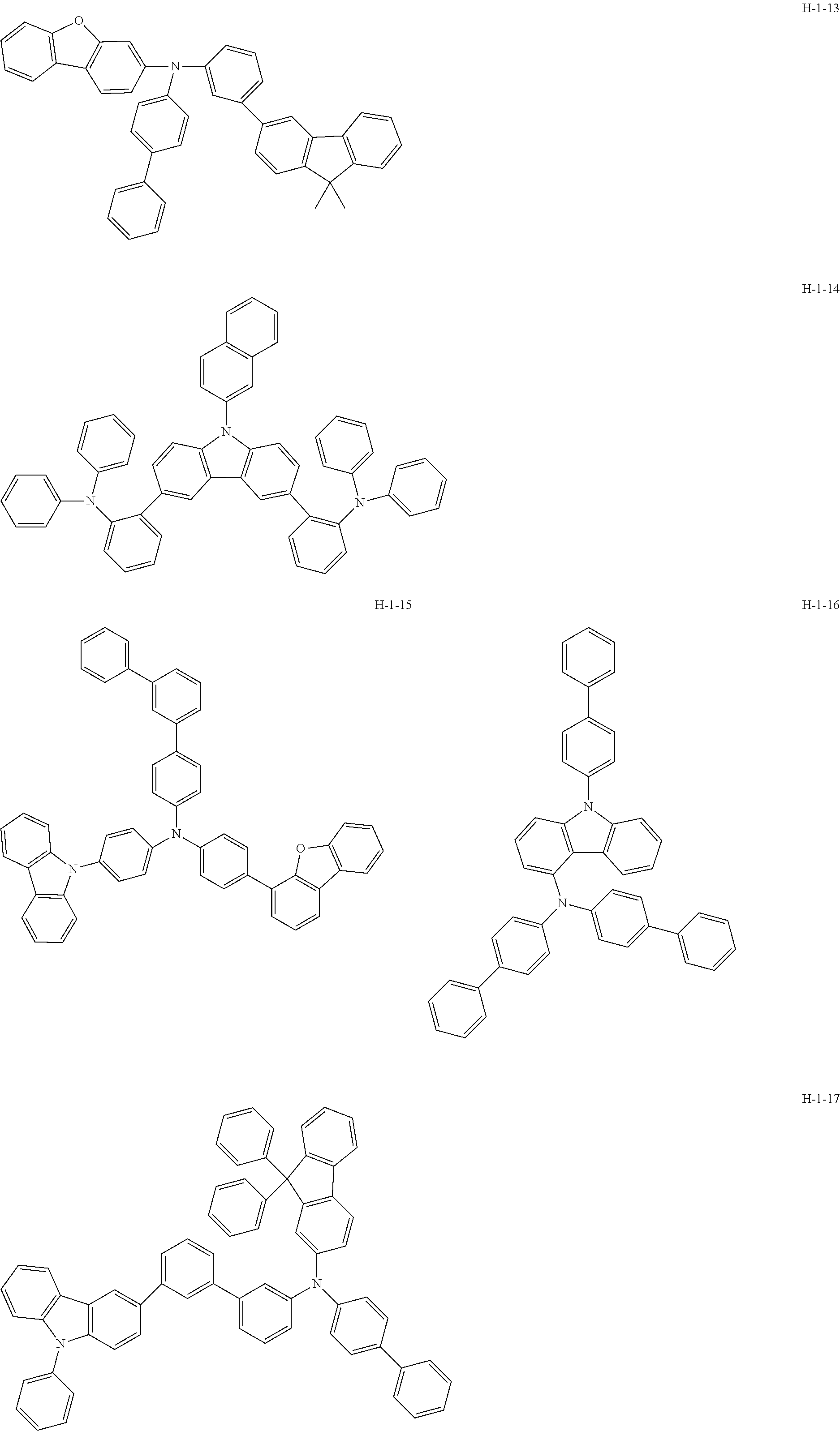 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

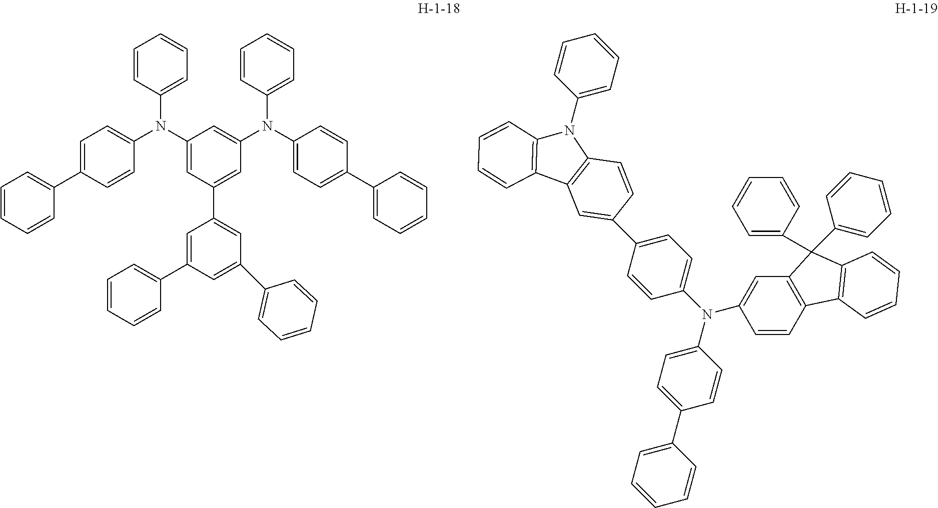 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

In one or more embodiments, the hole transport region HTR may include any one selected from among the compounds in Compound Group 4.

The hole transport region HTR may include the herein-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. If (e.g., when) the thicknesses of the hole transport region HTR, the hole injection layer HIL, the hole transport layer HTL and the electron blocking layer EBL satisfy the herein-described ranges, satisfactory hole transport properties may be achieved without a substantial increase in driving voltage.

The hole transport region HTR may further include a charge generating material to increase conductivity in addition to the herein-described materials. The charge generating material may be dispersed uniformly (e.g., substantially uniformly) or non-uniformly (e.g., substantially non-uniformly) in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but the embodiment of the present disclosure is not limited thereto.

As described herein, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be used as a material to be included in the buffer layer. The electron blocking layer EBL is a layer that serves to prevent the electron injection from the electron transport region ETR to the hole transport region HTR.

The emission layer EML is provided on the hole transport region HTR. The emission layer EML may have a thickness of, for example, about 100 Å to about 1000 Å or about 100 Å to about 300 Å. The emission layer EML may have a single layer formed using a single material, a single layer formed using a plurality of different materials, or may have a multi-layered structure having a plurality of layers formed using a plurality of different materials.

### Hetero Compound

The light-emitting element ED according to one or more embodiments may include a hetero compound represented by Formula 1 in at least one functional layer between a first electrode EL1 and a second electrode EL2. In the light-emitting element ED according to one or more embodiments, the emission layer EML may include a hetero compound according to one or more embodiments. In one or more embodiments, the emission layer EML may include the hetero compound according to one or more embodiments as a host. The hetero compound according to one or more embodiments may be a host material for the emission layer EML. In the present specification, the hetero compound according to one or more embodiments may be referred to as a first compound.

The hetero compound according to one or more embodiments includes first and second silicon atoms, each substituted with three aromatic rings, a first linker linking the first silicon atom and the second silicon atom, and a second linker linking any one selected from among the three aromatic rings connected to the first silicon atom and any one selected from among the three aromatic rings connected to the second silicon atom. In the hetero compound according to one or more embodiments, the first silicon atom may be substituted with a first aromatic ring, a second aromatic ring, and a third aromatic ring, and the second silicon atom may be substituted with a fourth aromatic ring, a fifth aromatic ring, and a sixth aromatic ring. The first linker may connect the first silicon atom with the second silicon atom, and the second linker may connect the first aromatic ring connected to the first silicon atom with the fourth aromatic ring connected to the second silicon atom. The hetero compound according to one or more embodiments may have a cyclic structure in which the first and second silicon atoms, the first linker linking the first and second silicon atoms, and the second linker linking the first aromatic ring connected to the first silicon atom with the fourth aromatic ring connected to the second silicon atom, are connected to each other.

The first linker may be bonded (bind) to each of the first silicon atom and the second silicon atom to connect the first silicon atom with the second silicon atom. The first linker may be between the first silicon atom and the second silicon atom. In one or more embodiments, the first linker may be a substituted or unsubstituted six-membered aromatic hydrocarbon ring, or a substituted or unsubstituted six-membered aromatic heterocycle including (containing) N as a ring-forming atom. For example, the first linker may be a substituted or unsubstituted benzene ring, a substituted or unsubstituted pyrazine ring, a substituted or unsubstituted pyridine ring, a substituted or unsubstituted 1,3,5-triazine ring, or a substituted or unsubstituted pyrimidine ring.

The second linker may be connected to each of the first aromatic ring among the aromatic rings connected to the first silicon atom, and the fourth aromatic ring among the aromatic rings connected to the second silicon atom, to thereby connect the first aromatic ring with the fourth aromatic ring. The first aromatic ring and the fourth aromatic ring may be connected to each other via the second linker. In the present specification, the first aromatic ring and the fourth aromatic ring connected by the second linker may be referred to as a “connected ring”. In one or more embodiments, the second linker may be a nitrogen (N) atom, or oxygen (O) atom.

The second linker may be connected at a meta position with respect to each of the first and second silicon atoms. For example, the second linker may be connected to a meta-positioned carbon atom, among carbon atoms constituting the first aromatic ring, with respect to the first silicon atom and a meta-positioned carbon atom, among carbon atoms constituting the second aromatic ring, with respect to the second silicon atom.

In the hetero compound according to one or more embodiments, the first aromatic ring and the fourth aromatic ring may be each independently a substituted or unsubstituted 6-membered aromatic hydrocarbon ring, or a substituted or unsubstituted 6-membered aromatic heterocycle including (containing) N as a ring-forming atom. For example, the first aromatic ring and the fourth aromatic ring may be each independently a substituted or unsubstituted benzene ring, or a substituted or unsubstituted pyridine ring.

In the hetero compound according to one or more embodiments, the remaining aromatic rings other than the herein-described connected rings among the first to sixth aromatic rings may be each independently a substituted or unsubstituted 6-membered aromatic hydrocarbon ring. For example, the second aromatic ring, each of the third aromatic ring, the fifth aromatic ring, and the sixth aromatic ring may be a substituted or unsubstituted benzene ring.

The hetero compound according to one or more embodiments may have a cyclic structure in which the first and second silicon atoms each connected to three aromatic rings, the first linker linking the first and second silicon atoms, and the second linker linking any one selected from among the aromatic rings connected to the first silicon atom with any one selected from among the aromatic rings connected to the second silicon atom, are connected to each other. The hetero compound according to one or more embodiments may have a sterically bulky structure due to characteristics of a steric shape of the hetero compound according to one or more embodiments. The hetero compound according to one or more embodiments may be prevented from interacting with other compounds due to the bulky steric structure.

For example, the hetero compound according to one or more embodiments may include a hetero aromatic ring in which two silyl groups bind to each other via two linkers, thereby forming a ring. Such a hetero compound according to one or more embodiments may have high steric hindrance properties to adjacent compound molecules, compared to a compound forming no ring, due to a cyclic structure. Therefore, compared to the other compounds including two connected silyl groups that form no ring, the hetero compound according to one or more embodiments may have reduced interactions with the adjacent compound molecules.

The hetero compound according to one or more embodiments may be represented by Formula 1.

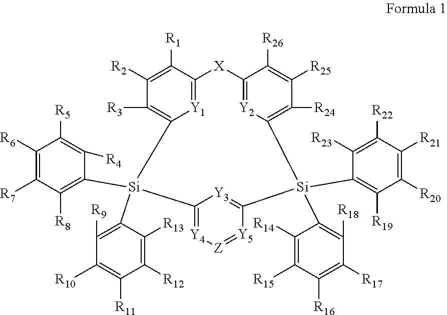

The hetero compound according to one or more embodiments, represented by Formula 1, includes a cyclic structure in which first and second silicon atoms each connected to three aromatic rings, a first linker linking the first and second silicon atoms, and a second linker linking any one selected from among the aromatic rings connected to the first silicon atom to any one selected from among the aromatic rings connected to the second silicon atom, are connected to each other.

In the present specification, in Formula 1, an aromatic ring substituted with a substituent represented by R₁ to R₃ may correspond to the herein-described first aromatic ring, and an aromatic ring substituted with a substituent represented by R₄ to R₈ and an aromatic ring substituted with a substituent represented by R₉ to R₁₃ may respectively correspond to the herein-described second and third aromatic ring. In some embodiments, in Formula 1, an aromatic ring substituted with a substituent represented by R₂₄ to R₂₆ may correspond to the herein-described fourth aromatic ring, and an aromatic ring substituted with a substituent represented by R₁₉ to R₂₃ and an aromatic ring substituted with a substituent represented by R₁₄ to R₁₈ may respectively correspond to the herein-described fifth and sixth aromatic ring. In some embodiments, in Formula 1, an aromatic ring substituted with a substituent represented by Z, and Y₃ to Y₅ may correspond to the herein-described first linker.

In Formula 1, X may be NAr₁ or O. Herein, N or O may correspond to the herein-described second linker.

In Formula 1, Z may be CR₂₇ or N.

In Formula 1, Y₁ to Y₅ may each independently be CR₂₈ or N. For example, Y₁ to Y₅ may each independently be CR₂₈. Alternatively, at least one selected from among Y₁ to Y₅ may be N, and the rest may each independently be CR₂₈. If (e.g., when) all Y₃ to Y₅ are N, Z may be CR₂₇.

In Formula 1, Ar₁ may be a substituted or unsubstituted aryl group having 6 to 30 ring-forming carbons, or a substituted or unsubstituted heteroaryl group having 2 to 30 ring-forming carbons. Alternatively, Ar₁ may be bonded (bind) to an adjacent group to form a ring. In one or more embodiments, Ar₁ may be a substituted or unsubstituted aryl group having 6 to 30 ring-forming carbons. For example, Ar₁ may be a substituted or unsubstituted phenyl group.

In Formula 1, R₁ to R₂₈ may each independently be a hydrogen atom, a deuterium atom, a cyano group, a substituted or unsubstituted silyl group, a substituted or unsubstituted alkyl group having 1 to 20 carbons, a substituted or unsubstituted cycloalkyl group having 3 to 20 ring-forming carbons, a substituted or unsubstituted hetero cycloalkyl group having 3 to 20 ring-forming carbons, a substituted or unsubstituted alkenyl group having 2 to 20 carbons, a substituted or unsubstituted cycloalkenyl group having 3 to 20 ring-forming carbons, a substituted or unsubstituted hetero cycloalkenyl group having 3 to 20 ring-forming carbons, a substituted or unsubstituted aryl group having 6 to 30 ring-forming carbons, or a substituted or unsubstituted heteroaryl group having 2 to 30 ring-forming carbons. Alternatively, R₁ to R₂₈ may each independently be bonded (bind) to an adjacent group to form a ring. For example, in Formula 1, at least one pair among R₈ and R₉ and R₁₈ and R₁₉ may be bonded (bind) to each other to form a ring. Alternatively, in Formula 1, X may be NAr₁, and in Formula 1, at least one selected from among R₁ and R₂₆ may be bonded (bind) to Ar₁ to form a ring.

In one or more embodiments, R₁ to R₂₈ may be each independently a hydrogen atom, a deuterium atom, a substituted or unsubstituted aryl group having 6 to 30 ring-forming carbons, or a substituted or unsubstituted heteroaryl group having 2 to 30 ring-forming carbons. For example, R₁ to R₂₈ may be each independently a hydrogen atom, a deuterium atom, a substituted or unsubstituted phenyl group, a substituted or unsubstituted biphenyl group, or a substituted or unsubstituted carbazole group.

In one or more embodiments, the first compound represented by Formula 1 may be represented by any one of Formula 1-1 or Formula 1-2.

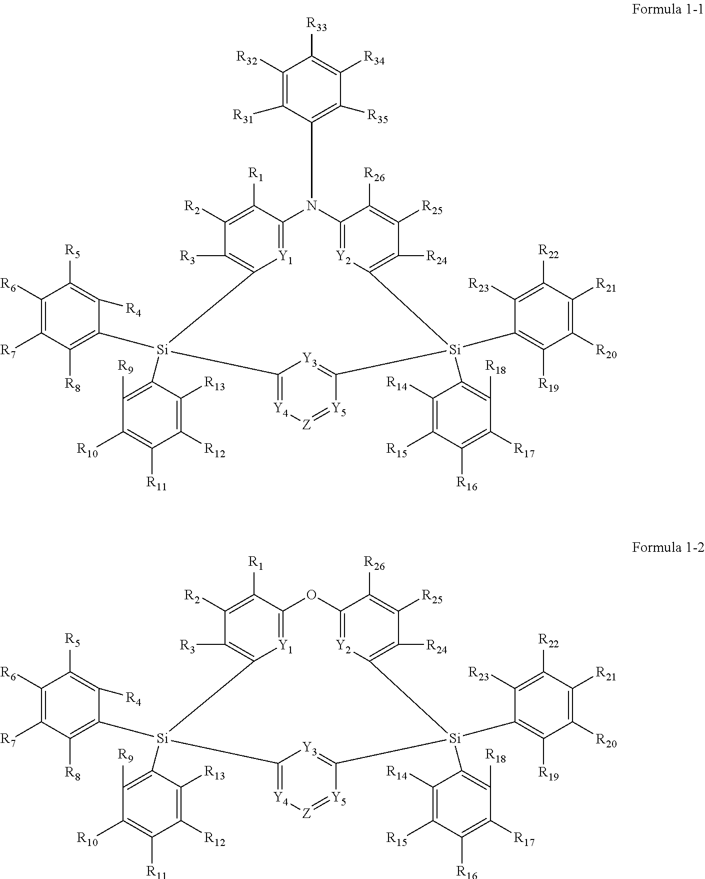

Formula 1-1 and Formula 1-2 each represent a case where a type (kind) of X is specified in Formula 1.

In Formula 1-1, R₃₁ to R₃₅ may each independently be a hydrogen atom, a deuterium atom, a cyano group, a substituted or unsubstituted silyl group, a substituted or unsubstituted alkyl group having 1 to 20 carbons, a substituted or unsubstituted cycloalkyl group having 3 to 20 ring-forming carbons, a substituted or unsubstituted hetero cycloalkyl group having 3 to 20 ring-forming carbons, a substituted or unsubstituted alkenyl group having 2 to 20 carbons, a substituted or unsubstituted cycloalkenyl group having 3 to 20 ring-forming carbons, a substituted or unsubstituted hetero cycloalkenyl group having 3 to 20 ring-forming carbons, a substituted or unsubstituted aryl group having 6 to 30 ring-forming carbons, or a substituted or unsubstituted heteroaryl group having 2 to 30 ring-forming carbons. Alternatively, each of R₃₁ to R₃₅ may be bonded (bind) to an adjacent group to form a ring. For example, in Formula 1-1, at least one pair among R₁ and R₃₁, and R₂₆ and R₃₅ may be bonded (bind) to each other to form a ring.

In one or more embodiments, R₃₁ to R₃₅ may each independently be a hydrogen atom, a deuterium atom, or a substituted or unsubstituted carbazole group.

In Formula 1-1 and Formula 1-2, the descriptions explained in Formula 1 may be similarly applied for Z, Y₁ to Y₅, and R₁ to R₂₆.

In one or more embodiments, the first compound represented by Formula 1 may be represented by Formula 2-1 or Formula 2-2.

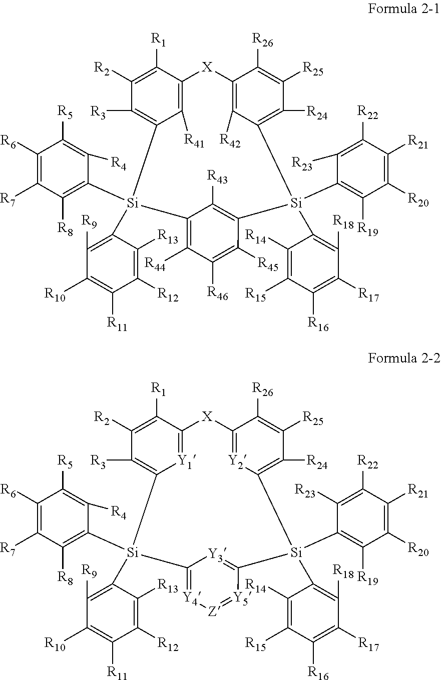

Formula 2-1 and Formula 2-2 represent cases where types (kinds) of Z and Y₁ to Y₅ are specified in Formula 1.

In Formula 2-1, R₄₁ to R₄₆ may each independently be a hydrogen atom, a deuterium atom, or a substituted or unsubstituted carbazole group.

In Formula 2-2, at least any one selected from among Y₁′ to Y₅′, and Z′ may be N, and the rest (any remaining Y₁′ to Y₅′, and Z′) may each independently be CR₄₇.

In Formula 2-2, R₄₇ may be a hydrogen atom, or a deuterium atom.

In Formula 2-1 and Formula 2-2, the descriptions explained in Formula 1 may be similarly applied for X, and R₁ to R₂₆.

The first compound represented by Formula 1 may be represented by any one of Formula 3-1 to Formula 3-3.

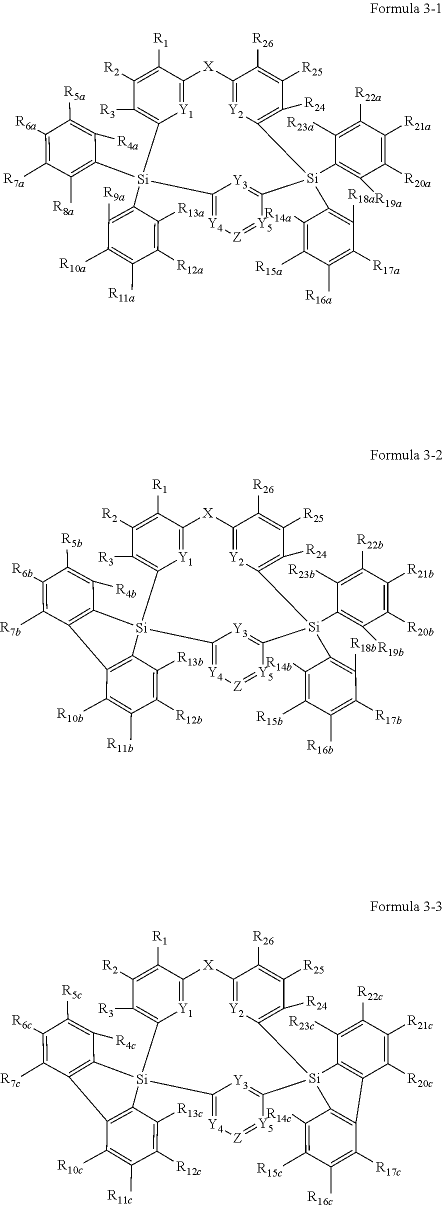

Formula 3-1, R₄ₐ to R₂₃ₐ may each independently be a hydrogen atom, a deuterium atom, or a substituted or unsubstituted carbazole group.

In Formula 3-2, R_{4b} to R_{7b}, R_{10b} to R_{13b}, and R_{14b} to R_{23b} may each independently be a hydrogen atom, a deuterium atom, or a substituted or unsubstituted carbazole group.

In Formula 3-3, R_{4c} to R_{7c}, R_{10c} to R_{13c}, R_{14c} to R_{17c}, and R_{20c} to R_{23c} may each independently be a hydrogen atom, a deuterium atom, or a substituted or unsubstituted carbazole group.

In Formula 3-1 to Formula 3-3, the descriptions explained in Formula 1 may be similarly applied for X, Z, Y₁ to Y₅, R₁ to R₃, and R₂₄ to R₂₆.

In one or more embodiments, the first compound represented by Formula 1 may be represented by any one selected from among Formula 4-1 to Formula 4-3.

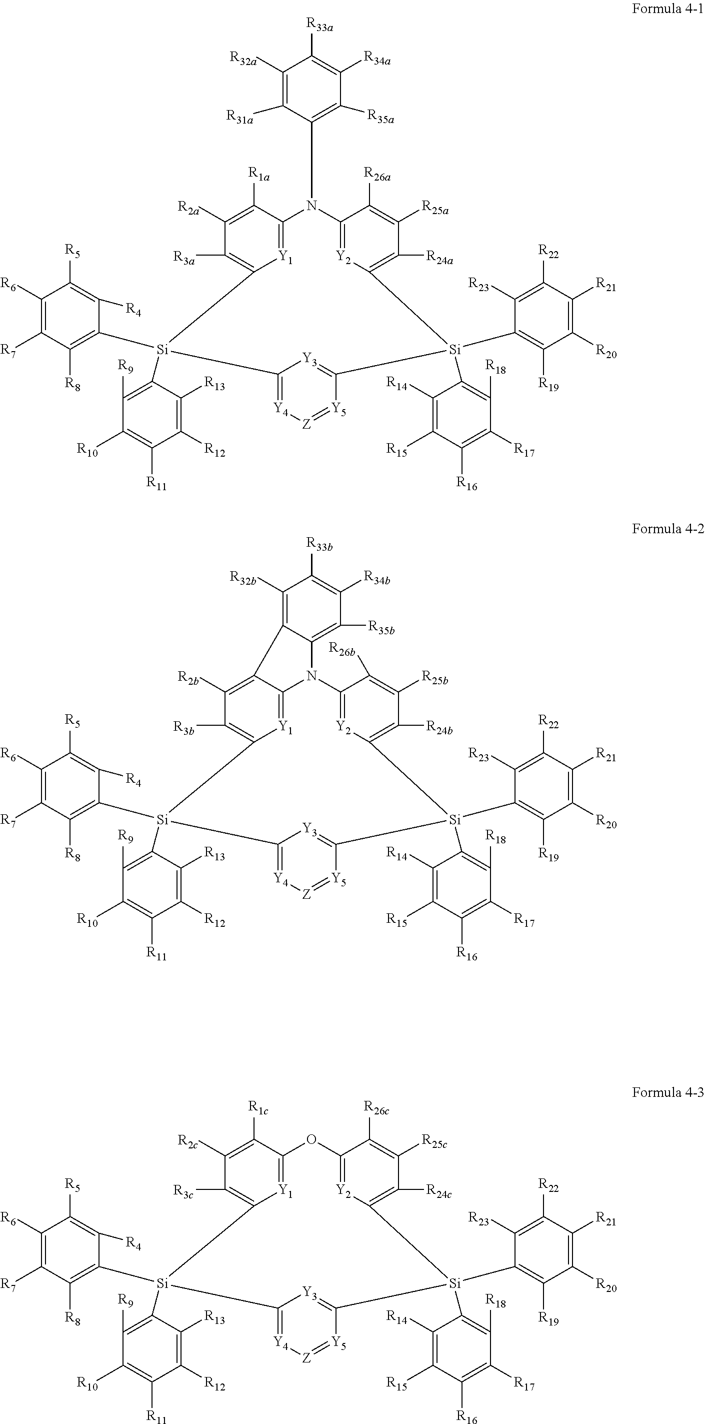

In Formula 4-1, R₁ₐ to R₃ₐ, R₂₄ₐ to R₂₆ₐ, and R₃₁ₐ to R₃₅ₐ may each independently be a hydrogen atom, a deuterium atom, or a substituted or unsubstituted carbazole group.

In Formula 4-2, R_{2b}, R_{3b}, R_{24b} to R_{26b}, and R_{32b} to R_{35b} may each independently be a hydrogen atom, a deuterium atom, or a substituted or unsubstituted carbazole group.

In Formula 4-3, R_{1c} to R_{3c}, and R_{24c} to R_{26c} may each independently be a hydrogen atom, a deuterium atom, or a substituted or unsubstituted carbazole group.

In Formula 4-1 to Formula 4-3, the descriptions explained in Formula 1 may be similarly applied for Z, Y₁ to Y₅, and R₄ to R₂₃.

In one or more embodiments, the hetero compound according to one or more embodiments, represented by Formula 1 may include at least one deuterium atom as a substituent. The hetero compound according to one or more embodiments, represented by Formula 1 may include a structure in which at least one hydrogen atom is substituted with a deuterium atom.

The hetero compound according to one or more embodiments may be any one selected from among compounds present in Compound Group 1. At least one functional layer included in the light-emitting element ED according to one or more embodiments may include (contain) at least one hetero compound selected from among the compounds present in Compound Group 1. The light-emitting element ED according to one or more embodiments may include (contain), in an emission layer EML, at least one hetero compound selected from among the compounds present in Compound Group 1. Alternatively, the light-emitting element ED according to one or more embodiments may include (contain), in an electron transport region ETR, at least one hetero compound selected from among the compounds present in Compound Group 1.

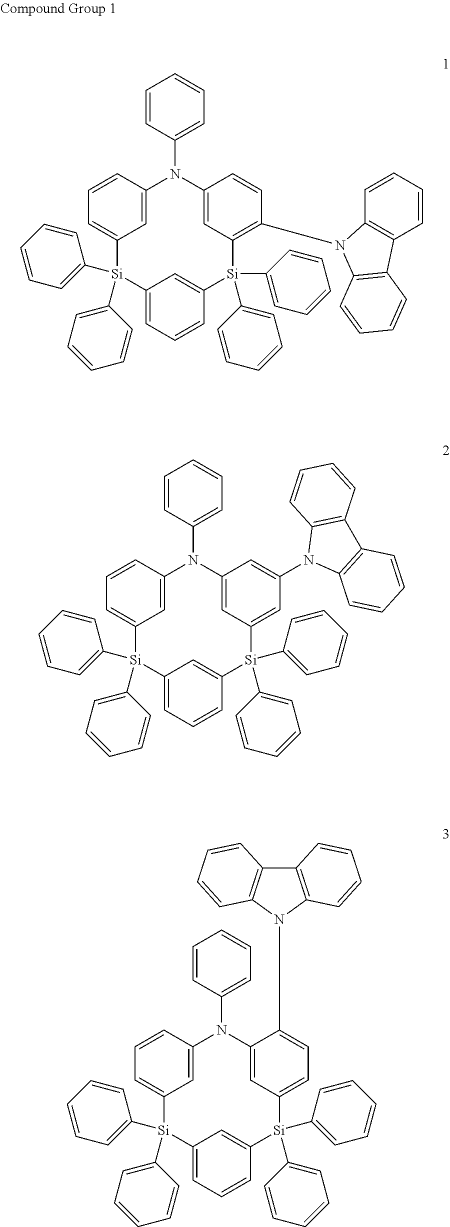 [SMILES: c1ccc(N2c3cccc(c3)[Si](c3ccccc3)(c3ccccc3)c3cccc(c3)[Si](c3ccccc3)(c3ccccc3)c3cc2ccc3-n2c3ccccc3c3ccccc32)cc1 ; c1ccc(N2c3cccc(c3)[Si](c3ccccc3)(c3ccccc3)c3cccc(c3)[Si](c3ccccc3)(c3ccccc3)c3cc2cc(-n2c4ccccc4c4ccccc42)c3)cc1 ; c1ccc(N2c3cccc(c3)[Si](c3ccccc3)(c3ccccc3)c3cccc(c3)[Si](c3ccccc3)(c3ccccc3)c3ccc(-n4c5ccccc5c5ccccc54)c2c3)cc1]

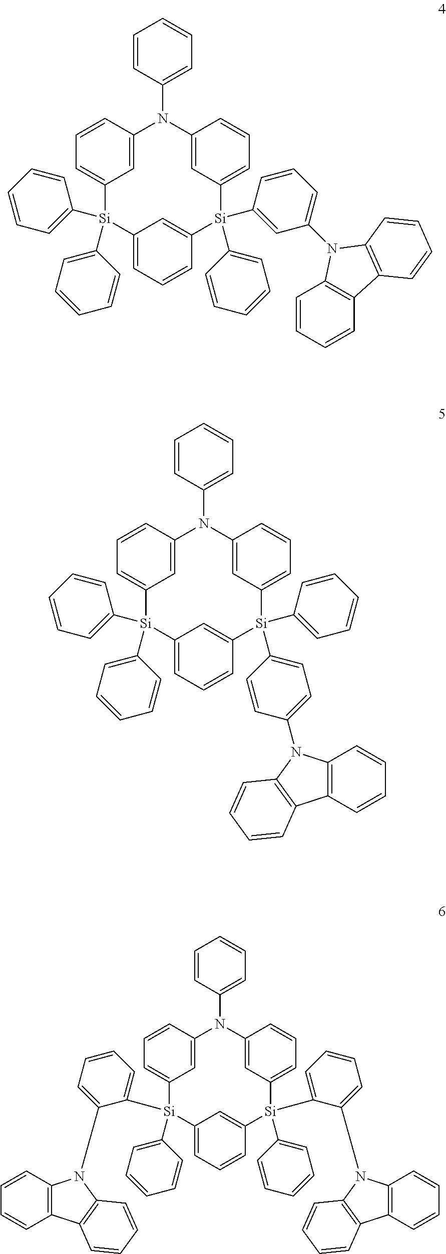 [SMILES: c1ccc(N2c3cccc(c3)[Si](c3ccccc3)(c3ccccc3)c3cccc(c3)[Si](c3ccccc3)(c3cccc(-n4c5ccccc5c5ccccc54)c3)c3cccc2c3)cc1 ; c1ccc(N2c3cccc(c3)[Si](c3ccccc3)(c3ccccc3)c3cccc(c3)[Si](c3ccccc3)(c3ccc(-n4c5ccccc5c5ccccc54)cc3)c3cccc2c3)cc1 ; c1ccc(N2c3cccc(c3)[Si](c3ccccc3)(c3ccccc3-n3c4ccccc4c4ccccc43)c3cccc(c3)[Si](c3ccccc3)(c3ccccc3-n3c4ccccc4c4ccccc43)c3cccc2c3)cc1]

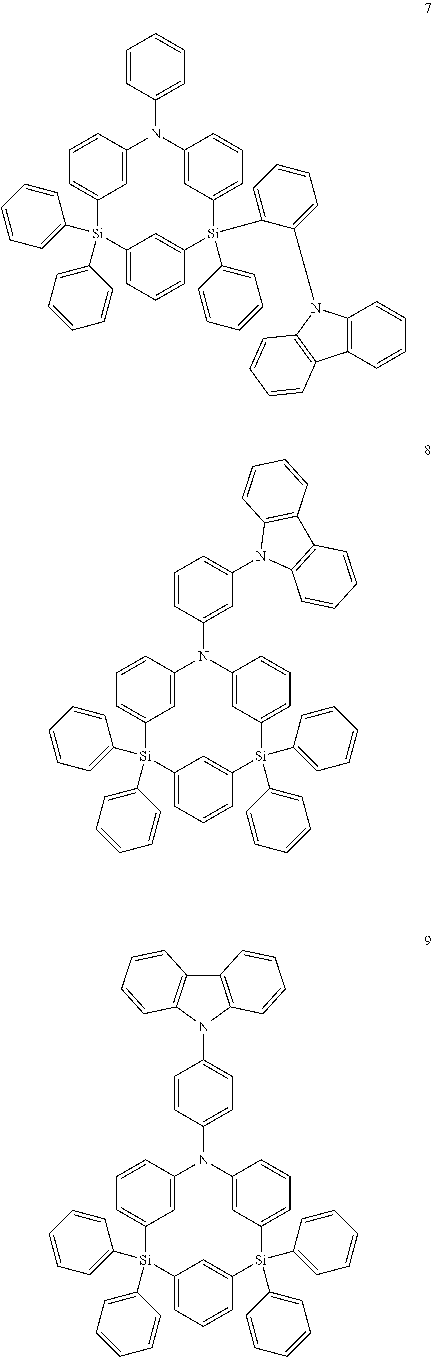 [SMILES: c1ccc(N2c3cccc(c3)[Si](c3ccccc3)(c3ccccc3)c3cccc(c3)[Si](c3ccccc3)(c3ccccc3-n3c4ccccc4c4ccccc43)c3cccc2c3)cc1 ; c1ccc([Si]2(c3ccccc3)c3cccc(c3)N(c3cccc(-n4c5ccccc5c5ccccc54)c3)c3cccc(c3)[Si](c3ccccc3)(c3ccccc3)c3cccc2c3)cc1 ; c1ccc([Si]2(c3ccccc3)c3cccc(c3)N(c3ccc(-n4c5ccccc5c5ccccc54)cc3)c3cccc(c3)[Si](c3ccccc3)(c3ccccc3)c3cccc2c3)cc1]

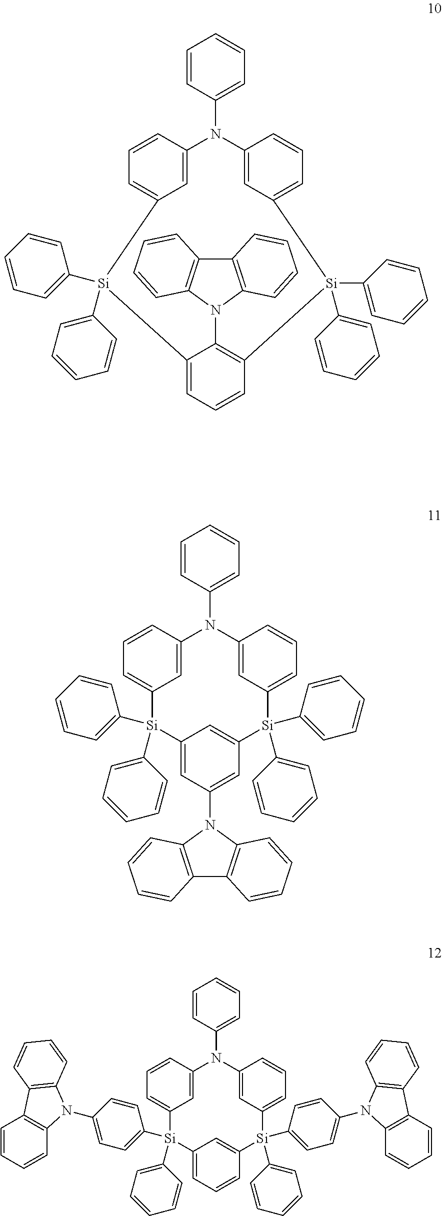 [SMILES: c1ccc(N2c3cccc(c3)[Si](c3ccccc3)(c3ccccc3)c3cccc(c3-n3c4ccccc4c4ccccc43)[Si](c3ccccc3)(c3ccccc3)c3cccc2c3)cc1 ; c1ccc(N2c3cccc(c3)[Si](c3ccccc3)(c3ccccc3)c3cc(-n4c5ccccc5c5ccccc54)cc(c3)[Si](c3ccccc3)(c3ccccc3)c3cccc2c3)cc1 ; c1ccc(N2c3cccc(c3)[Si](c3ccccc3)(c3ccc(-n4c5ccccc5c5ccccc54)cc3)c3cccc(c3)[Si](c3ccccc3)(c3ccc(-n4c5ccccc5c5ccccc54)cc3)c3cccc2c3)cc1]

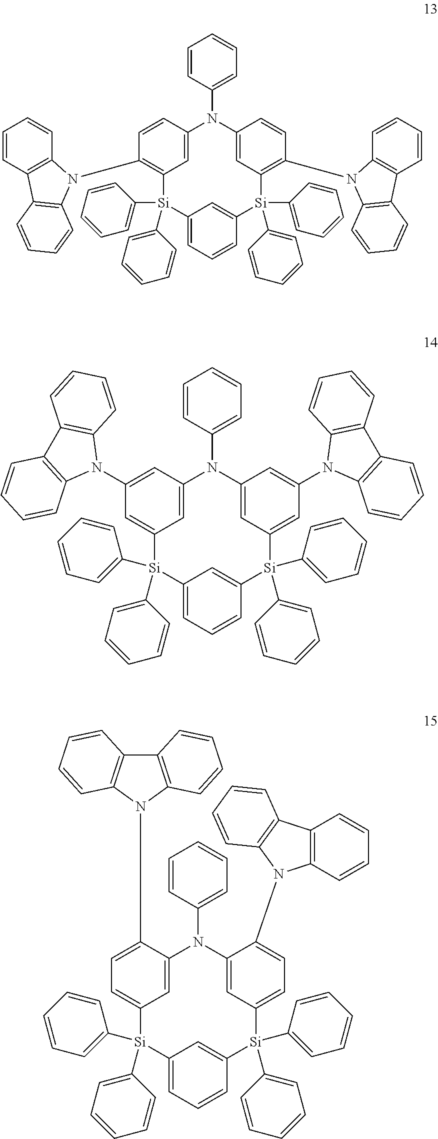 [SMILES: c1ccc(N2c3ccc(-n4c5ccccc5c5ccccc54)c(c3)[Si](c3ccccc3)(c3ccccc3)c3cccc(c3)[Si](c3ccccc3)(c3ccccc3)c3cc2ccc3-n2c3ccccc3c3ccccc32)cc1 ; c1ccc(N2c3cc(-n4c5ccccc5c5ccccc54)cc(c3)[Si](c3ccccc3)(c3ccccc3)c3cccc(c3)[Si](c3ccccc3)(c3ccccc3)c3cc2cc(-n2c4ccccc4c4ccccc42)c3)cc1 ; c1ccc(N2c3cc(ccc3-n3c4ccccc4c4ccccc43)[Si](c3ccccc3)(c3ccccc3)c3cccc(c3)[Si](c3ccccc3)(c3ccccc3)c3ccc(-n4c5ccccc5c5ccccc54)c2c3)cc1]

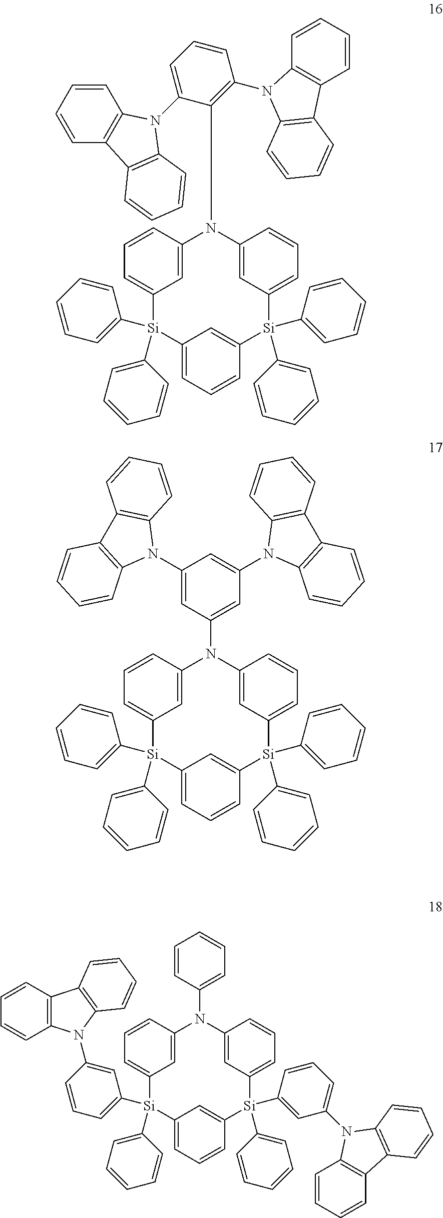

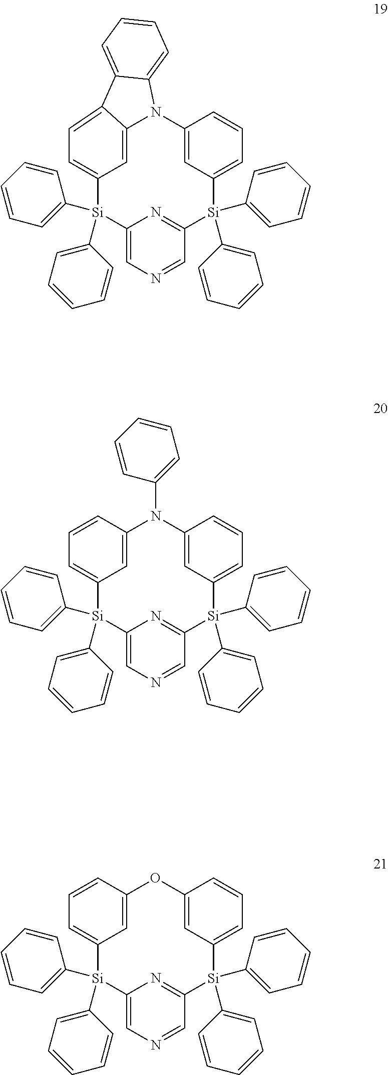 [SMILES: c1ccc([Si]2(c3ccccc3)c3cccc(c3)-n3c4ccccc4c4ccc(cc43)[Si](c3ccccc3)(c3ccccc3)c3cncc2n3)cc1 ; c1ccc(N2c3cccc(c3)[Si](c3ccccc3)(c3ccccc3)c3cncc(n3)[Si](c3ccccc3)(c3ccccc3)c3cccc2c3)cc1 ; c1ccc([Si]2(c3ccccc3)c3cccc(c3)Oc3cccc(c3)[Si](c3ccccc3)(c3ccccc3)c3cncc2n3)cc1]

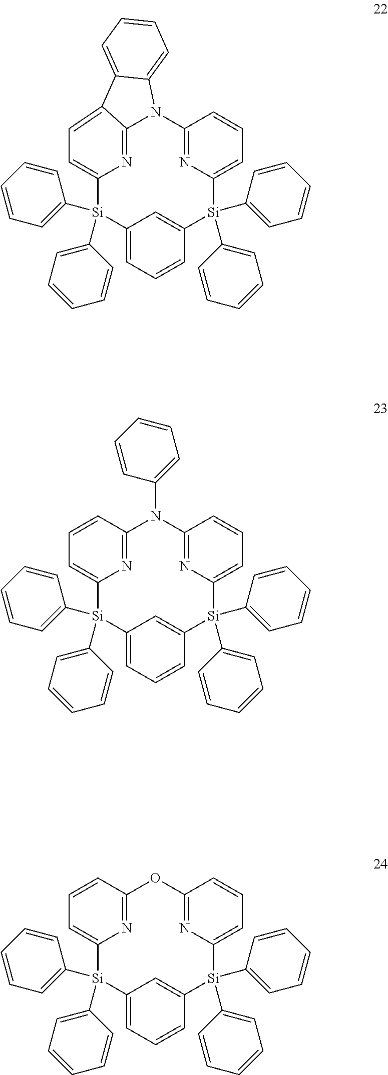 [SMILES: c1ccc([Si]2(c3ccccc3)c3cccc(c3)[Si](c3ccccc3)(c3ccccc3)c3ccc4c5ccccc5n(c4n3)-c3cccc2n3)cc1 ; c1ccc(N2c3cccc(n3)[Si](c3ccccc3)(c3ccccc3)c3cccc(c3)[Si](c3ccccc3)(c3ccccc3)c3cccc2n3)cc1 ; c1ccc([Si]2(c3ccccc3)c3cccc(c3)[Si](c3ccccc3)(c3ccccc3)c3cccc(n3)Oc3cccc2n3)cc1]

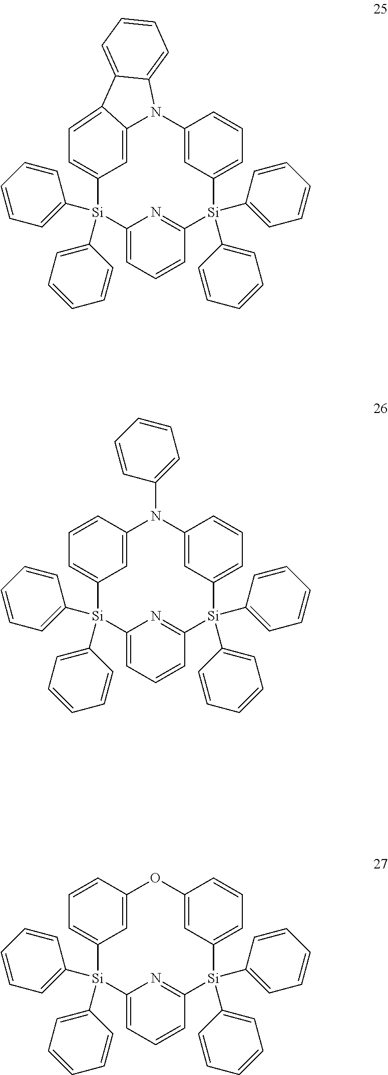 [SMILES: c1ccc([Si]2(c3ccccc3)c3cccc(c3)-n3c4ccccc4c4ccc(cc43)[Si](c3ccccc3)(c3ccccc3)c3cccc2n3)cc1 ; c1ccc(N2c3cccc(c3)[Si](c3ccccc3)(c3ccccc3)c3cccc(n3)[Si](c3ccccc3)(c3ccccc3)c3cccc2c3)cc1 ; c1ccc([Si]2(c3ccccc3)c3cccc(c3)Oc3cccc(c3)[Si](c3ccccc3)(c3ccccc3)c3cccc2n3)cc1]

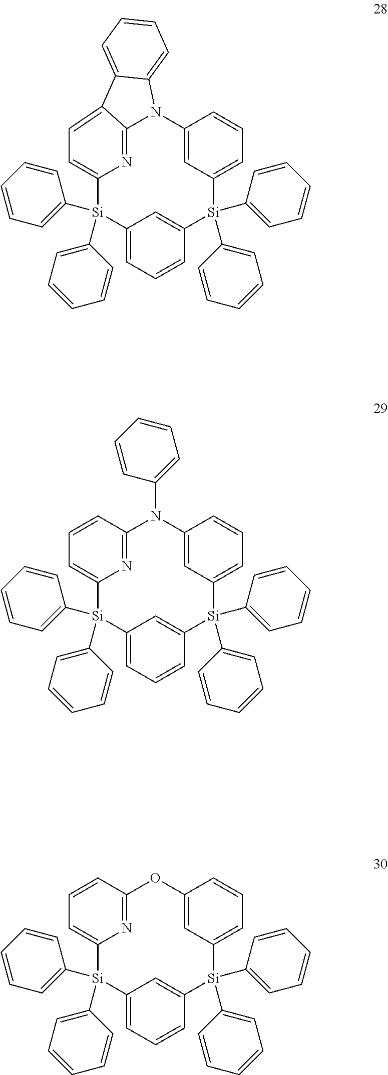 [SMILES: c1ccc([Si]2(c3ccccc3)c3cccc(c3)-n3c4ccccc4c4ccc(nc43)[Si](c3ccccc3)(c3ccccc3)c3cccc2c3)cc1 ; c1ccc(N2c3cccc(c3)[Si](c3ccccc3)(c3ccccc3)c3cccc(c3)[Si](c3ccccc3)(c3ccccc3)c3cccc2n3)cc1 ; c1ccc([Si]2(c3ccccc3)c3cccc(c3)Oc3cccc(n3)[Si](c3ccccc3)(c3ccccc3)c3cccc2c3)cc1]

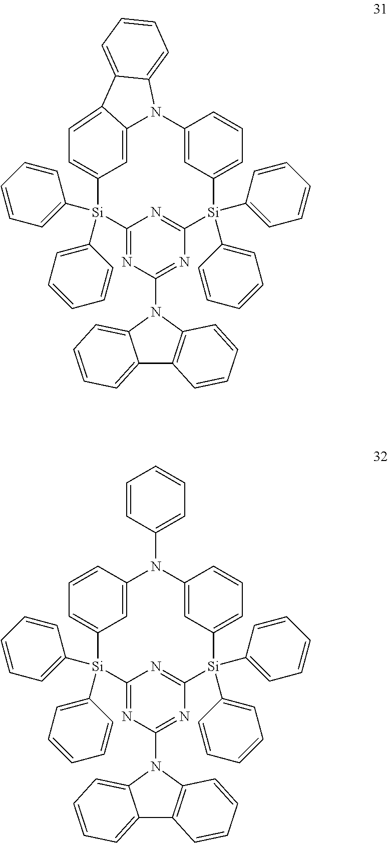 [SMILES: c1ccc([Si]2(c3ccccc3)c3cccc(c3)-n3c4ccccc4c4ccc(cc43)[Si](c3ccccc3)(c3ccccc3)c3nc(-n4c5ccccc5c5ccccc54)nc2n3)cc1 ; c1ccc(N2c3cccc(c3)[Si](c3ccccc3)(c3ccccc3)c3nc(-n4c5ccccc5c5ccccc54)nc(n3)[Si](c3ccccc3)(c3ccccc3)c3cccc2c3)cc1]

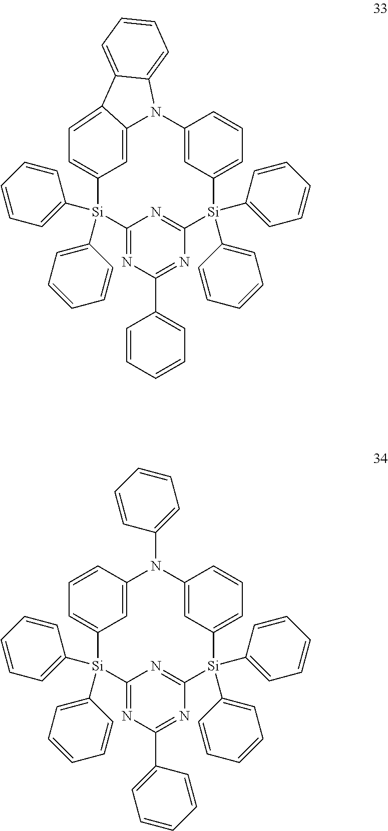 [SMILES: c1ccc(-c2nc3nc(n2)[Si](c2ccccc2)(c2ccccc2)c2ccc4c5ccccc5n(c4c2)-c2cccc(c2)[Si]3(c2ccccc2)c2ccccc2)cc1 ; c1ccc(-c2nc3nc(n2)[Si](c2ccccc2)(c2ccccc2)c2cccc(c2)N(c2ccccc2)c2cccc(c2)[Si]3(c2ccccc2)c2ccccc2)cc1]

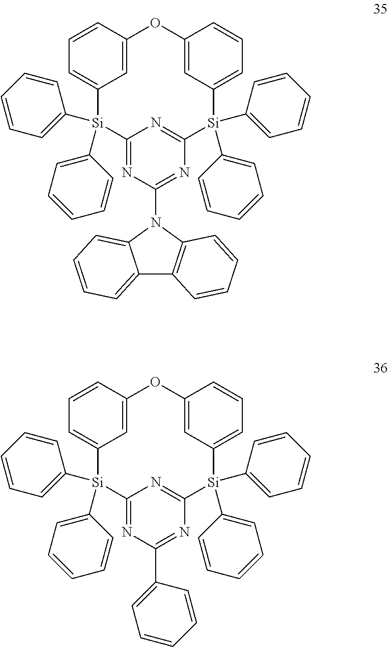 [SMILES: c1ccc([Si]2(c3ccccc3)c3cccc(c3)Oc3cccc(c3)[Si](c3ccccc3)(c3ccccc3)c3nc(-n4c5ccccc5c5ccccc54)nc2n3)cc1 ; c1ccc(-c2nc3nc(n2)[Si](c2ccccc2)(c2ccccc2)c2cccc(c2)Oc2cccc(c2)[Si]3(c2ccccc2)c2ccccc2)cc1]

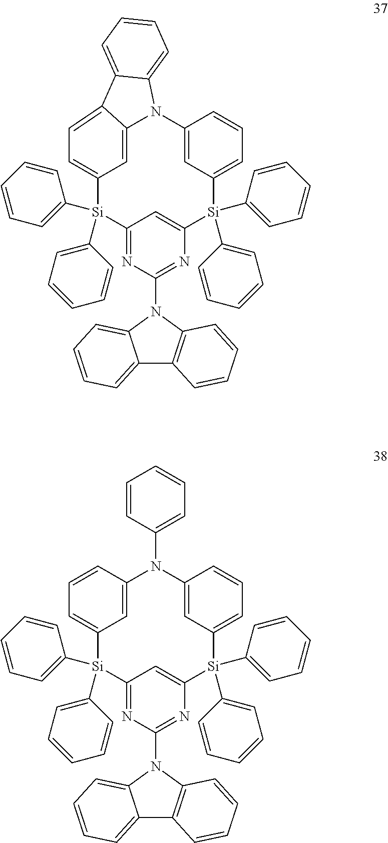 [SMILES: c1ccc([Si]2(c3ccccc3)c3cccc(c3)-n3c4ccccc4c4ccc(cc43)[Si](c3ccccc3)(c3ccccc3)c3cc2nc(-n2c4ccccc4c4ccccc42)n3)cc1 ; c1ccc(N2c3cccc(c3)[Si](c3ccccc3)(c3ccccc3)c3cc(nc(-n4c5ccccc5c5ccccc54)n3)[Si](c3ccccc3)(c3ccccc3)c3cccc2c3)cc1]

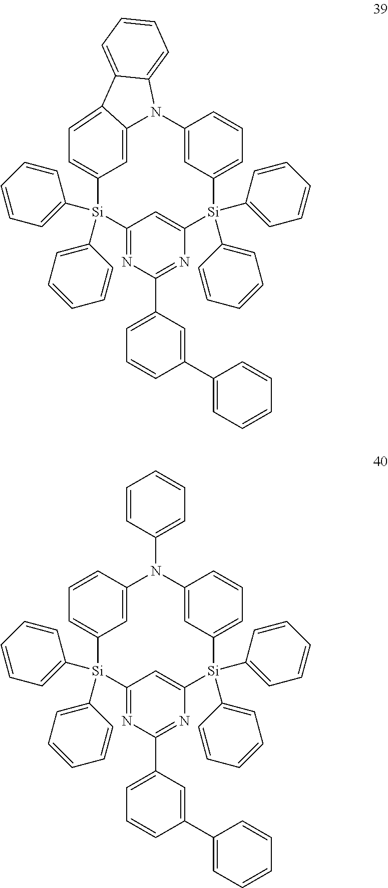 [SMILES: c1ccc(-c2cccc(-c3nc4cc(n3)[Si](c3ccccc3)(c3ccccc3)c3ccc5c6ccccc6n(c5c3)-c3cccc(c3)[Si]4(c3ccccc3)c3ccccc3)c2)cc1 ; c1ccc(-c2cccc(-c3nc4cc(n3)[Si](c3ccccc3)(c3ccccc3)c3cccc(c3)N(c3ccccc3)c3cccc(c3)[Si]4(c3ccccc3)c3ccccc3)c2)cc1]

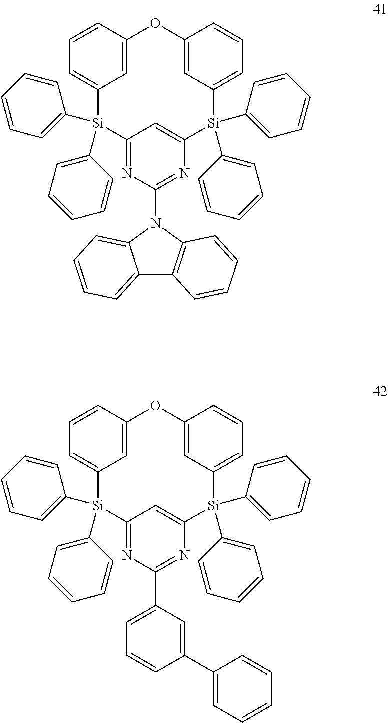 [SMILES: c1ccc([Si]2(c3ccccc3)c3cccc(c3)Oc3cccc(c3)[Si](c3ccccc3)(c3ccccc3)c3cc2nc(-n2c4ccccc4c4ccccc42)n3)cc1 ; c1ccc(-c2cccc(-c3nc4cc(n3)[Si](c3ccccc3)(c3ccccc3)c3cccc(c3)Oc3cccc(c3)[Si]4(c3ccccc3)c3ccccc3)c2)cc1]

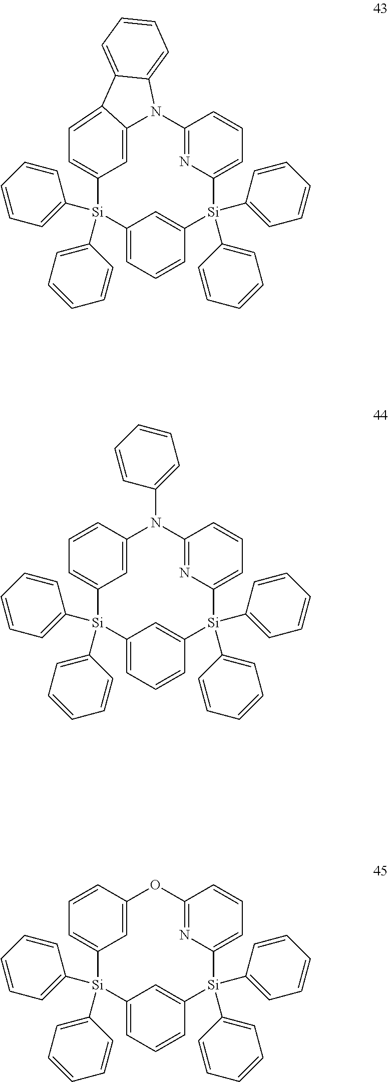 [SMILES: c1ccc([Si]2(c3ccccc3)c3cccc(c3)[Si](c3ccccc3)(c3ccccc3)c3cccc(n3)-n3c4ccccc4c4ccc2cc43)cc1 ; c1ccc(N2c3cccc(c3)[Si](c3ccccc3)(c3ccccc3)c3cccc(c3)[Si](c3ccccc3)(c3ccccc3)c3cccc2n3)cc1 ; c1ccc([Si]2(c3ccccc3)c3cccc(c3)Oc3cccc(n3)[Si](c3ccccc3)(c3ccccc3)c3cccc2c3)cc1]

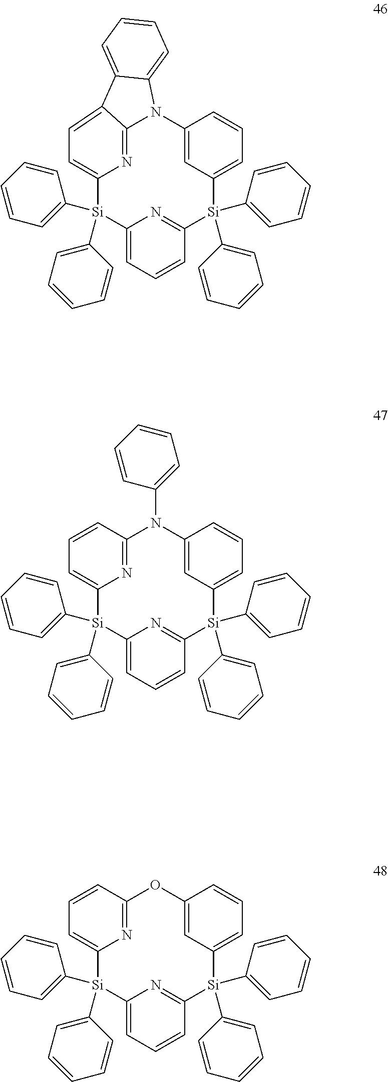 [SMILES: c1ccc([Si]2(c3ccccc3)c3cccc(c3)-n3c4ccccc4c4ccc(nc43)[Si](c3ccccc3)(c3ccccc3)c3cccc2n3)cc1 ; c1ccc(N2c3cccc(c3)[Si](c3ccccc3)(c3ccccc3)c3cccc(n3)[Si](c3ccccc3)(c3ccccc3)c3cccc2n3)cc1 ; c1ccc([Si]2(c3ccccc3)c3cccc(c3)Oc3cccc(n3)[Si](c3ccccc3)(c3ccccc3)c3cccc2n3)cc1]

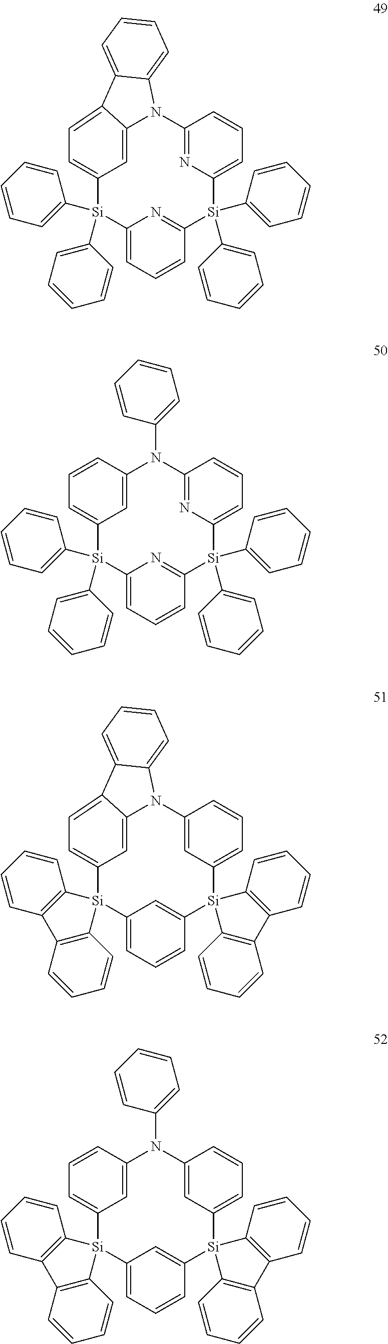 [SMILES: c1ccc([Si]2(c3ccccc3)c3ccc4c5ccccc5n(c4c3)-c3cccc(n3)[Si](c3ccccc3)(c3ccccc3)c3cccc2n3)cc1 ; c1ccc(N2c3cccc(c3)[Si](c3ccccc3)(c3ccccc3)c3cccc(n3)[Si](c3ccccc3)(c3ccccc3)c3cccc2n3)cc1 ; c1cc2cc(c1)[Si]1(c3cccc(c3)[Si]3(c4ccc5c6ccccc6n-2c5c4)c2ccccc2-c2ccccc23)c2ccccc2-c2ccccc21 ; c1ccc(N2c3cccc(c3)[Si]3(c4cccc(c4)[Si]4(c5cccc2c5)c2ccccc2-c2ccccc24)c2ccccc2-c2ccccc23)cc1]

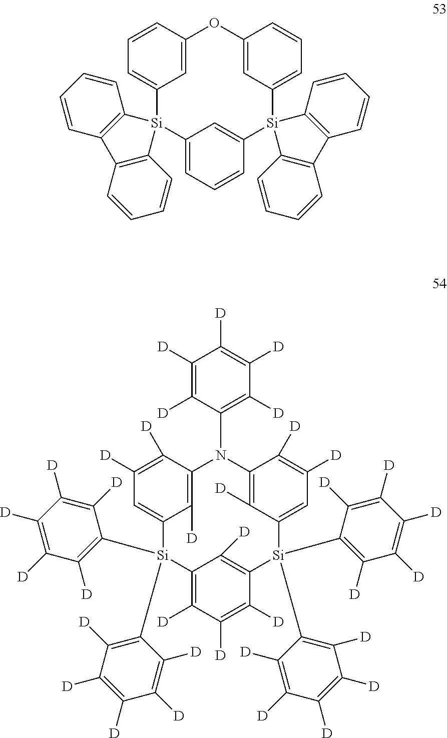 [SMILES: c1cc2cc(c1)[Si]1(c3cccc(c3)[Si]3(c4cccc(c4)O2)c2ccccc2-c2ccccc23)c2ccccc2-c2ccccc21 ; [2H]c1cc2c([2H])c(c1[2H])N(c1c([2H])c([2H])c([2H])c([2H])c1[2H])c1c([2H])c([2H])cc(c1[2H])[Si](c1c([2H])c([2H])c([2H])c([2H])c1[2H])(c1c([2H])c([2H])c([2H])c([2H])c1[2H])c1c([2H])c([2H])c([2H])c(c1[2H])[Si]2(c1c([2H])c([2H])c([2H])c([2H])c1[2H])c1c([2H])c([2H])c([2H])c([2H])c1[2H]]

In specific compounds suggested in Compound Group 1, “D” means (refers to) a deuterium atom.

In the light-emitting element ED illustrated in FIG. 3 to FIG. 6, the emission layer EML may include a host and a dopant, and the emission layer EML may include (contain) a hetero compound represented by Formula 1 as a host material. However, one or more embodiments of the present disclosure is not limited thereto. For example, in the light-emitting element ED according to one or more embodiments, the electron transport region HTR may include (contain) the hetero compound represented by Formula 1.

The hetero compound according to one or more embodiments may be a thermally activated delayed fluorescent host or phosphorescent host. The emission layer EML including (containing) the hetero compound according to one or more embodiments may be to emit phosphorescence or thermally activated delayed fluorescence. For example, the emission layer EML may be to emit phosphorescence.

The hetero compound according to one or more embodiments may have a cyclic structure in which the first and second silicon atoms, each connected to three aromatic rings, a first linker linking the first and second silicon atoms, and a second linker linking any one selected from among the three aromatic rings connected to the first silicon atom with any one selected from among the three aromatic rings connected to the second silicon atom, are connected to each other. The hetero compound according to one or more embodiments may have a sterically bulky structure due to characteristics of a steric shape of the hetero compound according to one or more embodiments. Due to the bulky steric structure, the polycyclic compound according to one or more embodiments may be prevented from interacting with other compounds.

For example, the hetero compound according to one or more embodiments may include a hetero aromatic ring in which two silyl groups are bonded (bind) to each other via two linkers to form a ring. Such a hetero compound according to one or more embodiments may have high steric hindrance properties to an adjacent compound molecule due to the cyclic structure, compared to a compound that forms no ring. Therefore, compared to the other compounds including two connected silyl groups that form no ring, the hetero compound according to one or more embodiments may have reduced interaction with the adjacent compound (molecule).

When the hetero compound according to one or more embodiments is included (contained) in the emission layer EML and used as a host material, the hetero compound according to one or more embodiments may have less interaction with the dopant material included in the emission layer EML due to the steric hindrance of the bulky structure. Therefore, the hetero compound according to one or more embodiments has no influence on luminescent properties of the dopant, and the light-emitting element ED according to one or more embodiments including (containing) the hetero compound according to one or more embodiments in the emission layer EML may exhibit excellent color reproductivity. In some embodiments, the hetero compound according to one or more embodiments may have rigid properties due to the cyclic structure, and thus may exhibit excellent material stability. Since the hetero compound according to one or more embodiments has suitable or excellent material stability, the light-emitting element ED according to one or more embodiments including the same may have an enhanced or improved (effect on an) element lifespan.

Therefore, the light-emitting element ED according to one or more embodiments includes the hetero compound according to the present disclosure in the emission layer EML as a blue phosphorescent host or thermally activated delayed fluorescent host, and thus may exhibit properties of high efficacy and long lifespan simultaneously, e.g., at the same time.

The emission layer EML may include (contain) one or more hetero compound in Compound Group, as previously described herein.

In some embodiments, the emission layer EML of the light-emitting element ED may be to emit blue light. For example, the emission layer EML of the light-emitting element ED may emit blue light in a wavelength of about 430 nanometer (nm) to about 490 nm.

However, one or more embodiments of the present disclosure is not limited thereto, and the emission layer EML may be to emit green light or red light.

The hetero compound according to one or more embodiments may be included (contained) in the emission layer EML. The hetero compound according to one or more embodiments may be included (contained) in the emission layer EML as a host material. For example, the emission layer EML in the light-emitting element ED according to one or more embodiments may include (contain) at least one selected from among the herein-described hetero compounds present in Compound Group 1 as a host material. However, use of the hetero compound according to one or more embodiments is not limited thereto.

In one or more embodiments, the emission layer EML may include (contain) a plurality of compounds. The emission layer EML according to one or more embodiments may include a host and a dopant. For example, the emission layer EML according to one or more embodiments may include a host and a phosphorescent dopant. Alternatively, the emission layer EML according to one or more embodiments may include a host and a thermally activated delayed fluorescent dopant. In one or more embodiments, the host may be represented by Formula 1, previously described, and the dopant may be represented by Formula M-a. The dopant represented by Formula M-1 may be a phosphorescent dopant.

For example, the emission layer EML may include an organometallic complex including platinum (Ir) as a central metal atom and ligands bonded to the central metal atom, as a dopant. In the light emitting element ED of one or more embodiments, the emission layer EML may include a compound represented by Formula D-1 as the a dopant.

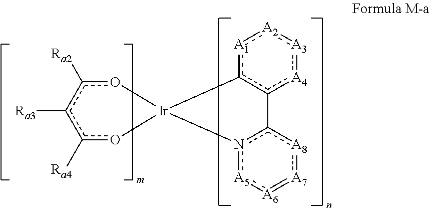

In Formula M-a, A₁ to A₈ may each independently be CRₐ₁ or N.

In Formula M-a, Rₐ₁ to Rₐ₄ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula M-a, “m” is 0 or 1, and “n” is 2 or 3. In Formula M-a, if (e.g., when) “m” is 0, “n” is 3, and if (e.g., when) “m” is 1, “n” is 2.

The compound represented by Formula M-a may be used as a phosphorescence dopant.

The compound represented by Formula M-a may be represented by any one selected from among Compounds M-a1 to M-a26. However, Compounds M-a1 to M-a26 are illustrations, and the compound represented by Formula M-a is not limited to the compounds represented by Compounds M-a1 to M-a26.

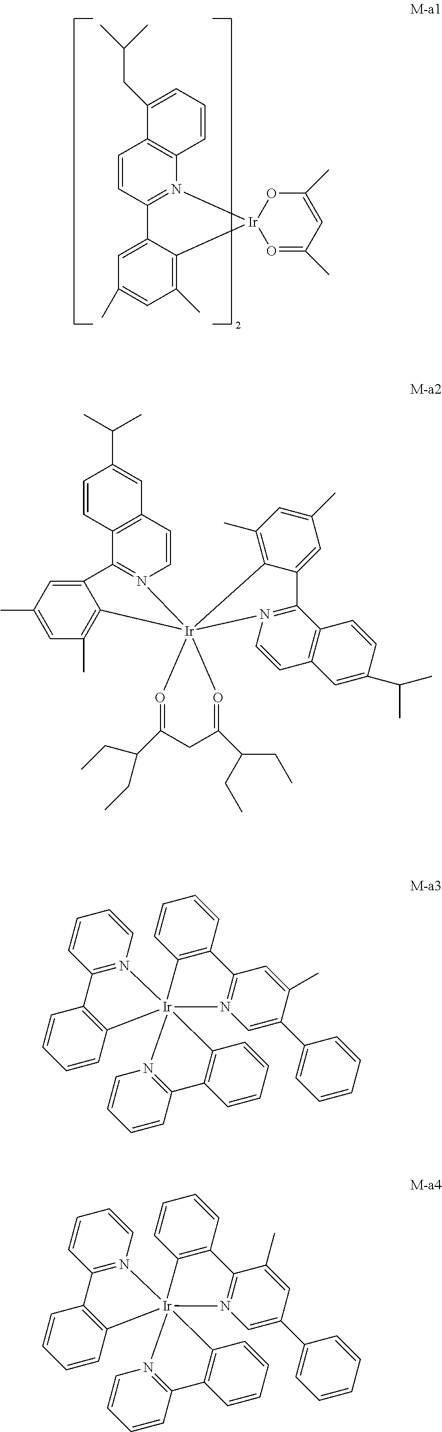

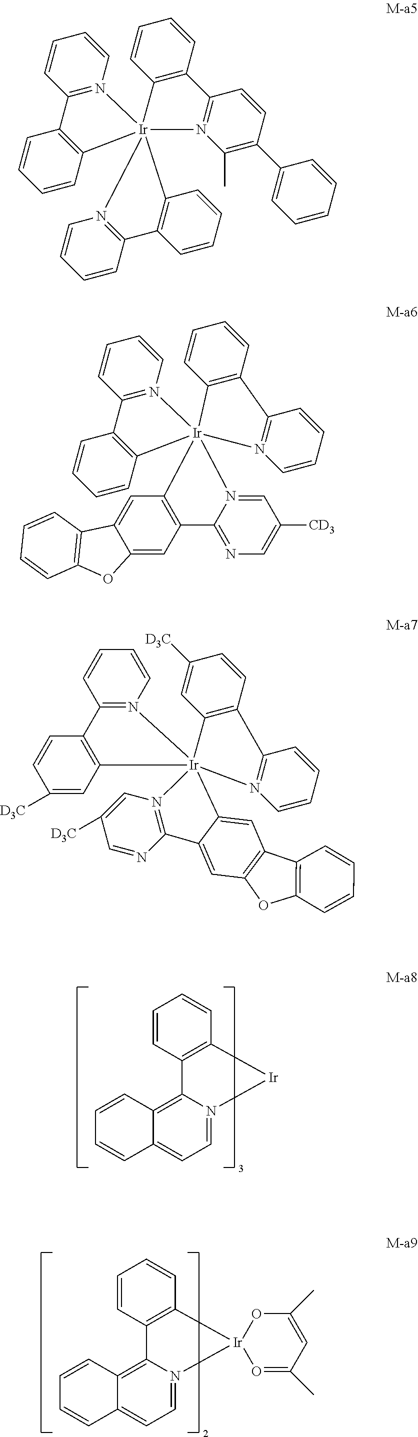

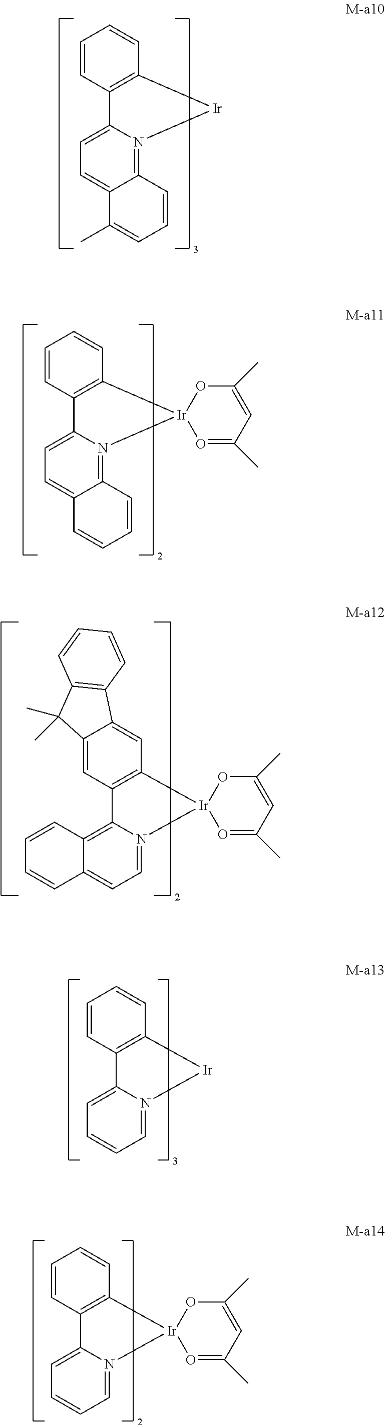

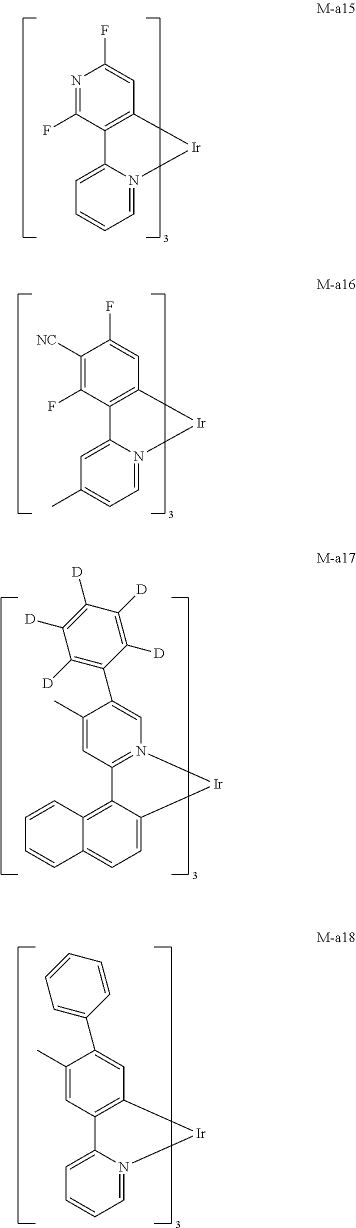

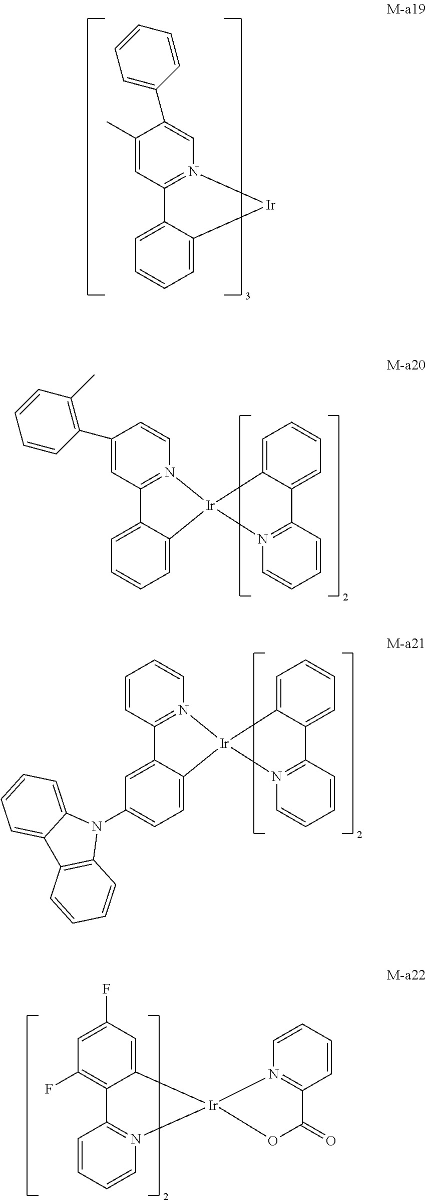

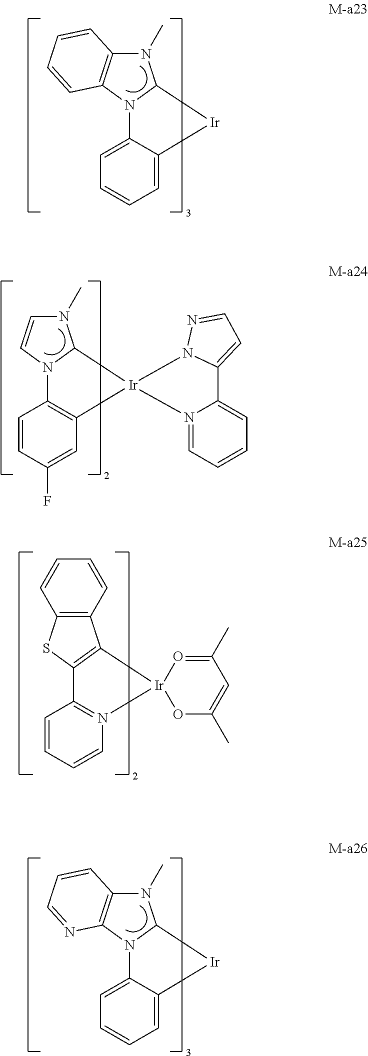

In the light-emitting element ED according to one or more embodiments, the emission layer EML may include first and second hosts different from each other, and a dopant. For example, the emission layer EML according to one or more embodiments may include the first and second hosts, different from each other, and a phosphorescent dopant. Alternatively, the emission layer EML according to one or more embodiments may include the first and second hosts different from each other, and a thermally activated delayed fluorescence dopant. In one or more embodiments, the first host may be represented by Formula 1, previously described, the second host may be represented by Formula HT, and the dopant may be represented by Formula M-a.

In one or more embodiments, the emission layer EML may include the first compound represented by Formula 1, and may further include the second compound represented by Formula HT-1, and the third compound represented by Formula M-a.

In one or more embodiments, the emission layer EML may include a second compound represented by Formula HT-1. In one or more embodiments, the first compound may be used as the electron transporting host material for the emission layer EML, and the second compound may be used as the hole transporting host material for the emission layer EML. The third compound may be used as a phosphorescent dopant material for the emission layer EML.

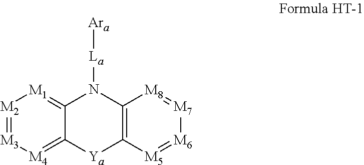

In Formula HT-1, M₁ to M₈ may each independently be N or CR₅₁. For example, all M₁ to M₈ may be CR₅₁. Otherwise, any one selected from among M₁ to M₈ may be N, and the remainder may be CR₅₁.

In Formula HT-1, Lₐ may be a direct linkage, a substituted or unsubstituted arylene group of 6 to 30 ring-forming carbon atoms, or a substituted or unsubstituted heteroarylene group of 2 to 30 ring-forming carbon atoms. For example, Lₐ may be a direct linkage, a substituted or unsubstituted phenylene group, a substituted or unsubstituted divalent biphenyl group, a substituted or unsubstituted divalent carbazole group, and/or the like, but one or more embodiments of the present disclosure is not limited thereto.

In Formula HT-1, Yₐ may be a direct linkage, CR₅₂R₅₃, or SiR₅₄R₅₅. For example, it may refer to that two benzene rings connected with the nitrogeno atom of Formula HT-1 may be connected via a direct linkage,

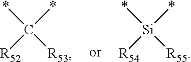

In Formula HT-1, if (e.g., when) Yₐ is a direct linkage, the substituent represented by Formula HT-1 may include a carbazole moiety.

In Formula HT-1, Arₐ may be a substituted or unsubstituted aryl group of 6 to 30 ring-forming carbon atoms, or a substituted or unsubstituted heteroaryl group of 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, and/or the like, but one or more embodiments of the present disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. Otherwise, each of R₅₁ to R₅₅ may be combined with an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any one selected from among the compounds represented in Compound Group 2. An emission layer EML may include at least one selected from among the compounds represented in Compound Group 2 as a hole transport host material.

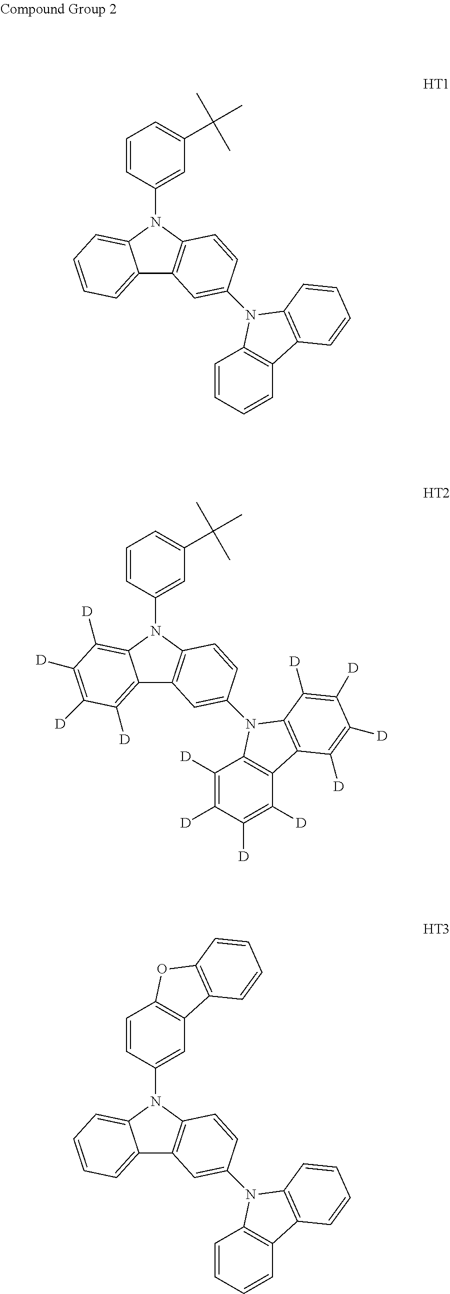 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

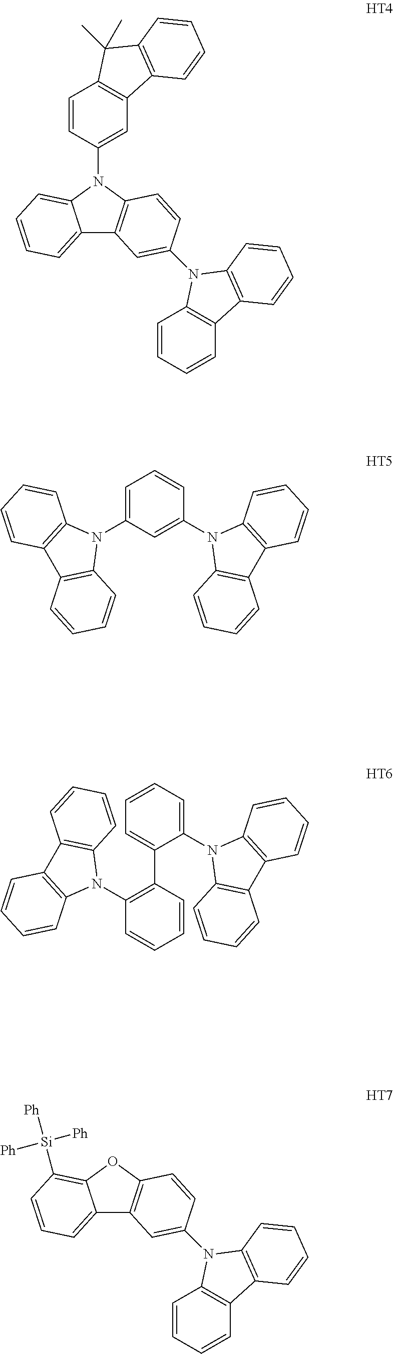 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

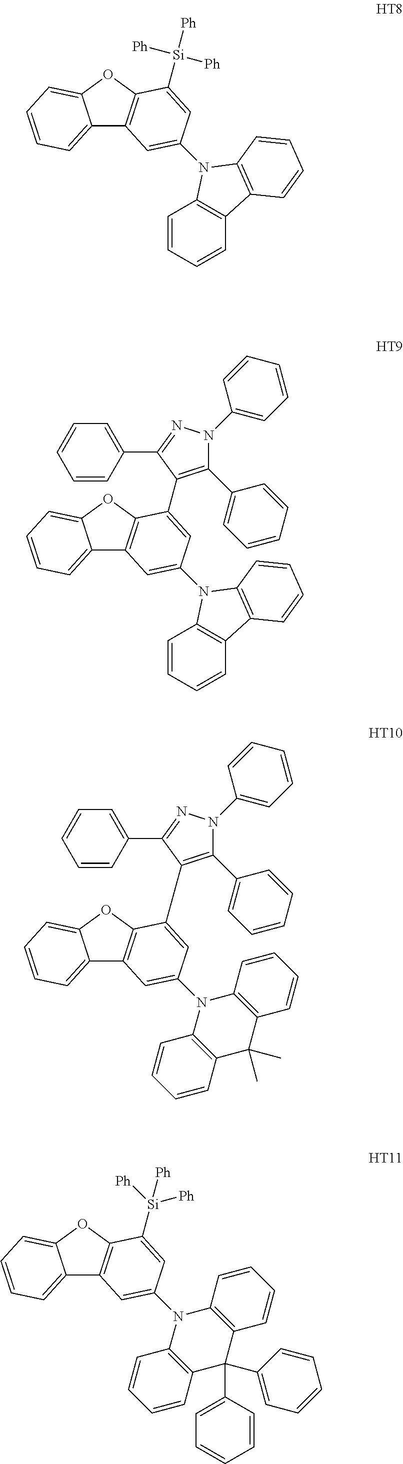 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

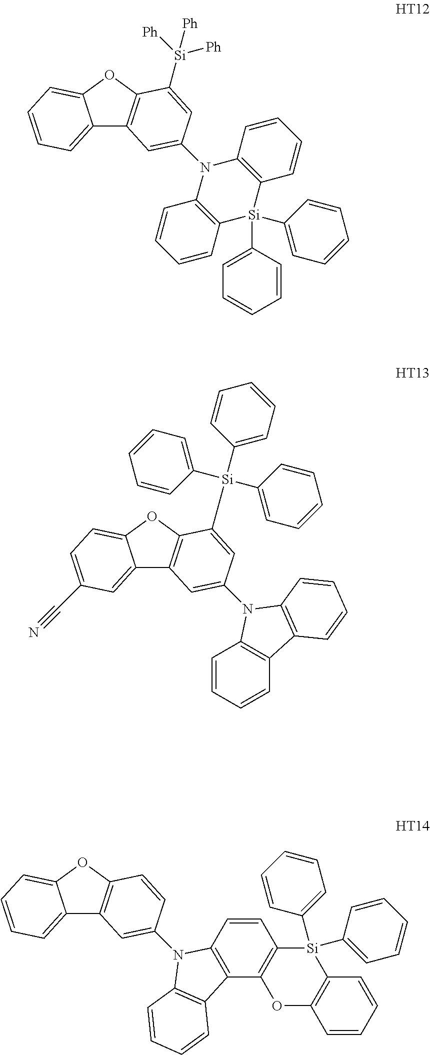 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

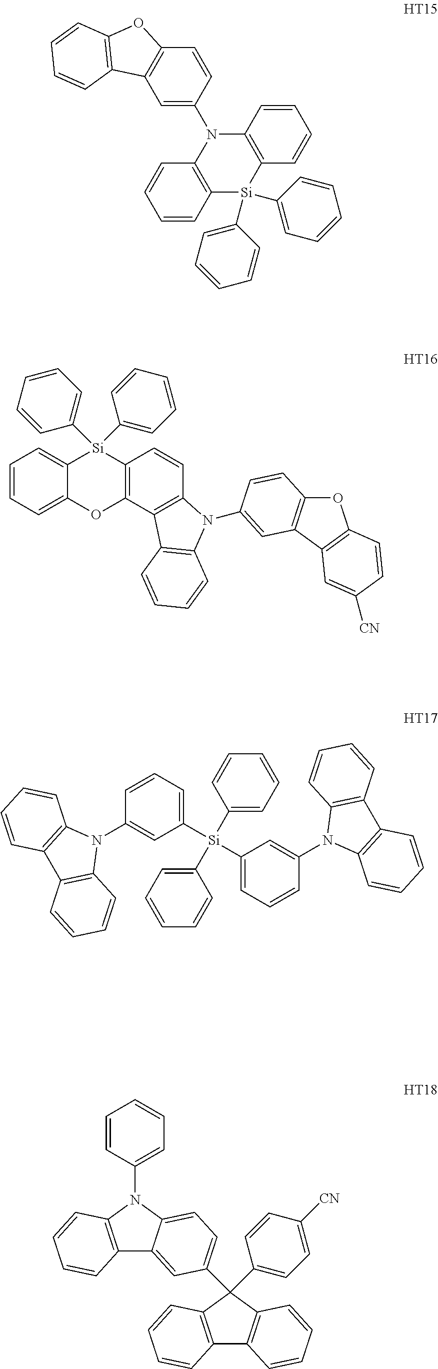 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

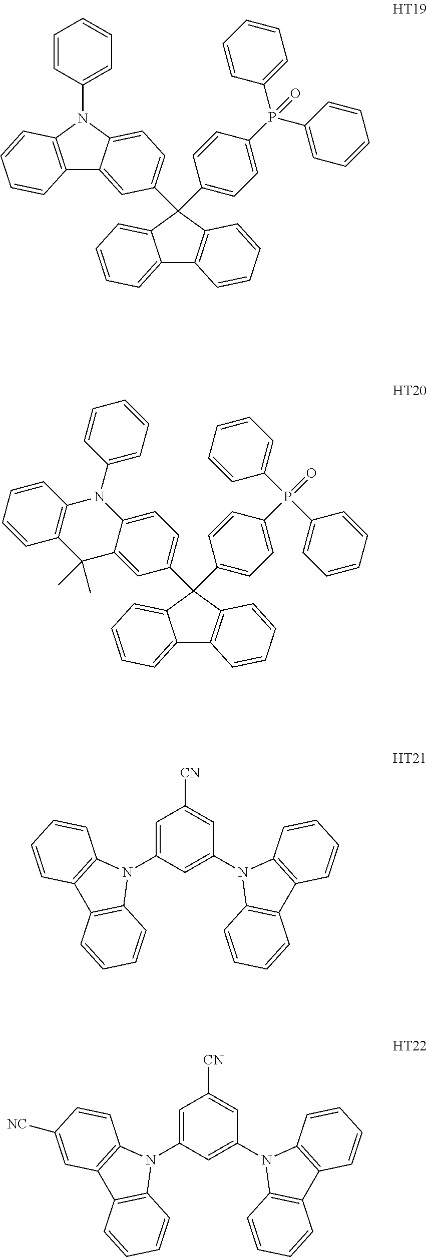 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

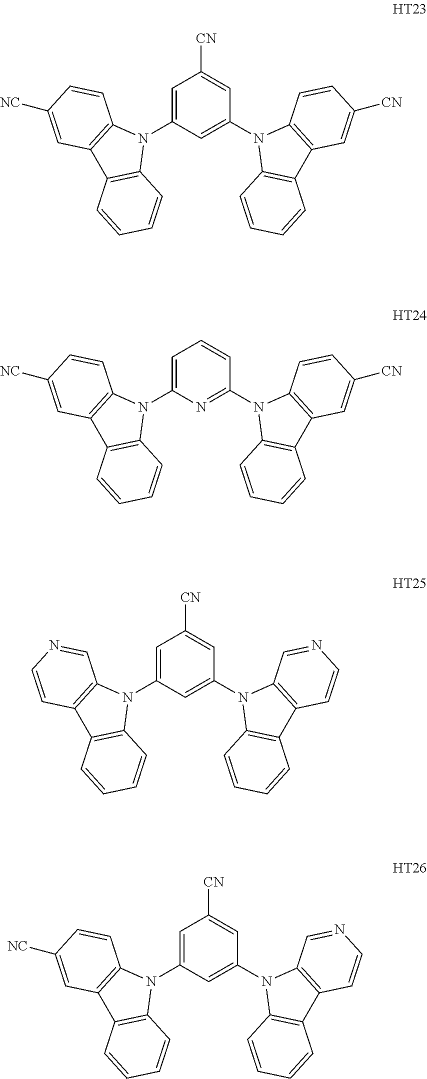 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

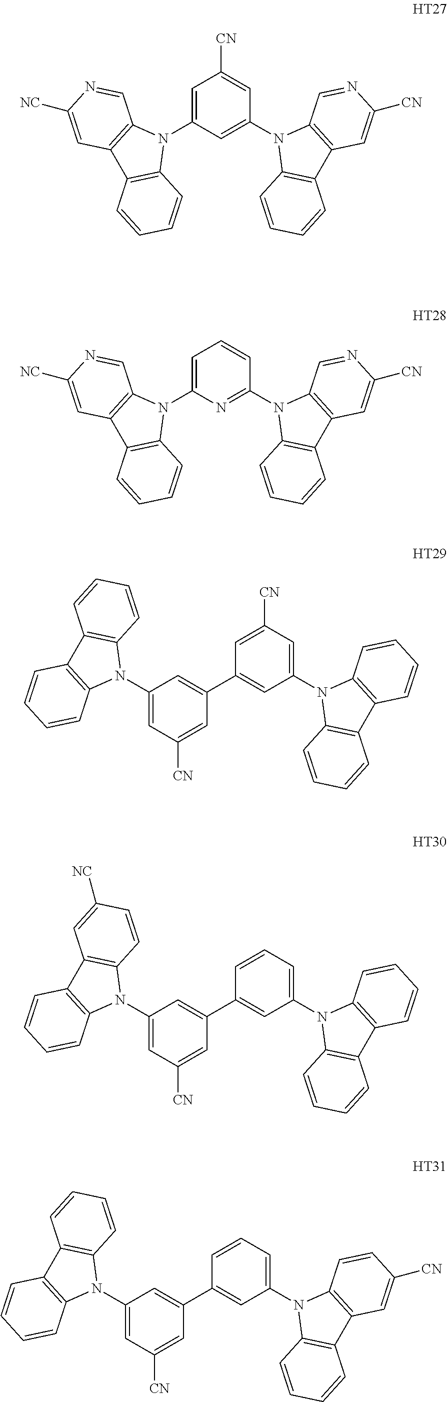 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

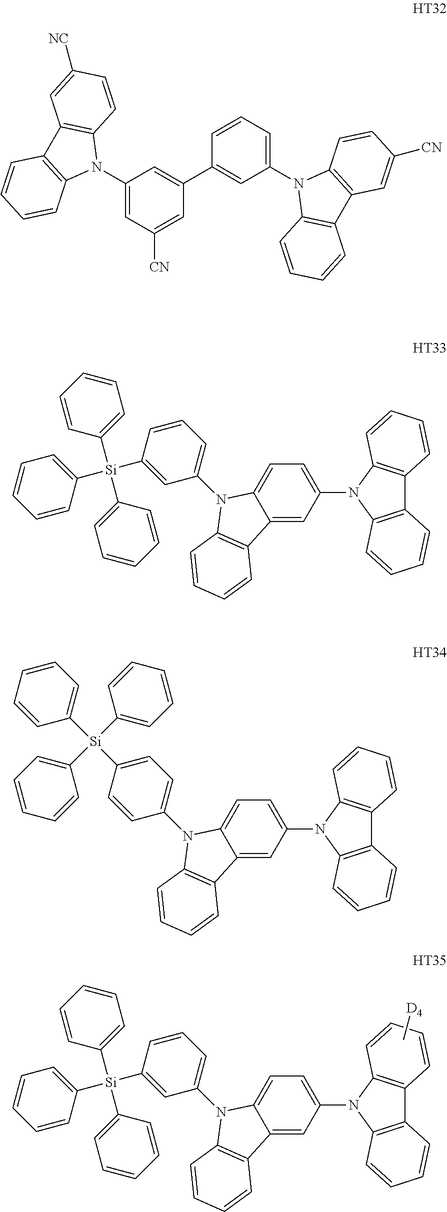

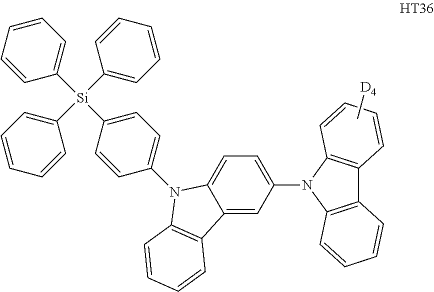

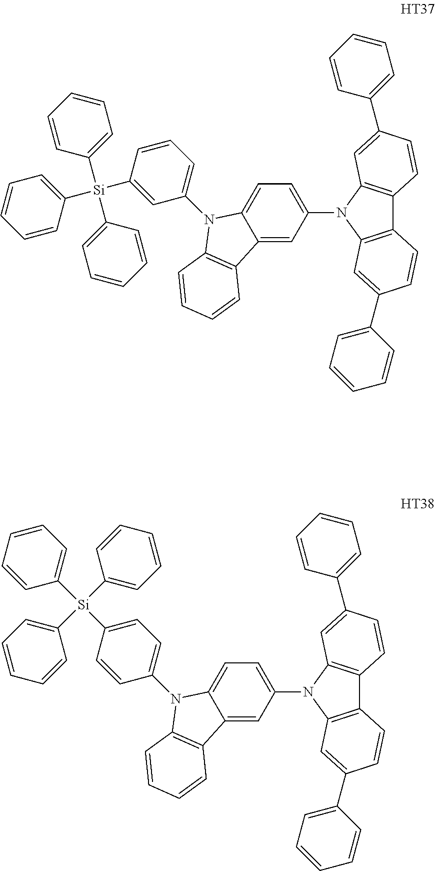 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

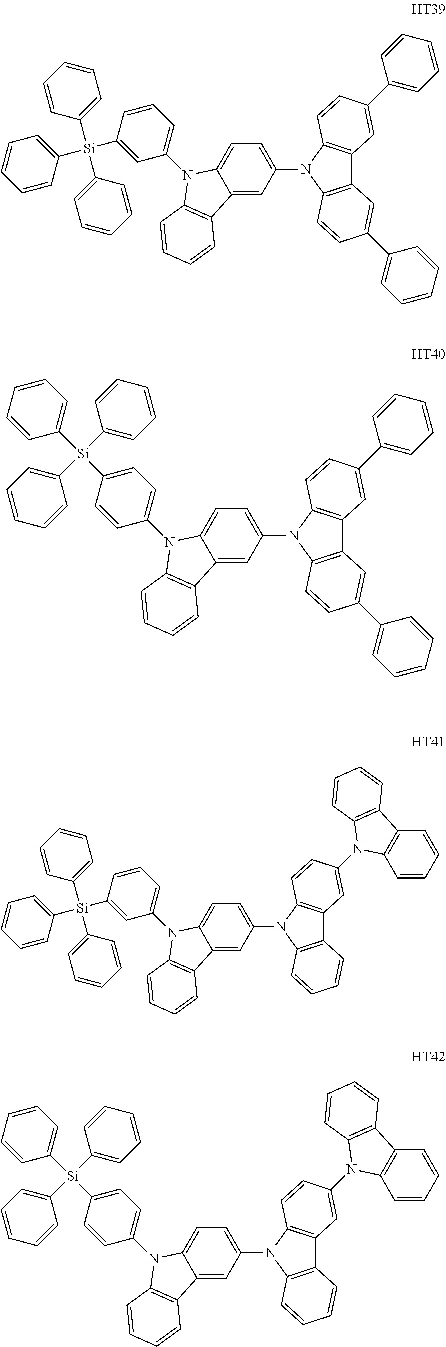 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

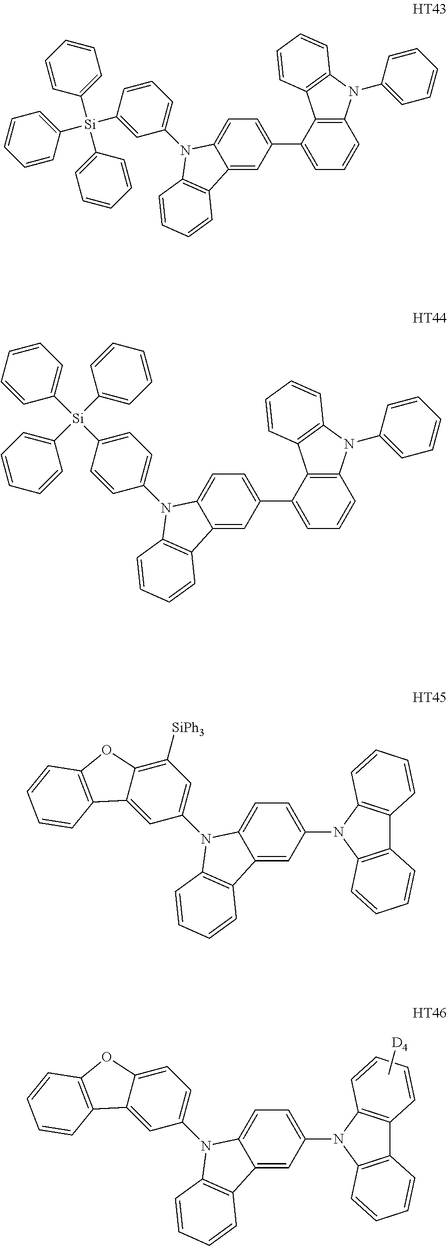

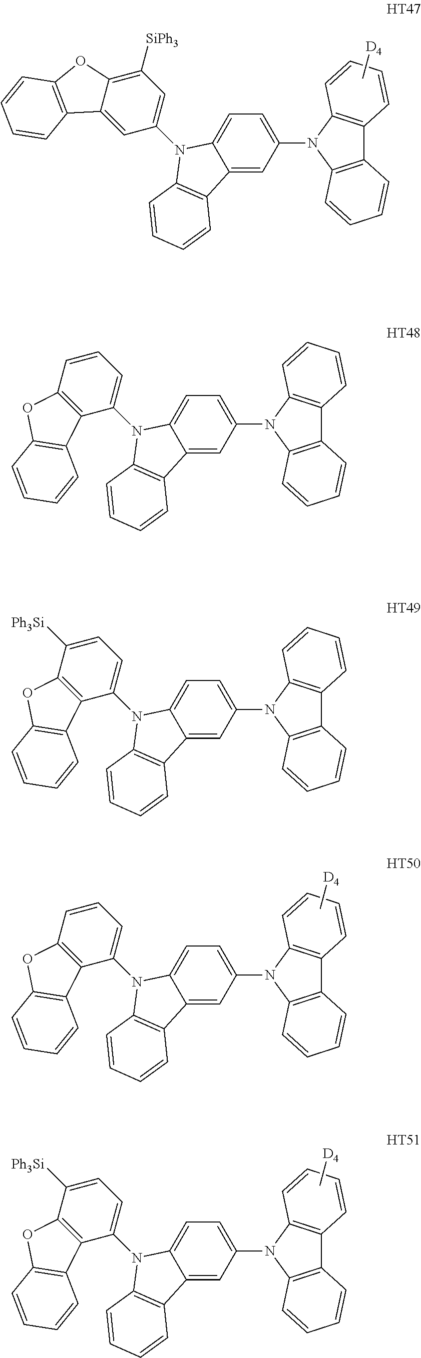

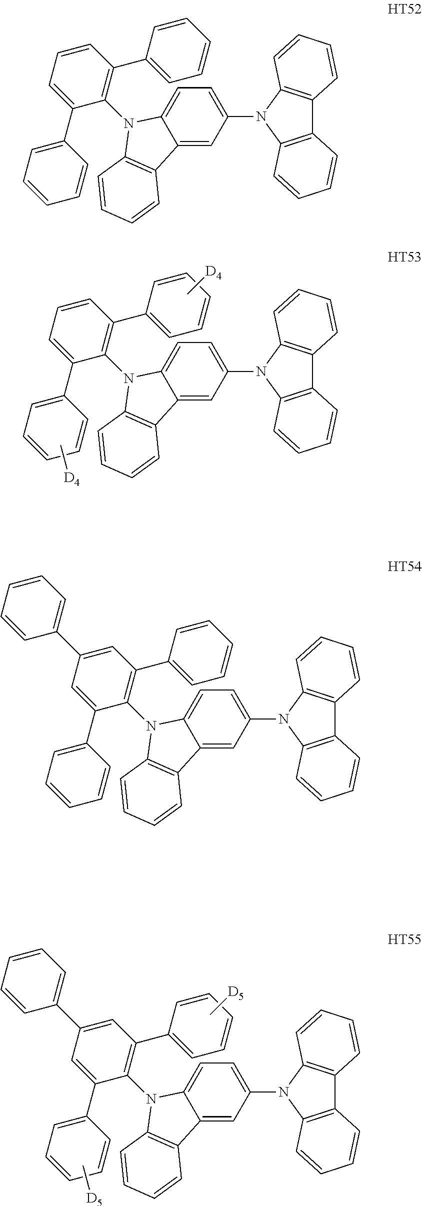

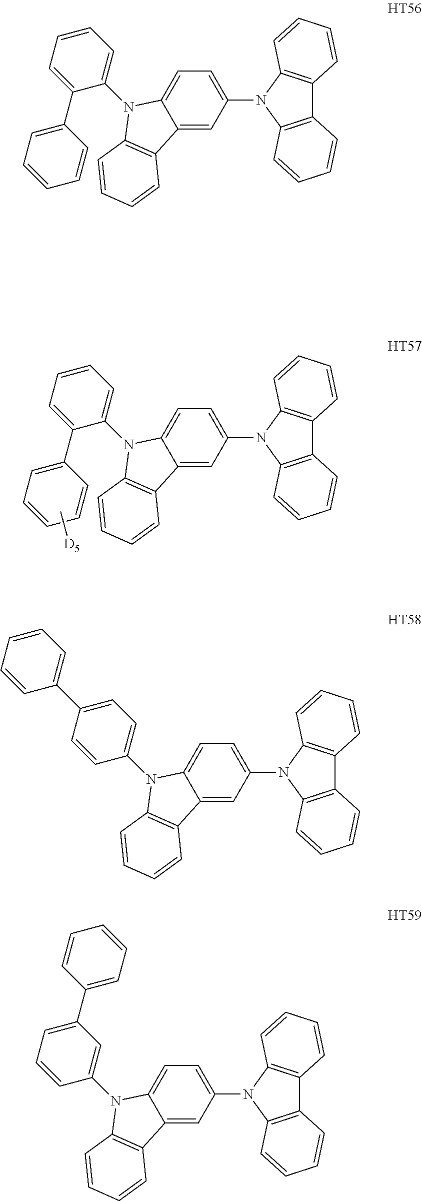

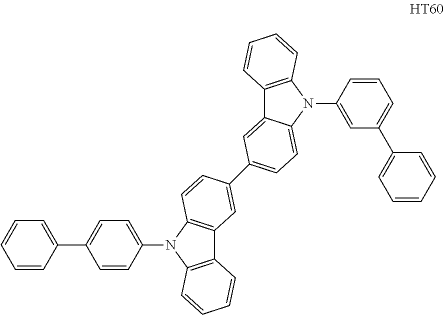 [SMILES: c1ccc(-c2ccc(-n3c4ccccc4c4cc(-c5ccc6c(c5)c5ccccc5n6-c5cccc(-c6ccccc6)c5)ccc43)cc2)cc1]

In the particular compounds suggested in Compound Group 2, “D” means (refers to) a deuterium atom, and “Ph” may refer to an unsubstituted phenyl group.

The emission layer EML may include the first compound and the second compound, and the first compound and the second compound may form exciplex. The emission layer EML may include a first compound represented by chemical formula 1 as an electron transport host, and a second compound represented by chemical formula HT-1 as a hole transport host, and an exciplex may be formed by the hole transport host and the electron transport host. In this case, the triplet energy of the exciplex formed by the hole transport host and the electron transport host may correspond to a difference between the lowest unoccupied molecular orbital (LUMO) energy level of the electron transport host and the highest occupied molecular orbital (HOMO) energy level of the hole transport host.

For example, the absolute value of the triplet energy level (T1) of the exciplex formed by the hole transport host and the electron transport host may be about 2.4 electron volt (eV) to about 3.0 eV. In some embodiments, the triplet energy of the exciplex may be a smaller value than the energy gap of each host material. The exciplex may have a triplet energy of about 3.0 eV or less, that is the energy gap between the hole transport host and the electron transport host.

The light-emitting element ED according to one or more embodiments may include a plurality of emission layers. The plurality of emission layers are sequentially stacked and provided, and for example, the light-emitting element ED including the plurality of emission layers may be to emit white light. The light-emitting element including the plurality of emission layers may be a light-emitting element having a tandem structure. When the light-emitting element ED includes the plurality of emission layers, at least one emission layer EML may include a first compound according to one or more embodiments, represented by Formula 1. In some embodiments, when the light-emitting element ED includes the plurality of emission layers, at least one emission layer EML may include the first compound and the third compound, as described herein. In some embodiments, when the light-emitting element ED includes a plurality of emission layers, at least one emission layer EML may include all the first compound, the second compound, and the third compound, as described herein.

In the light-emitting element ED according to one or more embodiments, when the emission layer EML includes all of the herein-described first compound, second compound, and third compound, on the basis of the total weight of the first compound, the second compound, and the third compound, a content of the third compound may be about 0.1 wt % to about 20 wt %. However, one or more embodiments of the present disclosure is not limited thereto. When the content of the third compound falls within the herein-described ratio, energy transfer from the first compound and the second compound to the third compound may increase, and thus luminous efficiency and element lifespan may increase.

In the emission layer EML, contents of the first compound and the second compound may be the remaining weight after excluding the herein-described third compound. For example, in the emission layer EML, the contents of the first compound and the second compound may be about 65 wt % to 95 wt % on the basis of the total weight of the first compound, the second compound, and the third compound.

In the total weight of the first compound and the second compound, a weight ratio of the first compound to the second compound may be about 3:7 to about 7:3.

When the contents of the first compound and the second compound fall within the herein-described ratio, charge balance properties within the emission layer EML improve, and thus luminous efficiency and element lifespan may increase. When the contents of the first compound and the second compound are out of the herein-described ratio range, the charge balance within the emission layer EML is broken to decrease luminous efficiency, and thus the element may easily deteriorate.

In the light-emitting element ED according to one or more embodiments, the emission layer EML may further include general materials known in the art, in addition to the herein-described hetero compound according to one or more embodiments.

In the light emitting element ED of one or more embodiments, the light emitting layer EML may further include anthracene derivatives, pyrene derivatives, fluoranthene derivatives, chrysene derivatives, dihydrobenzanthracene derivatives, or triphenylene derivatives. Particularly, the light emitting layer EML may include anthracene derivatives or pyrene derivatives.

In the light-emitting element ED according to one or more embodiments, illustrated in FIG. 3 to FIG. 6, the emission layer EML may further include known host and dopant in addition to the herein-described host and dopant, and the emission layer EML may include a compound represented by Formula E-1. The compound represented by Formula E-1 may be used as a fluorescent host material or delayed fluorescent host material.

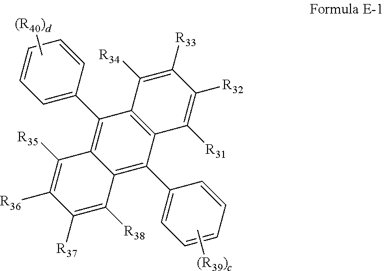

In Formula E-1, R₃₁ to R₄₀ may each independently be a hydrogen atom, a deuterium atom, a halogen atom, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. R₃₁ to R₄₀ may be combined with an adjacent group to form a saturated hydrocarbon ring, an unsaturated hydrocarbon ring, a saturated heterocycle or an unsaturated heterocycle.

In Formula E-1, “c” and “d” may each independently be an integer of 0 to 5.

Formula E-1 may be represented by any one selected from among Compound E1 to Compound E21.

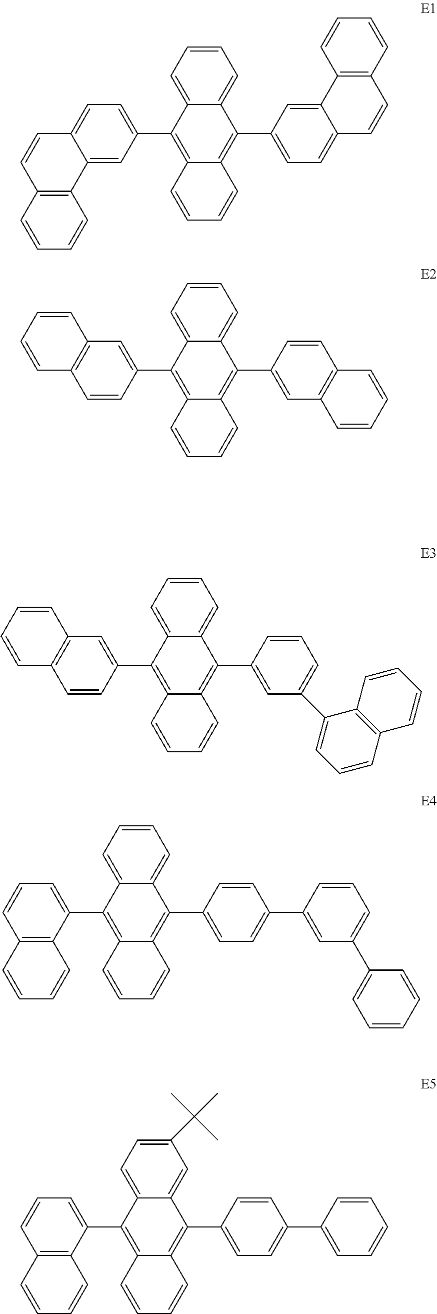

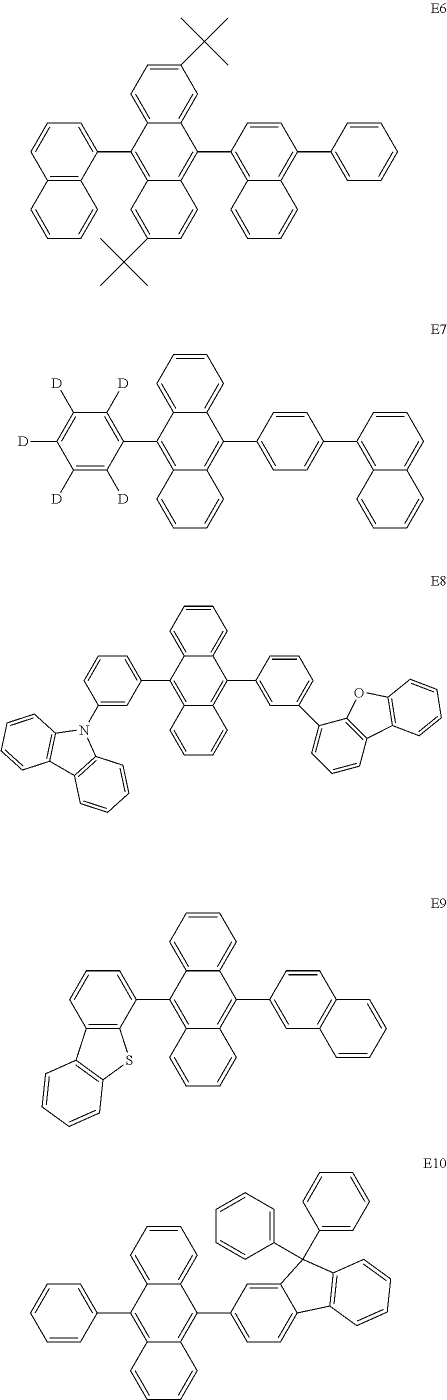

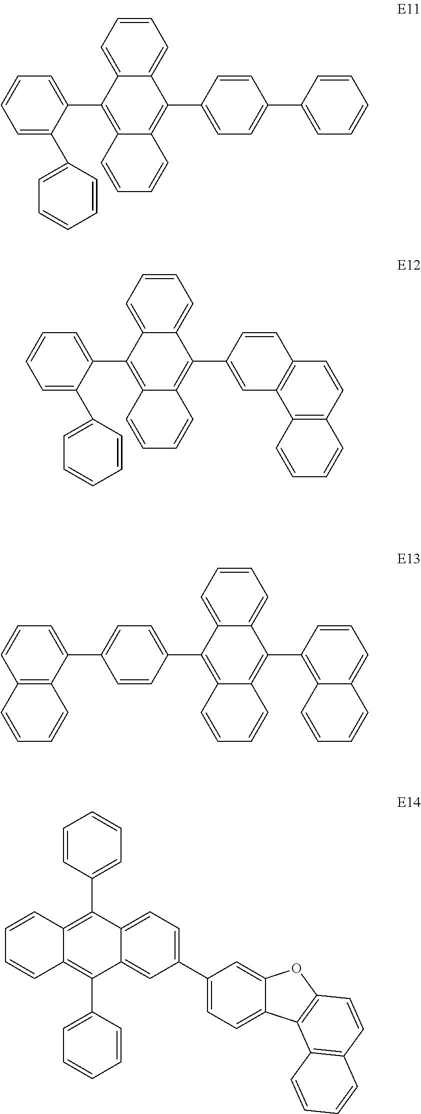

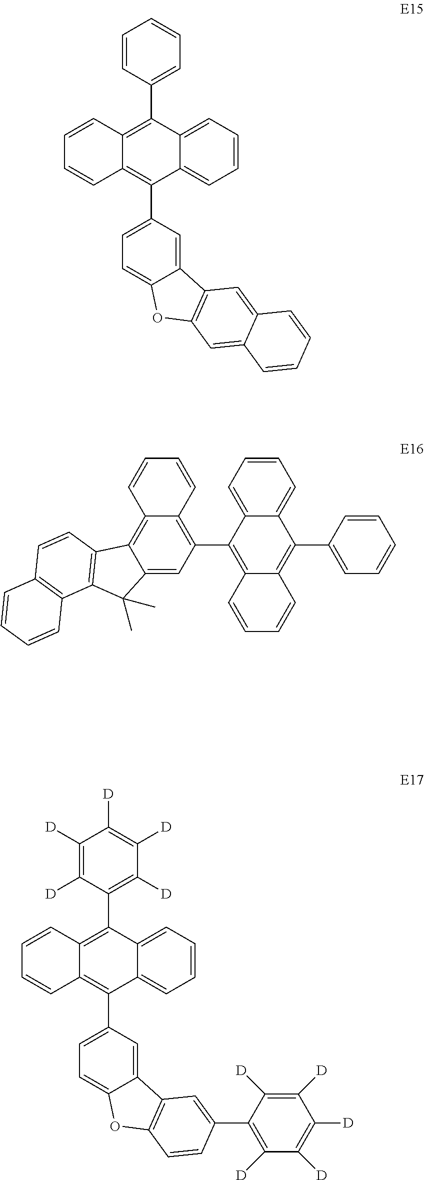

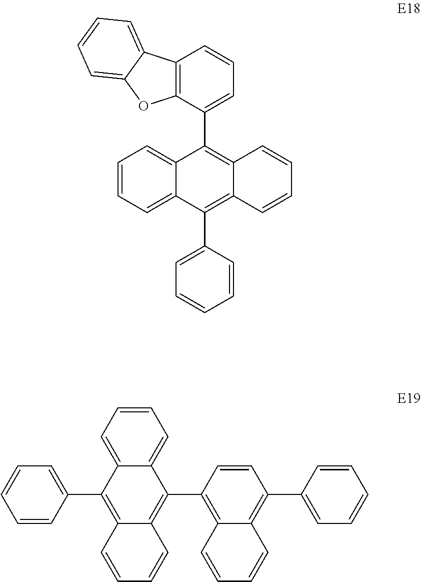

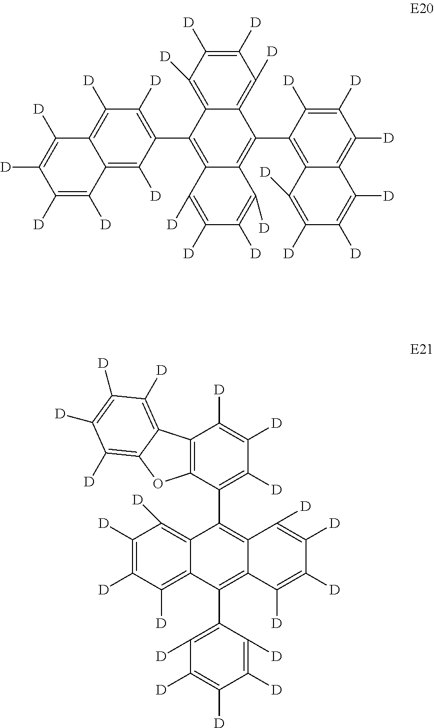 [SMILES: [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H] ; [2H]c1c([2H])c([2H])c(-c2c3c([2H])c([2H])c([2H])c([2H])c3c(-c3c([2H])c([2H])c([2H])c4c3oc3c([2H])c([2H])c([2H])c([2H])c34)c3c([2H])c([2H])c([2H])c([2H])c23)c([2H])c1[2H]]

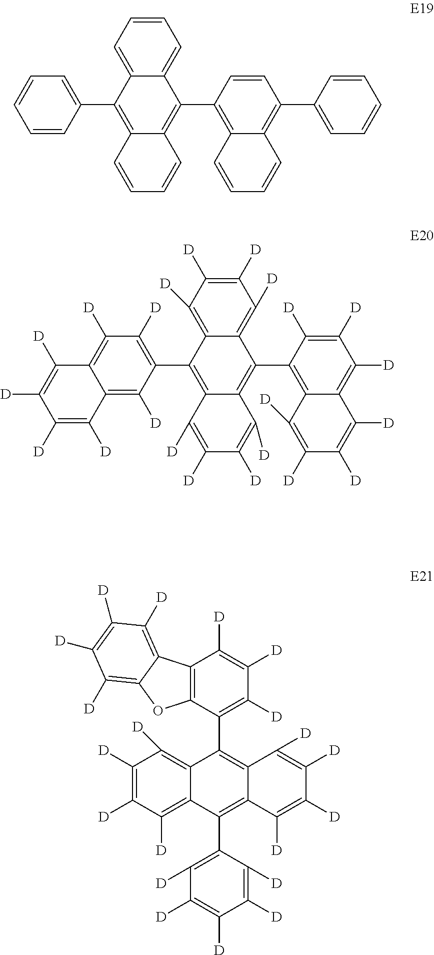

In one or more embodiments, the light emitting layer EML may include a compound represented by Formula E-2a or Formula E-2b. The compound represented by Formula E-2a or Formula E-2b may be used as a phosphorescence host material or a delayed fluorescence host material.

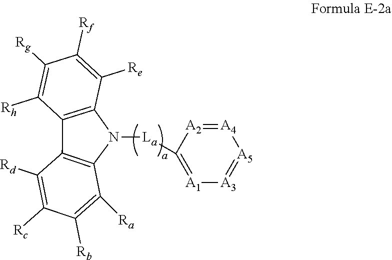

In Formula E-2a, “a” may be an integer of 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. If (e.g., when) “a” is an integer of 2 or more, multiple La may each independently be a substituted or unsubstituted arylene group of 6 to 30 ring-forming carbon atoms, or a substituted or unsubstituted heteroarylene group of 2 to 30 ring-forming carbon atoms.

In some embodiments, in Formula E-2a, A₁ to A₅ may each independently be N or CRi. Rₐ to Rᵢ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Rₐ to Rᵢ may be combined with an adjacent group to form a hydrocarbon ring or a heterocycle including N, O, S, and/or the like as a ring-forming atom.

In Formula E-2a, two or three selected from A₁ to A₅ may be N, and the remainder may be CRᵢ.

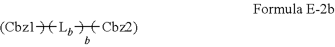

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and if (e.g., when) “b” is an integer of 2 or more, multiple L_{b} may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one selected from among the compounds in Compound Group E-2. However, the compounds shown in Compound Group E-2 are only illustrations, and the compound represented by Formula E-2a or Formula E-2b is not limited to the compounds represented in Compound Group E-2.

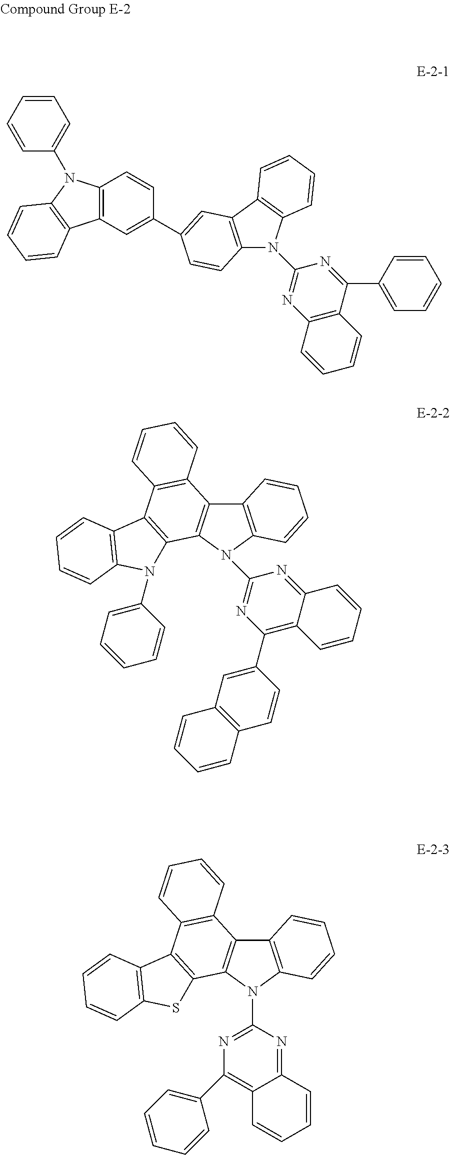 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

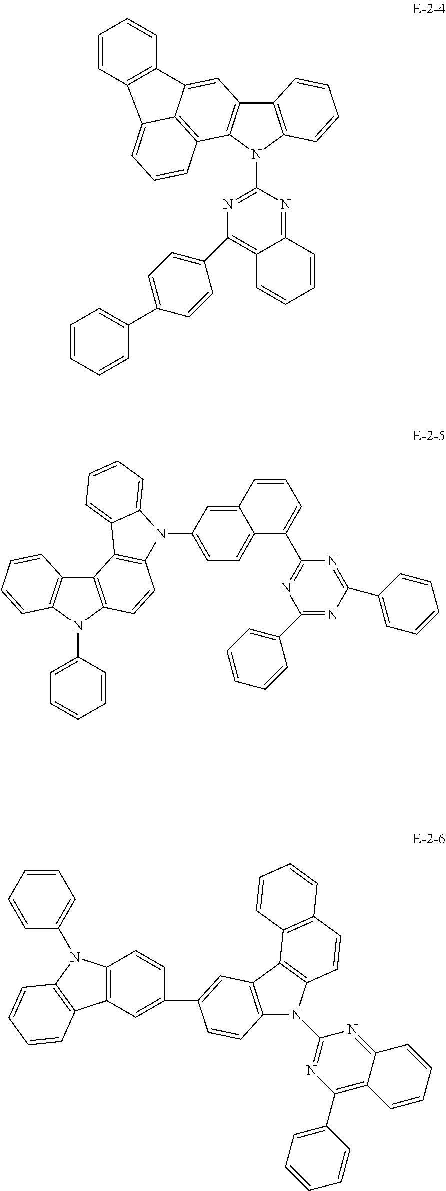 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

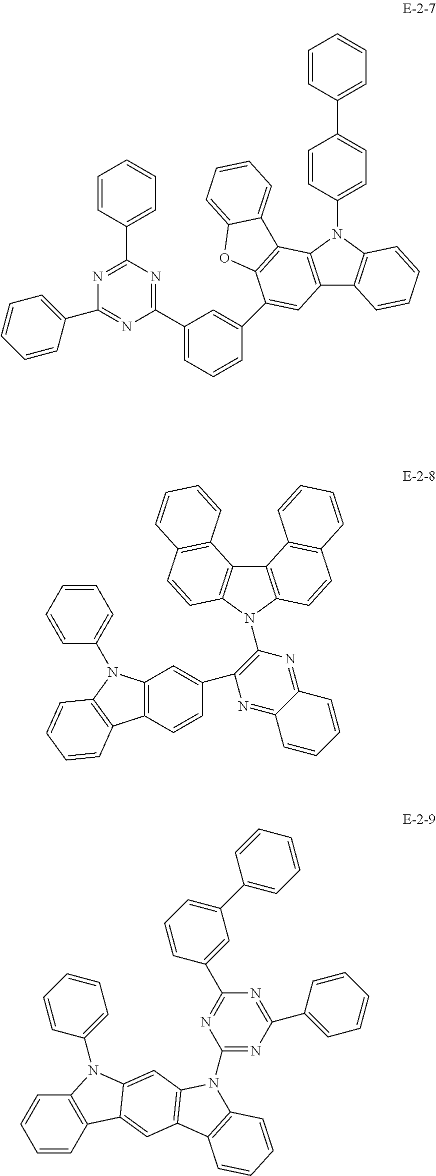 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

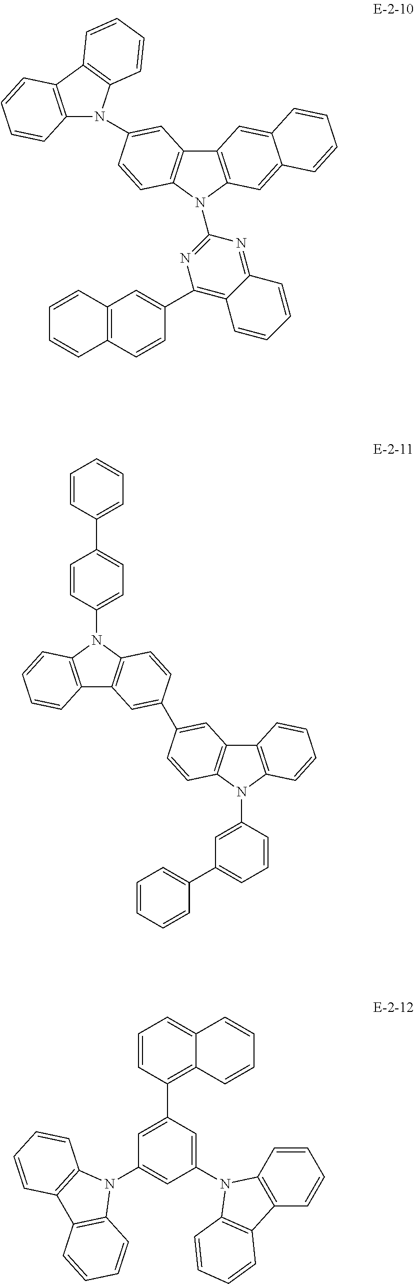 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

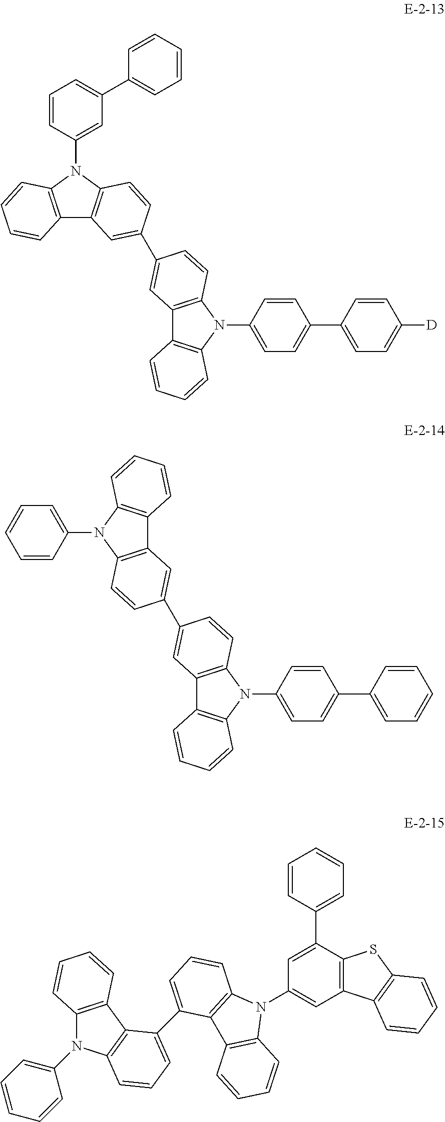 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

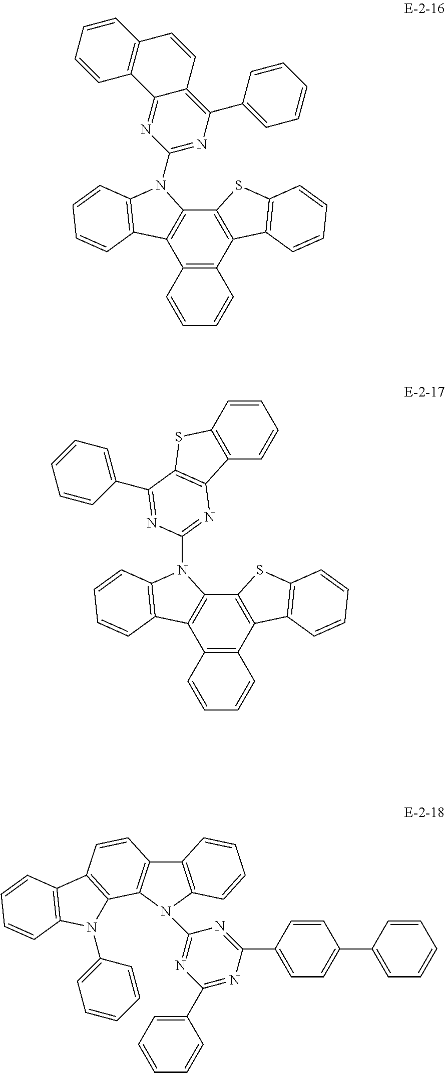 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

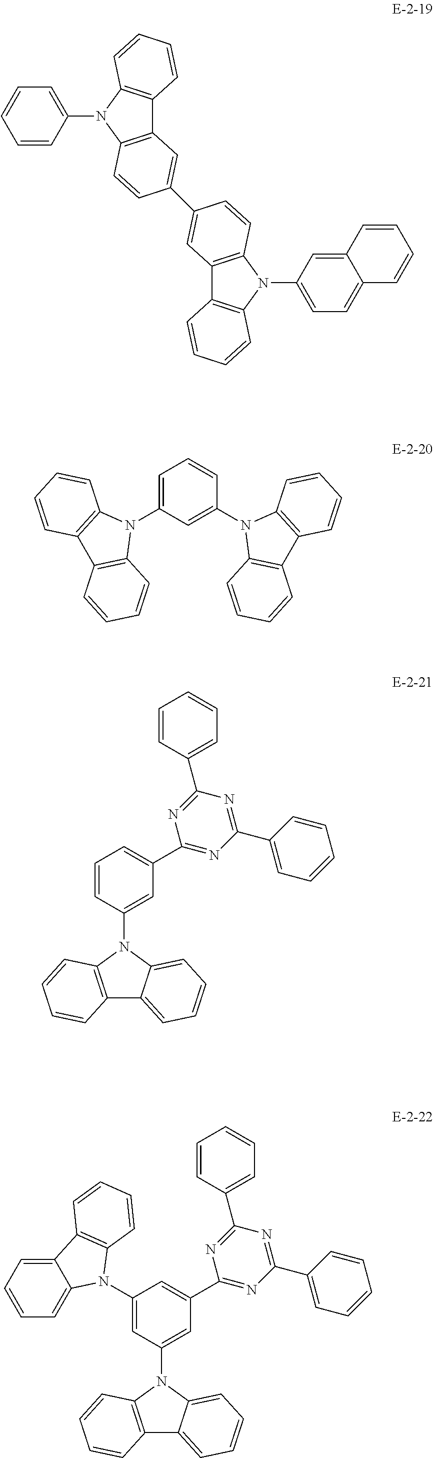 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

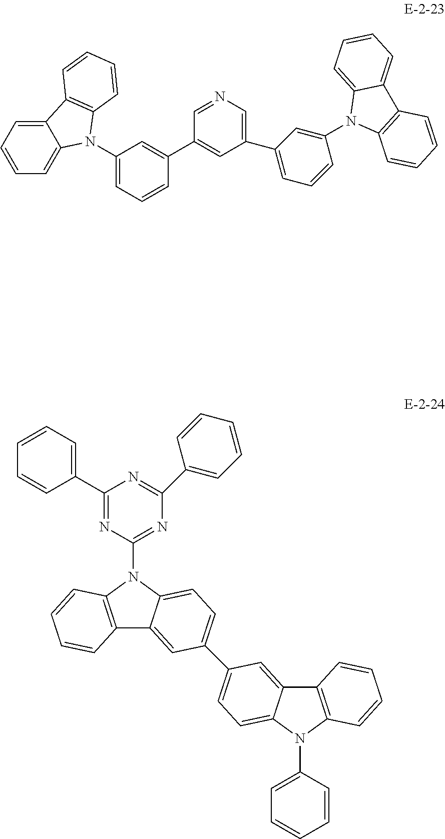 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The light emitting layer EML may further include a common material well-known in the art as a host material. For example, the light emitting layer EML may include as a host material, at least one of bis(4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, one or more embodiments of the present disclosure is not limited thereto. For example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), and/or the like may be used as the host material.

The light emitting layer EML may include a compound represented by Formula HT. The compound represented by Formula HT may be used as a phosphorescence dopant material or a delayed fluorescence host material.

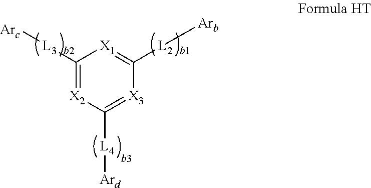

In Formula HT, at least one selected from among X₁ to X₃ may be N, and the remainder may be CR₅₆. For example, at least one selected from among X₁ to X₃ may be N, and the remainder two may each independently be CR₅₆. In this case, the second host represented by Formula HT may include a pyridine moiety. Otherwise, at least two selected from among X₁ to X₃ may be N, and the remainder may be CR₅₆. In this case, the second host represented by Formula HT may include a pyrimidine moiety. Otherwise, X₁ to X₃ may be all N. In this case, the second host represented by Formula HT may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer of 0 to 10.

In Formula ET-1, Ar_{b} to Ar_{d} may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar_{b} to Ar_{d} may be substituted or unsubstituted phenyl groups or substituted or unsubstituted carbazole groups.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. If (e.g., when) each of b1 to b3 is an integer of 2 or more, L₂ to L₄ may each independently be a substituted or unsubstituted arylene group of 6 to 30 ring-forming carbon atoms, or a substituted or unsubstituted heteroarylene group of 2 to 30 ring-forming carbon atoms.

In one or more embodiments, the compound represented by Formula HT may be any one selected from among the compounds in Compound Group 3. The light emitting element ED of one or more embodiments may include any one selected from among the compounds in Compound Group 3.

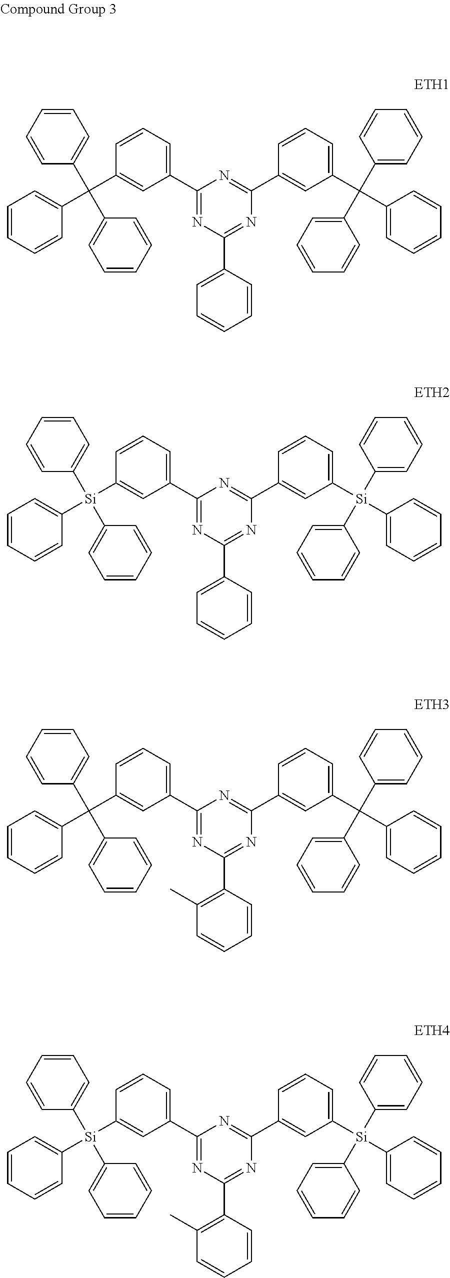 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

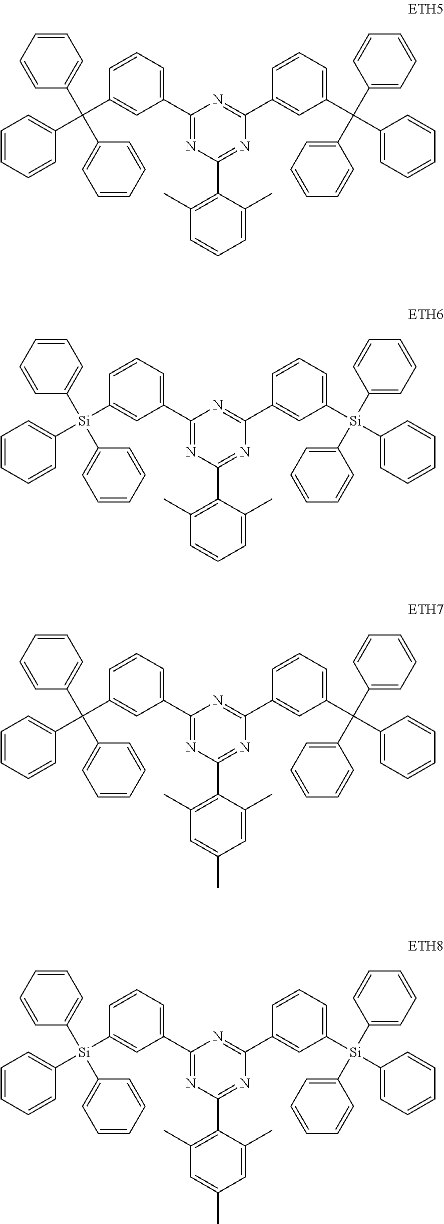 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

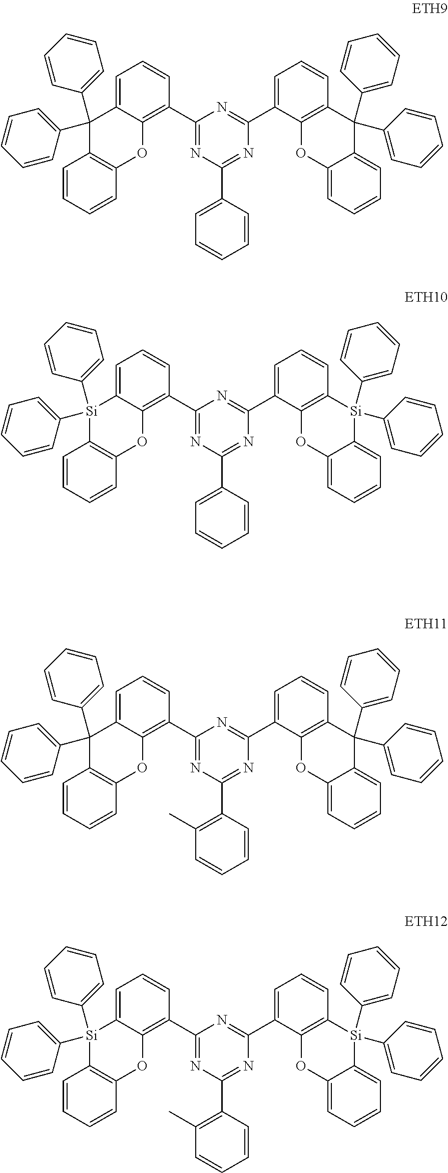 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

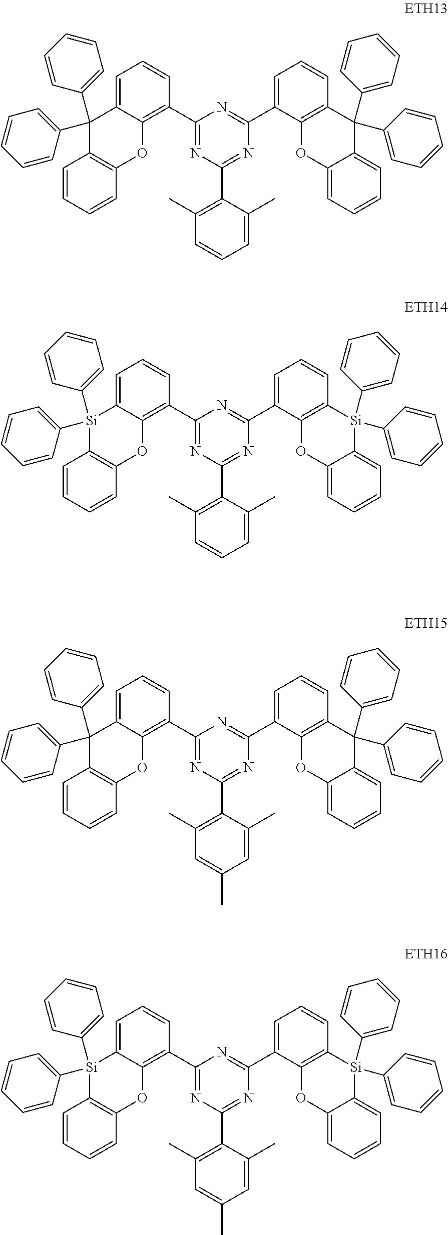 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

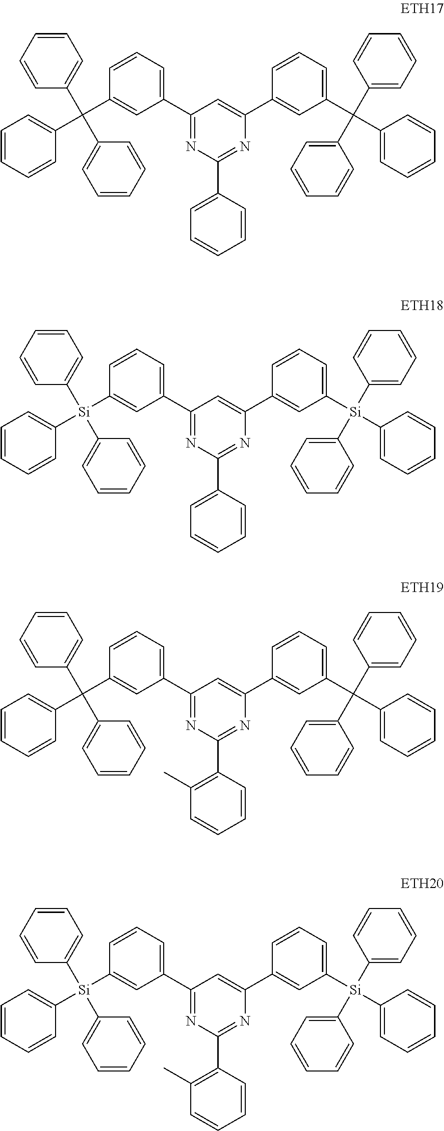 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

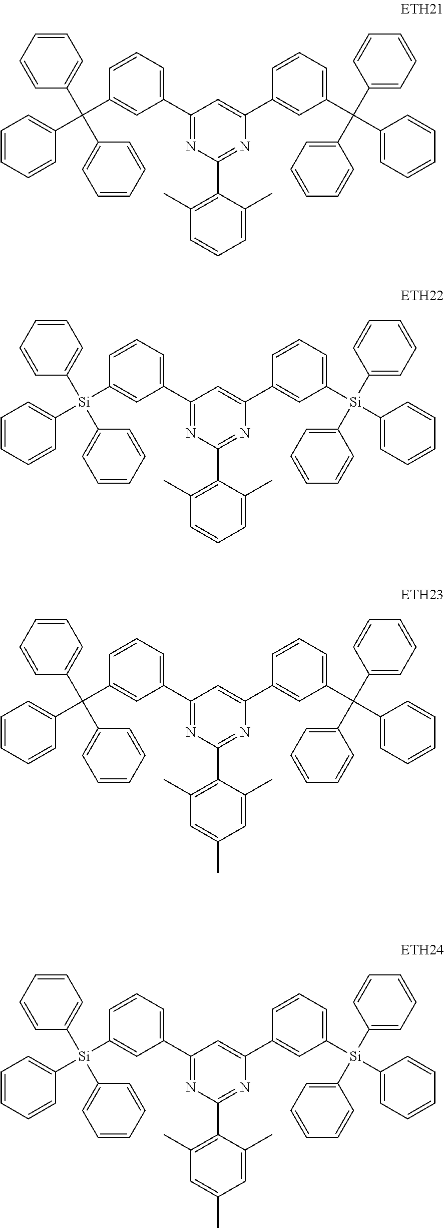 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

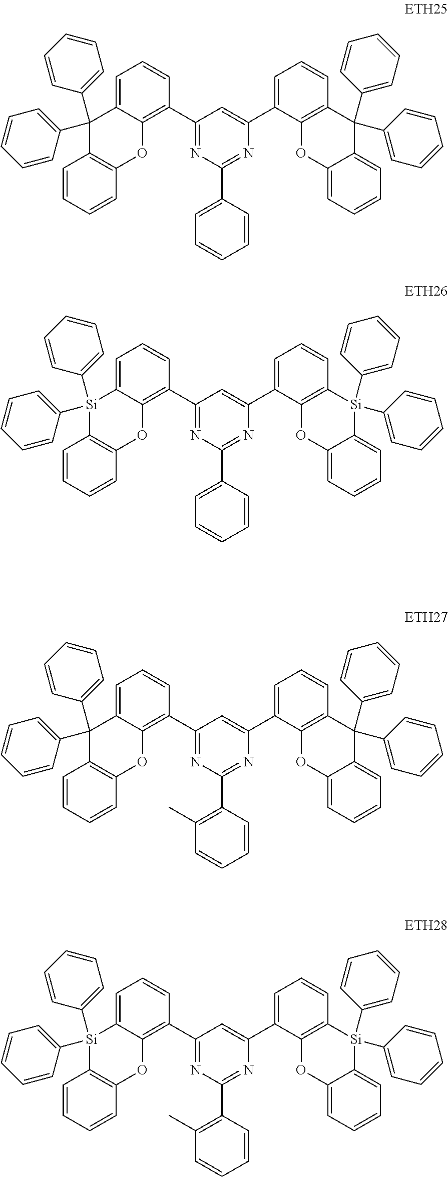 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

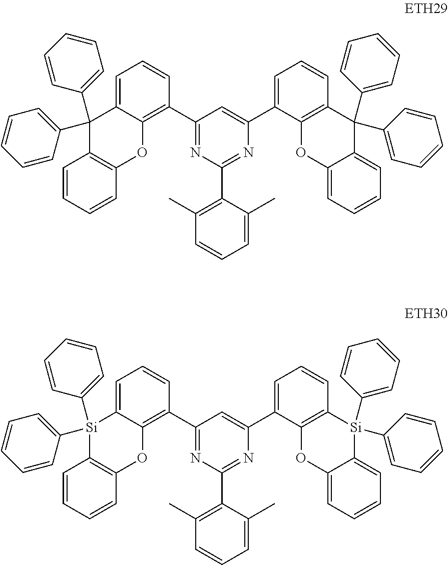 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

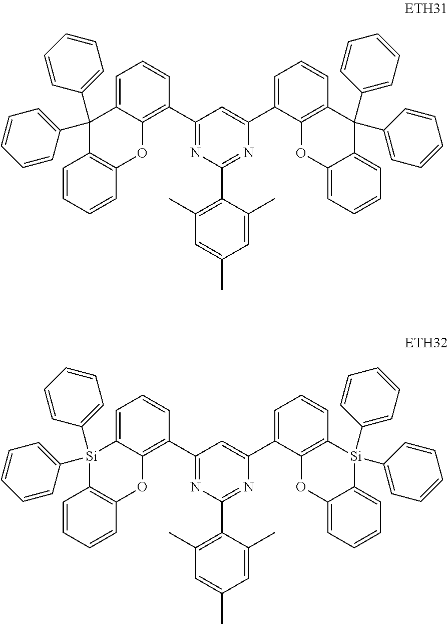 [SMILES: Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

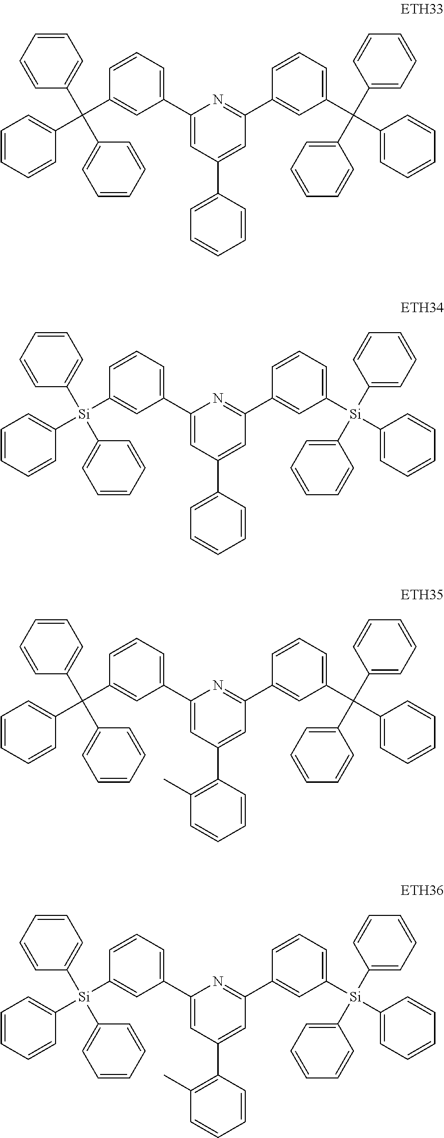 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

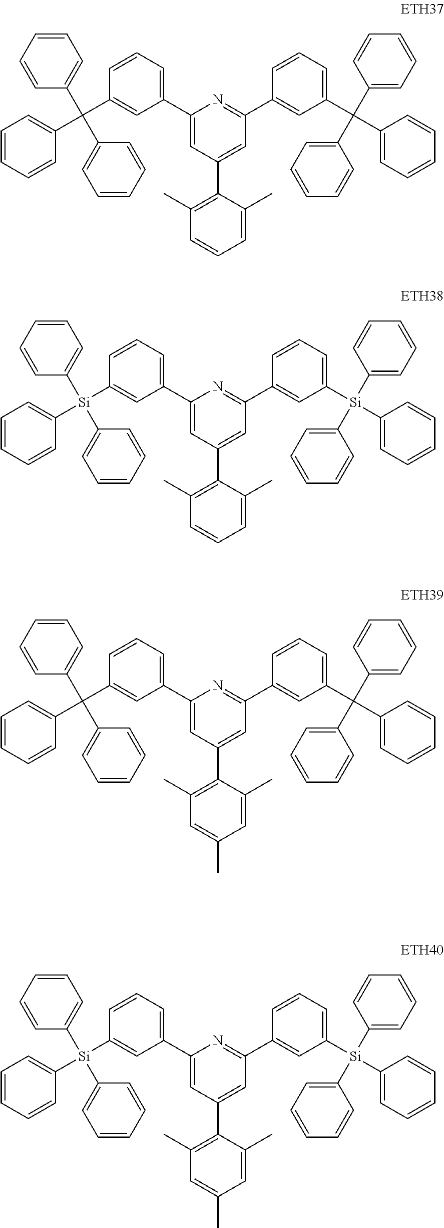 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

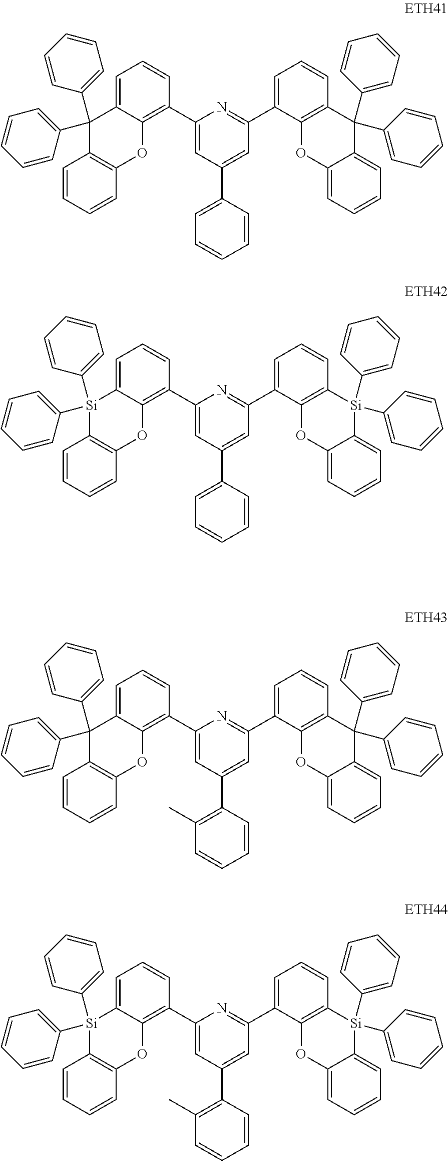 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

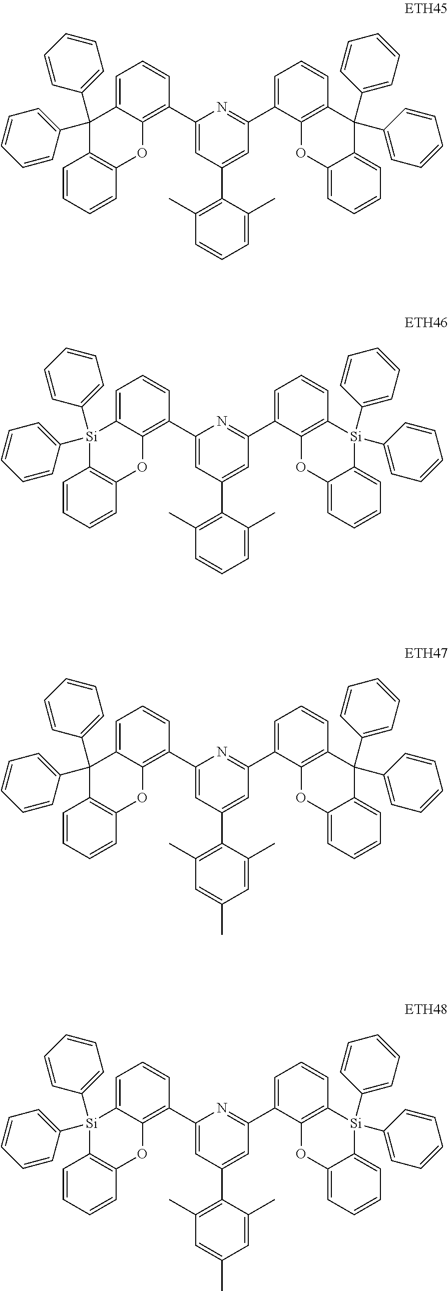 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

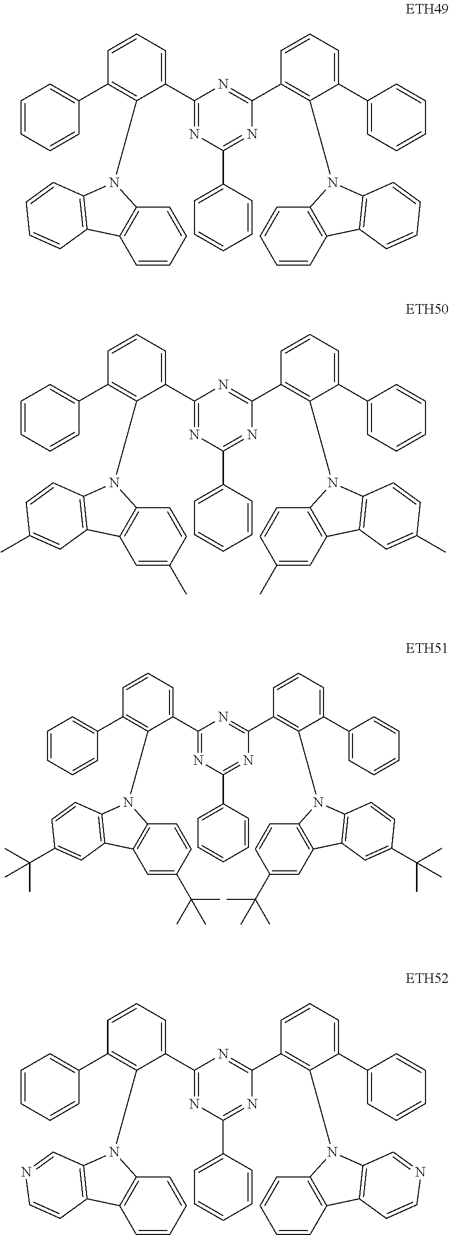

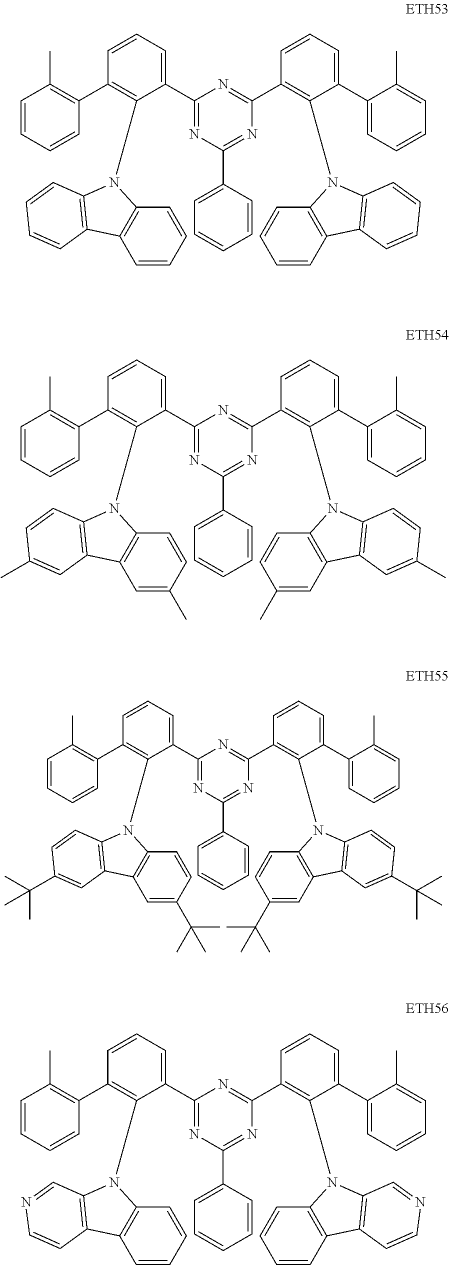

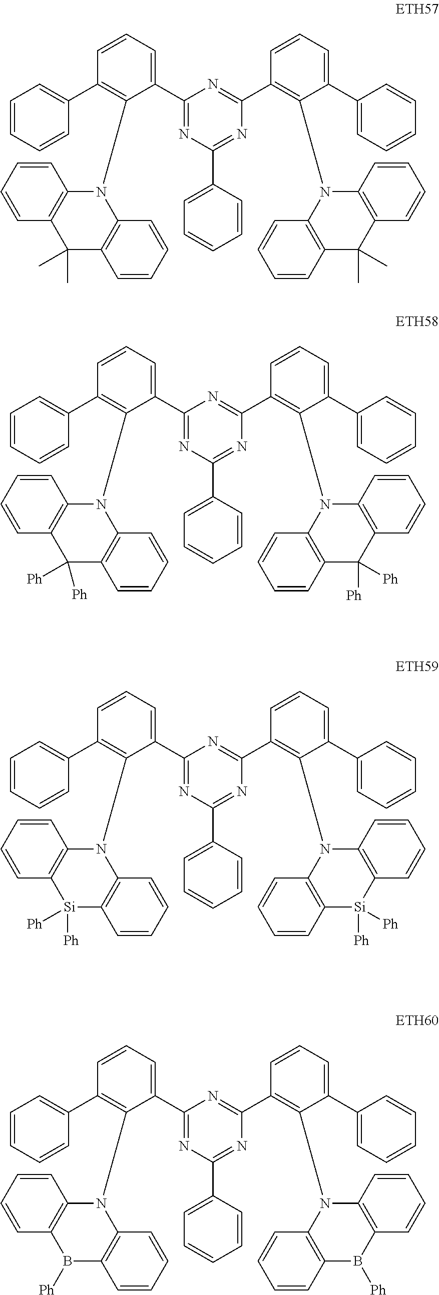

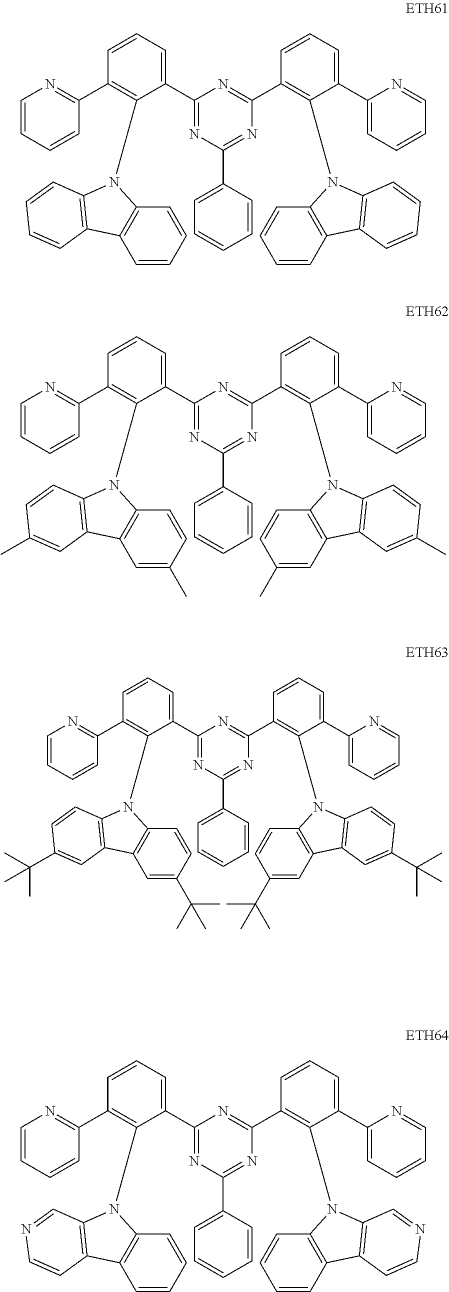

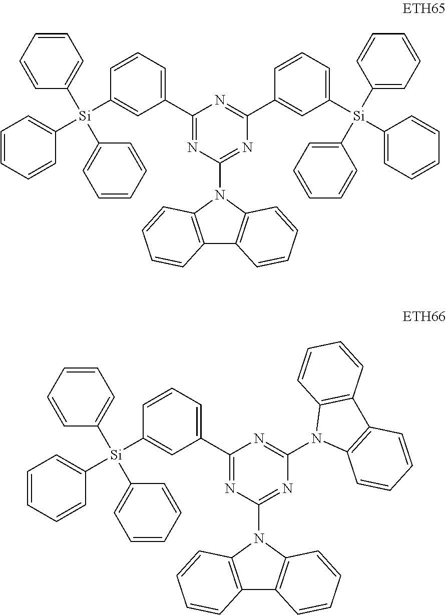 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

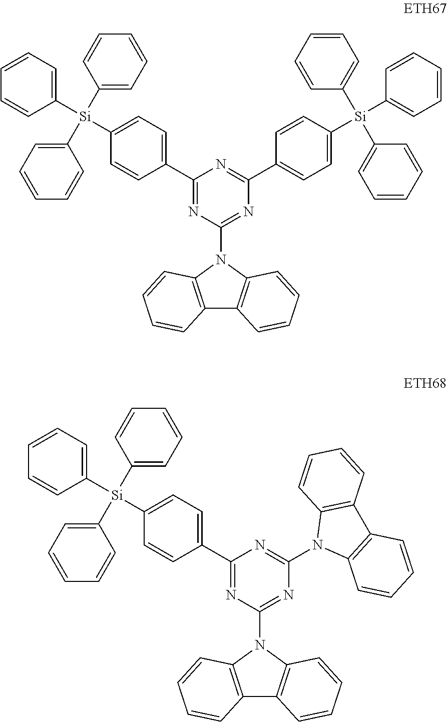 [SMILES: c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

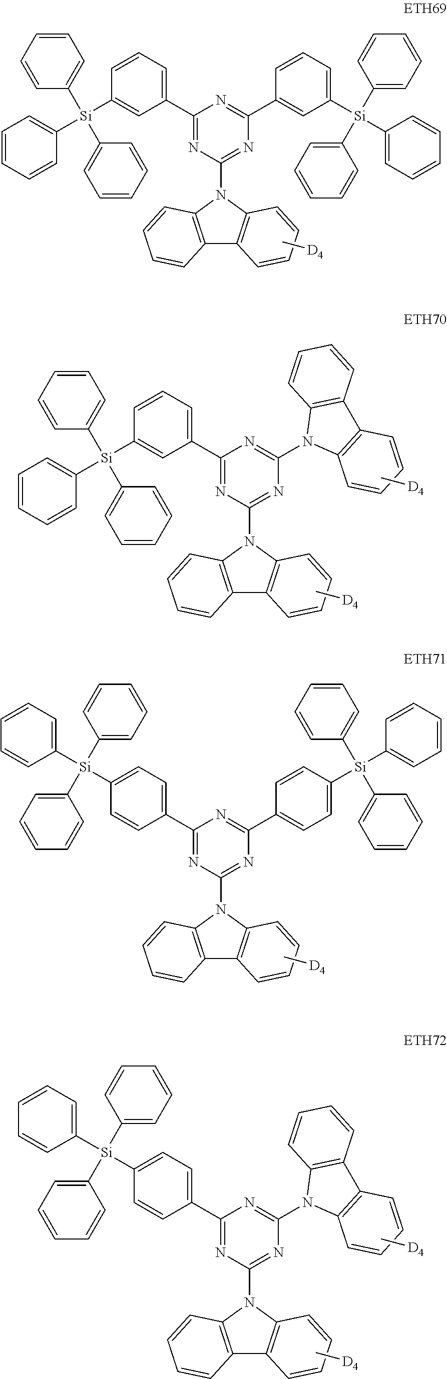

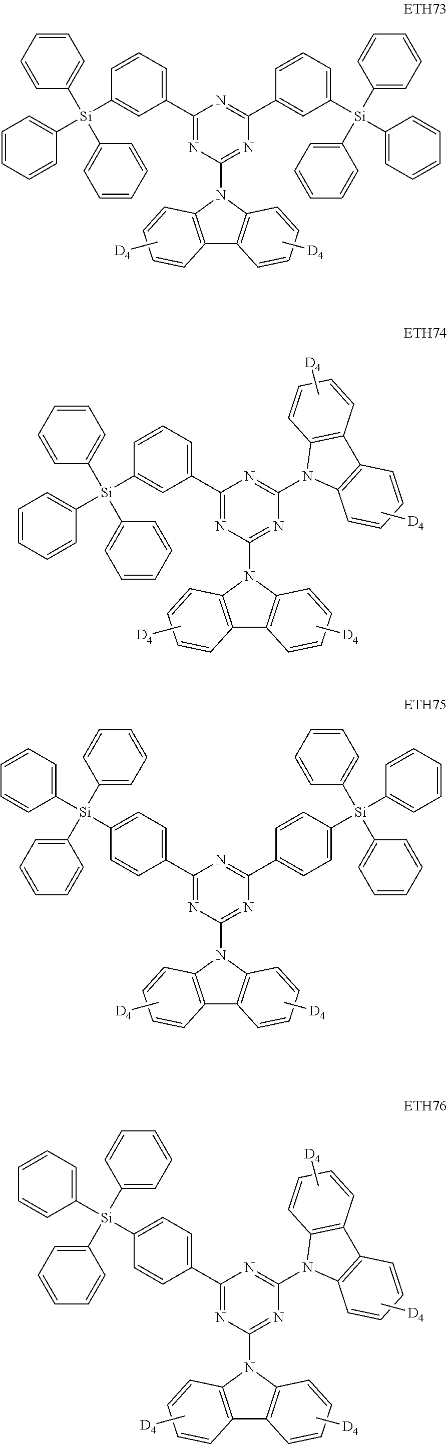

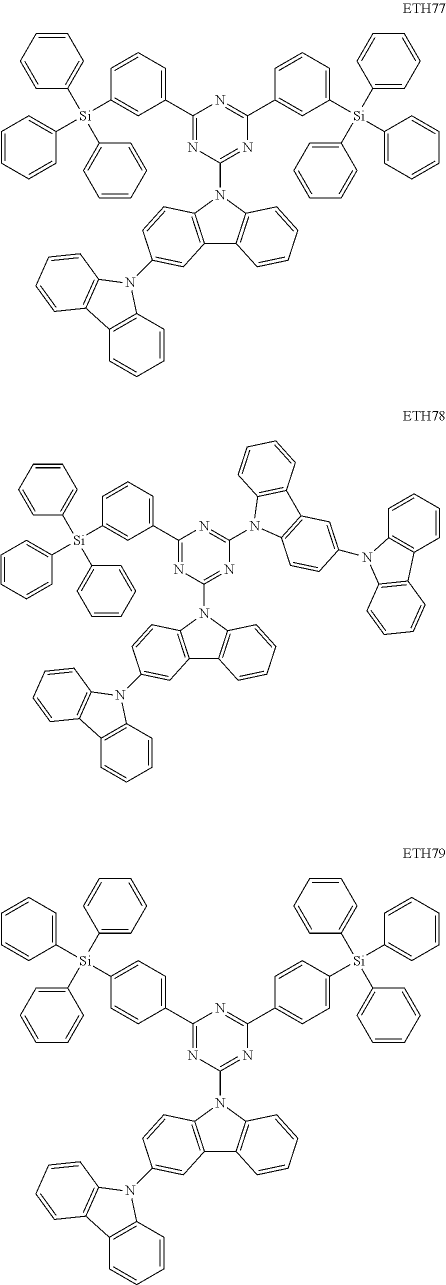 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

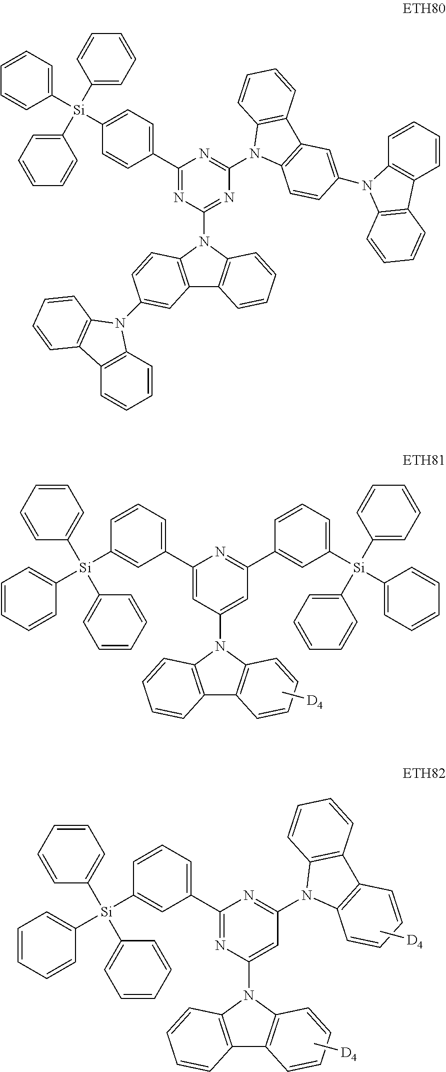

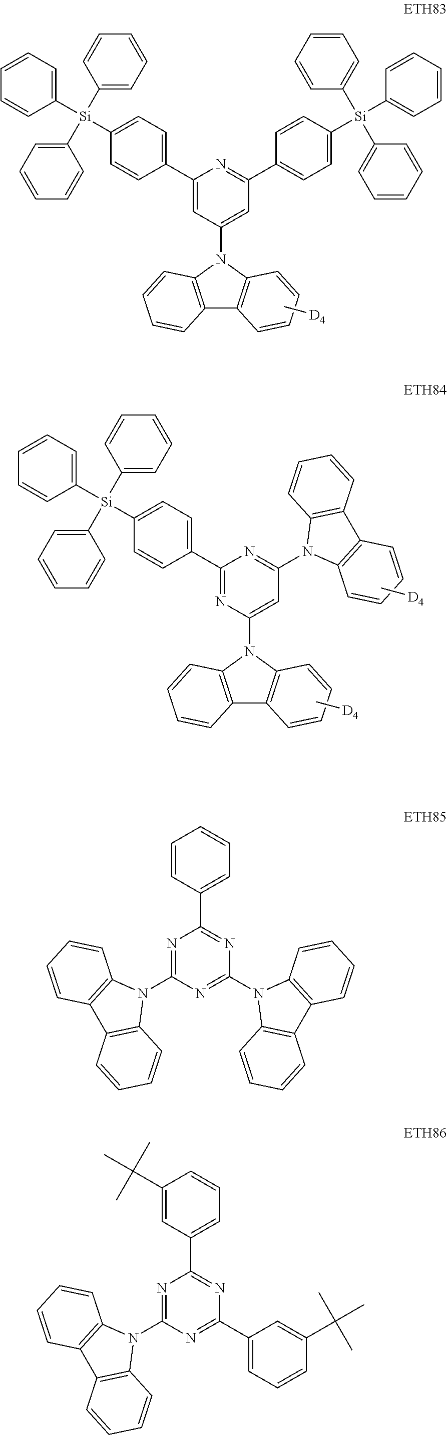

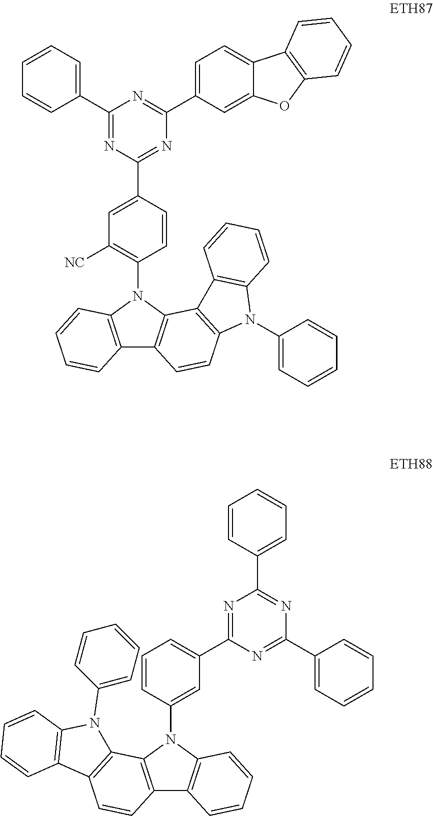 [SMILES: N#Cc1cc(-c2nc(-c3ccccc3)nc(-c3ccc4c(c3)oc3ccccc34)n2)ccc1-n1c2ccccc2c2ccc3c(c4ccccc4n3-c3ccccc3)c21 ; c1ccc(-c2nc(-c3ccccc3)nc(-c3cccc(-n4c5ccccc5c5ccc6c7ccccc7n(-c7ccccc7)c6c54)c3)n2)cc1]

In the particular compounds suggested in Compound Group 3, “D” means a deuterium atom, and “Ph” means (refers to) an unsubstituted phenyl group.

The emission layer EML may include a compound represented by Formula D-1. The compound represented by Formula D-1 may be used as a phosphorescent dopant material or phosphorescent sensitizer material.

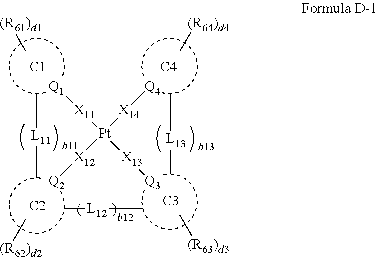

In Formula D-1, Q₁ to Q₄ may each independently be C or N.

In Formula D-1, C₁ to C₄ may each independently be a substituted or unsubstituted hydrocarbon ring of 5 to 30 ring-forming carbon atoms, or a substituted or unsubstituted heterocycle of 2 to 30 ring-forming carbon atoms.

In Formula D1, X₁₁ to X₁₄ may each independently be a direct linkage, or

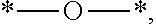

For example, any one of X₁₁ to X₁₄ may be

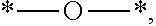

and the other one may be a direct linkage.

In Formula D-1, L₁₁ to L₁₃ may each independently be a direct linkage,

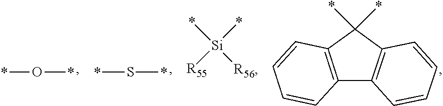

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, “ [symbol] ” means (refers to) a part [symbol] connected with C1 to C4.

In Formula D-1, b11 to b13 may each independently be 0 or 1. If (e.g., when) b11 is 0, C1 and C2 may be unconnected. If (e.g., when) b12 is 0, C2 and C3 may be unconnected. If (e.g., when) b3 is 0, C3 and C4 may be unconnected.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. Otherwise, each of R₆₁ to R₆₆ may be combined with an adjacent group to form a ring. R₆₁ to R₆₆ may each independently be a substituted or unsubstituted methyl group, or a substituted or unsubstituted t-butyl group.

In Formula D-1, d1 to d4 are each independently an integer of 0 to 4. In Formula D-1, if (e.g., when) d1 to d4 are 0, the fourth compound may be unsubstituted with R₆₁ to R₆₄, respectively. A case where d1 to d4 are 4, and R₆₁ to R₆₄ are hydrogen atoms, may be the same as a case where d1 to d4 are 0. If (e.g., when) d1 to d4 are integers of 2 or more, each of multiple R₆₁ to R₆₄ may be all the same, or at least one selected from among multiple R₆₁ to R₆₄ may be different.

In Formula D-1, C₁ to C₄ may each independently be a substituted or unsubstituted hydrocarbon ring or a substituted or unsubstituted heterocycle, represented by any one selected from among C-1 to C-5.

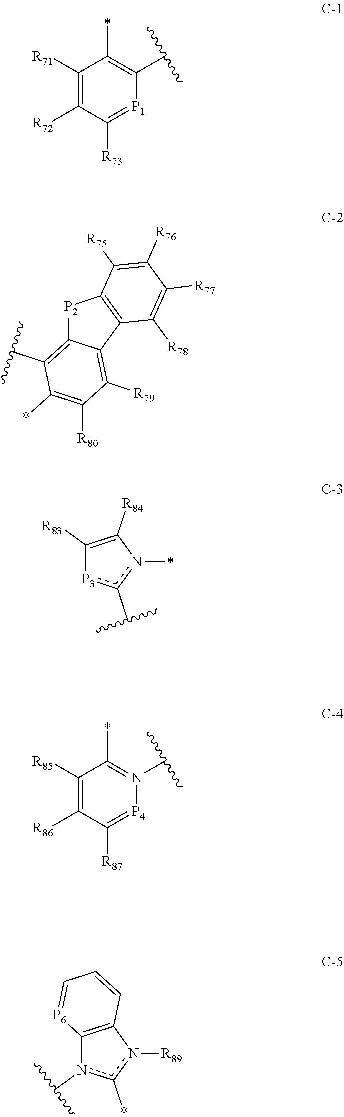

In C-1 to C-5, P₁ may be [symbol] or CR₇₄, P₂ may be [symbol] or NR₈₁, P₃ may be [symbol] or NR₈₂, P₄ may be [symbol] or CR₈₈, and P₆ may be [symbol] or CR₉₀. R₇₁ to R₉₀ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In some embodiments, in C-1 to C-5,

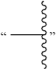

is a part connected with a central metal atom of Pt, and “ [symbol] ” corresponds to a part connected with an adjacent ring group (C1 to C4) or linker (L₁₁ to L₁₃).

The light emitting element ED of one or more embodiments includes all of the first host, the second host, and the dopant, and the light emitting layer EML may include the combination of two host materials and one dopant material. In the light emitting element ED of one or more embodiments, the light emitting layer EML may include the first host and the second host, which are two different hosts, and the phosphorescence dopant including an organometallic complex, simultaneously, and may show suitable or excellent emission efficiency properties.

In one or more embodiments, the dopant represented by Formula D-1 may be represented by at least one selected from among the compounds represented in Compound Group 4. The light emitting layer EML may include at least one selected from among the compounds represented in Compound Group 4 as a phosphorescence dopant.

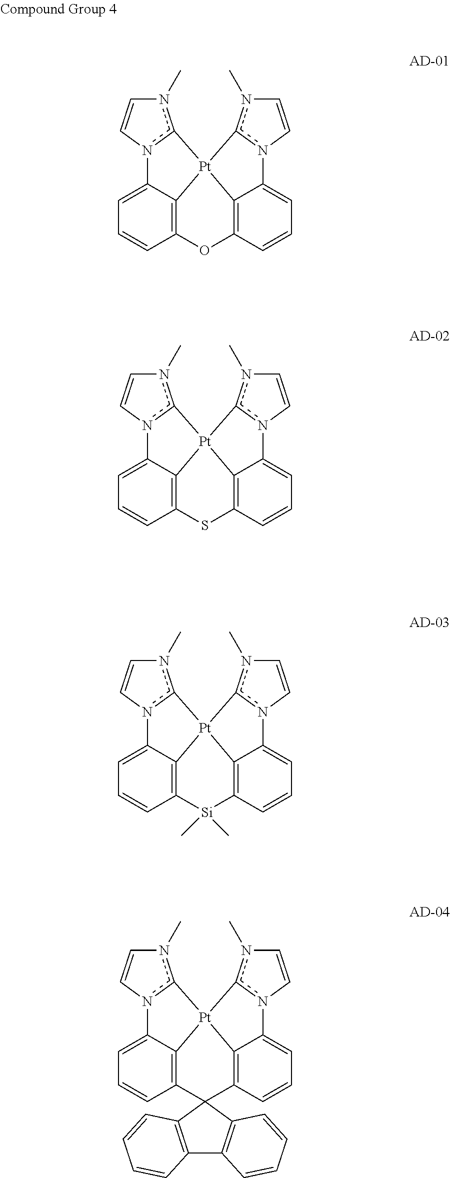

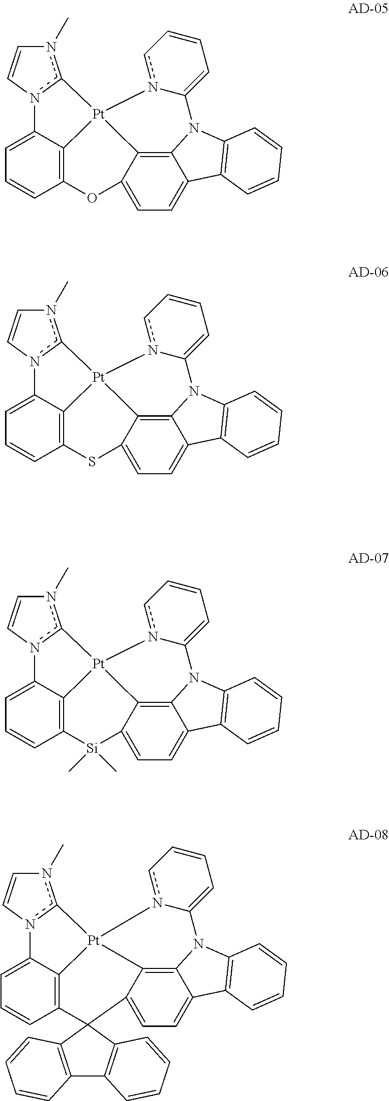

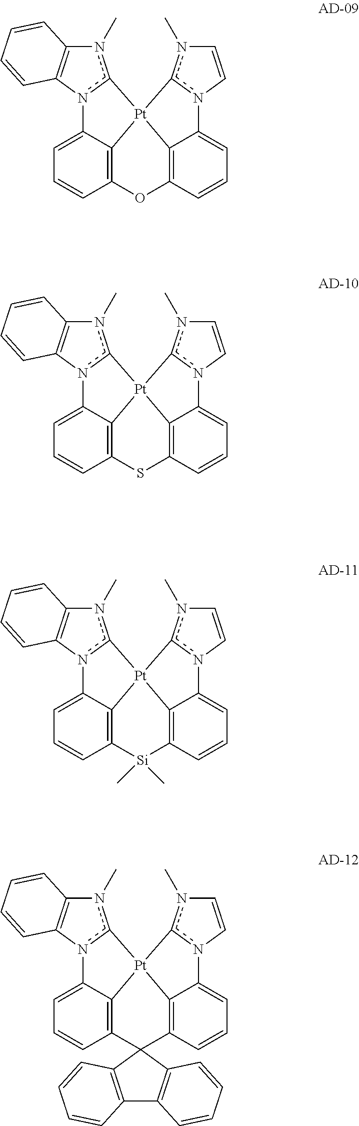

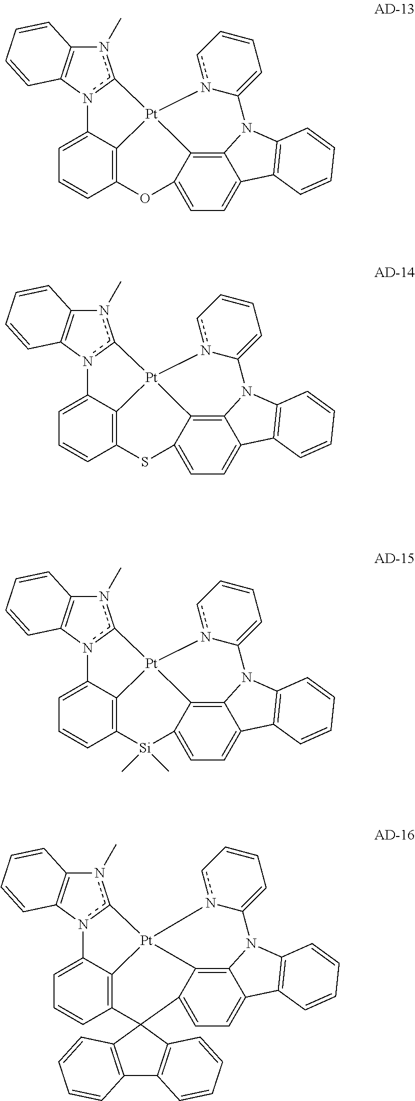

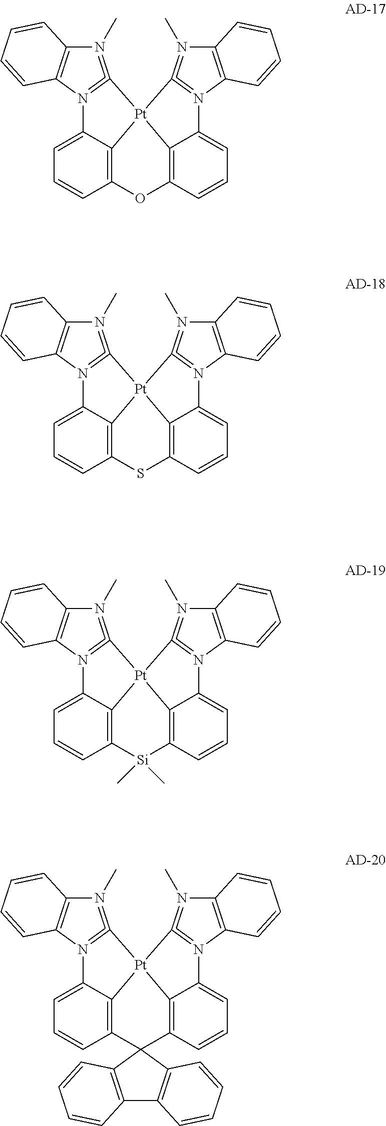

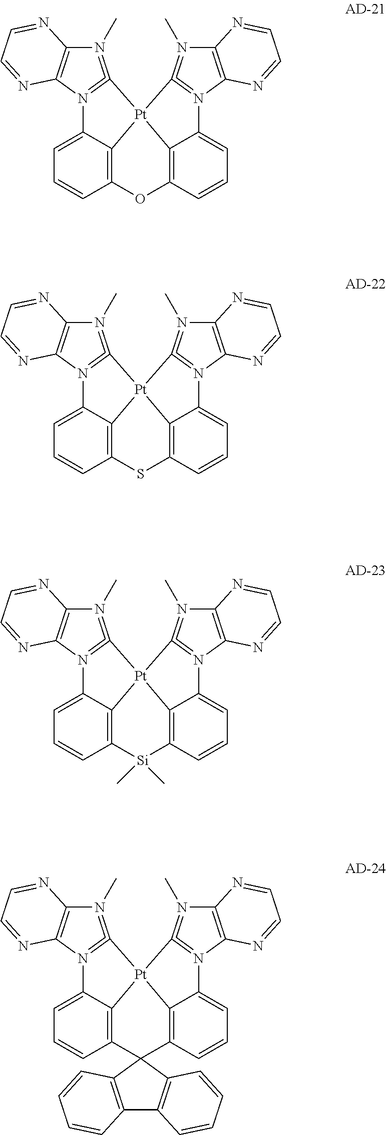

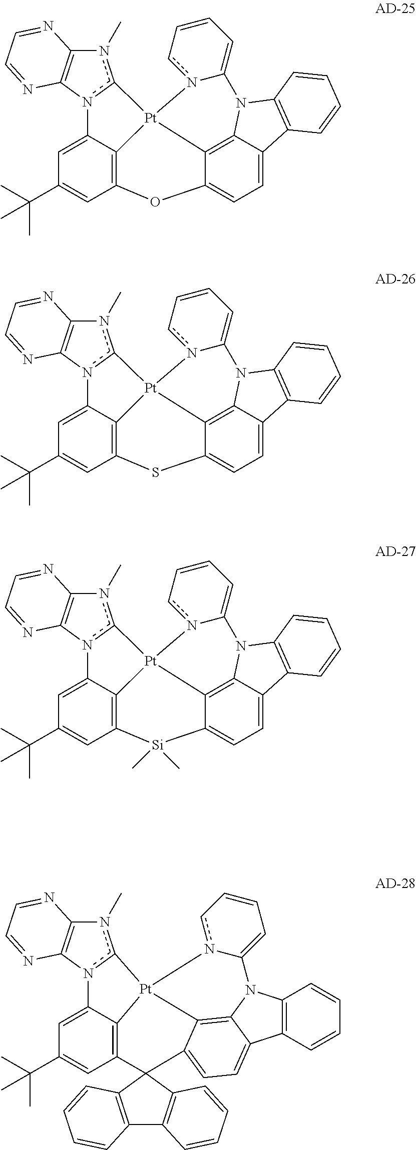

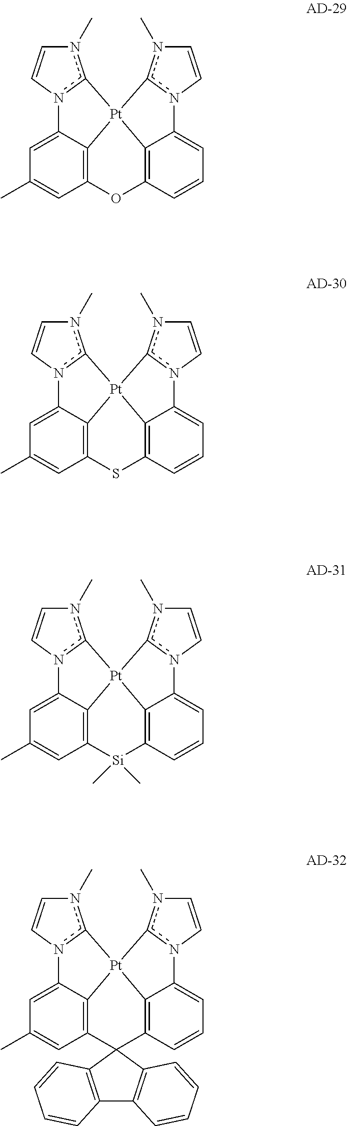

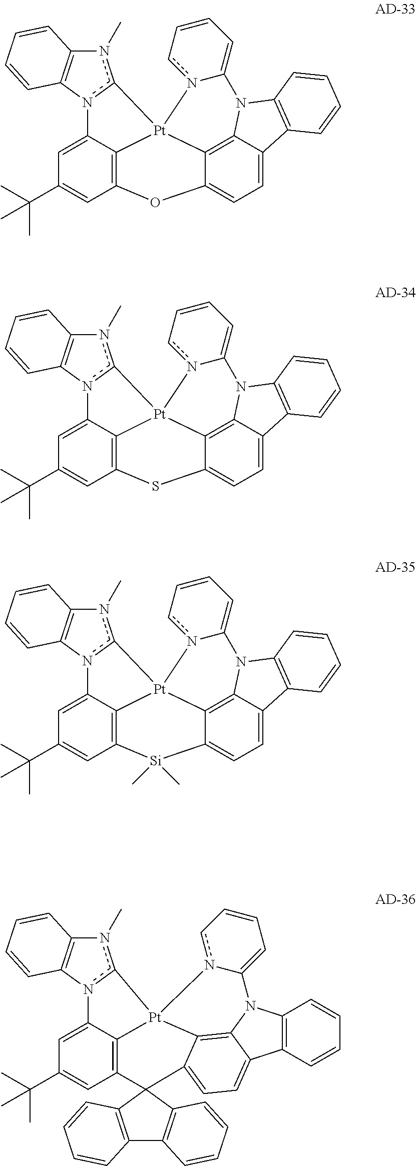

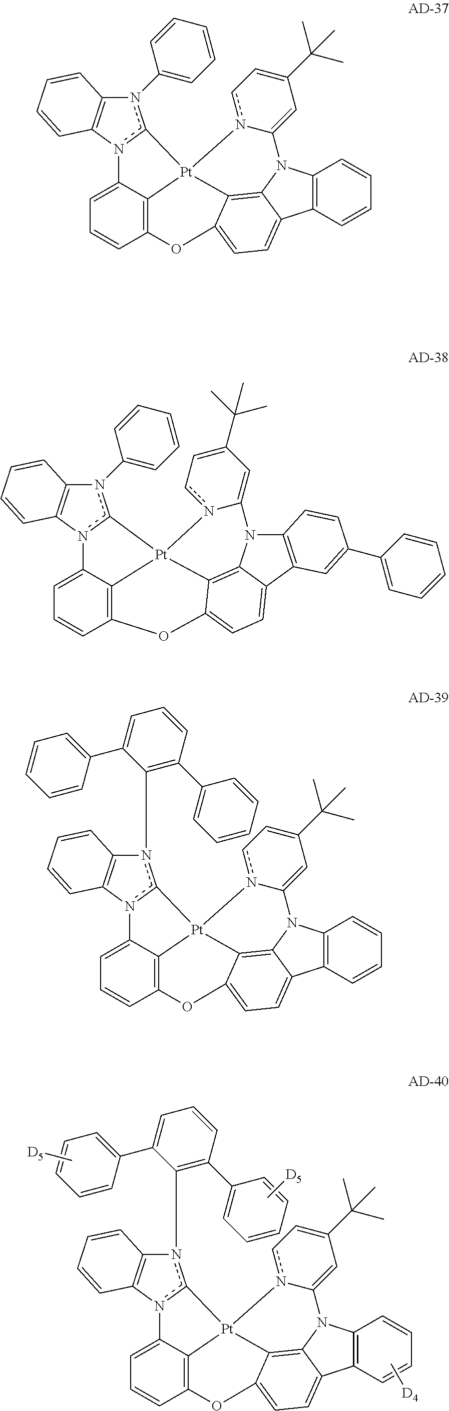

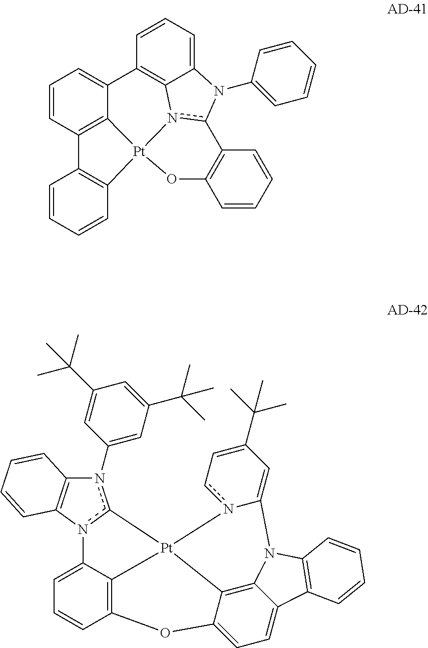

In the particular compounds suggested in Compound Group 4, “D” means (refers to) a deuterium atom.

The emission layer EML may include a compound represented by any one selected from among Formula F-a to Formula F-c. The compound represented by any one selected from among Formula F-a to Formula F-c may be used as a fluorescent dopant material or delayed fluorescent dopant material.

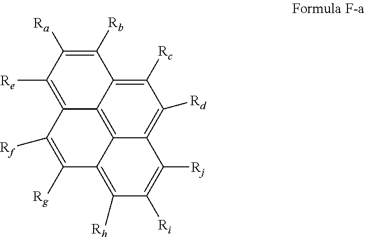

In Formula F-a, two selected from among Rₐ to Rⱼ may each independently be substituted with [symbol] . The remainder not substituted with [symbol] among Rₐ to Rⱼ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In [symbol] Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one selected from among Ar₁ and Ar₂ may be a heteroaryl group including O or S as a ring-forming atom.

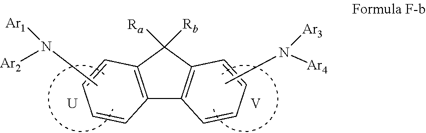

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms. At least one selected from among Ar₁ to Ar₄ may be a heteroaryl group including O or S as a ring-forming atom.

In Formula F-b, the number of rings represented by U and V may each independently be 0 or 1. For example, in Formula F-b, if (e.g., when) the number of U or V is 1, one ring may form a fused ring at the designated part by U or V, and if (e.g., when) the number of U or V is 0, a ring may not be present at the designated part by U or V. Particularly, if (e.g., when) the number of U is 0, and the number of V is 1, or if (e.g., when) the number of U is 1, and the number of V is 0, a fused ring having the fluorene core of Formula F-b may be a ring compound with four rings. In some embodiments, if (e.g., when) the number of both U and V is (e.g., simultaneously) 0, the fused ring of Formula F-b may be a ring compound with three rings. In some embodiments, if (e.g., when) the number of both U and V is (e.g., simultaneously) 1, a fused ring having the fluorene core of Formula F-b may be a ring compound with five rings.

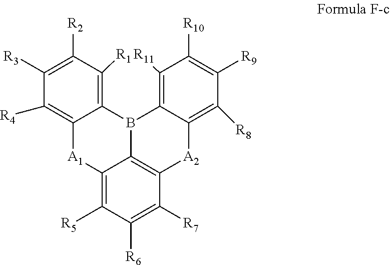

In Formula F-c, A₁ and A₂ may each independently be O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula F-c, A₁ and A₂ may each independently be combined with the substituents of an adjacent ring to form a fused ring. For example, if (e.g., when) A₁ and A₂ are each independently NRₘ, A₁ may be combined with R₄ or R₅ to form a ring. In some embodiments, A₂ may be combined with R₇ or R₈ to form a ring.

In one or more embodiments, the light emitting layer EML may include as a known dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino)pyrene), and/or the like.

The light emitting layer EML may include a known phosphorescence dopant material. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb) or thulium (Tm). Particularly, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), or platinum octaethyl porphyrin (PtOEP) may be used as the phosphorescence dopant. However, one or more embodiments of the present disclosure is not limited thereto.

The emission layer may include a quantum dot.

In the description, the quantum dot means (refers to) the crystal of a semiconductor compound. The quantum dot may emit light in one or more suitable emission wavelengths according to the size of the crystal. The quantum dot may emit light in one or more suitable emission wavelengths by controlling the element ratio in the quantum dot compound.

The diameter of the quantum dot may be, for example, about 1 nm to about 10 nm. A diameter of the quantum dots may be, for example, in a range of about 1 nanometer (nm) to about 10 nm. In the present disclosure, when quantum dot, quantum dots, or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dot may be synthesized by a chemical bath deposition, a metal organic chemical vapor deposition, a molecular beam epitaxy or a similar process therewith.

The chemical bath deposition is a method of mixing an organic solvent and a precursor material and then, growing a quantum dot particle crystal. During growing the crystal, the organic solvent may naturally play the role of a dispersant which is coordinated on the surface of the quantum dot crystal and may control the growth of the crystal. Accordingly, the chemical bath deposition is more advantageous when compared to a vapor deposition method including a metal organic chemical vapor deposition (MOCVD) and molecular beam epitaxy (MBE), and the growth of the quantum dot particle may be controlled through a low-cost process.

The light emitting layer EML may include a quantum dot material. The core of the quantum dot may be selected from a II-VI group compound, a III-VI group compound, a I-III-VI group compound, a III-V group compound, a III-II-V group compound, a IV-VI group compound, a IV group element, a IV group compound, and combinations thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof. The Group II-VI compound may further include a Group I metal and/or a Group IV element. The Group I-II-VI compound may be selected from CuSnS or CuZnS, and the Group II-IV-VI compound may be selected from ZnSnS and/or the like. The Group I-II-IV-VI compound may be selected from quaternary compounds selected from the group consisting of Cu₂ZnSnS₂, Cu₂ZnSnS₄, Cu₂ZnSnSe₄, Ag₂ZnSnS₂, and a mixture thereof.

The III-VI group compound may include a binary compound such as In₂S₃, and In₂Se₃, a ternary compound such as InGaS₃, and InGaSe₃, or arbitrary combinations thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂ and mixtures thereof, or a quaternary compound such as AgInGaS₂, and CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. The III-V group compound may further include a II group metal. For example, InZnP, and/or the like may be selected as a III-II-V group compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

The Group II-IV-V compound may be selected from a ternary compound selected from the group consisting of ZnSnP, ZnSnP₂, ZnSnAs₂, ZnGeP₂, ZnGeAs₂, CdSnP₂, and CdGeP₂ and a mixture thereof.

The Group IV element may be selected from the group consisting of Si, Ge, and a mixture thereof. The Group IV compound may be a binary compound selected from the group consisting of SiC, SiGe, and a mixture thereof.

Each element included in the multi-element compound such as the binary compound, ternary compound, and quaternary compound may be present in particles at a uniform (e.g., substantially uniform) concentration or a non-uniform (e.g., substantially non-uniform) concentration. For example, the preceding Formula indicates the types (kinds) of elements included in a compound, and element ratios in the compound may be different. For example, AgInGaS₂ may indicate AgInₓGa₁₋ₓS₂ (x is a real number between 0 and 1).

In this case, the binary compound, the ternary compound or the quaternary compound may be present at uniform (e.g., substantially uniform) concentration in a particle or may be present at a partially different concentration distribution state in the same particle. In some embodiments, a core/shell structure in which one quantum dot wraps another quantum dot may be possible. The interface of the core and the shell may have a concentration gradient in which the concentration of an element present in the shell is decreased toward the center.

In some embodiments, the quantum dot may have the herein-described core-shell structure including a core including a nanocrystal and a shell wrapping around the core. The shell of the quantum dot may play the role of a protection layer for preventing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, or a ternary compound such as MgA₁₂O₄, CoFe₂O₄, NiFe₂O₄ and CoMn₂O₄, but one or more embodiments of the present disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but one or more embodiments of the present disclosure is not limited thereto.

The quantum dot may have a full width of half maximum (FWHM) of emission wavelength spectrum of about 45 nm or less, about 40 nm or less, or about 30 nm or less. Within this range, color purity or color reproducibility may be enhanced or improved. In some embodiments, light emitted via such quantum dot is emitted in all directions, and light view angle properties may be enhanced or improved.

In some embodiments, the shape of the quantum dot may be generally used shapes in the art, without specific limitation. More particularly, the shape of spherical, pyramidal, multi-arm, or cubic nanoparticle, nanotube, nanowire, nanofiber, nanoplate particle, and/or the like may be used.

As the size of the quantum dot or the ratio of elements in the quantum dot compound is regulated, the energy band gap may be accordingly controlled to obtain light of one or more suitable wavelengths from the quantum dot emission layer. Therefore, by using the quantum dots as described herein (using quantum dots of different sizes or having different element ratios in the quantum dot compound), a light emitting element emitting light of one or more suitable wavelengths may be obtained. For example, the size of the quantum dots or the ratio of elements in the quantum dot compound may be regulated to emit red, green, and/or blue light. In some embodiments, the quantum dots may be configured to emit white light by combining light of one or more suitable colors.

In the light emitting element ED of embodiments, as shown in FIG. 3 to FIG. 6, the electron transport region ETR is provided on the light emitting layer EML. The electron transport region ETR may include at least one of an electron blocking layer HBL, an electron transport layer ETL or an electron injection layer EIL. However, one or more embodiments of the present disclosure is not limited thereto.

The electron transport region ETR may have a single layer formed using a single material, a single layer formed using multiple different materials, or a multilayer structure having multiple layers formed using multiple different materials.

The electron transport region ETR may include the herein-described hetero compound represented by Formula 1. For example, the electron transport region ETR may include the hetero compound according to one or more embodiments in, among the herein-described plurality of functional layers, a layer in contact with the emission layer EML. For example, the hetero compound according to one or more embodiments may be included (contained) in the electron transport layer ETL. However, one or more embodiments of the present disclosure is not limited thereto. In addition to the electron transport layer ETL, the hole blocking layer HBL or an electron injection layer EIL may include the hetero compound according to one or more embodiments. The description of the hetero compound included in the emission layer EML may be similarly applied for the hetero compound, and thus detailed descriptions will not be included (be omitted).

The hetero compound according to one or more embodiments may include a heterocyclic aromatic ring, which is formed by linkage of two silyl groups via two linkers. The hetero compound according to one or more embodiments may have greater steric hindrance properties for an adjacent compound molecule due to the cyclic structure, compared to a non-cyclic compound. Therefore, compared to other compounds including the two connected silyl groups that form no ring, the hetero compound according to one or more embodiments may have less interaction with an adjacent compound molecule.

The hetero compound according to one or more embodiments may have a cyclic structure in which a first and second silicon atoms, each connected to three aromatic rings, a first linker linking the first and second silicon atoms, and a second linker linking any one selected from among the aromatic rings connected to the first silicon atom with any one selected from among the aromatic rings connected to the second silicon atom, are connected to each other. The hetero compound according to one or more embodiments may have excellent electron transporting properties and high lowest excited triplet energy level due to the herein-described specific molecular structure.

Therefore, the light-emitting element ED according to one or more embodiments may include the hetero compound according to one or more embodiments in the electron transport region ETR, and thus high efficiency and long lifespan may be achieved. For example, the light-emitting element ED according to one or more embodiments may include the hetero polycyclic compound according to one or more embodiments, in the electron transport layer ETL, and thus high efficiency and long lifespan may be achieved. However, one or more embodiments of the present disclosure is not limited thereto, and the plurality of functional layers of the electron transport region ETR may include the hetero compound according to one or more embodiments without limitation.

The electron transport region ETR may have a single layer formed using a single material, a single layer formed using multiple different materials, or a multilayer structure having multiple layers formed using multiple different materials.

For example, the electron transport region ETR may have a single layer structure of an electron injection layer EIL or an electron transport layer ETL, or a single layer structure formed using an electron injection material and an electron transport material. Further, the electron transport region ETR may have a single layer structure formed using multiple different materials, or a structure stacked from the light emitting layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may include one or more hetero compounds represented by Formula 1. For example, the electron transport region ETR may include at least one selected from among the compounds present in Compound Group 1, previously described.

The electron transport region ETR may be formed using one or more suitable methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2.

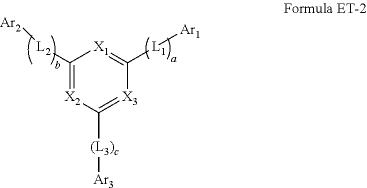

In Formula ET-2, at least one selected from among X₁ to X₃ may be N, and the remainder are CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may each independently be an integer of 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If (e.g., when) “a” to “c” are integers of 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, one or more embodiments of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAIq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), CNNPTRZ(4′-(4-(4-(4,6-diphenyl-1,3,5-triazin-2-yl)phenyl)naphthalen-1-yl)-[1,1′-biphenyl]-4-carbonitrile) and mixtures thereof, without limitation.

In one or more embodiments, electron transport region ETR may include any one selected from among the compounds in Compound Group 2.

The electron transport region ETR may include at least one selected from among Compounds ET1 to ET38.

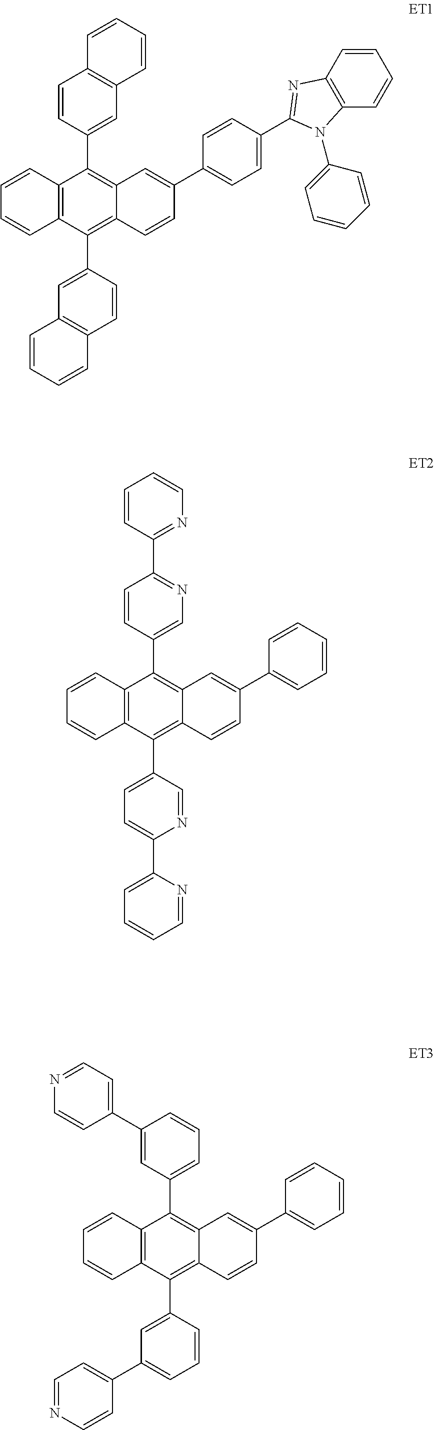 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

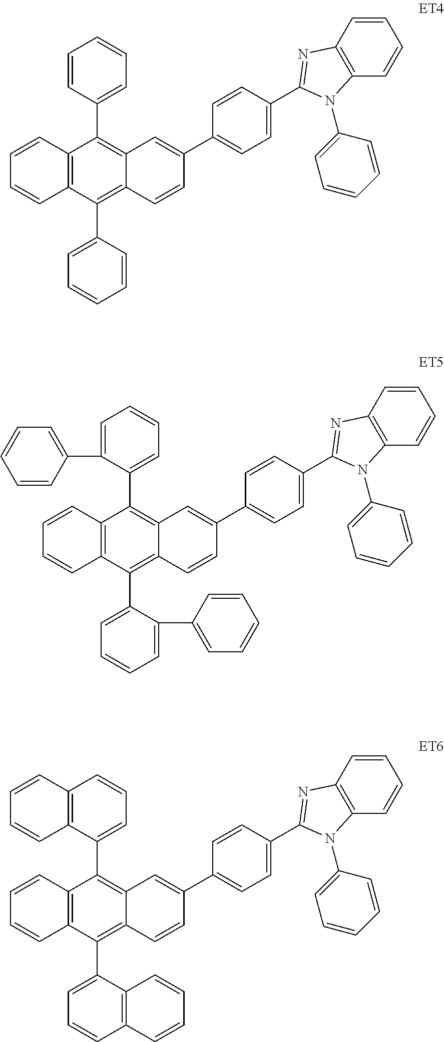 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

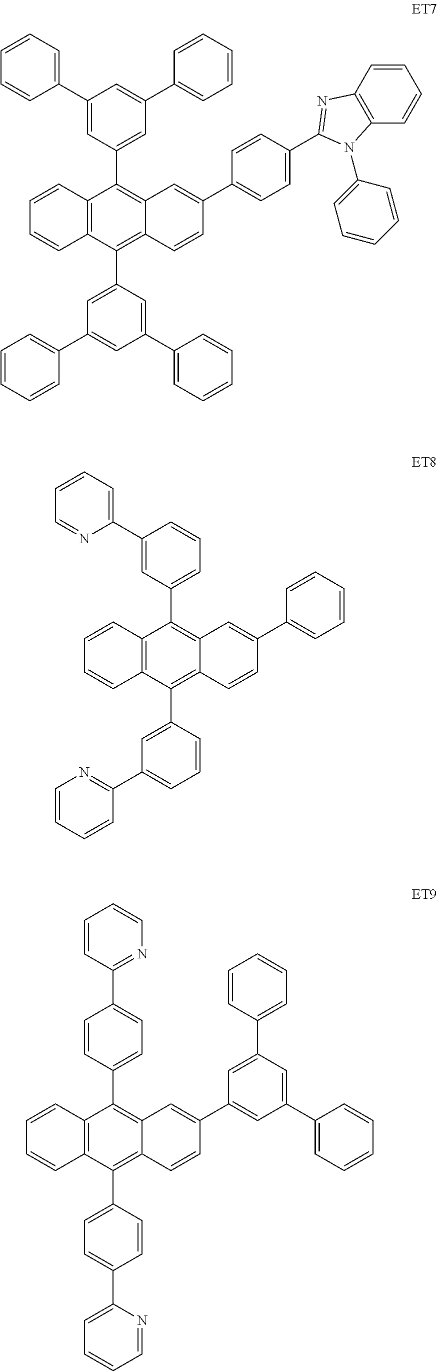 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2ccc3c(-c4cccc(-c5ccccn5)c4)c4ccccc4c(-c4cccc(-c5ccccn5)c4)c3c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

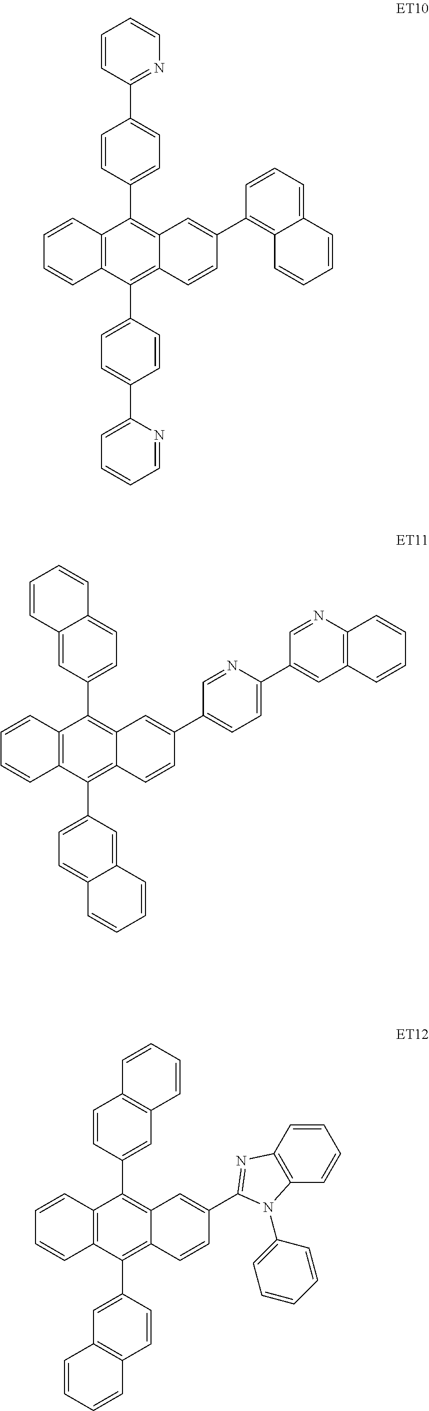 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

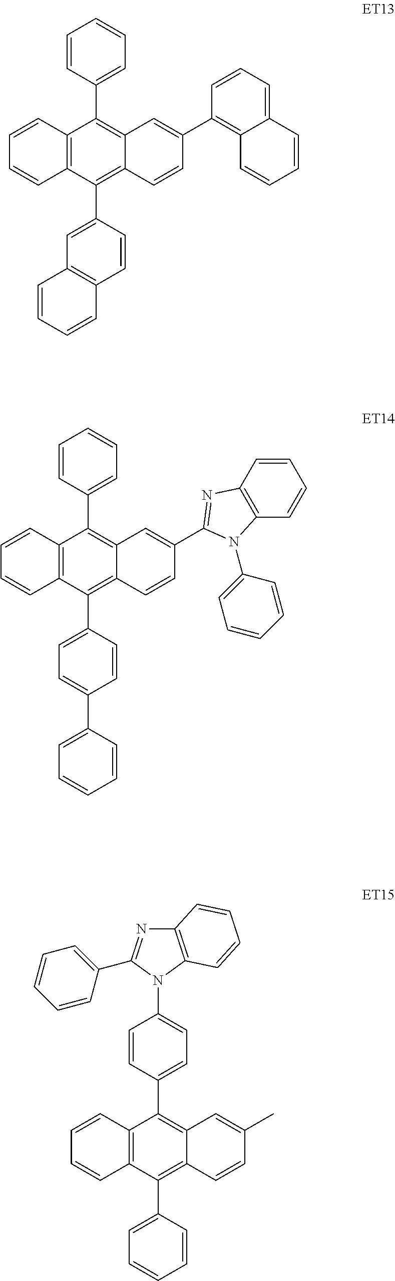

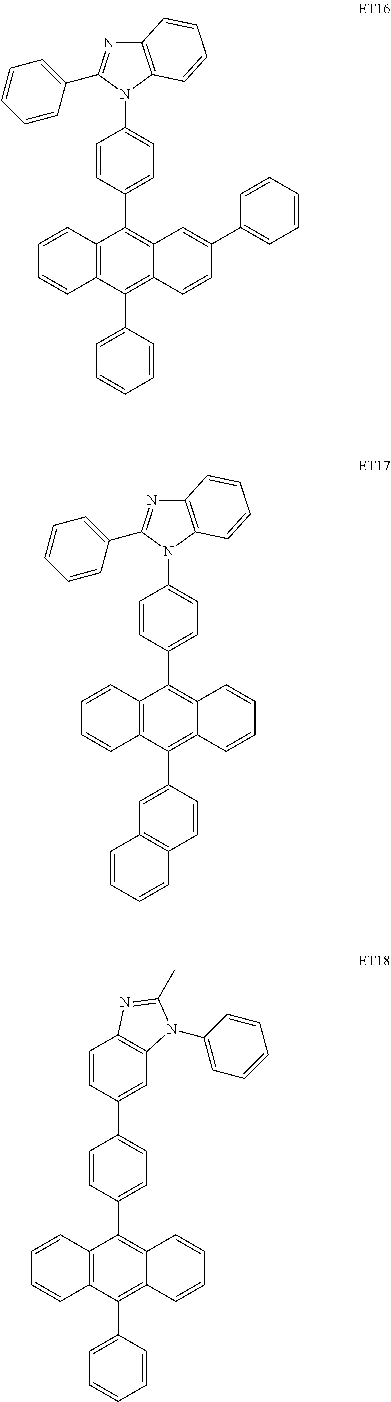 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

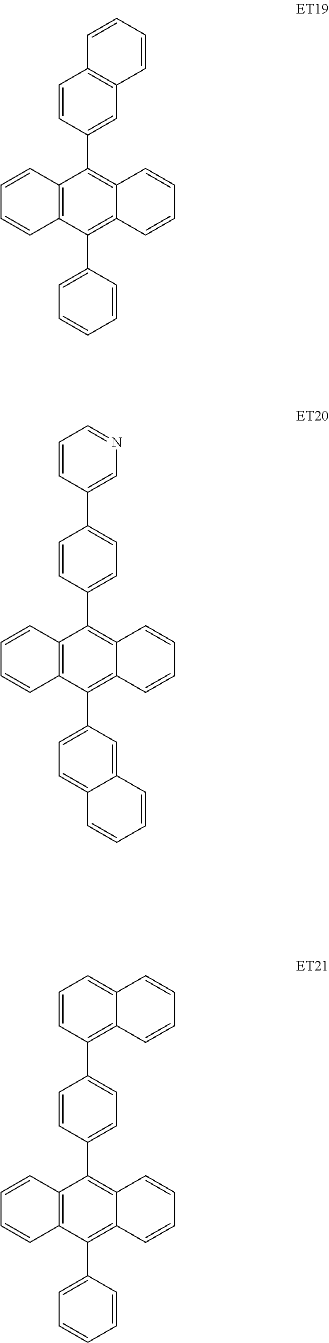

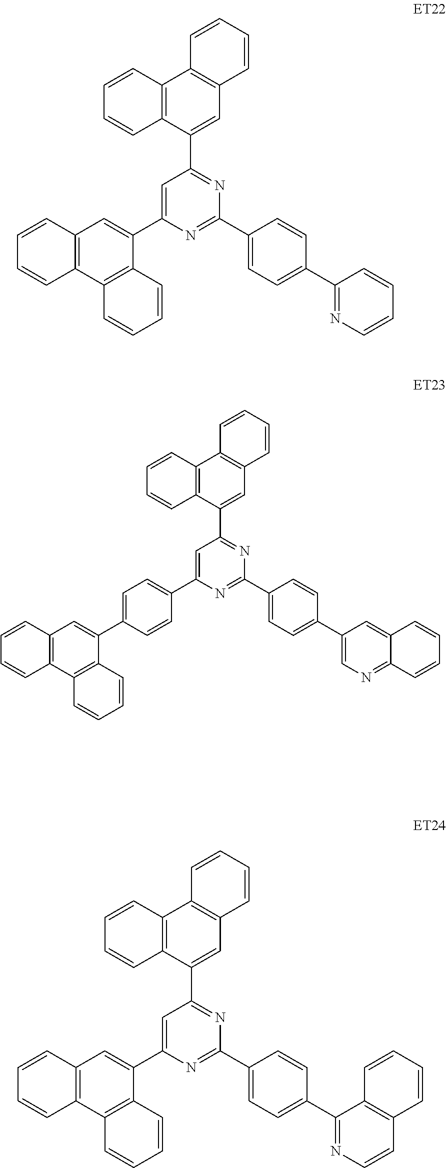 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

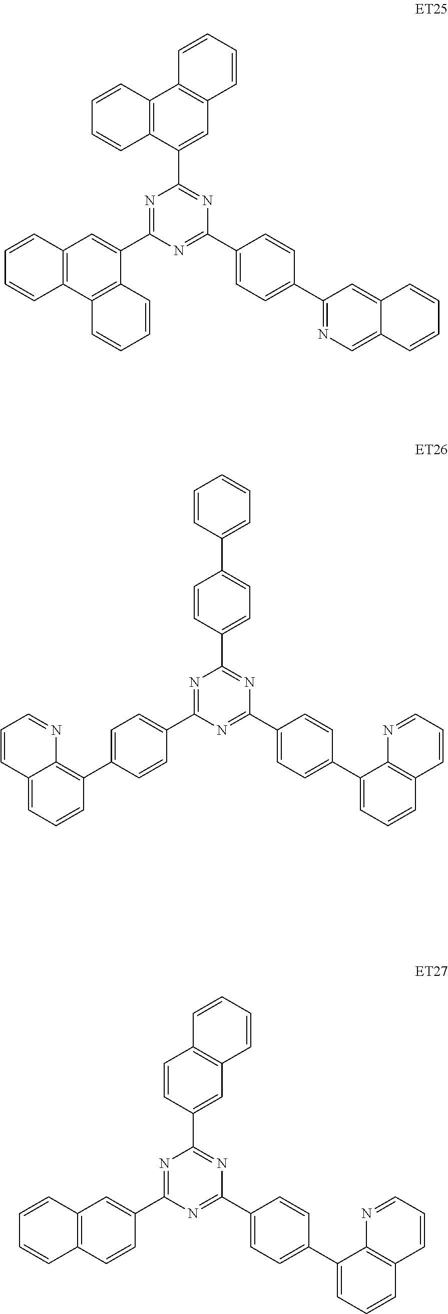 [SMILES: c1ccc2cc(-c3ccc(-c4nc(-c5cc6ccccc6c6ccccc56)nc(-c5cc6ccccc6c6ccccc56)n4)cc3)ncc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

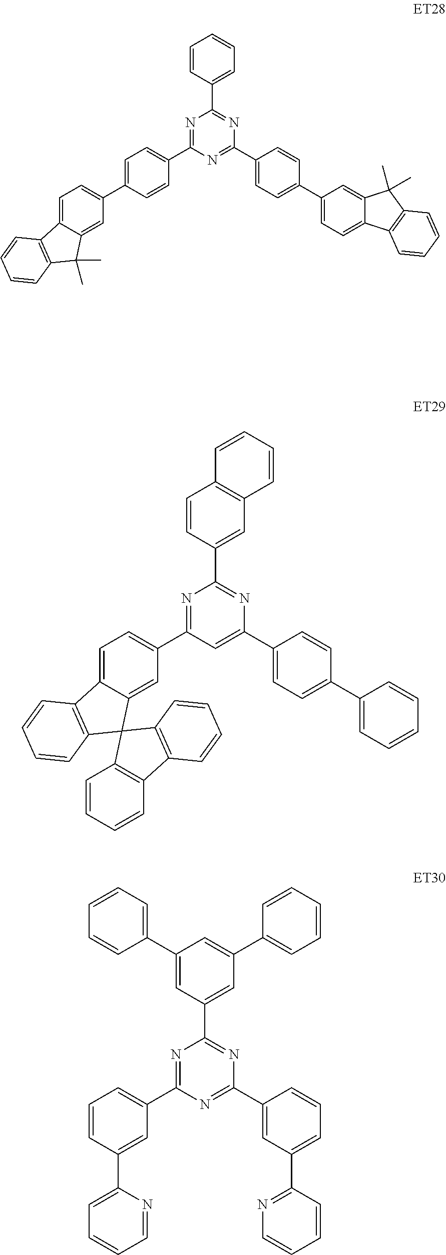 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

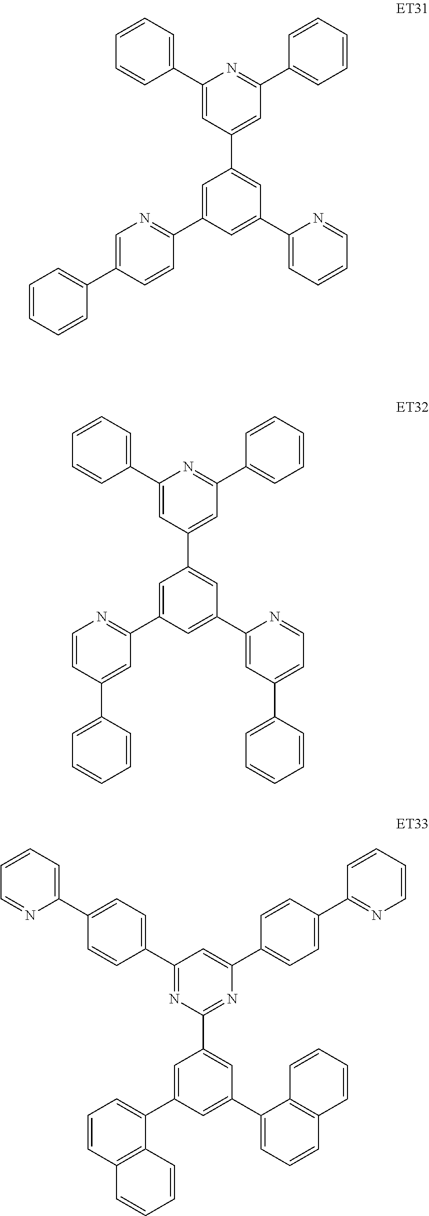 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

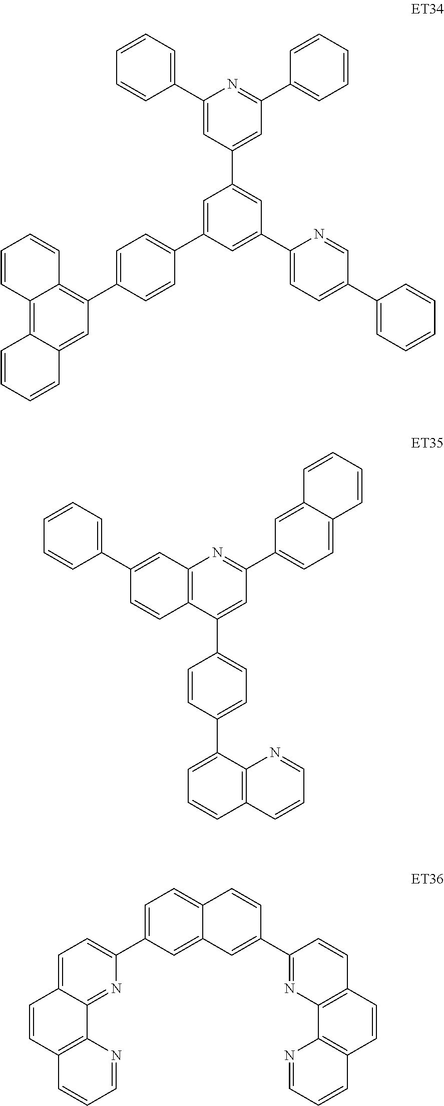 [SMILES: c1ccc(-c2ccc(-c3cc(-c4ccc(-c5cc6ccccc6c6ccccc56)cc4)cc(-c4cc(-c5ccccc5)nc(-c5ccccc5)c4)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI and KI, a metal in lanthanides such as Yb, or a co-depositing material of the metal halide and the metal in lanthanides. For example, the electron transport region ETR may include KI:Yb, RbI:Yb, LiF:Yb, and/or the like, as the co-depositing material. The electron transport region ETR may use a metal oxide such as Li₂O and BaO, or 8-hydroxy-lithium quinolate (Liq). However, one or more embodiments of the present disclosure is not limited thereto. The electron transport region ETR also may be formed using a mixture material of an electron transport material and an insulating organo metal salt. The organo metal salt may be a material having an energy band gap of about 4 eV or more. Particularly, the organo metal salt may include, for example, metal acetates, metal benzoates, metal acetoacetates, metal acetylacetonates, or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, one or more embodiments of the present disclosure is not limited thereto.

The electron transport region ETR may include the compounds of the electron transport region in at least one selected from among an electron injection layer EIL, an electron transport layer ETL, and a hole blocking layer HBL.

If the electron transport region ETR includes the electron transport layer ETL, the thickness of the electron transport layer ETL may be from about 100 Å to about 1,000 Å, for example, from about 150 Å to about 500 Å. If (e.g., when) the thickness of the electron transport layer ETL satisfies the herein-described range, satisfactory electron transport properties may be obtained without substantial increase of a driving voltage. If (e.g., when) the electron transport region ETR includes the electron injection layer EIL, the thickness of the electron injection layer EIL may be from about 1 Å to about 100 Å, and from about 3 Å to about 90 Å. If (e.g., when) the thickness of the electron injection layer EIL satisfies the preceding described ranges, satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but one or more embodiments of the present disclosure is not limited thereto. For example, if (e.g., when) the first electrode EL₁ is an anode, the second cathode EL2 may be a cathode, and if (e.g., when) the first electrode EL₁ is a cathode, the second electrode EL2 may be an anode.

The second electrode EL2 may be a transmissive electrode, a transflective electrode or a reflective electrode. If (e.g., when) the second electrode EL2 is the transmissive electrode, the second electrode EL2 may include a transparent metal oxide, for example, ITO, IZO, ZnO, ITZO, and/or the like.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compounds including thereof, or mixtures thereof (for example, AgMg, AgYb, or MgYb). Otherwise, the second electrode EL2 may have a multilayered structure including a reflective layer or a transflective layer formed using the herein-described materials and a transparent conductive layer formed using ITO, IZO, ZnO, ITZO, and/or the like. For example, the second electrode EL2 may include the aforementioned metal materials, combinations of two or more metal materials selected from the aforementioned metal materials, or oxides of the aforementioned metal materials.

In one or more embodiments, the second electrode EL2 may be connected with an auxiliary electrode. If (e.g., when) the second electrode EL2 is connected with the auxiliary electrode, the resistance of the second electrode EL2 may decrease.

On the second electrode EL2 in the light emitting element ED of one or more embodiments, a capping layer CPL may be further arranged. The capping layer CPL may include a multilayer or a single layer.

In one or more embodiments, the capping layer CPL may be an organic layer or an inorganic layer. For example, if (e.g., when) the capping layer CPL includes an inorganic material, the inorganic material may include an alkali metal compound such as LiF, an alkaline earth metal compound such as MgF₂, SiON, SiNx, SiOy, and/or the like.

For example, if (e.g., when) the capping layer CPL includes an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), and/or the like, or includes an epoxy resin, or acrylate such as methacrylate. In some embodiments, a capping layer CPL may include at least one selected from among Compounds P1 to P5, but one or more embodiments of the present disclosure is not limited thereto.

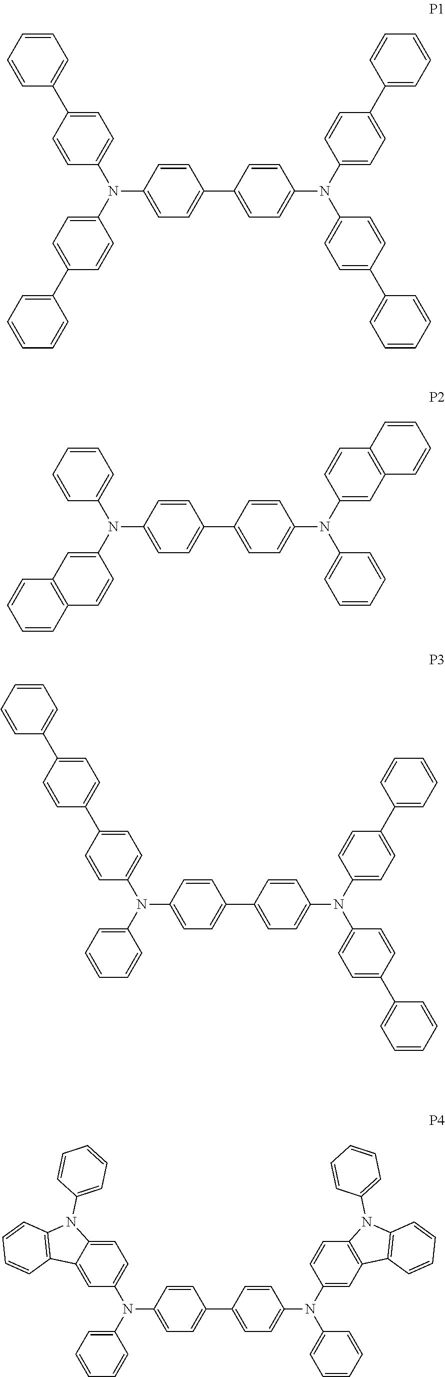 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

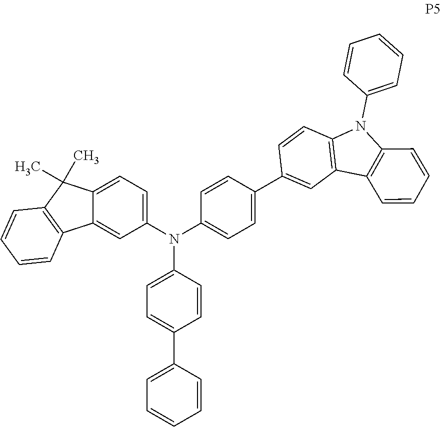 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be at least about 1.6 (e.g., or more). Particularly, the refractive index of the capping layer CPL with respect to light in a wavelength range of about 550 nm to about 660 nm may be at least about 1.6 (e.g., or more).

In the light-emitting element ED, as a voltage is applied to each of the first electrode EL1 and the second electrode EL2, holes injected from the first electrode EL1 pass through the hole transport region HTR to move to the emission layer EML, and electrons injected from the second electrode EL2 pass through the electron transport region ETR to move to the emission layer EML. The electrons and holes recombine to generate excitons in the emission layer EML, and the excitons transit from an excited state to the ground state, thereby emitting light.

The hetero compound according to one or more embodiments may have a cyclic structure in which first and second silicon atoms, each connected to three aromatic rings, a first liker linking the first and second silicon atoms, and a second linker linking any one selected from among the aromatic rings connected to the first silicon atom with any one selected from among the aromatic rings connected to the second silicon atom, are connected to each other. The hetero compound according to one or more embodiments may have excellent electron transport properties and high lowest excited triplet energy level (T1 level) due to the herein-described specific molecular structure.

The hetero compound according to one or more embodiments may have an excited triplet energy level (T1 level) of about 2.8 eV or greater. Therefore, the light-emitting element ED according to one or more embodiments may use the hetero compound according to one or more embodiments as a host in the emission layer EML to emit blue phosphorescence or blue thermally activated delayed fluorescence. In some embodiments, since having high electron mobility, the hetero compound according to one or more embodiments may excellently serve to transport electrons when being included in the electron transport region ETR. Therefore, the light-emitting element ED may have properties of high efficiency and long lifespan.

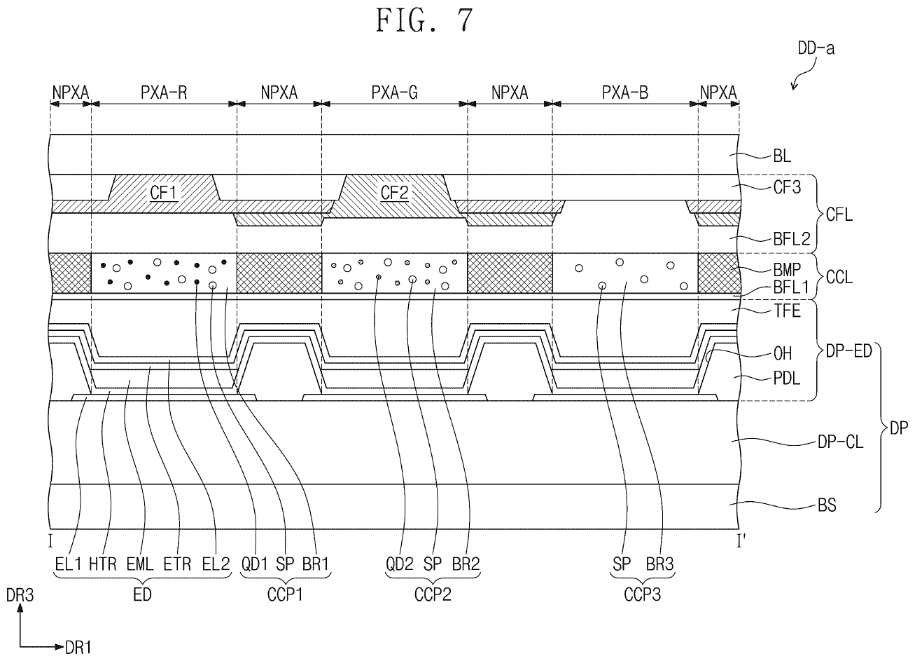

FIG. 7 to FIG. 10 are cross-sectional views on display devices according to one or more embodiments, respectively. In the explanation on the display devices of embodiments referring to FIG. 7 to FIG. 10, the overlapping parts with the explanation on FIG. 1 to FIG. 6 will not be explained again, and the different features will be explained, chiefly, in more detail.

Referring to FIG. 7, the display device DD-a according to one or more embodiments may include a display panel DP including a display device layer DP-ED, a light controlling layer CCL on the display panel DP and a color filter layer CFL. In one or more embodiments shown in FIG. 7, the display panel DP includes a base layer BS, a circuit layer DP-CL provided on the base layer BS and a display device layer DP-ED, and the display device layer DP-ED may include a light emitting element ED.

The light emitting element ED may include a first electrode EL1, a hole transport region HTR on the first electrode EL1, a light emitting layer EML on the hole transport region HTR, an electron transport region ETR on the light emitting layer EML, and a second electrode EL2 on the electron transport region ETR. The same structures as the light emitting elements of FIG. 3 to FIG. 6 may be applied to the structure of the light emitting element ED shown in FIG. 7.

An emission layer EML of the light-emitting element ED included in a light-emitting element DD-a according to one or more embodiments may include (contain) the hetero compound according to one or more embodiments described previously. Alternatively, an electron transport region ETR of the light-emitting element ED included in a light-emitting element DD-a may include the hetero compound according to one or more embodiments.

Referring to FIG. 7, the light emitting layer EML may be in an opening part OH defined in a pixel definition layer PDL. For example, the light emitting layer EML divided (i.e., defined) by the pixel definition layer PDL and correspondingly provided to each of luminous areas PXA-R, PXA-G and PXA-B may be to emit light in the same wavelength region. In the display device DD-a of one or more embodiments, the light emitting layer EML may be to emit blue light. Different from the drawings, in one or more embodiments, the light emitting layer EML may be provided as a common layer for all luminous areas PXA-R, PXA-G and PXA-B.

The light controlling layer CCL may be on the display panel DP. The light controlling layer CCL may include a light converter. The light converter may be a quantum dot or a phosphor. The light converter may transform the wavelength of light provided and then emit. For example, the light controlling layer CCL may be a layer including a quantum dot or a layer including a phosphor.

The light controlling layer CCL may include multiple light controlling parts CCP1, CCP2 and CCP3. The light controlling parts CCP1, CCP2 and CCP3 may be separated from one another.

Referring to FIG. 7, a partition pattern BMP may be between the separated light controlling parts CCP1, CCP2 and CCP3, but one or more embodiments of the present disclosure is not limited thereto. In FIG. 7, the partition pattern BMP is shown not to be overlapped with the light controlling parts CCP1, CCP2 and CCP3, but at least a portion of the edge of the light controlling parts CCP1, CCP2 and CCP3 may be overlapped with the partition pattern BMP.

The light controlling layer CCL may include a first light controlling part CCP1 including a first quantum dot QD1 converting first color light provided from the light emitting element ED into second color light, a second light controlling part CCP2 including a second quantum dot QD2 converting first color light into third color light, and a third light controlling part CCP3 transmitting first color light. In one or more embodiments, the first light controlling part CCP1 may provide red light which is the second color light, and the second light controlling part CCP2 may provide green light which is the third color light. The third color controlling part CCP3 may transmit and provide blue light which is the first color light provided from the light emitting element ED. For example, the first quantum dot QD1 may be a red quantum dot, and the second quantum dot QD2 may be a green quantum dot. On the quantum dots QD1 and QD2, the same contents as those described herein may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) a quantum dot but include the scatterer SP.

The scatterer SP may be an inorganic particle. For example, the scatterer SP may include at least one selected from among TiO₂, ZnO, Al₂O₃, SiO₂, and hollow silica. The scatterer SP may include at least one selected from among TiO₂, ZnO, Al₂O₃, SiO₂, and hollow silica, or may be a mixture of two or more materials selected among TiO₂, ZnO, Al₂O₃, SiO₂, and hollow silica.

Each of the first light controlling part CCP1, the second light controlling part CCP₂, and the third light controlling part CCP3 may include base resins BR1, BR2 and BR3 dispersing the quantum dots QD1 and QD2 and the scatterer SP. In one or more embodiments, the first light controlling part CCP1 may include the first quantum dot QD1 and the scatterer SP dispersed in the first base resin BR1, the second light controlling part CCP₂ may include the second quantum dot QD2 and the scatterer SP dispersed in the second base resin BR2, and the third light controlling part CCP3 may include the scatterer particle SP dispersed in the third base resin BR3.

The base resins BR1, BR2 and BR3 are mediums in which the quantum dots QD1 and QD2 and the scatterer SP are dispersed, and may be composed of one or more suitable resin compositions which may be generally referred to as a binder. For example, the base resins BR1, BR2 and BR3 may be acrylic resins, urethane-based resins, silicone-based resins, epoxy-based resins, and/or the like. The base resins BR1, BR2 and BR3 may be transparent resins. In one or more embodiments, the first base resin BR1, the second base resin BR2 and the third base resin BR3 may be the same or different from each other.

The light controlling layer CCL may include a barrier layer BFL1. The barrier layer BFL1 may play the role of blocking the penetration of moisture and/or oxygen (hereinafter, will be referred to as “humidity/oxygen”). The barrier layer BFL1 may block the exposure of the light controlling parts CCP1, CCP2 and CCP3 to humidity/oxygen. The barrier layer BFL1 may cover the light controlling parts CCP1, CCP2 and CCP3. In some embodiments, a color filter layer CFL, which will be explained later, may include a barrier layer BFL2 on the light controlling parts CCP1, CCP2 and CCP3.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and silicon oxynitride or a metal thin film securing light transmittance. The barrier layers BFL1 and BFL2 may further include an organic layer. The barrier layers BFL1 and BFL2 may be composed of a single layer of multiple layers.

In the display device DD-a of one or more embodiments, the color filter layer CFL may be on the light controlling layer CCL. For example, the color filter layer CFL may be directly on the light controlling layer CCL. In this case, the barrier layer BFL2 may not be included (be omitted).

The color filter layer CFL may include filters CF1, CF2 and CF3. Each of the first to third filters CF1, CF2 and CF3 may be corresponding to a red luminous area PXA-R, a green luminous area PXA-G, and a blue luminous area PXA-B, respectively.

The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment or dye. The first filter CF1 may include a red pigment or dye, the second filter CF2 may include a green pigment or dye, and the third filter CF3 may include a blue pigment or dye.

One or more embodiments of the present disclosure is not limited thereto, and the third filter CF3 may not include the pigment or dye. The third filter CF3 may include a polymer photosensitive resin and not include (e.g., may exclude) a pigment or dye. The third filter CF3 may be transparent. The third filter CF3 may be formed using a transparent photosensitive resin.

In some embodiments, in one or more embodiments, the first filter CF1 and the second filter CF2 may be yellow filters. The first filter CF1 and the second filter CF2 may be provided in one body without distinction.

In some embodiments, the color filter layer CFL may further include alight blocking part. The light blocking part may be a black matrix. The light blocking part may be formed by including an organic light blocking material or an inorganic light blocking material including a black pigment or black dye. The light blocking part may prevent light leakage phenomenon and divide the boundaries among adjacent filters CF1, CF2 and CF3.

On the color filter layer CFL, a base substrate BL may be arranged. The base substrate BL may be a member providing a base surface on which the color filter layer CFL, the light controlling layer CCL, and/or the like are arranged. The base substrate BL may be a glass substrate, a metal substrate, a plastic substrate, and/or the like. However, one or more embodiments of the present disclosure is not limited thereto, and the base substrate BL may be an inorganic layer, an organic layer or a composite material layer. In some embodiments, different from the drawing, the base substrate BL may not be included (be omitted) in one or more embodiments.

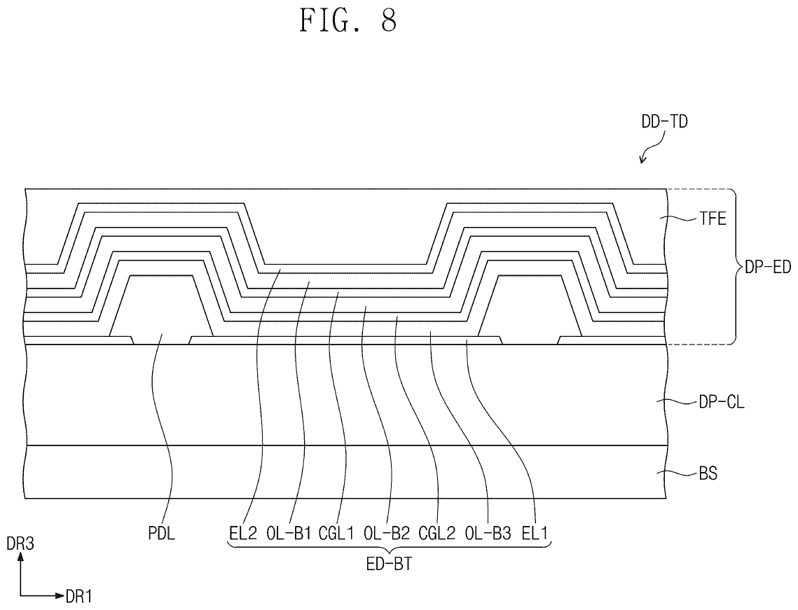

FIG. 8 is a cross-sectional view showing a portion of the display device according to one or more embodiments. In a display device DD-TD of one or more embodiments, the light emitting element ED-BT may include multiple light emitting structures OL-B1, OL-B2 and OL-B3. The light emitting element ED-BT may include oppositely first electrode EL1 and second electrode EL2, and the multiple light emitting structures OL-B1, OL-B2 and OL-B3 stacked in order in a thickness direction and provided between the first electrode EL1 and the second electrode EL2. Each of the light emitting structures OL-B1, OL-B2 and OL-B3 may include a light emitting layer EML (FIG. 7), and a hole transport region HTR and an electron transport region ETR with the light emitting layer EML (FIG. 7) therebetween.

For example, the light emitting element ED-BT included in the display device DD-TD of one or more embodiments may be a light emitting element of a tandem structure including multiple emission layers.

In one or more embodiments shown in FIG. 8, light emitted from the light emitting structures OL-B1, OL-B2 and OL-B3 may be all blue light. However, one or more embodiments of the present disclosure is not limited thereto, and the wavelength regions of light emitted from the light emitting structures OL-B1, OL-B2 and OL-B3 may be different from each other. For example, the light emitting element ED-BT including the multiple light emitting structures OL-B1, OL-B2 and OL-B3 emitting light in different wavelength regions may emit white light.

Between neighboring light emitting structures OL-B1, OL-B2 and OL-B3, charge generating layers CGL1 and CGL2 may be arranged. The charge generating layers CGL1 and CGL2 may include a p-type (kind) charge generating layer and/or an n-type (kind) charge generating layer.

At least one selected from among emission structures OL-B1, OL-B2, and OL-B3 included in a display device DD-TD according to one or more embodiments may include (contain) the herein-described hetero compound according to one or more embodiments. For example, at least one selected from among a plurality of emission layers included in a light-emitting element ED-BT may include (contain) the hetero compound according to one or more embodiments. Alternatively, an electron transport region ETR included in the light-emitting element ED-BT may include the hetero compound according to one or more embodiments.

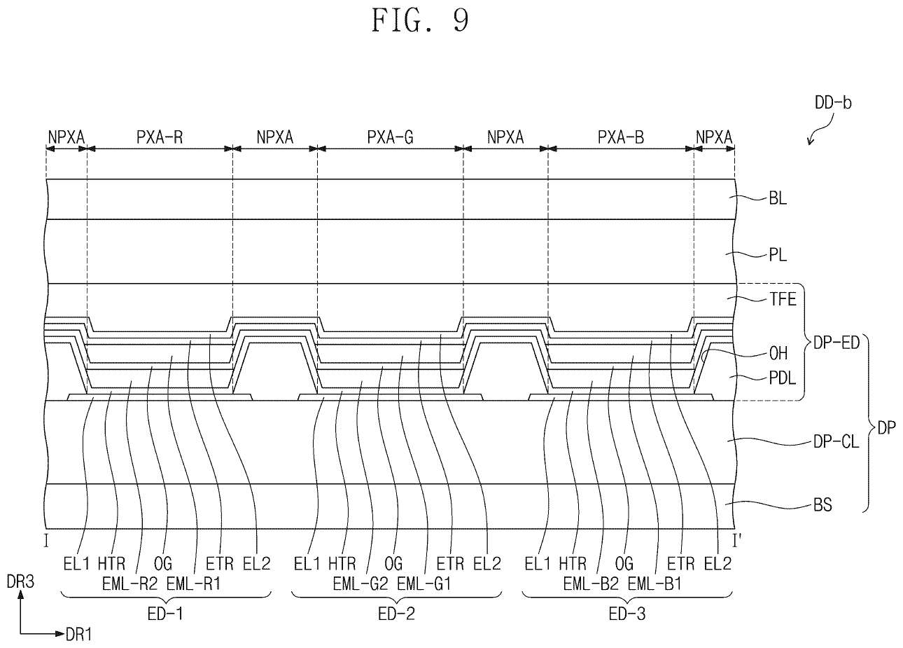

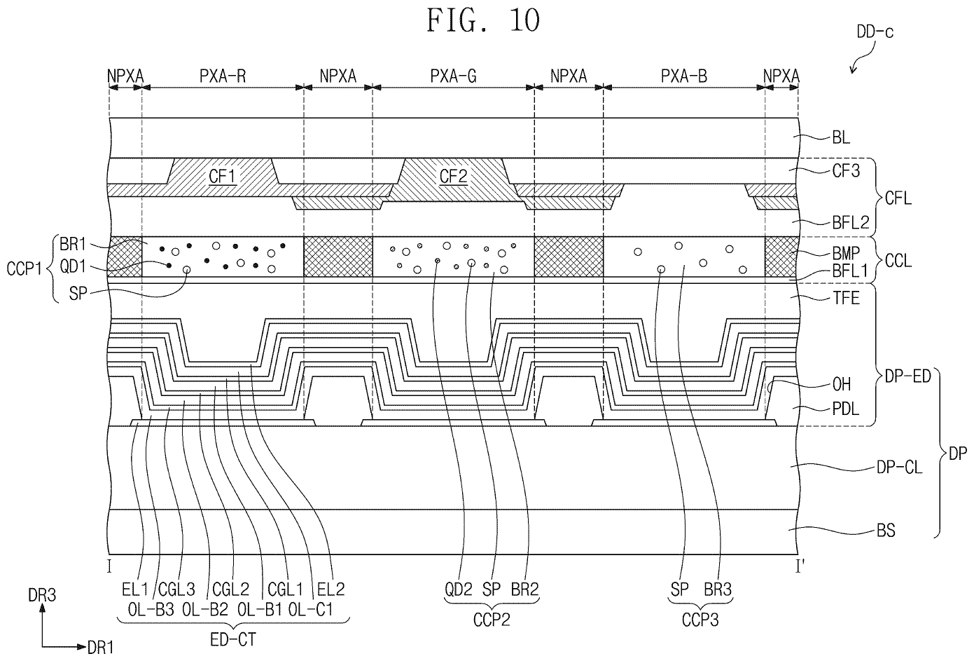

FIG. 9 is a cross-sectional view showing a display device according to one or more embodiments of the present disclosure. FIG. 10 is a cross-sectional view showing a display device according to one or more embodiments of the present disclosure.

Referring to FIG. 9, a display device DD-b according to one or more embodiments may include light emitting elements ED-1, ED-2 and ED-3, formed by stacking two emission layers. Compared to the display device DD of one or more embodiments, shown in FIG. 2, one or more embodiments shown in FIG. 9 is different in that first to third light emitting elements ED-1, ED-2 and ED-3 include two emission layers stacked in a thickness direction, each. In the first to third light emitting elements ED-1, ED-2 and ED-3, two emission layers may be to emit light in the same wavelength region.

The first light emitting element ED-1 may include a first red light emitting layer EML-R1 and a second red light emitting layer EML-R2. The second light emitting element ED-2 may include a first green light emitting layer EML-G1 and a second green light emitting layer EML-G2. In some embodiments, the third light emitting element ED-3 may include a first blue light emitting layer EML-B1 and a second blue light emitting layer EML-B2. Between the first red light emitting layer EML-R1 and the second red light emitting layer EML-R2, between the first green light emitting layer EML-G1 and the second green light emitting layer EML-G2, and between the first blue light emitting layer EML-B1 and the second blue light emitting layer EML-B2, an emission auxiliary part OG may be arranged.

The emission auxiliary part OG may include a single layer or a multilayer. The emission auxiliary part OG may include a charge generating layer. More particularly, the emission auxiliary part OG may include an electron transport region, a charge generating layer, and a hole transport region stacked in order. The emission auxiliary part OG may be provided as a common layer in all of the first to third light emitting elements ED-1, ED-2 and ED-3. However, one or more embodiments of the present disclosure is not limited thereto, and the emission auxiliary part OG may be patterned and provided in an opening part OH defined in a pixel definition layer PDL.

The first red light emitting layer EML-R1, the first green light emitting layer EML-G1 and the first blue light emitting layer EML-B1 may be between the electron transport region ETR and the emission auxiliary part OG. The second red light emitting layer EML-R2, the second green light emitting layer EML-G2 and the second blue light emitting layer EML-B2 may be between the emission auxiliary part OG and the hole transport region HTR.

For example, the first light emitting element ED-1 may include a first electrode EL1, a hole transport region HTR, a second red light emitting layer EML-R2, an emission auxiliary part OG, a first red light emitting layer EML-R1, an electron transport region ETR, and a second electrode EL2, stacked in order. The second light emitting element ED-2 may include a first electrode EL1, a hole transport region HTR, a second green light emitting layer EML-G2, an emission auxiliary part OG, a first green light emitting layer EML-G1, an electron transport region ETR, and a second electrode EL2, stacked in order. The third light emitting element ED-3 may include a first electrode EL1, a hole transport region HTR, a second blue light emitting layer EML-B2, an emission auxiliary part OG, a first blue light emitting layer EML-B1, an electron transport region ETR, and a second electrode EL2, stacked in order.

An optical auxiliary layer PL may be on a display device layer DP-ED. The optical auxiliary layer PL may include a polarization layer. The optical auxiliary layer PL may be on a display panel DP and may control reflected light at the display panel DP by external light. Different from the drawings, the optical auxiliary layer PL may not be included (be omitted) from the display device according to one or more embodiments.

At least one emission layer included in a display device DD-b according to one or more embodiments, illustrated in FIG. 9, may include the herein-described hetero compound according to one or more embodiments. For example, in one or more embodiments, at least one selected from among a first blue emission layer EML-B1 and a second blue emission layer EML-B2 may include the hetero compound according to one or more embodiments. Alternatively, an electron transport region ETR included in the display device DD-b according to one or more embodiments may include the herein-described hetero compound according to one or more embodiments.

Different from FIG. 8 and FIG. 9, a display device DD-c in FIG. 10 is shown to include four light emitting structures OL-B1, OL-B2, OL-B3 and OL-C1. A light emitting element ED-CT may include oppositely first electrode EL1 and second electrode EL2, and first to fourth light emitting structures OL-B1, OL-B2, OL-B3 and OL-C1 stacked in order in a thickness direction between the first electrode EL1 and the second electrode EL2. The third light emitting structures OL-B3, the second light emitting structures OL-B2, the first light emitting structures OL-B1, and the fourth light emitting structures OL-C1 are stacked in order in a thickness direction. Between the first to fourth light emitting structures OL-B1, OL-B2, OL-B3 and OL-C1, charge generating layers CGL1, CGL2 and CGL3 may be arranged. For example, A first charge generating layer CGL1 is between the first light emitting structures OL-B1 and the fourth light emitting structures OL-C1. A second charge generating layer CGL2 is between the first light emitting structures OL-B1 and the second light emitting structures OL-B2. A third charge generating layer CGL3 is between the second light emitting structures OL-B2 and the third light emitting structures OL-B3.

Among the four light emitting structures, the first to third light emitting structures OL-B1, OL-B2 and OL-B3 emit blue light, and the fourth light emitting structure OL-C1 may be to emit green light. However, one or more embodiments of the present disclosure is not limited thereto, and the first to fourth light emitting structures OL-B1, OL-B2, OL-B3 and OL-C1 may emit different wavelengths of light.

Between neighboring light emitting structures OL-B1, OL-B2 and OL-B3, charge generating layers CGL1 and CGL2 may be arranged. The charge generating layers CGL1 and CGL2 may include a p-type (kind) charge generating layer and/or an n-type (kind) charge generating layer.

The herein-described hetero compound according to one or more embodiments may be included in at least one emission structures OL-B1, OL-B2, OL-B3, and OL-C1 included in a display device DD-c according to one or more embodiments. For example, in one or more embodiments, at least one selected from among the first to third emission structures OL-B1, OL-B2, and OL-B3 may include the herein-described hetero compound according to one or more embodiments.

The light-emitting element ED according to one or more embodiments of the present disclosure includes the hetero compound according to one or more embodiments, represented by the herein-described Formula 1, in at least one functional layer between the first electrode and the second electrode, and thus exhibit properties of suitable or excellent luminous efficiency and improved lifespan. For example, the hetero compound according to one or more embodiments may be included in the emission layer EML of the light-emitting element ED according to one or more embodiments, and thus the light-emitting element according to one or more embodiments may exhibit properties of high efficiency and long lifespan.

In one or more embodiments, an electronic apparatus may include a display device including multiple light emitting elements and a control part controlling the display device. The electronic apparatus of one or more embodiments may be an apparatus activated according to electrical signals. The electronic apparatus may include display devices of one or more suitable embodiments. For example, the electronic apparatus may include televisions, monitors, large-size display devices such as outside billboards, personal computers, laptop computers, personal digital terminals, display devices for automobiles, game consoles, portable electronic devices, medium- and small-size display devices such as cameras and/or the like.

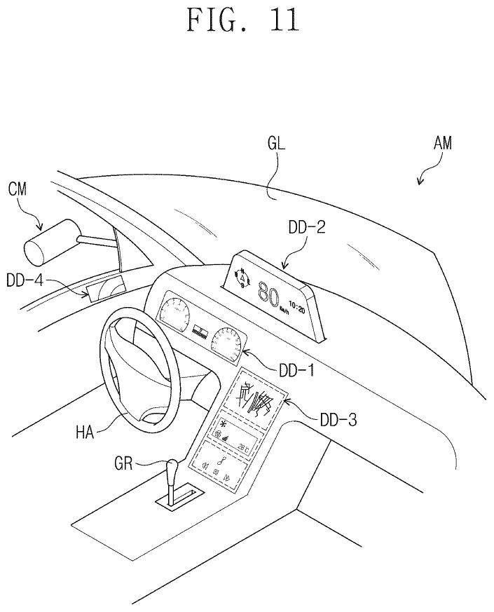

FIG. 11 is a diagram showing an automobile AM in which first to fourth display devices DD-1, DD-2, DD-3 and DD-4 are arranged. At least one selected from among the first to fourth display devices DD-1, DD-2, DD-3 and DD-4 may include the same configurations of the display devices DD, DD-TD, DD-a, DD-b and DD-c of embodiments, explained referring to FIGS. 1, 2, and 7 to 10.

In FIG. 11, a vehicle is shown as an automobile AM, but this is an illustration, and the first to fourth display devices DD-1, DD-2, DD-3 and DD-4 may be on other transport means (refers to) such as bicycles, motorcycles, trains, ships and airplanes. In some embodiments, at least one selected from among the first to fourth display devices DD-1, DD-2, DD-3 and DD-4 including the same configurations of the display devices DD, DD-TD, DD-a, DD-b and DD-c may be introduced in personal computers, laptop computers, personal digital terminals, game consoles, portable electronic devices, televisions, monitors, external billboards, and/or the like. In some embodiments, these are suggested as examples, and the display device may be introduced in other electronic devices as long as not deviated from the present disclosure.

At least one selected from among first to fourth display devices DD-1, DD-2, DD-3, and DD-4 may include the light-emitting element ED according to one or more embodiments described with reference to FIG. 3 to FIG. 6. The light-emitting element ED according to one or more embodiments may include (contain) the hetero compound according to one or more embodiments. At least one selected from among the first to fourth display devices DD-1, DD-2, DD-3, and DD-4 includes the light-emitting element ED including (containing) the hetero compound according to one or more embodiments, and thus may have improved display lifespan.

Referring to FIG. 11, an automobile AM may include a steering wheel HA for the operation of the automobile AM and a gear GR. In some embodiments, the automobile AM may include a front window GL to face a driver.

A first display device DD-1 may be in a first region overlapping with the steering wheel HA. For example, the first display device DD-1 may be a digital cluster displaying the first information of the automobile AM. The first information may include a first graduation showing the running speed of the automobile AM, a second graduation showing the number of revolution of an engine (i.e., revolutions per minute (RPM)), and images showing a fuel state. First graduation and second graduation may be represented by digital images.

A second display device DD-2 may be in a second region facing a driver's seat and overlapping with the front window GL. The driver's seat may be a seat where the steering wheel HA is arranged. For example, the second display device DD-2 may be a head up display (HUD) showing the second information of the automobile AM. The second display device DD-2 may be optically clear. The second information may include digital numbers showing the running speed of the automobile AM and may further include information including the current time. Different from the drawing, the second information of the second display device DD-2 may be projected and displayed on the front window GL.

A third display device DD-3 may be in a third region adjacent to the gear GR. For example, the third display device DD-3 may be a center information display (CID) for an automobile, between a driver's seat and a passenger seat and showing third information. The passenger seat may be a seat separated from the driver's seat with the gear GR therebetween. The third information may include information on road conditions (for example, navigation information), on playing music or radio, on playing a dynamic image (or image), on the temperature in the automobile AM, and/or the like.

A fourth display device DD-4 may be in a fourth region separated from the steering wheel HA and the gear GR and adjacent to the side of the automobile AM. For example, the fourth display device DD-4 may be a digital wing mirror displaying fourth information. The fourth display device DD-4 may display the external image of the automobile AM, taken by a camera module CM at the outside of the automobile AM. The fourth information may include the external image of the automobile AM.

The herein-described first to fourth information is for illustration, and the first to fourth display devices DD-1, DD-2, DD-3 and DD-4 may further display information on the inside and outside of the automobile. The first to fourth information may include different information from each other. However, one or more embodiments of the present disclosure is not limited thereto, and a portion of the first to fourth information may include the same information.

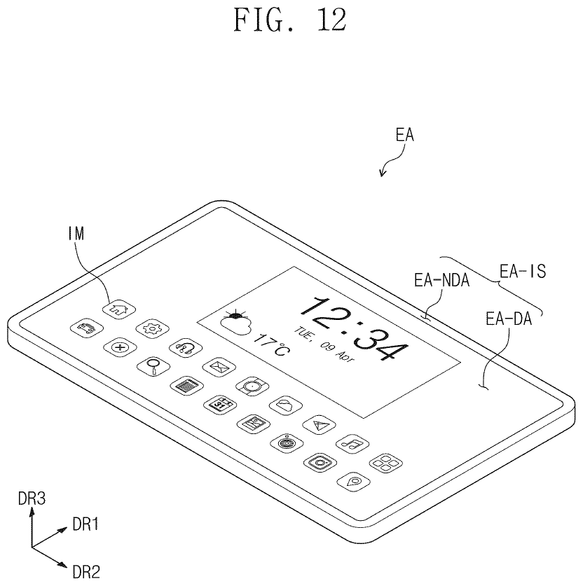

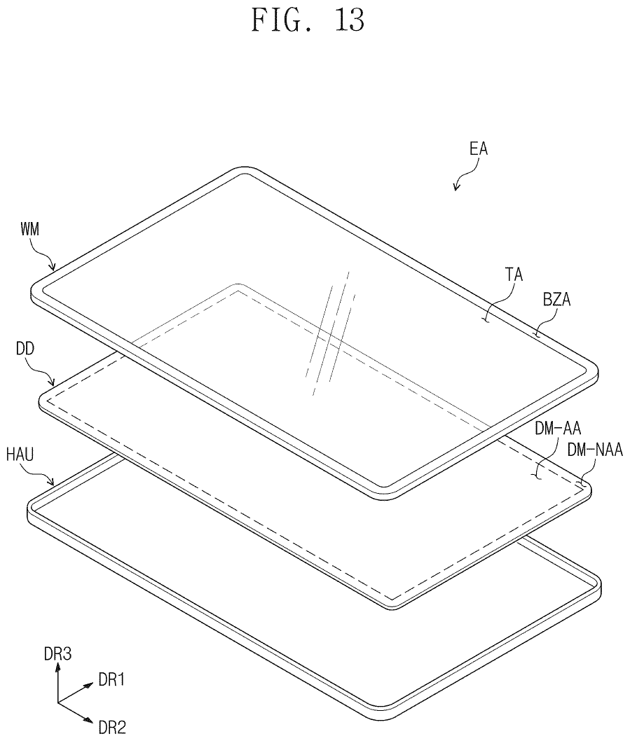

FIG. 12 is a perspective view showing an electronic apparatus of one or more embodiments. FIG. 13 is an exploded perspective view showing an electronic apparatus of one or more embodiments.

The electronic apparatus EA may display an image IM through a display surface EA-IS. The image IM may include a dynamic image as well as a static image. The display surface EA-IS may be parallel to a plane defined by a first direction axis DR1 and a second direction axis DR2. FIG. 12 illustrates an electronic apparatus EA having a flat display surface EA-IS, but one or more embodiments of the present disclosure is not limited thereto. For example, the electronic apparatus EA may include a curved display surface or a three-dimensional display surface. The three-dimensional display surface may include a plurality of display areas indicating different directions from each other.

The display surface EA-IS may include a display area EA-DA and a non-display area EA-NDA. The electronic apparatus EA may display an image IM through the display area EA-DA.

The non-display area EA-NDA may have a predetermined color. The non-display area EA-NDA may be adjacent to the display area EA-DA. The non-display area EA-NDA may surround the display area EA-DA. Accordingly, the shape of the display area EA-DA may be substantially defined by the non-display area EA-NDA. However, FIG. 12 is an illustration, and the non-display area EA-NDA may be adjacent to only one side of the display area EA-DA or may not be included (be omitted).

Referring to FIG. 13, the electronic apparatus EA may include a display device DD. In some embodiments, the electronic apparatus EA may further include a window member WM and a housing HAU.

The window member WM may cover the entire outer side of the electronic apparatus EA. The window member WM may include a transparent area TA and a bezel area BZA. The front surface of the window member WM including the transparent area TA and the bezel area BZA may correspond to the front surface of the electronic apparatus EA. The transparent area TA may correspond to the display area EA-DA of the electronic apparatus EA illustrated in FIG. 12, and the bezel area BZA may correspond to the non-display area EA-NDA of the electronic apparatus EA illustrated in FIG. 12.

The transparent area TA may be an optically transparent area. The bezel area BZA may be an area having a relatively low light transmittance compared to the transparent area TA. The bezel area BZA may have a predetermined color. The bezel area BZA may be adjacent to the transparent area TA and may surround the transparent area TA. The bezel area BZA may define the shape of the transparent area TA. However, one or more embodiments of the present disclosure is not limited thereto, and the bezel area BZA may be adjacent to only one side of the transparent area TA, or a portion thereof may not be included (be omitted).

The housing HAU may include a material having relatively high rigidity. For example, the housing HAU may include a frame and/or a plate made of glass, plastic, or metal. The frames and/or plates may be provided in multiple pieces. The housing HAU may provide a predetermined receiving space. The display device DD may be accommodated in the receiving space and protected from external impact.

The display device DD may include the same configurations as those of at least one of the display devices DD, DD-TD, DD-a, DD-b, and DD-c of the embodiments described with reference to FIGS. 1, 2, and 7 to 10. The display device DD may include the light emitting element ED described with reference to FIGS. 3 to 6. Accordingly, the electronic apparatus EA including the display device DD according to one or more embodiments may exhibit excellent reliability.

An active area DM-AA and a peripheral area DM-NAA may be defined in the display device DD. The active area DM-AA may overlap the display area EA-DA illustrated in FIG. 12, and the peripheral area DM-NAA may overlap the non-display area EA-NDA illustrated in FIG. 12.

The active area DM-AA may be an area activated according to an electrical signal. The peripheral area DM-NAA may be an area positioned adjacent to at least one side of the active area DM-AA. The active area DM-AA may include the non-light emitting area NPXA and light emitting areas PXA-R, PXA-G and PXA-B, illustrated in FIG. 1. The peripheral area DM-NAA may be to surround the active area DM-AA. However, one or more embodiments of the present disclosure is not limited thereto, and unlike what is shown, some of the peripheral areas DM-NAA may not be included (be omitted). A driving circuit or driving wiring for driving the active area DM-AA may be in the peripheral area DM-NAA.

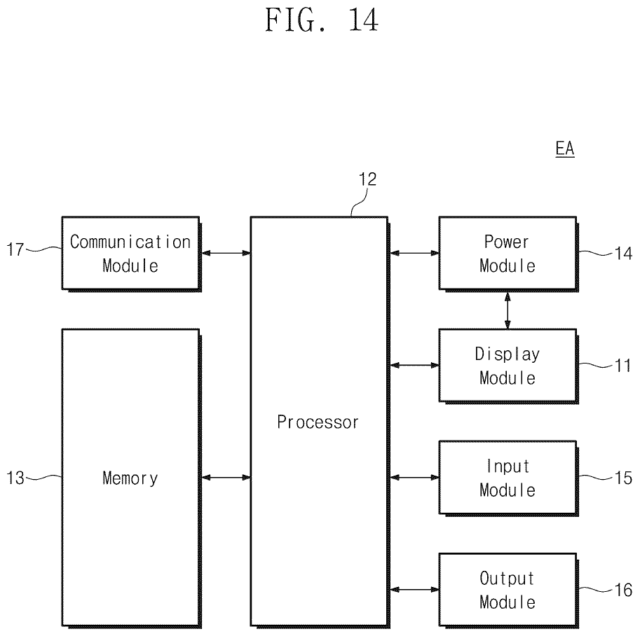

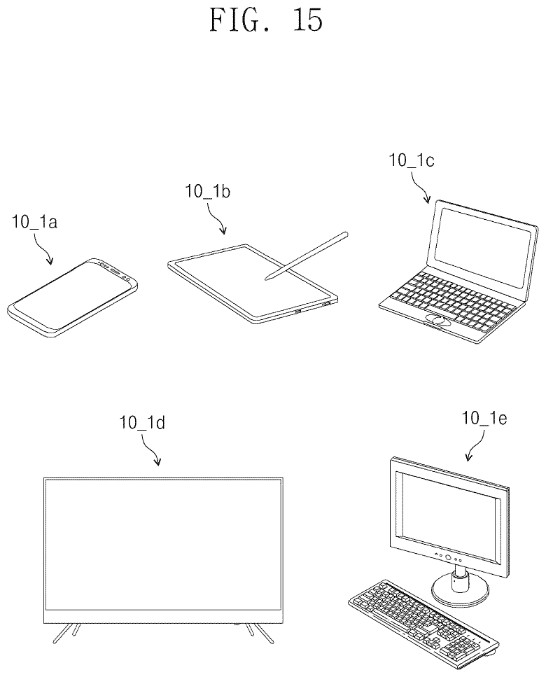

The electronic apparatus EA according to one or more embodiments includes the display device described herein, and may further include a module or device having an additional function, in addition to the display device. FIG. 14 is a block diagram of an electronic apparatus according to one or more embodiments. Referring to FIG. 14, an electronic apparatus EA according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. Data information necessary for the operation of the processor 12 or the display module 11 may be stored in the memory 13. If (e.g., when) the processor 12 executes an application stored in the memory 13, an image data signal and/or an input control signal are transmitted to the display module 11, and the display module 11 may process the received signal and output image information through a display screen.

The power module 14 may include a power supply module such as a power adapter or a battery device, and a power conversion module that converts the power supplied by the power supply module to generate power necessary for the operation of the electronic apparatus EA.

The display module 11 may include at least some configurations of the display devices DD, DD-TD, DD-a, DD-b, and DD-c, described with reference to FIGS. 1, 2, and 7 to 10. For example, the display module 11 may include a base layer BS, a circuit layer DP-CL, and a display element layer DP-ED among the configurations of the display devices DD, DD-TD, DD-a, DD-b, and DD-c, described with reference to FIGS. 1, 2, and 7 to 10. In some embodiments, the display module 11 may further include at least one of an optical layer PP (FIG. 2), a light control layer CCL (FIGS. 7 and 10), a color filter layer CFL (FIGS. 7 and 10), and an optical auxiliary layer PL (FIG. 10).

The electronic apparatus EA may further include an input module 15, a non-image output module 16, and/or a communication module 17.

The input module 15 may provide input information to the processor 12 and/or the display module 11. The input module 15 may include one or more suitable sensor modules as well as physical buttons, a keyboard, and a microphone. Examples of sensor module include touch sensors, pressure sensors, distance sensors, position sensors, digitizers, motion recognition sensors, camera sensors, photodetector, photoelectric conversion sensors, temperature sensors, and biosensors such as blood pressure sensors, blood sugar sensors, electrocardiogram sensors, heart rate sensors and/or the like.

The non-image output module 16 may receive information other than images transmitted from the processor 12 and provide the information to the user. Examples of the non-image output module 16 include an audio module, a haptic module, a light emitting module, and/or the like, and may include other electronic device-specific functional modules (e.g., a cooling module of a refrigerator, and/or the like).

The communication module 17 is a module responsible for transmitting and receiving information between the electronic apparatus EA and an external device, and may include a receiving part and a transmitting part. The communication module 17 may include one or more suitable wireless communication modules such as a mobile communication module, a Wi-Fi module, and a Bluetooth module, or one or more suitable wired communication modules.

At least one of the configurations of the electronic apparatus EA described herein may be included in the herein-described display device (at least one of DD, DD-TD, DD-a, DD-b, and DD-c, FIGS. 1, 2, and 7 to 10) according to one or more embodiments. In some embodiments, some of the individual modules functionally included in one module may be included in the display device, and other modules may be provided separately from the display device. For example, the display device may include the display module 11, and the processor 12, the memory 13, and the power module 14 may be provided in the form of other devices within the electronic apparatus EA other than the display device.

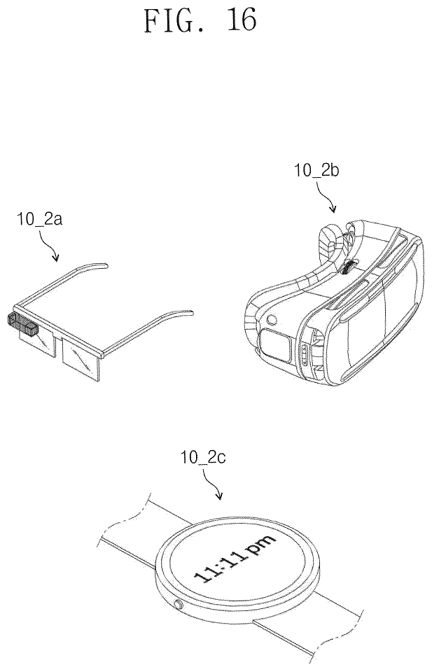

FIGS. 15 and 16 are schematic diagrams showing electronic apparatuses according to one or more suitable embodiments. Referring to FIGS. 15 and 16, one or more suitable electronic apparatuses to which a display device (at least one of DD, DD-TD, DD-a, DD-b, and DD-c, FIGS. 1, 2, and 7 to 10) according to one or more embodiments is applied may include not only image display electronic apparatuses such as a smart phone 10_1a, a tablet PC 10_1b, a laptop 10_1c, a TV 10_1d, and a monitor for a desk 10_1e, but also wearable electronic apparatuses including display modules such as smart glasses 10_2a, a head-mounted display 10_2b, and a smart watch 10_2c. However, these are embodiments, and the electronic apparatus according to one or more embodiments is not limited thereto.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

Hereinafter, with reference to examples and comparative examples, the hetero compound according to one or more embodiments of the present disclosure and the light-emitting element according to one or more embodiments will be specifically described. In some embodiments, examples shown herein are exemplified only for helping the understanding of the present disclosure, and the scope of the present disclosure is not limited thereto.

### Examples

### 1. Synthesis of Hetero Compound

First, a synthetic method of the hetero compound according to the present embodiment will be specifically described by exemplifying synthetic methods of Compounds 8, 21, 25, 31, 36, 41, 52, and 54. In some embodiments, in the following descriptions, the synthetic method of the hetero compound is provided as an example, but the synthetic method of the hetero compound according to one or more embodiments of the present disclosure is not limited to the examples herein.

### (1) Synthesis of Compound 8

Hetero Compound 8 according to one or more embodiments may be synthesized by, for example, a reaction scheme herein.

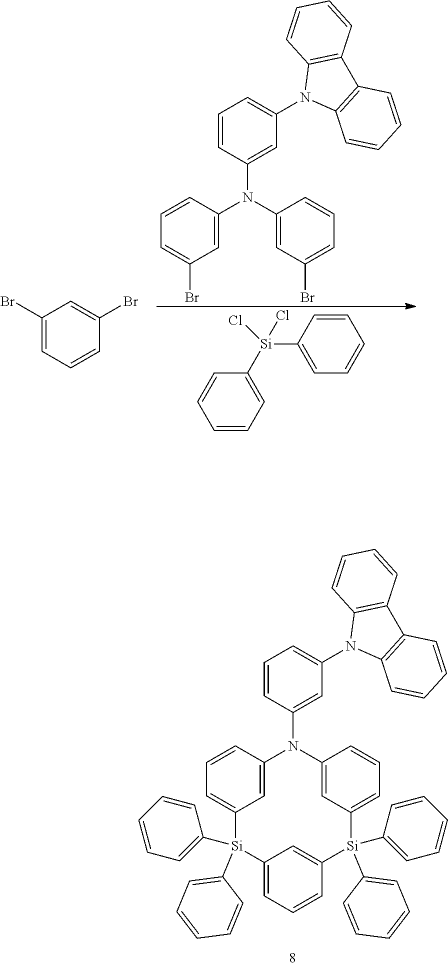

In a first round-bottom flask, 5 gram (g) of Intermediate 1,3-dibromobenzene (1 eq) was put and dissolved in 200 milliliter (mL) of tetrahydrofuran (THF), and then the mixture was stabilized at about −78° C. N-BuLi (2 eq) was slowly added dropwise, and then the mixture was stirred for about 1 hour at low temperature. Dichlorodiphenylsilane (2 eq) was added rapidly to the reaction mixture, and the mixture was stirred for about 2 hours at low temperature.

In a second round-bottom flask, N-(3-(9H-carbazol-9-yl)phenyl)-3-bromo-N-(3-bromophenyl)aniline (1 eq) was put and dissolved in THE of 200 mL, and then the mixture was stabilized at about −78° C. N-BuLi (2 eq) was slowly added dropwise, and then the mixture was stirred for 1 hour at low temperature.

Thereafter, the reaction mixture in the first round-bottom flask was rapidly added to the second round-bottom flask dropwise, and then stirred for about 12 hours at room temperature. After completion of the reaction, the reaction solution was subjected to extraction with ethyl acetate to collect an organic layer. The organic layer was dried using magnesium sulfate to obtain the residue. The residue was purified and separated by column chromatography using silica gel to obtain Compound 8 (yield: 41%). Compound 8 was identified by LC-MS and 1H-NMR.

LC-MS for Compound 8: C₆₀H₄₄N₂Si₂M⁻¹: 849.20

### (2) Synthesis of Compound 21

Hetero Compound 21 according to one or more embodiments may be synthesized by, for example, a reaction scheme herein.

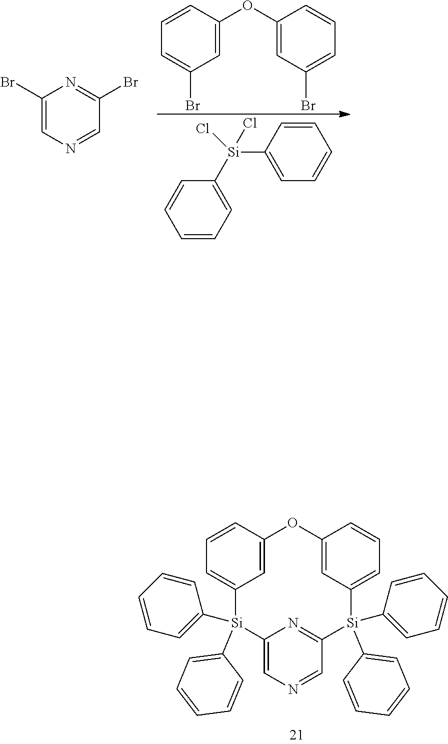

In a first round-bottom flask, 5 g of 2,6-dibromopyrazine (1 eq) was put and dissolved in 200 mL of THF, and then the mixture was stabilized at about −78° C. N-BuLi (2 eq) was slowly added dropwise, and then the mixture was stirred for about 1 hour at low temperature. Dichlorodiphenylsilane (2 eq) was added rapidly to the reaction mixture, and the mixture was stirred for about 2 hours at low temperature.

In a second round-bottom flask, N-(3 3,3′-oxybis(bromobenzene) (1 eq) was put and dissolved in THE of 200 mL, and then the mixture was stabilized at about −78° C. N-BuLi (2 eq) was slowly added dropwise, and then the mixture was stirred for 1 hour at low temperature.

Thereafter, the reaction mixture in the first round-bottom flask was rapidly added to the second round-bottom flask dropwise, and then stirred for about 12 hours at room temperature. After completion of the reaction, the reaction solution was subjected to extraction with ethyl acetate to collect an organic layer. The organic layer was dried using magnesium sulfate to obtain the residue. The residue was purified and separated by column chromatography using silica gel to obtain Compound 21 (yield: 30%). Compound 21 was identified by LC-MS and 1H-NMR.

LC-MS for Compound 21: C₄₀H₃₀N₂OSi₂M⁺¹: 611.06

### (3) Synthesis of Compound 25

Hetero Compound 25 according to one or more embodiments may be synthesized by, for example, a reaction scheme herein.

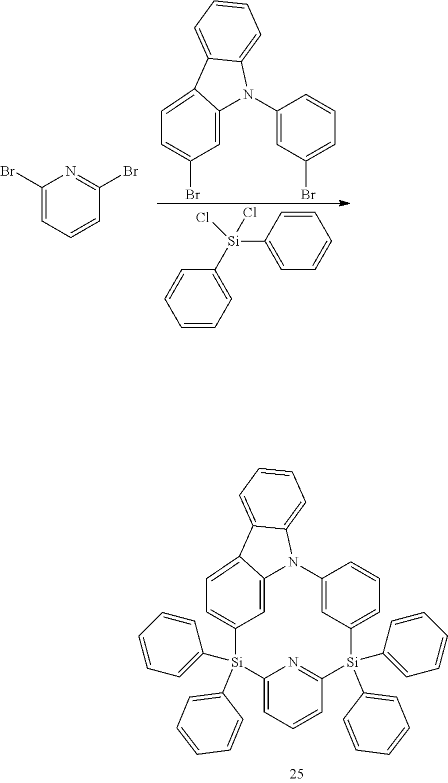

In a first round-bottom flask, 5 g of 2,6-dibromopyridine (1 eq) was put and dissolved in 200 mL of THF, and then the mixture was stabilized at about −78° C. N-BuLi (2 eq) was slowly added dropwise, and then the mixture was stirred for about 1 hour at low temperature. Dichlorodiphenylsilane (2 eq) was added rapidly to the reaction mixture, and the mixture was stirred for about 2 hours at low temperature.

In a second round-bottom flask, N-(3 2-bromo-9-(3-bromophenyl)-9H-carbazole (1 eq) was put and dissolved in THE of 200 mL, and then the mixture was stabilized at about −78° C. N-BuLi (2 eq) was slowly added dropwise, and then the mixture was stirred for 1 hour at low temperature.

Thereafter, the reaction mixture in the first round-bottom flask was rapidly added to the second round-bottom flask dropwise, and then stirred for about 12 hours at room temperature. After completion of the reaction, the reaction solution was subjected to extraction with ethyl acetate to collect an organic layer. The organic layer was dried using magnesium sulfate to obtain the residue. The residue was purified and separated by column chromatography using silica gel to obtain Compound 25 (yield: 35%). Compound 25 was identified by LC-MS and 1H-NMR.

LC-MS for Compound 25: C₄₇H₃₄N₂Si₂M⁺¹: 683.14

### (4) Synthesis of Compound 31

Hetero Compound 31 according to one or more embodiments may be synthesized by, for example, a reaction scheme herein.

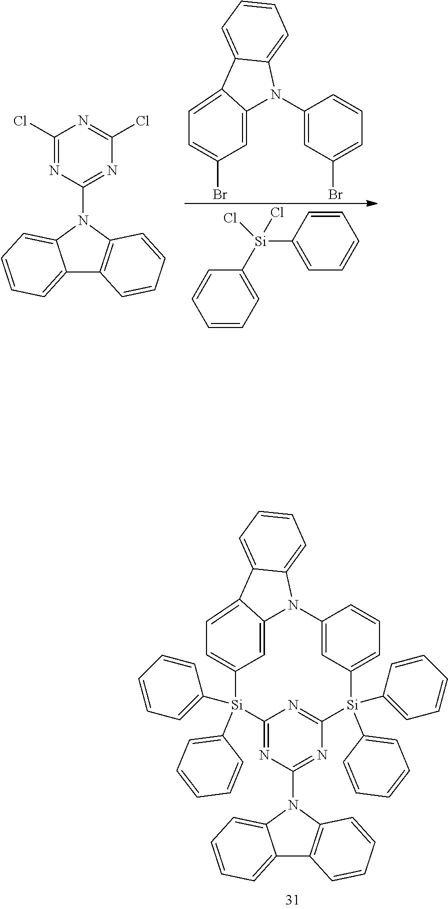

In a first round-bottom flask, 5 g of 9-(4,6-dichloro-1,3,5-triazin-2-yl)-9H-carbazole (1 eq) was put and dissolved in 200 mL of toluene, and then the mixture was stabilized at about −78° C. N-BuLi (2 eq) was slowly added dropwise, and then the mixture was stirred for about 20 minutes at low temperature. Dichlorodiphenylsilane (2 eq) was added rapidly to the reaction mixture, and the mixture was stirred for about 2 hours at low temperature.

In a second round-bottom flask, N-(3 2-bromo-9-(3-bromophenyl)-9H-carbazole (1 eq) was put and dissolved in THE of 200 mL, and then the mixture was stabilized at about −78° C. N-BuLi (2 eq) was slowly added dropwise, and then the mixture was stirred for 1 hour at low temperature.

Thereafter, the reaction mixture in the first round-bottom flask was rapidly added to the second round-bottom flask dropwise and then stirred for about 12 hours at room temperature. After completion of the reaction, the reaction solution was subjected to extraction with ethyl acetate to collect an organic layer. The organic layer was dried using magnesium sulfate to obtain the residue. The residue was purified and separated by column chromatography using silica gel to obtain Compound 31 (yield: 35%). Compound 31 was identified by LC-MS and 1H-NMR.

LC-MS for Compound 31: C₅₇H₃₉N₅Si₂M⁺¹: 850.15

### (5) Synthesis of Compound 36

Hetero Compound 36 according to one or more embodiments may be synthesized by, for example, a reaction scheme herein.

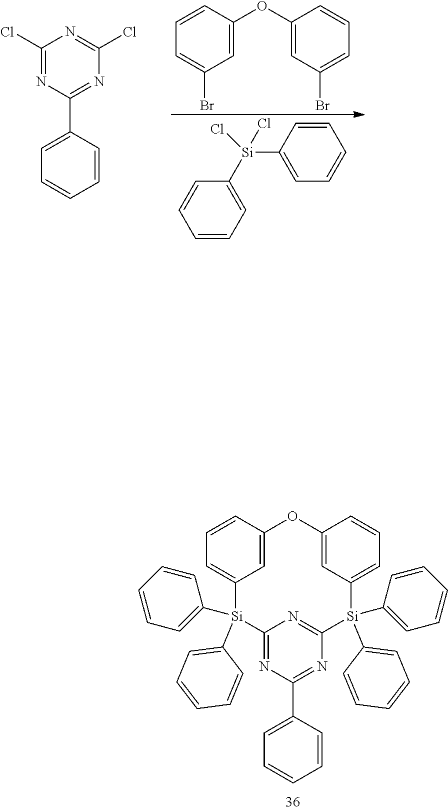

In a first round-bottom flask, 5 g of 2,4-dichloro-6-phenyl-1,3,5-triazine (1 eq) was put and dissolved in 200 mL of toluene, and then the mixture was stabilized at about −78° C. N-BuLi (2 eq) was slowly added dropwise, and then the mixture was stirred for about 20 minutes at low temperature. Dichlorodiphenylsilane (2 eq) was added rapidly to the reaction mixture, and the mixture was stirred for about 2 hours at low temperature.

In a second round-bottom flask, N-(3 3,3′-oxybis(bromobenzene) (1 eq) was put and dissolved in THE of 200 mL, and then the mixture was stabilized at about −78° C. N-BuLi (2 eq) was slowly added dropwise, and then the mixture was stirred for about 1 hour at low temperature.

Thereafter, the reaction mixture in the first round-bottom flask was rapidly added to the second round-bottom flask dropwise and then stirred for about 12 hours at room temperature. After completion of the reaction, the reaction solution was subjected to extraction with ethyl acetate to collect an organic layer. The organic layer was dried using magnesium sulfate to obtain the residue. The residue was purified and separated by column chromatography using silica gel to obtain Compound 36 (yield: 30%). Compound 36 was identified by LC-MS and 1H-NMR.

LC-MS for Compound 36: C₄₅H₃₃N₃OSi₂M⁺¹: 688.01

### (6) Synthesis of Compound 41

Hetero Compound 41 according to one or more embodiments may be synthesized by, for example, a reaction scheme herein.

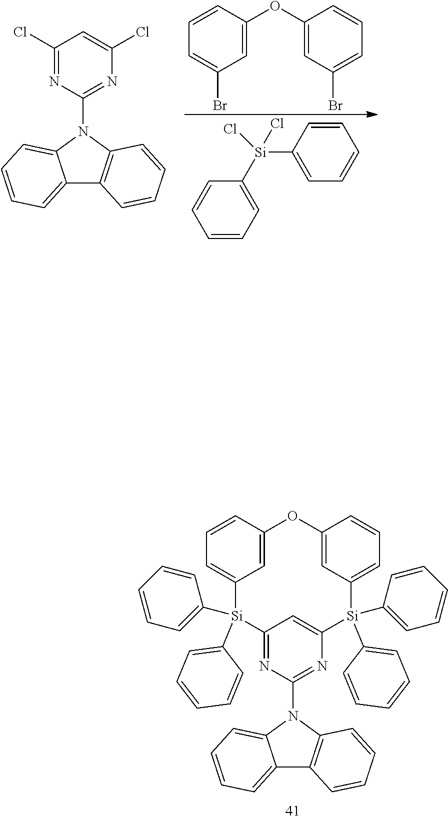

In a first round-bottom flask, 5 g of 2 9-(4,6-dichloropyrimidin-2-yl)-9H-carbazole (1 eq) was put and dissolved in 200 mL of toluene, and then the mixture was stabilized at about −78° C. N-BuLi (2 eq) was slowly added dropwise, and then the mixture was stirred for about 20 minutes at low temperature. Dichlorodiphenylsilane (2 eq) was added rapidly to the reaction mixture, and the mixture was stirred for about 2 hours at low temperature.

In a second round-bottom flask, N-(3 3,3′-oxybis(bromobenzene) (1 eq) was put and dissolved in THE of 200 mL, and then the mixture was stabilized at about −78° C. N-BuLi (2 eq) was slowly added dropwise, and then the mixture was stirred for about 1 hour at low temperature.

Thereafter, the reaction mixture in the first round-bottom flask was rapidly added to the second round-bottom flask dropwise and then stirred for about 12 hours at room temperature. After completion of the reaction, the reaction solution was subjected to extraction with ethyl acetate to collect an organic layer. The organic layer was dried using magnesium sulfate to obtain the residue. The residue was purified and separated by column chromatography using silica gel to obtain Compound 41 (yield: 30%). Compound 41 was identified by LC-MS and 1H-NMR.

LC-MS for Compound 41: C₅₂H₃₇N₃OSi₂M⁺¹: 776.15

### (7) Synthesis of Compound 52

Hetero Compound 52 according to one or more embodiments may be synthesized by, for example, a reaction scheme herein.

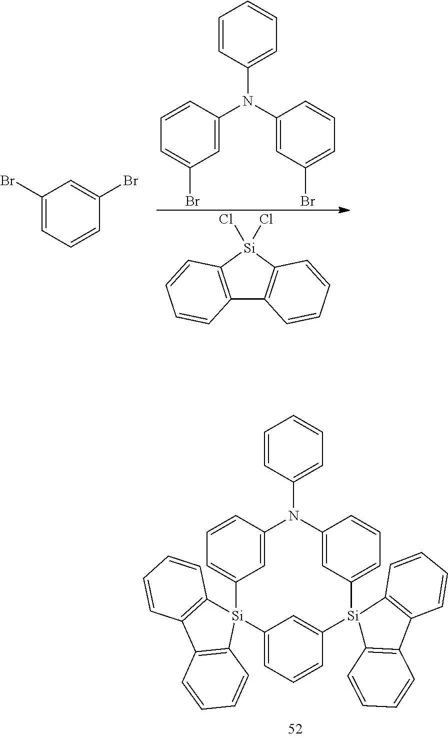

In a first round-bottom flask, 5 g of 1,3-dibromobenzene (1 eq) was put and dissolved in 200 mL of THF, and then the mixture was stabilized at about −78° C. N-BuLi (2 eq) was slowly added dropwise, and then the mixture was stirred for about 1 hour at low temperature. 5,5-dichloro-5H-dibenzo[b,d]silole (2 eq) was added rapidly to the reaction mixture, and the mixture was stirred for about 2 hours at low temperature.

In a second round-bottom flask, 3-bromo-N-(3-bromophenyl)-N-phenylaniline (1 eq) was put and dissolved in THE of 200 mL, and then the mixture was stabilized at about −78° C. N-BuLi (2 eq) was slowly added dropwise, and then the mixture was stirred for about 1 hour at low temperature.

Thereafter, the reaction mixture in the first round-bottom flask was rapidly added to the second round-bottom flask dropwise and then stirred for about 12 hours at room temperature. After completion of the reaction, the reaction solution was subjected to extraction with ethyl acetate to collect an organic layer. The organic layer was dried using magnesium sulfate to obtain the residue. The residue was purified and separated by column chromatography using silica gel to obtain 6.47 g of Compound 52 (yield: 45%). Compound 52 was identified by LC-MS and 1H-NMR.

LC-MS for Compound 52: C₄₈H₃₃NSi₂M⁺¹: 680.20

### (8) Synthesis of Compound 54

Hetero Compound 54 according to one or more embodiments may be synthesized by, for example, a reaction scheme herein.

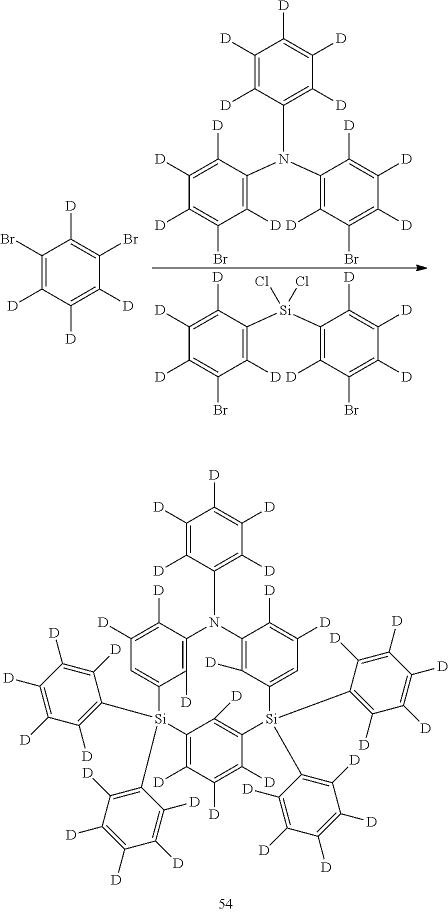

In a first round-bottom flask, 5 g of 1,3-dibromobenzene-2,4,5,6-d₄ (1 eq) was put and dissolved in 200 mL of THF, and then the mixture was stabilized at about −78° C. N-BuLi (2 eq) was slowly added dropwise, and then the mixture was stirred for about 20 minutes at low temperature. Dichlorobis(phenyl-d₅)silane (2 eq) was added rapidly to the reaction solution, and the mixture was stirred for about 2 hours at low temperature.

In a second round-bottom flask, N,N-bis(3-bromophenyl-2,4,5,6-d₄)aniline-d₅ (1 eq) was put and dissolved in THE of 200 mL, and then the mixture was stabilized at about −78° C. N-BuLi (2 eq) was slowly added dropwise, and then the mixture was stirred for about 1 hour at low temperature.

Thereafter, the reaction mixture in the first round-bottom flask was rapidly added to the second round-bottom flask dropwise and then stirred for about 12 hours at room temperature. After completion of the reaction, the reaction solution was subjected to extraction with ethyl acetate to collect an organic layer. The organic layer was dried using magnesium sulfate to obtain the residue. The residue was purified and separated by column chromatography using silica gel to obtain Compound 54 (yield: 45%). Compound 54 was identified by LC-MS and 1H-NMR.

LC-MS for Compound 54: C₄₈H₂D₃₅NSi₂M⁺¹: 719.34

### 2. Manufacturer and Evaluation of Light-Emitting Element

The light-emitting elements according to one or more embodiments respectively including the hetero compounds according to Examples in the emission layer were manufactured by the following method. The light-emitting elements according to Example 1 to Example 8 were manufactured using, as host materials for the emission layer, the hetero compounds of Compounds 8, 21, 25, 31, 36, 41, 52, and 54, which are Example compounds previously described. The light-emitting elements according to Comparative Example 1 to Comparative Example 4 correspond to the light-emitting elements manufactured by using Comparative Example Compound C1 to Comparative Example Compound C4 as host materials of the emission layer.

### Example Compounds

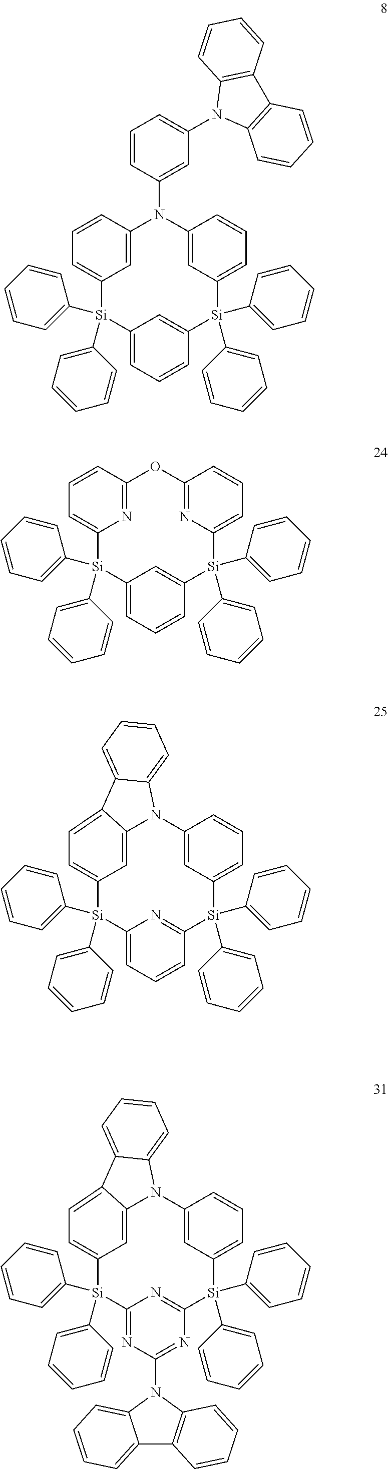 [SMILES: c1ccc([Si]2(c3ccccc3)c3cccc(c3)N(c3cccc(-n4c5ccccc5c5ccccc54)c3)c3cccc(c3)[Si](c3ccccc3)(c3ccccc3)c3cccc2c3)cc1 ; c1ccc([Si]2(c3ccccc3)c3cccc(c3)[Si](c3ccccc3)(c3ccccc3)c3cccc(n3)Oc3cccc2n3)cc1 ; c1ccc([Si]2(c3ccccc3)c3cccc(c3)-n3c4ccccc4c4ccc(cc43)[Si](c3ccccc3)(c3ccccc3)c3cccc2n3)cc1 ; c1ccc([Si]2(c3ccccc3)c3cccc(c3)-n3c4ccccc4c4ccc(cc43)[Si](c3ccccc3)(c3ccccc3)c3nc(-n4c5ccccc5c5ccccc54)nc2n3)cc1]

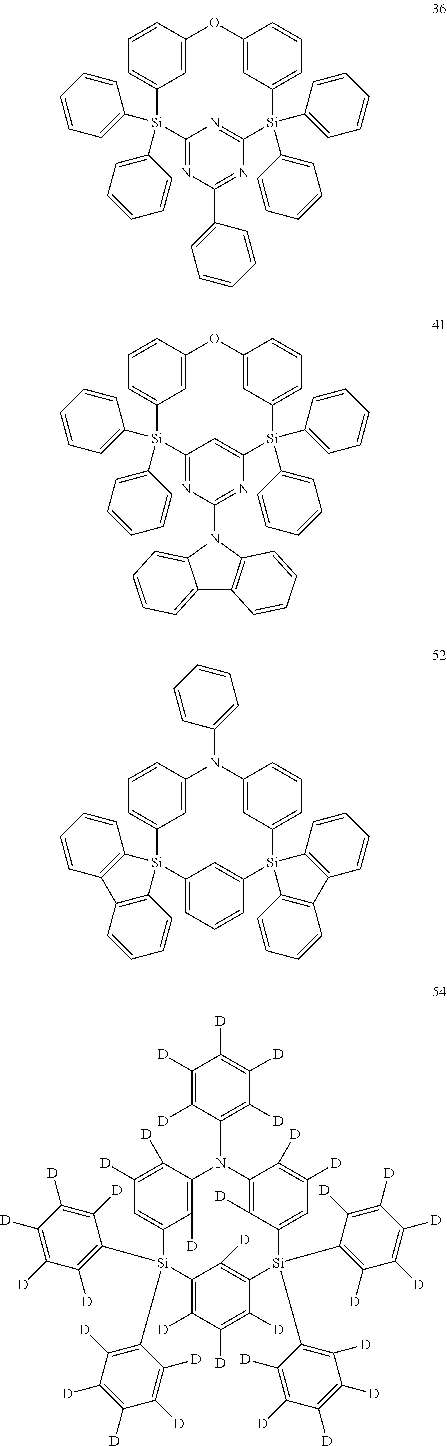

### Comparative Example Compounds

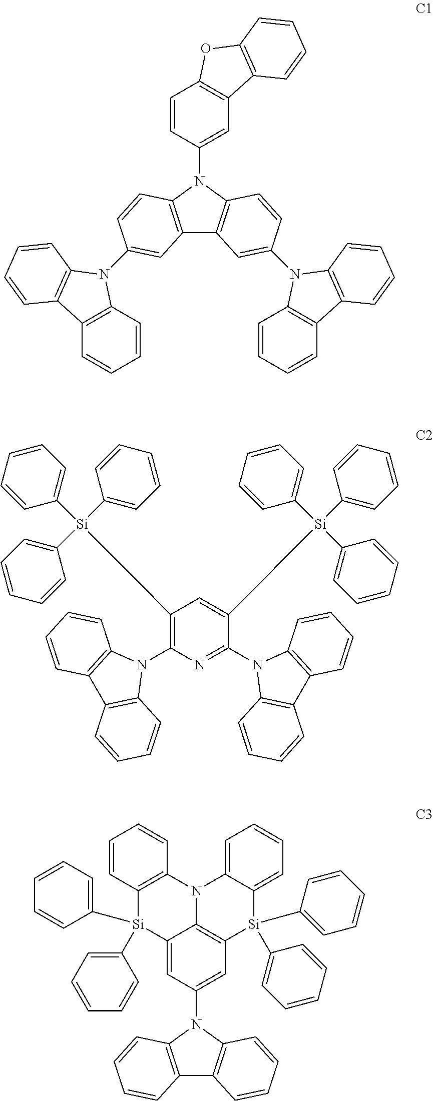

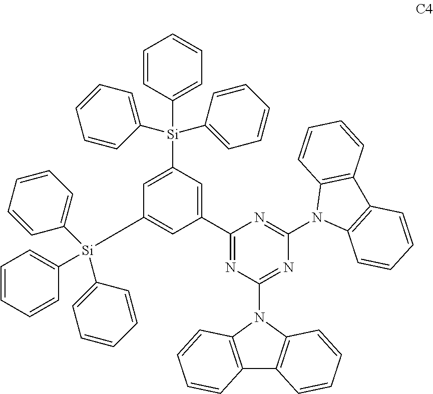 [SMILES: c1ccc([Si](c2ccccc2)(c2ccccc2)c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1]

### Manufacture of Light-Emitting Element

The light-emitting element according to one or more embodiments including the hetero compound according to one or more embodiments in the emission layer was manufactured by following methods. The light-emitting elements according to Example 1 to Example 8 were manufactured respectively using Compounds 8, 21, 25, 31, 36, 41, 52, and 54, previously described as a host material in the emission layer. The light-emitting elements according to Comparative Example 1 to Comparative Example 4 were manufactured respectively using Comparative Example Compound C1 to Comparative Example Compound C4 as a host material in the emission layer. Phosphorescent materials were used for a dopant material in the emission layer.

For each of the light-emitting elements according to Examples and Comparative Examples, a glass substrate (made by Corning Co.), on which an ITO electrode of about 15 ohm per square centimeter (Ω/cm²) (1,200 angstrom (Å)) was formed as an anode, was cut to a size of about 50 millimeter (mm)×50 mm×0.7 mm, cleansed by ultrasonic waves using isopropyl alcohol and pure water for about five minutes each, and then irradiated with ultraviolet rays for about 30 minutes and exposed to ozone to be cleansed. Then, the glass substrate was mounted on a vacuum deposition apparatus.

N,N′-di(naphthalene-l-yl)-N,N′-diphenyl-benzidine (NPB) was deposited on the anode to form a hole injection layer having a thickness of about 300 Å, then mCP was vacuum deposited on the hole injection layer to form a hole transport layer having a thickness of about 200 Å.

Example compound or Comparative example compound and M-a26 which is a phosphorescent dopant were co-deposited on the hole transport layer at a weight ratio of about 92:8 to form an emission layer having a thickness of about 250 Å.

Thereafter, 3-(4-biphenylyl)-4-phenyl-5-tert-butylphenyl-1,2,4-triazole (TAZ) was deposited on the emission layer to form an electron transport layer having a thickness of about 200 Å. LiF, which is an alkali metal halide, was deposited on the electron transport layer to form an electron injection layer having a thickness of about 10 Å. Then, aluminum (Al) was deposited in a thickness of about 100 Å to from a LiF/Al electrode, thereby manufacturing a light-emitting element. Each layer was formed by vacuum deposition.

Compounds used for manufacture of the light-emitting elements according to examples and comparative examples are disclosed herein.

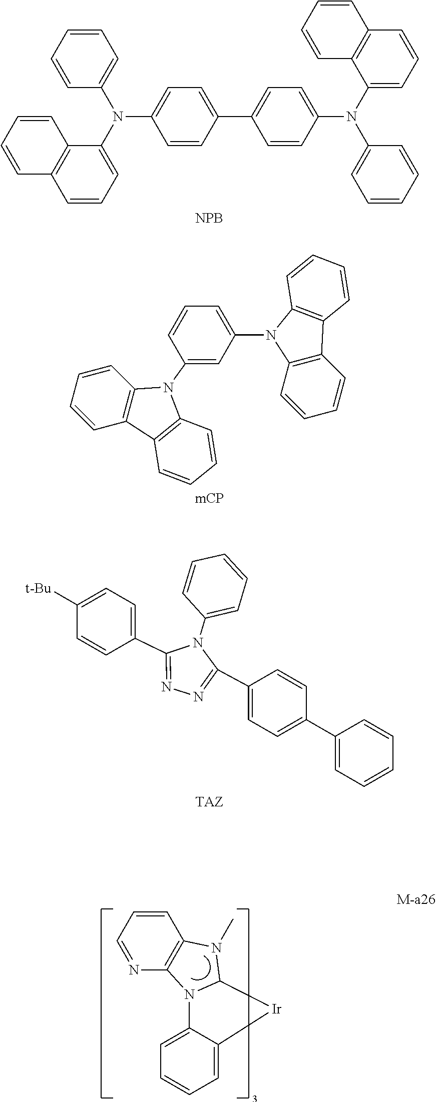

### Evaluation of Properties of Light-Emitting Elements

In order to evaluate properties of the light-emitting elements manufactured respectively using Compounds 8, 21, 25, 31, 36, 41, 52, and 54 and Comparative Example Compounds C1 to C4, a driving voltage at a current density at about 10 milliampere per square centimeter (mA/cm²), a current density and maximum quantum efficiency of the light-emitting element were measured. The driving voltage and the current density were measured using a source meter (Keithley Instrument, 2400 series), the maximum quantum efficiency was measured using external quantum efficiency system C9920-2-12 made by Hamamatsu Photonics K.K. In evaluation of the maximum quantum efficiency, luminance/current density was measured using a luminance meter with wavelength sensitivity calibration, and the value was converted into maximum quantum efficiency by assuming a Lambertian angular luminance distribution luminance distribution for a perfectly diffusive reflector. The evaluation results of the organic electroluminescent element were listed in Table 1.

TABLE 1

| | | | | Maximum | | Peak |
|---|---|---|---|---|---|---|
| | | | | quantum | | emission |
| | | Driving | Efficiency | efficiency | Emission | wavelength |
| Classification | Emission layer | voltage(V) | (Cd/A) | (%) | color | (nm) |
| Example 1 | Compound 8 | 4.3 | 21.4 | 29.3 | Blue | 463 |
| Example 2 | Compound 21 | 3.9 | 20.5 | 29.1 | Blue | 466 |
| Example 3 | Compound 25 | 4.0 | 22.2 | 29.3 | Blue | 462 |
| Example 4 | Compound 31 | 3.7 | 23.5 | 28.2 | Blue | 463 |
| Example 5 | Compound 36 | 3.6 | 22.7 | 28.7 | Blue | 462 |
| Example 6 | Compound 41 | 3.8 | 22.6 | 28.1 | Blue | 462 |
| Example 7 | Compound 52 | 4.1 | 23.0 | 29.9 | Blue | 461 |
| Example 8 | Compound 54 | 4.0 | 24.2 | 30.0 | Blue | 461 |
| Comparative | Comparative | 5.7 | 12.8 | 22.4 | Blue | 472 |
| Example 1 | Example | | | | | |
| | Compound C1 | | | | | |
| Comparative | Comparative | 5.1 | 15.2 | 25.2 | Blue | 469 |
| Example 2 | Example | | | | | |
| | Compound C2 | | | | | |
| Comparative | Comparative | 5.0 | 17.1 | 25.8 | Blue | 468 |
| Example 3 | Example | | | | | |
| | Compound C3 | | | | | |
| Comparative | Comparative | 4.5 | 19.9 | 27.9 | Blue | 465 |
| Example 4 | Example | | | | | |
| | Compound C4 | | | | | |

Referring to the results in Table 1, it can be seen that all the light-emitting elements according to examples and comparative examples exhibit properties of emission color of blue. When the hetero compound according to one or more embodiments is used as a host material in the emission layer of the light-emitting element, low driving voltage, high efficiency, and long lifespan may be achieved. For example, it can be confirmed that the light-emitting elements according to Example 1 to Example 8 exhibit low driving voltage, and high efficiency properties, compared the light-emitting elements according to Comparative Example 1 to Comparative Example 4. Without wishing to be limited by theory, because the Example compounds have a bulky structure, compared to Comparative Example Compound C1 used in the light-emitting element according to Comparative Example 1, interactions with adjacent compounds decrease, which does not have a detrimental influence on luminous properties, and thus the light-emitting elements according to Examples have similar emission color properties to the light-emitting elements according to Comparative Examples. In some embodiments, the light-emitting elements according to Examples exhibit similar driving voltage properties to the light-emitting elements according to Comparative Examples.

Comparative Example Compound C2 and Comparative Example Compound C4 respectively included in the light-emitting elements according to Comparative Example 2 and Comparative Example 4, and have a structure in which two silyl groups are connected to each other via a pyridine linker, but have no cyclic structure around the two silyl groups. Comparative Example Compound C2 and Comparative Example Compound C4, each having a non-cyclic structure, may not provide sufficient steric hindrance effects compared to the Example Compounds having the cyclic structure. Therefore, it can be confirmed that when Comparative Example Compound C2 and Comparative Example Compound C4 are applied to the elements, the light-emitting elements have high driving-voltage and low luminous efficiency, compared to the light-emitting elements according to the Examples.

Comparative Example Compound C3 included in the light-emitting element according to Comparative Example 3 has a different connection structure between the silyl group and the linker, compared to the Example Compounds. The Example Compounds have a structure in which a nitrogen atom or oxygen atom, which is the second linker linking two silyl groups, is connected at a meta-position with respect to the silicon atom of each of the silyl groups. In contrast, Comparative Example Compound C3 corresponds to a compound in which a nitrogen atom corresponding to the second linker is connected at an ortho-position with respect to the silicon atom to form an additional hetero fused ring, and steric hindrance effects decrease with such a structure, which makes it difficult to achieve the desired steric hindrance effects. The second linker in the Example Compounds is connected at a meta-position with respect to the silicon atom, and thus the bulky structure may be maintained. Due to this connection relationship, the Example Compounds may have enhanced or improved properties of luminous efficiency due to increased prevention effect of intermolecular interactions. The light-emitting element according to the Examples may exhibit more suitable or excellent luminous efficiency properties than the light-emitting element according to Comparative Examples. Without wishing to be limited by theory, the enhanced luminous efficiency of the Example Compounds may be the result of their suitable or excellent material stability created by the steric structural characteristics of the Example Compounds, compared to Comparative Example Compounds.

The hetero compound according to one or more embodiments may have a cyclic structure in which all three of: (A) the first and second silicon atoms, each connected to three aromatic rings; (B) the first linker linking the first and the second silicon atoms; and (C) the second linker linking any one of (e.g., among) the aromatic rings that are connected to the first silicon atom with any one of (e.g., among) the aromatic rings that are connected to the second silicon atom, are connected to each other. The hetero compound according to one or more embodiments may have a sterically bulky structure due to characteristics of a steric shape of the hetero compound according to one or more embodiments. Due to the characteristics of the steric structure, the hetero compound according to one or more embodiments may have reduced interactions with the adjacent compounds. For example, the hetero compound according to one or more embodiments may have minimized interference effects to the dopant and/or the like used together, and thus luminous properties of the dopant may be unaffected, thereby minimizing alteration in the emission color of the dopant. Therefore, the hetero compound according to one or more embodiments may enhance or improve color reproductivity of the light-emitting element. In some embodiments, the hetero compound according to one or more embodiments may have rigid properties due to the cyclic structure, and thus may exhibit suitable or excellent material stability.

The light-emitting element according to one or more embodiments may exhibit high efficiency and excellent color reproductivity by including the hetero compound according to one or more embodiments. In some embodiments, the display device according to one or more embodiments may exhibit improved display quality by including the light-emitting element having excellent color reproductivity and suitable or excellent efficiency properties.

The light-emitting element according to one or more embodiments may exhibit enhanced or improved element properties in high efficiency and long lifespan.

The hetero compound according to one or more embodiments may contribute to enhancing or improving in high efficiency and long lifespan of the light-emitting element by being included (contained) in the emission layer of the light-emitting element.

The display device according to one or more embodiments may exhibit suitable or excellent display quality.

The display device, electronic apparatus, electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display device, electronic apparatus, and/or electronic device may be formed on one integrated circuit (IC) chip or on separate IC chips. Further, the one or more suitable components of the display device, electronic apparatus, and/or electronic device may be implemented on a flexible printed circuit film, a tape carrier package (TCP), a printed circuit board (PCB), or formed on one substrate. Further, the one or more suitable components of the display device, electronic apparatus, and/or electronic device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

Hitherto, although the embodiments of the present disclosure have been described, it is understood that the present disclosure should not be limited to these embodiments but one or more suitable changes and modifications can be made by one ordinary skilled in the art within the spirit and scope of the present disclosure as hereinafter claimed.

Therefore, the technical scope of the present disclosure is not intended to be limited to the contents set forth in the detailed description of the specification, but is intended to be defined by the appended claims.

What is claimed is:

1. A light-emitting element comprising:
a first electrode;
a second electrode opposite to the first electrode; and
at least one functional layer between the first electrode and the second electrode,
wherein the at least one functional layer comprises a first compound represented by Formula 1: 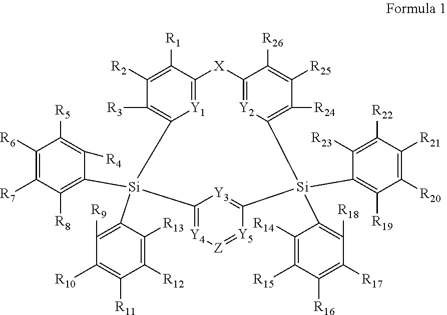
wherein, in Formula 1,
X is NAr₁ or 0,
Z is CR₂₇ or N,
Y₁ to Y₅ are each independently CR₂₈ or N,
Ar₁ is a substituted or unsubstituted aryl group having 6 to 30 ring-forming carbons, a substituted or unsubstituted heteroaryl group having 2 to 30 ring-forming carbons, or bonded to an adjacent group to form a ring,
R₁ to R₂₈ are each independently a hydrogen atom, a deuterium atom, a cyano group, a substituted or unsubstituted silyl group, a substituted or unsubstituted alkyl group having 1 to 20 carbons, a substituted or unsubstituted cycloalkyl group having 3 to 20 ring-forming carbons, a substituted or unsubstituted hetero cycloalkyl group having 3 to 20 ring-forming carbons, a substituted or unsubstituted alkenyl group having 2 to 20 carbons, a substituted or unsubstituted cycloalkenyl group having 3 to 20 ring-forming carbons, a substituted or unsubstituted hetero cycloalkenyl group having 3 to 20 ring-forming carbons, a substituted or unsubstituted aryl group having 6 to 30 ring-forming carbons, a substituted or unsubstituted heteroaryl group having 2 to 30 ring-forming carbons, or bonded to an adjacent group to form a ring.

2. The light-emitting element of claim 1, wherein the at least one functional layer comprises:
a hole transport region on the first electrode;
an emission layer on the hole transport region; and
an electron transport region between the emission layer and the second electrode.

3. The light-emitting element of claim 2,
wherein the emission layer is a phosphorescent emission layer comprising a host and a dopant, and
the host is the first compound.

4. The light-emitting element of claim 2, wherein the emission layer is configured to emit light, the light having an emission peak wavelength of about 430 nanometer (nm) to about 490 nm.

5. The light-emitting element of claim 2, wherein the emission layer comprises the first compound, and a second compound represented by Formula M-a: 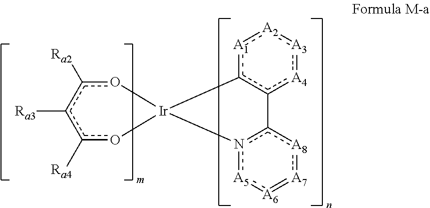
wherein, in Formula M-a,
A₁ to A₈ are each independently CRₐ₁ or N,
Rₐ₁ to Rₐ₄ are each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, a substituted or unsubstituted heteroaryl group having 2 to 30 ring-forming carbons, or bonded to an adjacent group to form a ring,
m is 0 or 1,
n is 2 or 3,
when m is 0, n is 3, and
when m is 1, n is 2.

6. The light-emitting element of claim 2, wherein the first compound is represented by any one of Formula 1-1 or Formula 1-2: 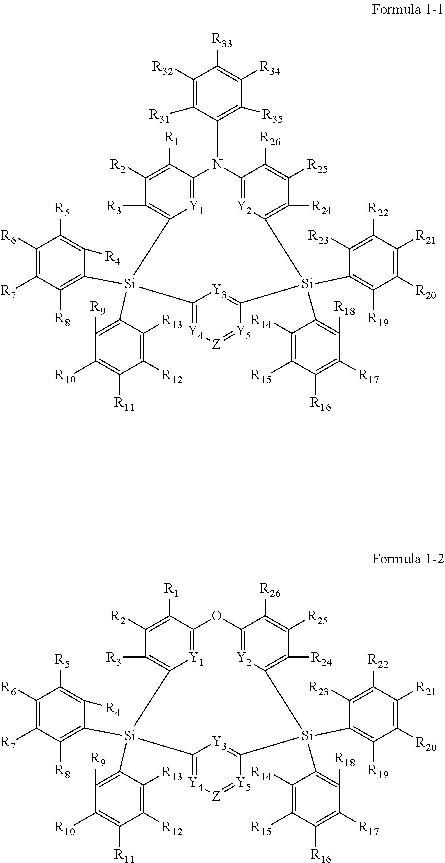
wherein, in Formula 1-1 and Formula 1-2,
R₃₁ to R₃₅ are each independently a hydrogen atom, a deuterium atom, a cyano group, a substituted or unsubstituted silyl group, a substituted or unsubstituted alkyl group having 1 to 20 carbons, a substituted or unsubstituted cycloalkyl group having 3 to 20 ring-forming carbons, a substituted or unsubstituted hetero cycloalkyl group having 3 to 20 ring-forming carbons, a substituted or unsubstituted alkenyl group having 2 to 20 carbons, a substituted or unsubstituted cycloalkenyl group having 3 to 20 ring-forming carbons, a substituted or unsubstituted heterocycloalkenyl group having 3 to 20 ring-forming carbons, a substituted or unsubstituted aryl group having 6 to 30 ring-forming carbons, a substituted or unsubstituted heteroaryl group having 2 to 30 ring-forming carbons, or bonded to an adjacent group to form a ring,
Z, Y₁ to Y₅, and R₁ to R₂₆ are as defined in Formula 1.

7. The light-emitting element of claim 1, wherein the first compound is represented by any one of Formula 2-1 or Formula 2-2: 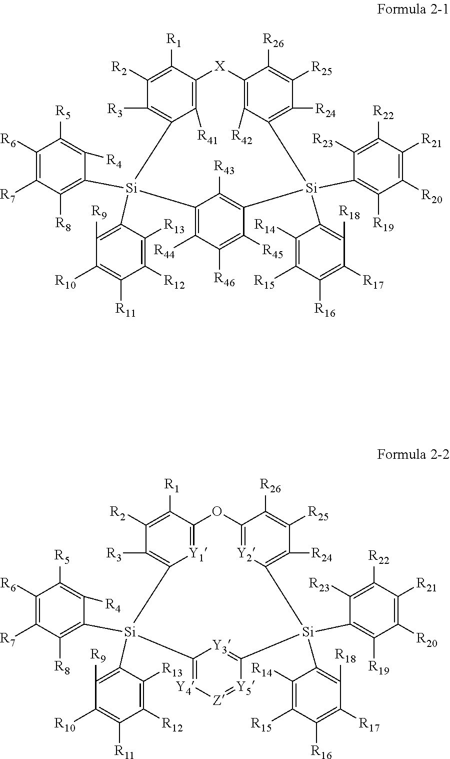
wherein, in Formula 2-1 and Formula 2-2,
R₄₁ to R₄₆ are each independently a hydrogen atom, a deuterium atom, or a substituted or unsubstituted carbazole group,
at least any one selected from among Y₁′ to Y₅′, and Z′ is N, and any remaining Y₁′ to Y₅′, and Z′ are each independently CR₄₇,
R₄₇ is a hydrogen atom or a deuterium atom, and
X, and R₁ to R₂₆ are as defined in Formula 1.

8. The light-emitting element of claim 1, wherein the first compound is represented by any one selected from among Formula 3-1 to Formula 3-3: 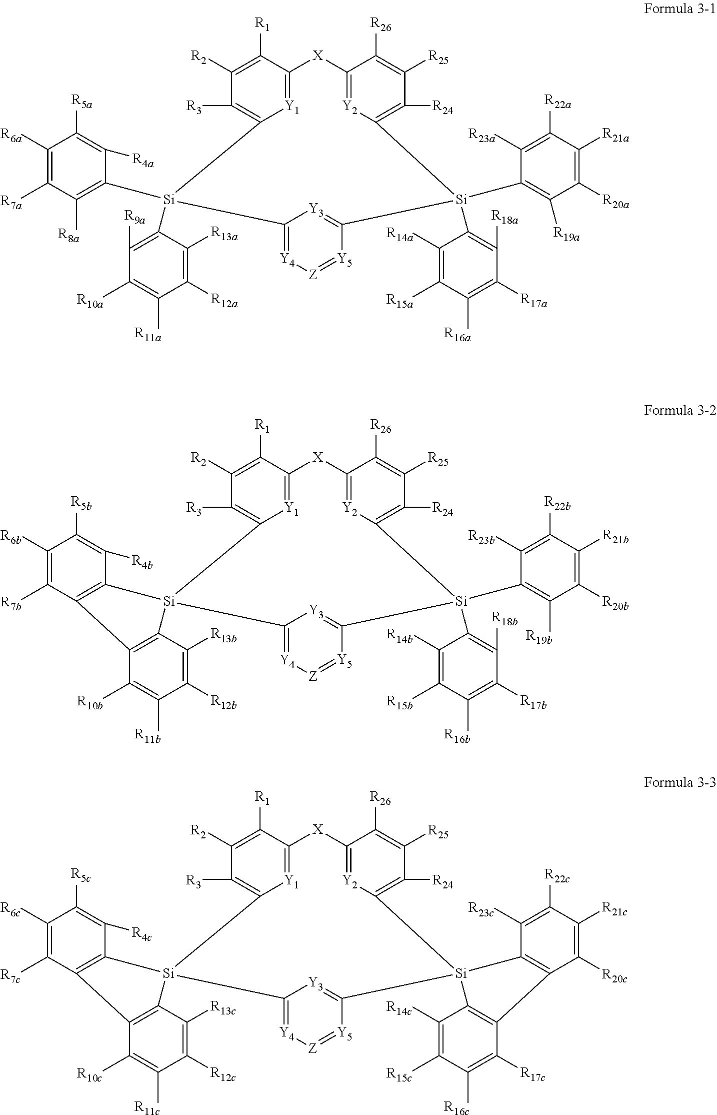
wherein, in Formula 3-1,
R₄ₐ to R₂₃ₐ are each independently a hydrogen atom, a deuterium atom, or a substituted or unsubstituted carbazole group,
in Formula 3-2,
R_{4b} to R_{7b}, R_{10b} to R_{13b}, and R_{14b} to R_{23b} are each independently a hydrogen atom, a deuterium atom, or a substituted or unsubstituted carbazole group,
in Formula 3-3,
R_{4c} to R_{7c}, R_{10c} to R_{13c}, R_{14c} to R_{17c}, and R_{20c} to R_{23c} are each independently a hydrogen atom, a deuterium atom, or a substituted or unsubstituted carbazole group, and
in Formula 3-1 to Formula 3-3,
X, Z, Y₁ to Y₅, R₁ to R₃, and R₂₄ to R₂₆ are as defined in Formula 1.

9. The light-emitting element of claim 1, wherein the first compound is represented by any one selected from among Formula 4-1 to Formula 4-3: 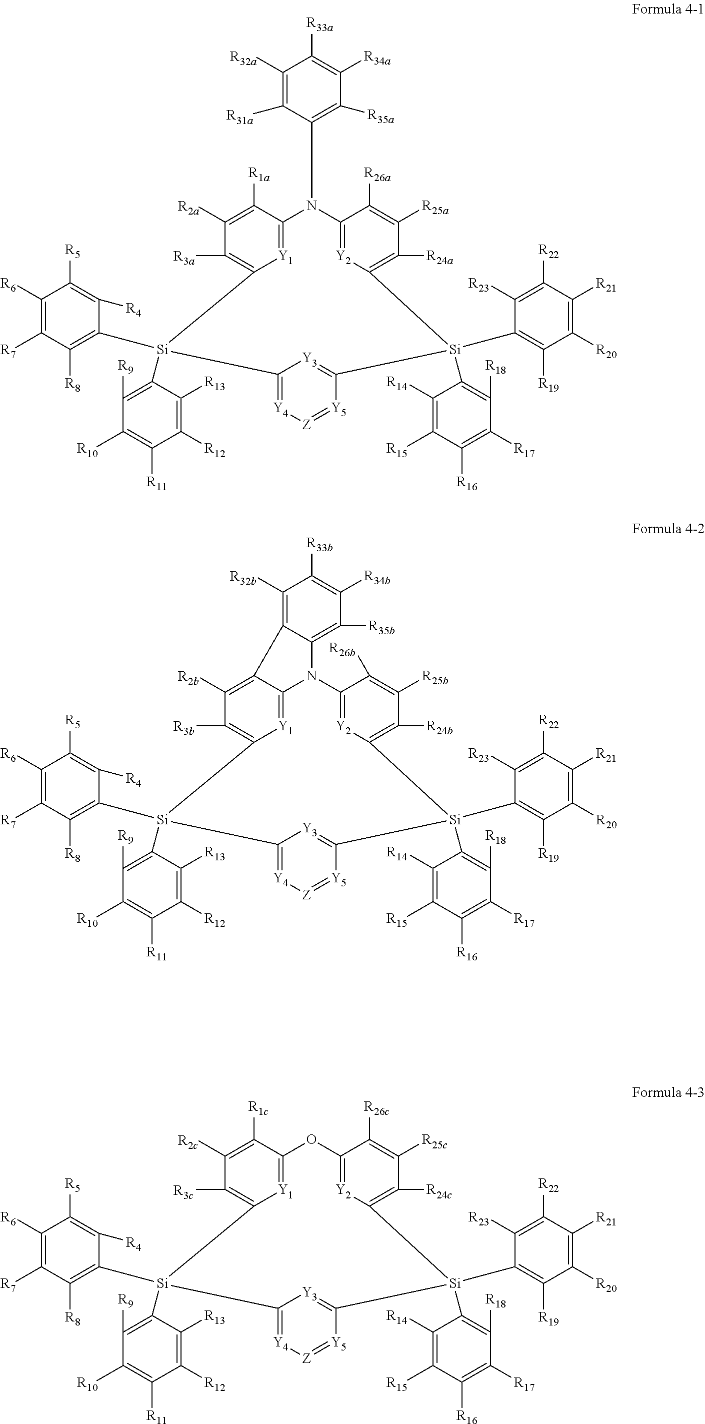
wherein, in Formula 4-1,
R₁ₐ to R₃ₐ, R₂₄ₐ to R₂₆ₐ, and R₃₁ₐ to R₃₅ₐ are each independently a hydrogen atom, a deuterium atom, or a substituted or unsubstituted carbazole group,
in Formula 4-2,
R_{2b}, R_{3b}, R_{24b} to R_{26b}, and R_{32b} to R_{35b} are each independently a hydrogen atom, a deuterium atom, or a substituted or unsubstituted carbazole group,
in Formula 4-3,
R_{1c} to R_{3c}, and R_{24c} to R_{26c} are each independently a hydrogen atom, a deuterium atom, or a substituted or unsubstituted carbazole group, and
in Formula 4-1 to Formula 4-3,
Z, Y₁ to Y₅, and R₄ to R₂₃ are as defined in Formula 1.

10. The light-emitting element of claim 1, wherein the first compound comprises at least one selected from among compounds in Compound Group 1:

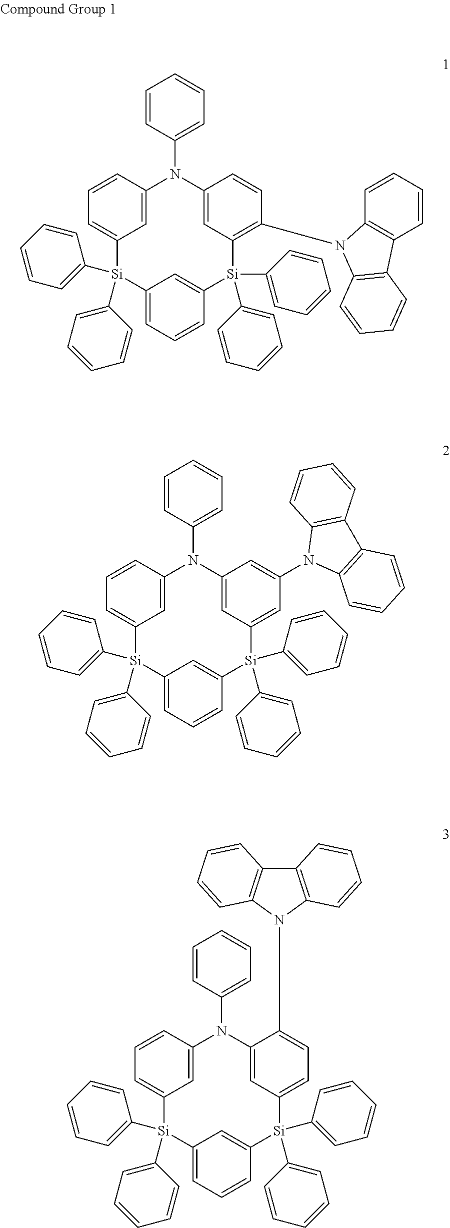 [SMILES: c1ccc(N2c3cccc(c3)[Si](c3ccccc3)(c3ccccc3)c3cccc(c3)[Si](c3ccccc3)(c3ccccc3)c3cc2ccc3-n2c3ccccc3c3ccccc32)cc1 ; c1ccc(N2c3cccc(c3)[Si](c3ccccc3)(c3ccccc3)c3cccc(c3)[Si](c3ccccc3)(c3ccccc3)c3cc2cc(-n2c4ccccc4c4ccccc42)c3)cc1 ; c1ccc(N2c3cccc(c3)[Si](c3ccccc3)(c3ccccc3)c3cccc(c3)[Si](c3ccccc3)(c3ccccc3)c3ccc(-n4c5ccccc5c5ccccc54)c2c3)cc1]

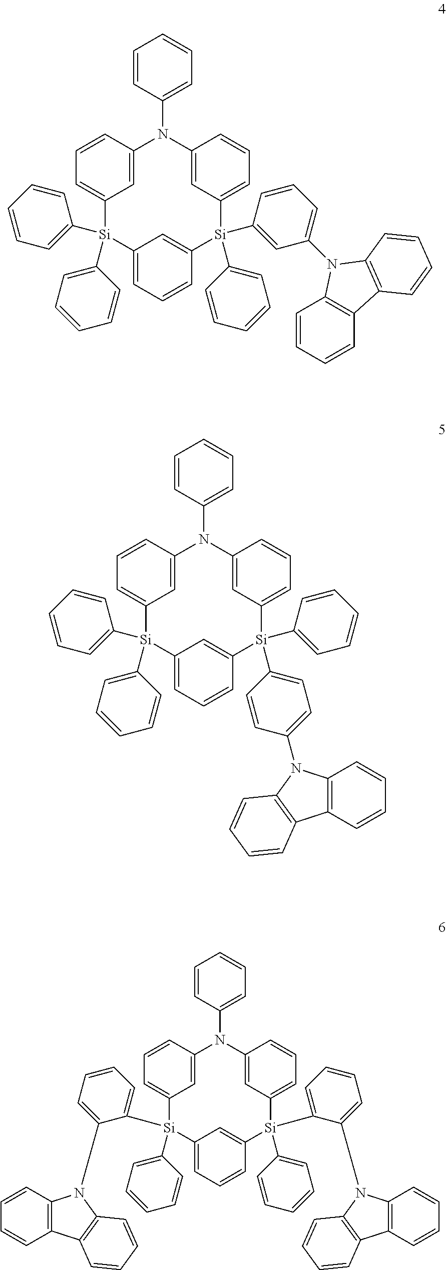 [SMILES: c1ccc(N2c3cccc(c3)[Si](c3ccccc3)(c3ccccc3)c3cccc(c3)[Si](c3ccccc3)(c3cccc(-n4c5ccccc5c5ccccc54)c3)c3cccc2c3)cc1 ; c1ccc(N2c3cccc(c3)[Si](c3ccccc3)(c3ccccc3)c3cccc(c3)[Si](c3ccccc3)(c3ccc(-n4c5ccccc5c5ccccc54)cc3)c3cccc2c3)cc1 ; c1ccc(N2c3cccc(c3)[Si](c3ccccc3)(c3ccccc3-n3c4ccccc4c4ccccc43)c3cccc(c3)[Si](c3ccccc3)(c3ccccc3-n3c4ccccc4c4ccccc43)c3cccc2c3)cc1]

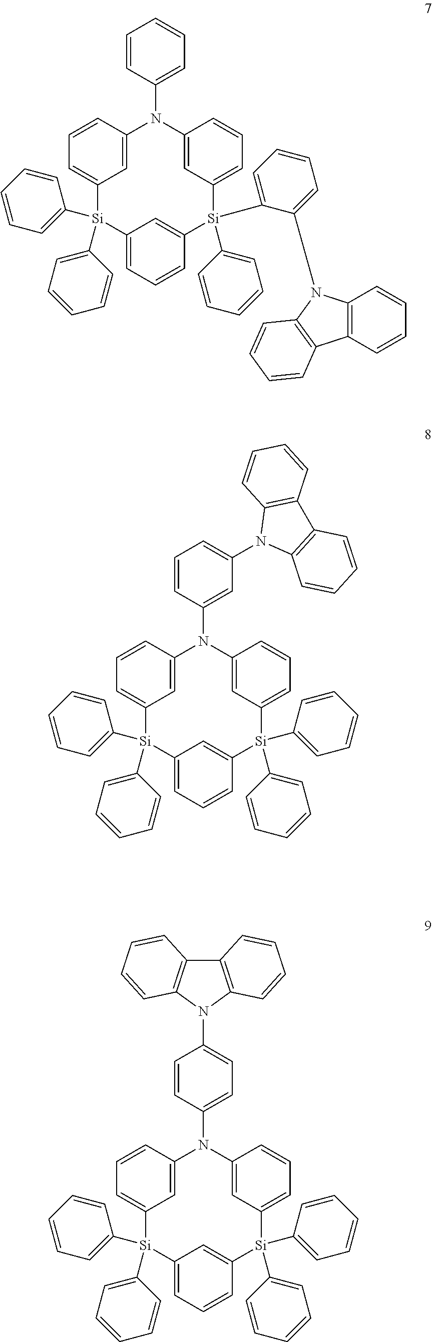 [SMILES: c1ccc(N2c3cccc(c3)[Si](c3ccccc3)(c3ccccc3)c3cccc(c3)[Si](c3ccccc3)(c3ccccc3-n3c4ccccc4c4ccccc43)c3cccc2c3)cc1 ; c1ccc([Si]2(c3ccccc3)c3cccc(c3)N(c3cccc(-n4c5ccccc5c5ccccc54)c3)c3cccc(c3)[Si](c3ccccc3)(c3ccccc3)c3cccc2c3)cc1 ; c1ccc([Si]2(c3ccccc3)c3cccc(c3)N(c3ccc(-n4c5ccccc5c5ccccc54)cc3)c3cccc(c3)[Si](c3ccccc3)(c3ccccc3)c3cccc2c3)cc1]

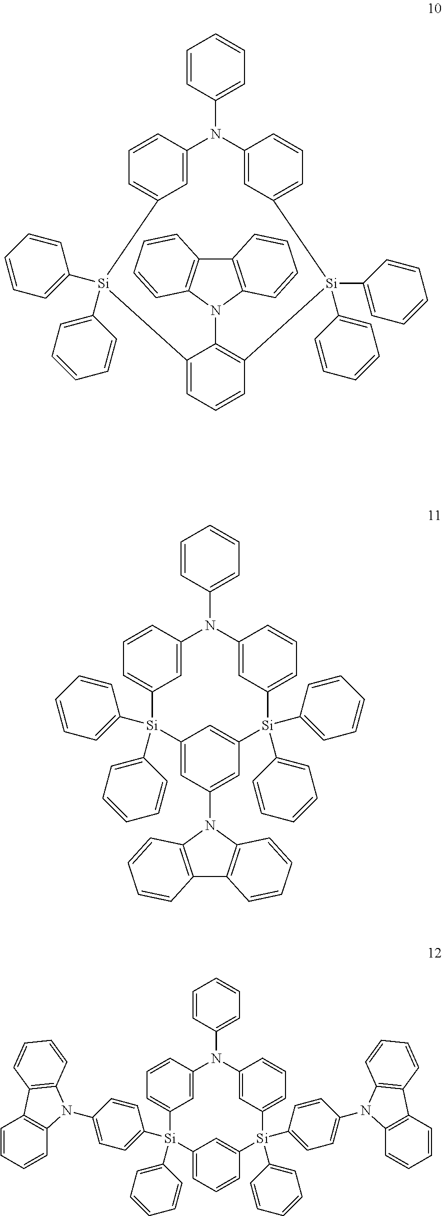 [SMILES: c1ccc(N2c3cccc(c3)[Si](c3ccccc3)(c3ccccc3)c3cccc(c3-n3c4ccccc4c4ccccc43)[Si](c3ccccc3)(c3ccccc3)c3cccc2c3)cc1 ; c1ccc(N2c3cccc(c3)[Si](c3ccccc3)(c3ccccc3)c3cc(-n4c5ccccc5c5ccccc54)cc(c3)[Si](c3ccccc3)(c3ccccc3)c3cccc2c3)cc1 ; c1ccc(N2c3cccc(c3)[Si](c3ccccc3)(c3ccc(-n4c5ccccc5c5ccccc54)cc3)c3cccc(c3)[Si](c3ccccc3)(c3ccc(-n4c5ccccc5c5ccccc54)cc3)c3cccc2c3)cc1]

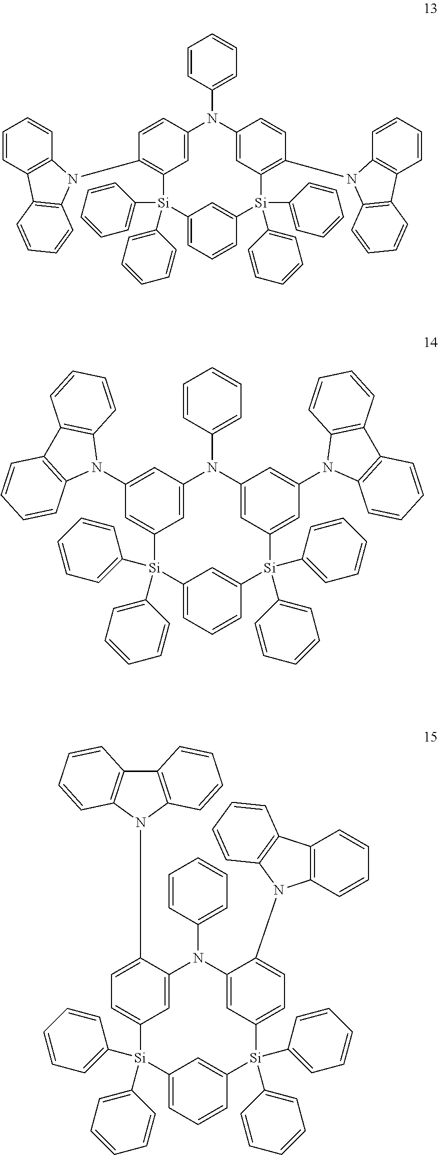 [SMILES: c1ccc(N2c3ccc(-n4c5ccccc5c5ccccc54)c(c3)[Si](c3ccccc3)(c3ccccc3)c3cccc(c3)[Si](c3ccccc3)(c3ccccc3)c3cc2ccc3-n2c3ccccc3c3ccccc32)cc1 ; c1ccc(N2c3cc(-n4c5ccccc5c5ccccc54)cc(c3)[Si](c3ccccc3)(c3ccccc3)c3cccc(c3)[Si](c3ccccc3)(c3ccccc3)c3cc2cc(-n2c4ccccc4c4ccccc42)c3)cc1 ; c1ccc(N2c3cc(ccc3-n3c4ccccc4c4ccccc43)[Si](c3ccccc3)(c3ccccc3)c3cccc(c3)[Si](c3ccccc3)(c3ccccc3)c3ccc(-n4c5ccccc5c5ccccc54)c2c3)cc1]

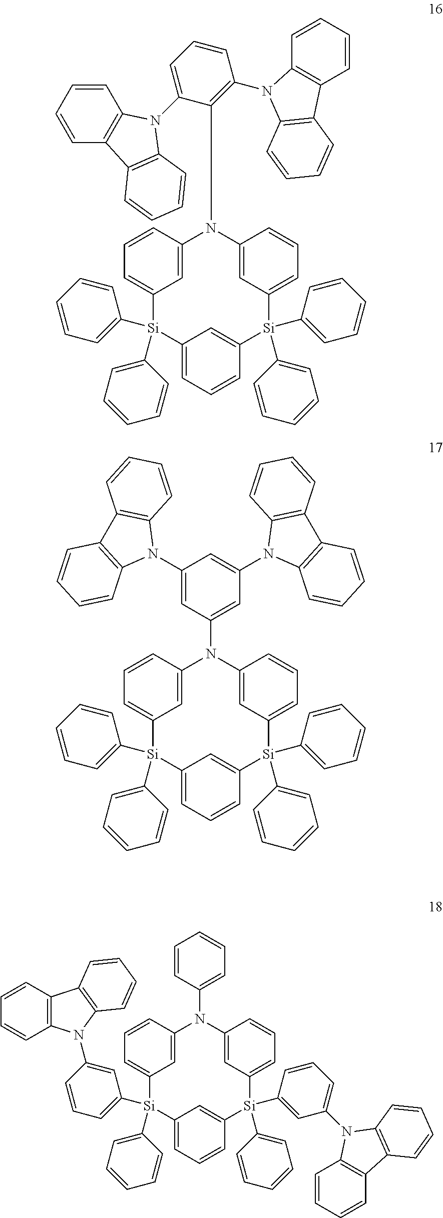

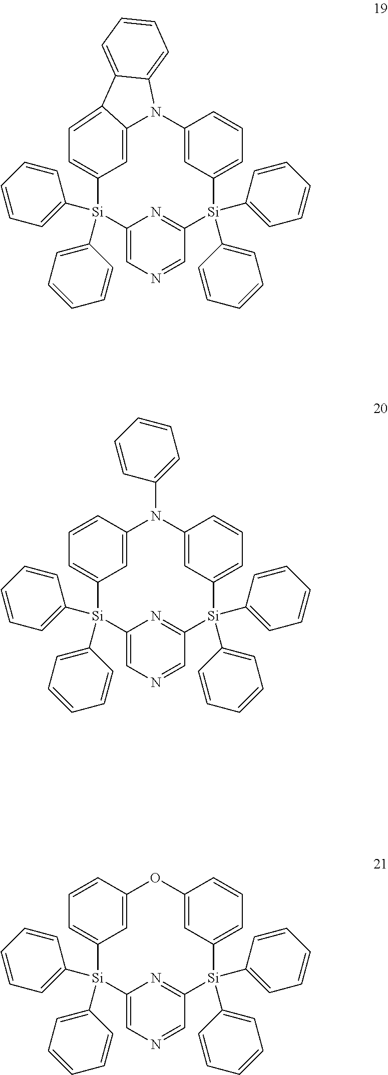 [SMILES: c1ccc([Si]2(c3ccccc3)c3cccc(c3)-n3c4ccccc4c4ccc(cc43)[Si](c3ccccc3)(c3ccccc3)c3cncc2n3)cc1 ; c1ccc(N2c3cccc(c3)[Si](c3ccccc3)(c3ccccc3)c3cncc(n3)[Si](c3ccccc3)(c3ccccc3)c3cccc2c3)cc1 ; c1ccc([Si]2(c3ccccc3)c3cccc(c3)Oc3cccc(c3)[Si](c3ccccc3)(c3ccccc3)c3cncc2n3)cc1]

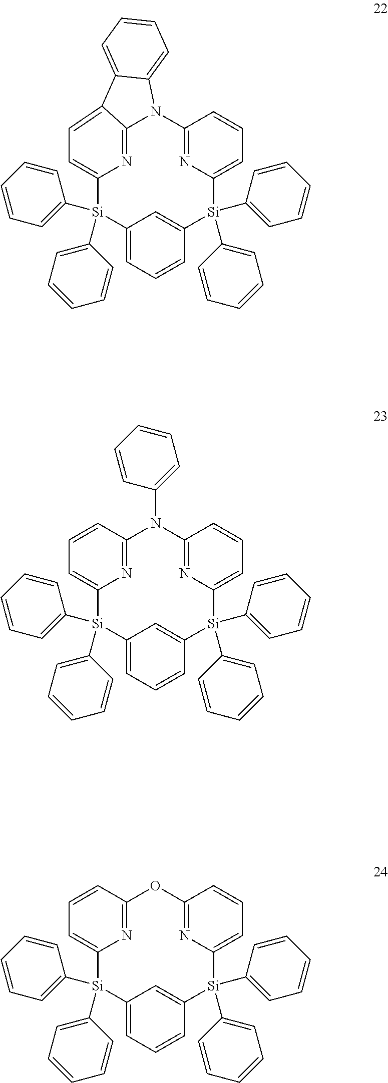 [SMILES: c1ccc([Si]2(c3ccccc3)c3cccc(c3)[Si](c3ccccc3)(c3ccccc3)c3ccc4c5ccccc5n(c4n3)-c3cccc2n3)cc1 ; c1ccc(N2c3cccc(n3)[Si](c3ccccc3)(c3ccccc3)c3cccc(c3)[Si](c3ccccc3)(c3ccccc3)c3cccc2n3)cc1 ; c1ccc([Si]2(c3ccccc3)c3cccc(c3)[Si](c3ccccc3)(c3ccccc3)c3cccc(n3)Oc3cccc2n3)cc1]

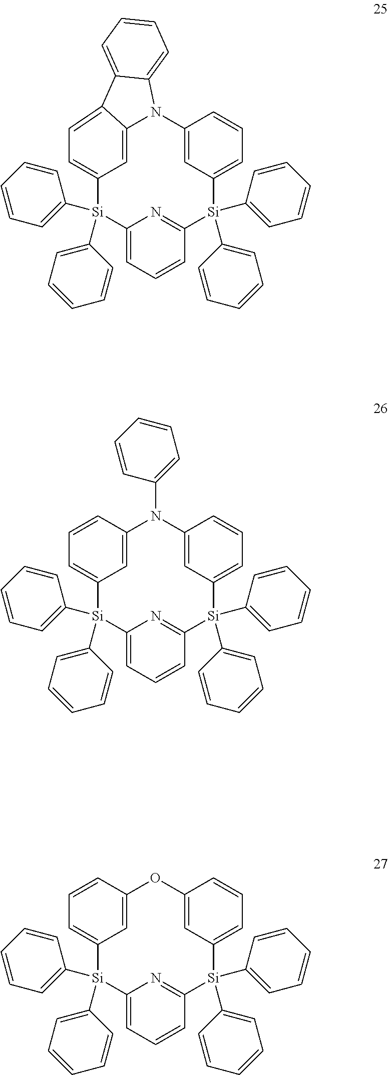 [SMILES: c1ccc([Si]2(c3ccccc3)c3cccc(c3)-n3c4ccccc4c4ccc(cc43)[Si](c3ccccc3)(c3ccccc3)c3cccc2n3)cc1 ; c1ccc(N2c3cccc(c3)[Si](c3ccccc3)(c3ccccc3)c3cccc(n3)[Si](c3ccccc3)(c3ccccc3)c3cccc2c3)cc1 ; c1ccc([Si]2(c3ccccc3)c3cccc(c3)Oc3cccc(c3)[Si](c3ccccc3)(c3ccccc3)c3cccc2n3)cc1]

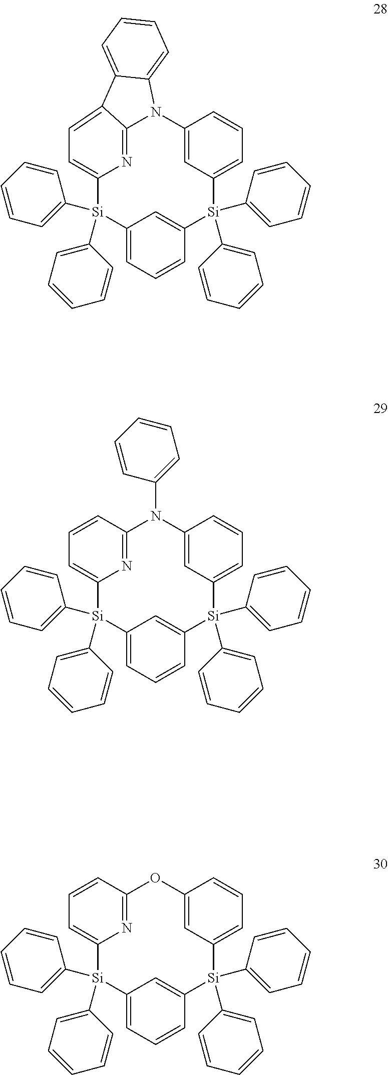 [SMILES: c1ccc([Si]2(c3ccccc3)c3cccc(c3)-n3c4ccccc4c4ccc(nc43)[Si](c3ccccc3)(c3ccccc3)c3cccc2c3)cc1 ; c1ccc(N2c3cccc(c3)[Si](c3ccccc3)(c3ccccc3)c3cccc(c3)[Si](c3ccccc3)(c3ccccc3)c3cccc2n3)cc1 ; c1ccc([Si]2(c3ccccc3)c3cccc(c3)Oc3cccc(n3)[Si](c3ccccc3)(c3ccccc3)c3cccc2c3)cc1]

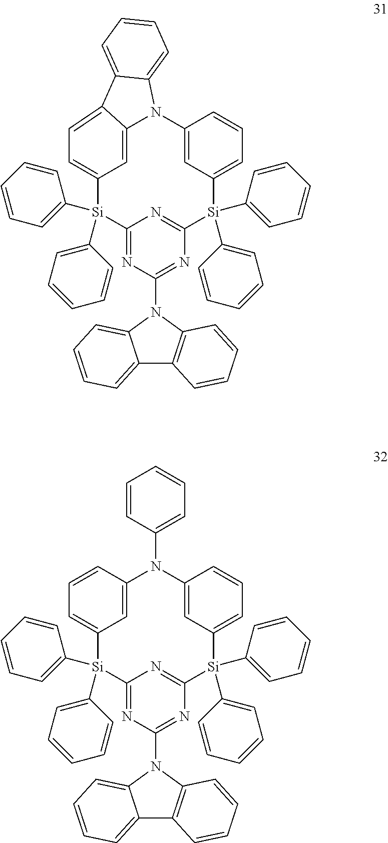 [SMILES: c1ccc([Si]2(c3ccccc3)c3cccc(c3)-n3c4ccccc4c4ccc(cc43)[Si](c3ccccc3)(c3ccccc3)c3nc(-n4c5ccccc5c5ccccc54)nc2n3)cc1 ; c1ccc(N2c3cccc(c3)[Si](c3ccccc3)(c3ccccc3)c3nc(-n4c5ccccc5c5ccccc54)nc(n3)[Si](c3ccccc3)(c3ccccc3)c3cccc2c3)cc1]

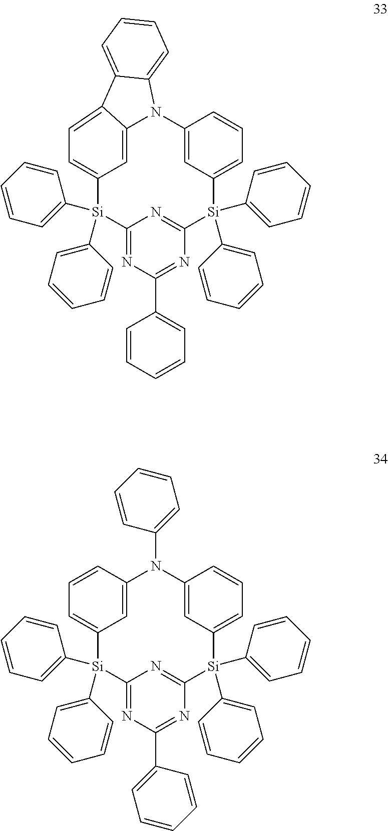 [SMILES: c1ccc(-c2nc3nc(n2)[Si](c2ccccc2)(c2ccccc2)c2ccc4c5ccccc5n(c4c2)-c2cccc(c2)[Si]3(c2ccccc2)c2ccccc2)cc1 ; c1ccc(-c2nc3nc(n2)[Si](c2ccccc2)(c2ccccc2)c2cccc(c2)N(c2ccccc2)c2cccc(c2)[Si]3(c2ccccc2)c2ccccc2)cc1]

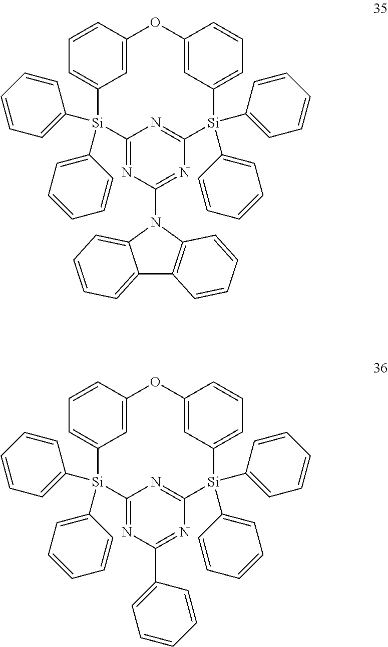 [SMILES: c1ccc([Si]2(c3ccccc3)c3cccc(c3)Oc3cccc(c3)[Si](c3ccccc3)(c3ccccc3)c3nc(-n4c5ccccc5c5ccccc54)nc2n3)cc1 ; c1ccc(-c2nc3nc(n2)[Si](c2ccccc2)(c2ccccc2)c2cccc(c2)Oc2cccc(c2)[Si]3(c2ccccc2)c2ccccc2)cc1]

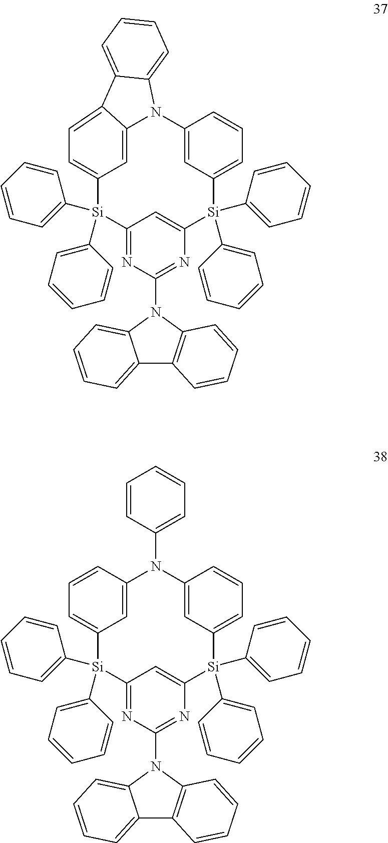 [SMILES: c1ccc([Si]2(c3ccccc3)c3cccc(c3)-n3c4ccccc4c4ccc(cc43)[Si](c3ccccc3)(c3ccccc3)c3cc2nc(-n2c4ccccc4c4ccccc42)n3)cc1 ; c1ccc(N2c3cccc(c3)[Si](c3ccccc3)(c3ccccc3)c3cc(nc(-n4c5ccccc5c5ccccc54)n3)[Si](c3ccccc3)(c3ccccc3)c3cccc2c3)cc1]

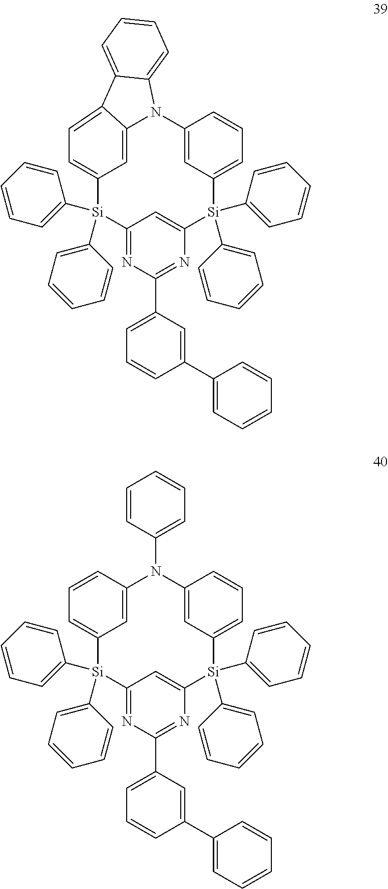 [SMILES: c1ccc(-c2cccc(-c3nc4cc(n3)[Si](c3ccccc3)(c3ccccc3)c3ccc5c6ccccc6n(c5c3)-c3cccc(c3)[Si]4(c3ccccc3)c3ccccc3)c2)cc1 ; c1ccc(-c2cccc(-c3nc4cc(n3)[Si](c3ccccc3)(c3ccccc3)c3cccc(c3)N(c3ccccc3)c3cccc(c3)[Si]4(c3ccccc3)c3ccccc3)c2)cc1]

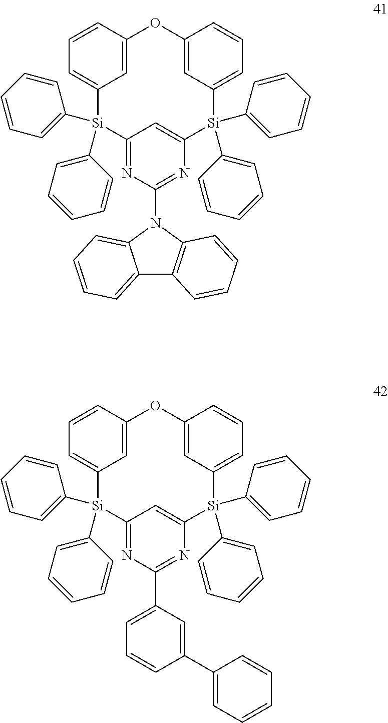 [SMILES: c1ccc([Si]2(c3ccccc3)c3cccc(c3)Oc3cccc(c3)[Si](c3ccccc3)(c3ccccc3)c3cc2nc(-n2c4ccccc4c4ccccc42)n3)cc1 ; c1ccc(-c2cccc(-c3nc4cc(n3)[Si](c3ccccc3)(c3ccccc3)c3cccc(c3)Oc3cccc(c3)[Si]4(c3ccccc3)c3ccccc3)c2)cc1]

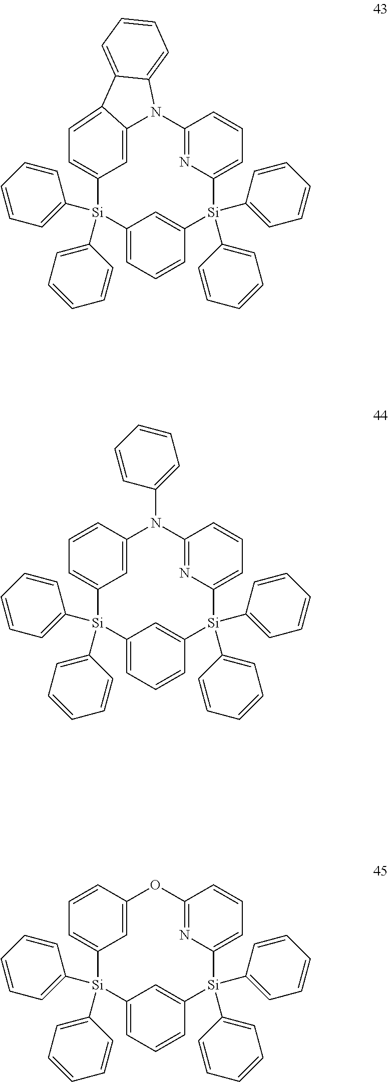 [SMILES: c1ccc([Si]2(c3ccccc3)c3cccc(c3)[Si](c3ccccc3)(c3ccccc3)c3cccc(n3)-n3c4ccccc4c4ccc2cc43)cc1 ; c1ccc(N2c3cccc(c3)[Si](c3ccccc3)(c3ccccc3)c3cccc(c3)[Si](c3ccccc3)(c3ccccc3)c3cccc2n3)cc1 ; c1ccc([Si]2(c3ccccc3)c3cccc(c3)Oc3cccc(n3)[Si](c3ccccc3)(c3ccccc3)c3cccc2c3)cc1]

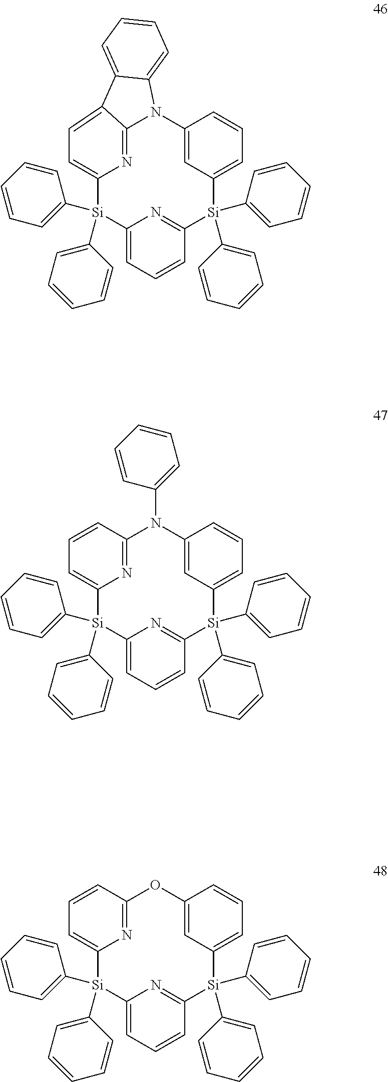 [SMILES: c1ccc([Si]2(c3ccccc3)c3cccc(c3)-n3c4ccccc4c4ccc(nc43)[Si](c3ccccc3)(c3ccccc3)c3cccc2n3)cc1 ; c1ccc(N2c3cccc(c3)[Si](c3ccccc3)(c3ccccc3)c3cccc(n3)[Si](c3ccccc3)(c3ccccc3)c3cccc2n3)cc1 ; c1ccc([Si]2(c3ccccc3)c3cccc(c3)Oc3cccc(n3)[Si](c3ccccc3)(c3ccccc3)c3cccc2n3)cc1]

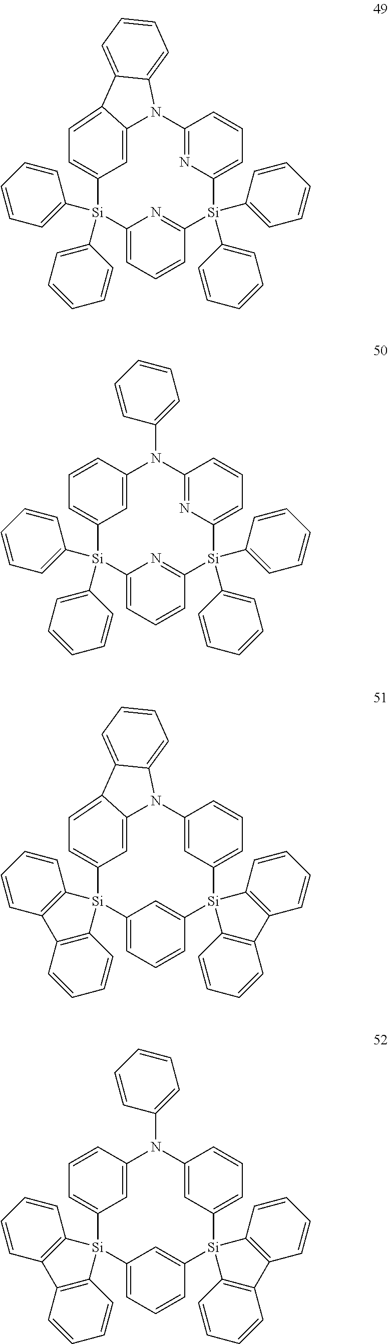 [SMILES: c1ccc([Si]2(c3ccccc3)c3ccc4c5ccccc5n(c4c3)-c3cccc(n3)[Si](c3ccccc3)(c3ccccc3)c3cccc2n3)cc1 ; c1ccc(N2c3cccc(c3)[Si](c3ccccc3)(c3ccccc3)c3cccc(n3)[Si](c3ccccc3)(c3ccccc3)c3cccc2n3)cc1 ; c1cc2cc(c1)[Si]1(c3cccc(c3)[Si]3(c4ccc5c6ccccc6n-2c5c4)c2ccccc2-c2ccccc23)c2ccccc2-c2ccccc21 ; c1ccc(N2c3cccc(c3)[Si]3(c4cccc(c4)[Si]4(c5cccc2c5)c2ccccc2-c2ccccc24)c2ccccc2-c2ccccc23)cc1]

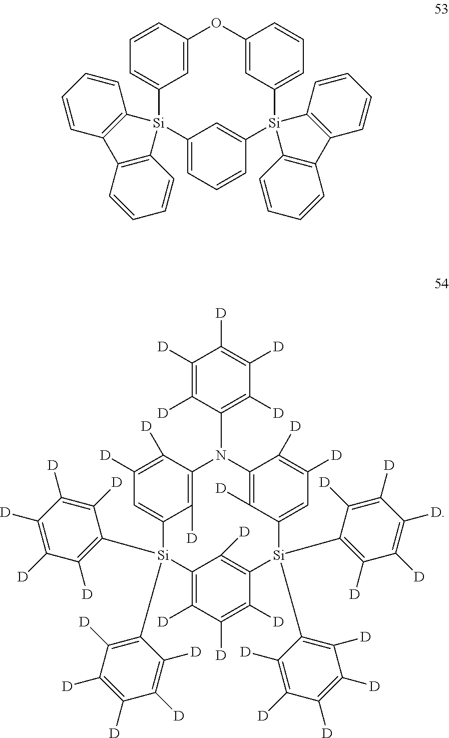

11. An electronic apparatus comprising:
a base layer;
a circuit layer on the base layer; and
a display element layer on the circuit layer and comprising a light-emitting element,
wherein the light-emitting element comprises:
a first electrode;
a second electrode opposite to the first electrode; and
at least one functional layer between the first electrode and the second electrode, and
the at least one functional layer comprising a first compound represented by Formula 1: 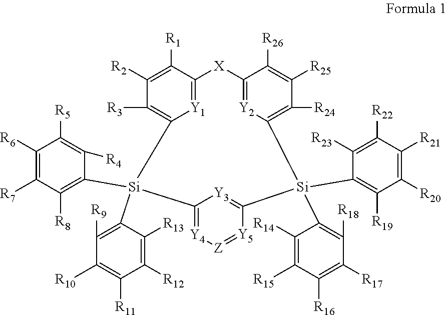
where in Formula 1,
X is NAr₁ or 0,
Z is CR₂₇ or N,
Y₁ to Y₅ are each independently CR₂₈ or N,
Ar₁ is a substituted or unsubstituted aryl group having 6 to 30 ring-forming carbons, a substituted or unsubstituted heteroaryl group having 2 to 30 ring-forming carbons, or bonded to an adjacent group to form a ring,
R₁ to R₂₈ are each independently a hydrogen atom, a deuterium atom, a cyano group, a substituted or unsubstituted silyl group, a substituted or unsubstituted alkyl group having 1 to 20 carbons, a substituted or unsubstituted cycloalkyl group having 3 to 20 ring-forming carbons, a substituted or unsubstituted hetero cycloalkyl group having 3 to 20 ring-forming carbons, a substituted or unsubstituted alkenyl group having 2 to 20 carbons, a substituted or unsubstituted cycloalkenyl group having 3 to 20 ring-forming carbons, a substituted or unsubstituted hetero cycloalkenyl group having ring-forming 3 to 20 carbons, a substituted or unsubstituted aryl group having 6 to 30 ring-forming carbons, a substituted or unsubstituted heteroaryl group having 2 to 30 ring-forming carbons, or bonded to an adjacent group to form a ring.

12. The electronic apparatus of claim 11,
wherein the light-emitting element further comprises a capping layer on the second electrode, and
the capping layer has a refractive index of at least about 1.6 for light in wavelength range of about 550 nm to about 660 nm.

13. The electronic apparatus of claim 11 further comprising a light control layer on the display element layer and comprising a quantum dot,
wherein the light-emitting element is configured to emit a first color light, and
the light control layer comprises:
a first light control part comprising a first quantum dot configured to convert the first color light into a second color light, a wavelength region of the second color light being longer than a wavelength region of the first color light;
a second light control part comprising a second quantum dot configured to convert the first color light into a third color light, a wavelength region of the third color light being longer than a wavelength region of the first color light and the wavelength region of the second color light; and
a third light control part configured to transmit the first color light.

14. The electronic apparatus of claim 13 further comprising a color filter layer on the light control layer,
wherein the color filter layer comprises:
a first filter configured to transmit the second color light;
a second filter configured to transmit the third color light; and
a third filter configured to transmit the first color light.

15. A hetero compound comprising a first compound represented by Formula 1: 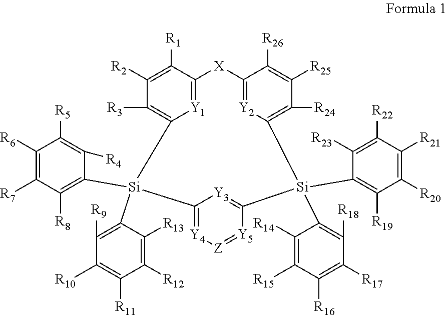
wherein, in Formula 1,
X is NAr₁ or 0,
Z is CR₂₇ or N,
Y₁ to Y₅ are each independently CR₂₈ or N,
Ar₁ is a substituted or unsubstituted aryl group having 6 to 30 ring-forming carbons, a substituted or unsubstituted heteroaryl group having 2 to 30 ring-forming carbons, or bonded to an adjacent group to form a ring, and
R₁ to R₂₈ are each independently a hydrogen atom, a deuterium atom, a cyano group, a substituted or unsubstituted silyl group, a substituted or unsubstituted alkyl group having 1 to 20 carbons, a substituted or unsubstituted cycloalkyl group having 3 to 20 ring-forming carbons, a substituted or unsubstituted hetero cycloalkyl group having 3 to 20 ring-forming carbons, a substituted or unsubstituted alkenyl group having 2 to 20 carbons, a substituted or unsubstituted cycloalkenyl group having 3 to 20 ring-forming carbons, a substituted or unsubstituted hetero cycloalkenyl group having 3 to 20 ring-forming carbons, a substituted or unsubstituted aryl group having 6 to 30 ring-forming carbons, a substituted or unsubstituted heteroaryl group having 2 to 30 ring-forming carbons, or bonded to an adjacent group to form a ring.

16. The hetero compound of claim 15, wherein the hetero compound is represented by any one of Formula 1-1 or Formula 1-2: 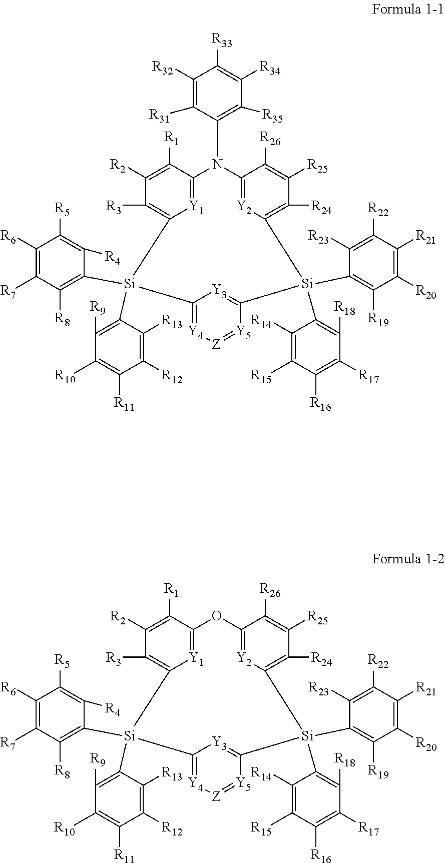
wherein, in Formula 1-1 and Formula 1-2,
R₃₁ to R₃₅ are each independently a hydrogen atom, a deuterium atom, a cyano group, a substituted or unsubstituted silyl group, a substituted or unsubstituted alkyl group having 1 to 20 carbons, a substituted or unsubstituted cycloalkyl group having 3 to 20 ring-forming carbons, a substituted or unsubstituted hetero cycloalkyl group having 3 to 20 ring-forming carbons, a substituted or unsubstituted alkenyl group having 2 to 20 carbons, a substituted or unsubstituted cycloalkenyl group having 3 to 20 ring-forming carbons, a substituted or unsubstituted heterocycloalkenyl group having 3 to 20 ring-forming carbons, a substituted or unsubstituted aryl group having 6 to 30 ring-forming carbons, a substituted or unsubstituted heteroaryl group having 2 to 30 ring-forming carbons, or bonded to an adjacent group to form a ring,
Z, Y₁ to Y₅, and R₁ to R₂₆ are as defined in Formula 1.

17. The hetero compound of claim 15, wherein the hetero compound is represented by any one Formula 2-1 or Formula 2-2: 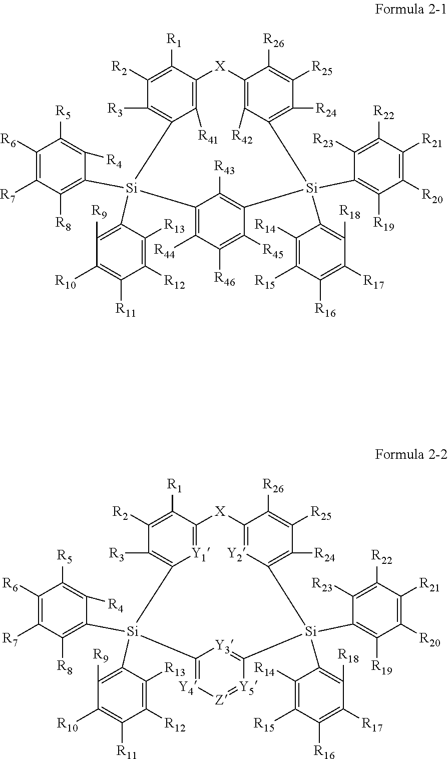
wherein, in Formula 2-1 and Formula 2-2,
R₄₁ to R₄₆ are each independently a hydrogen atom, a deuterium atom, or a substituted or unsubstituted carbazole group,
at least any one selected from among Y₁′ to Y₅′, and Z′ is N, and any remaining Y₁′ to Y₅′, and Z′ are each independently CR₄₇,
R₄₇ is a hydrogen atom or a deuterium atom, and
X, and R₁ to R₂₆ are as defined in Formula 1.

18. The hetero compound of claim 15, wherein the hetero compound is represented by any one selected from among Formula 3-1 to Formula 3-3: 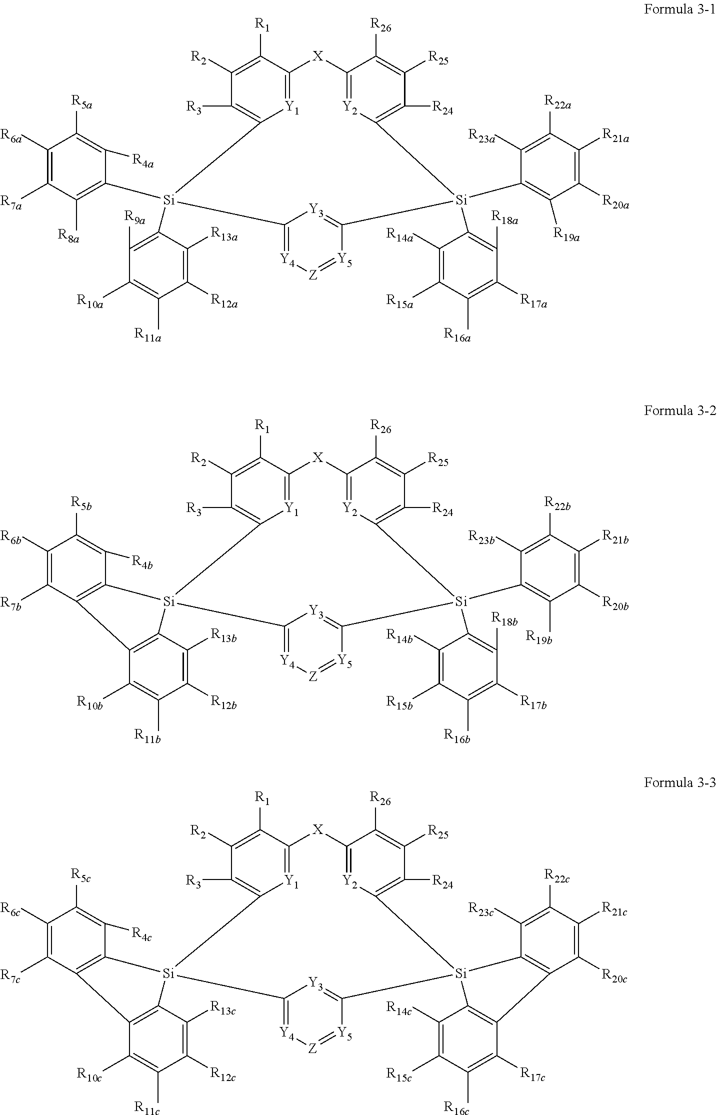
wherein, in Formula 3-1,
R₄ₐ to R₂₃ₐ are each independently a hydrogen atom, a deuterium atom, or a substituted or unsubstituted carbazole group,
in Formula 3-2,
R_{4b} to R_{7b}, R_{10b} to R_{13b}, and R_{14b} to R_{23b} are each independently a hydrogen atom, a deuterium atom, a substituted or unsubstituted carbazole group,
in Formula 3-3,
R_{4c} to R_{7c}, R_{10c} to R_{13c}, R_{14c} to R_{17c}, and R_{20c} to R_{23c} are each independently a hydrogen atom, a deuterium atom, or a substituted or unsubstituted carbazole group, and
in Formula 3-1 to Formula 3-3,
X, Z, Y₁ to Y₅, R₁ to R₃, and R₂₄ to R₂₆ are as defined in Formula 1.

19. The hetero compound of claim 15, wherein the hetero compound is re resented by any one selected from among Formula 4-1 to Formula 4-3: 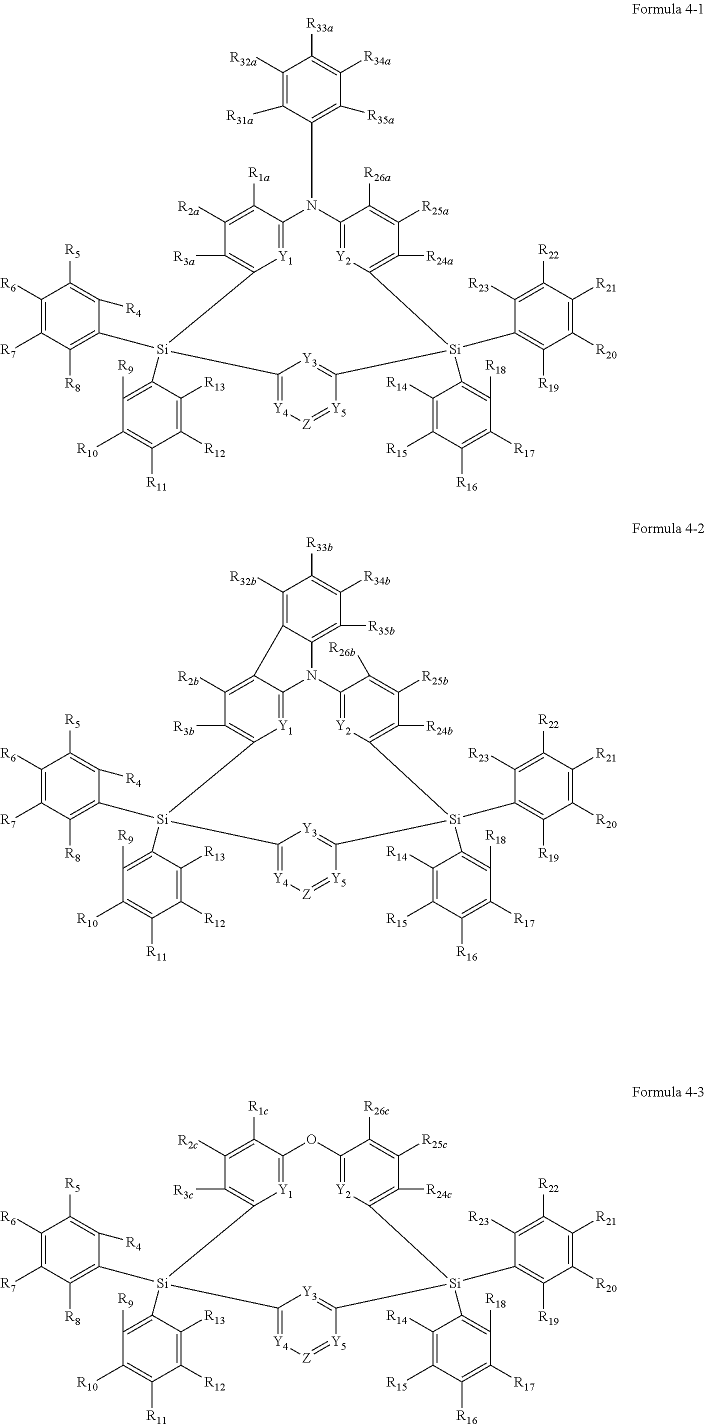
wherein, in Formula 4-1,
R₁ₐ to R₃ₐ, R₂₄ₐ to R₂₆ₐ, and R₃₁ₐ to R₃₅ₐ are each independently a hydrogen atom, a deuterium atom, or a substituted or unsubstituted carbazole group,
in Formula 4-2,
R_{2b}, R_{3b}, R_{24b} to R_{26b}, and R_{32b} to R_{35b} are each independently a hydrogen atom, a deuterium atom, or a substituted or unsubstituted carbazole group,
in Formula 4-3,
R_{1c} to R_{3c}, and R_{24c} to R_{26c} are each independently a hydrogen atom, a deuterium atom, or a substituted or unsubstituted carbazole group, and
in Formula 4-1 to Formula 4-3,
Z, Y₁ to Y₅, and R₄ to R₂₃ are as defined in Formula 1.

20. The hetero compound of claim 15, wherein the hetero compound comprises at least one selected from among compounds in Compound Group 1: 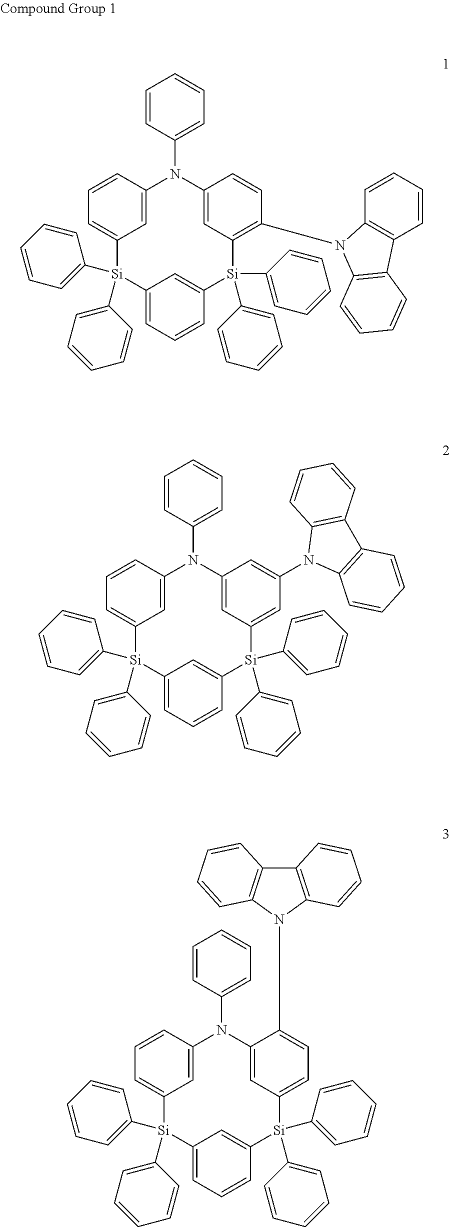 [SMILES: c1ccc(N2c3cccc(c3)[Si](c3ccccc3)(c3ccccc3)c3cccc(c3)[Si](c3ccccc3)(c3ccccc3)c3cc2ccc3-n2c3ccccc3c3ccccc32)cc1 ; c1ccc(N2c3cccc(c3)[Si](c3ccccc3)(c3ccccc3)c3cccc(c3)[Si](c3ccccc3)(c3ccccc3)c3cc2cc(-n2c4ccccc4c4ccccc42)c3)cc1 ; c1ccc(N2c3cccc(c3)[Si](c3ccccc3)(c3ccccc3)c3cccc(c3)[Si](c3ccccc3)(c3ccccc3)c3ccc(-n4c5ccccc5c5ccccc54)c2c3)cc1] 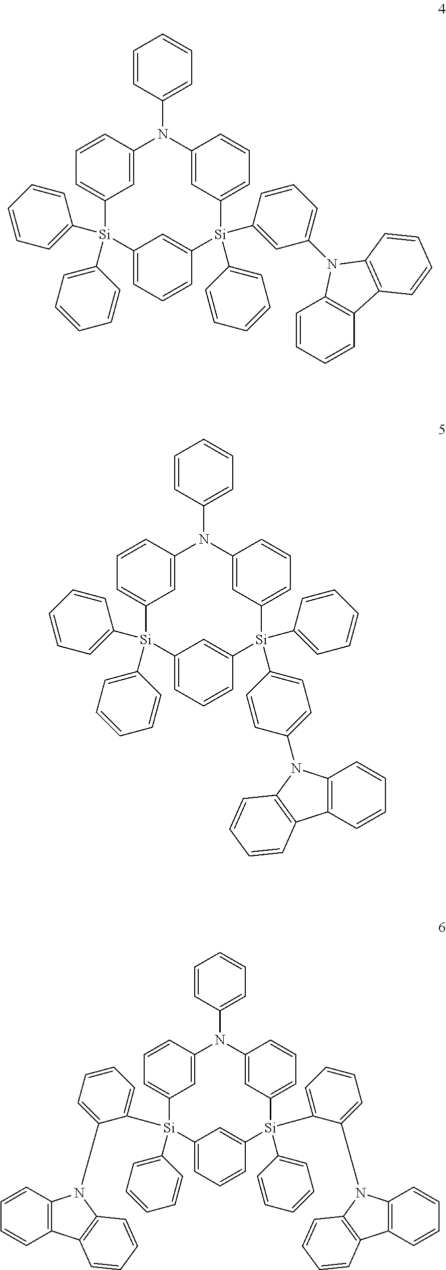 [SMILES: c1ccc(N2c3cccc(c3)[Si](c3ccccc3)(c3ccccc3)c3cccc(c3)[Si](c3ccccc3)(c3cccc(-n4c5ccccc5c5ccccc54)c3)c3cccc2c3)cc1 ; c1ccc(N2c3cccc(c3)[Si](c3ccccc3)(c3ccccc3)c3cccc(c3)[Si](c3ccccc3)(c3ccc(-n4c5ccccc5c5ccccc54)cc3)c3cccc2c3)cc1 ; c1ccc(N2c3cccc(c3)[Si](c3ccccc3)(c3ccccc3-n3c4ccccc4c4ccccc43)c3cccc(c3)[Si](c3ccccc3)(c3ccccc3-n3c4ccccc4c4ccccc43)c3cccc2c3)cc1] 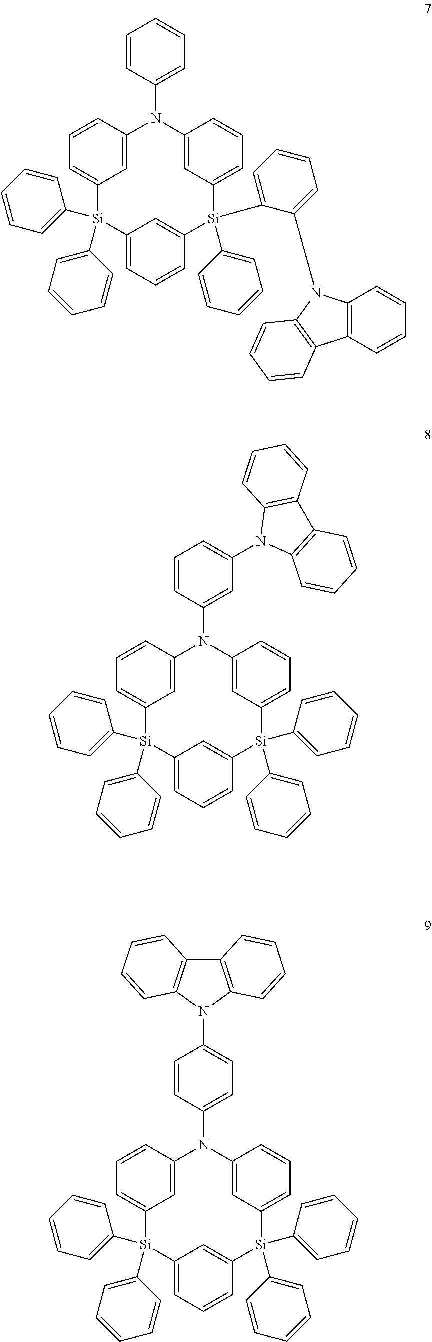 [SMILES: c1ccc(N2c3cccc(c3)[Si](c3ccccc3)(c3ccccc3)c3cccc(c3)[Si](c3ccccc3)(c3ccccc3-n3c4ccccc4c4ccccc43)c3cccc2c3)cc1 ; c1ccc([Si]2(c3ccccc3)c3cccc(c3)N(c3cccc(-n4c5ccccc5c5ccccc54)c3)c3cccc(c3)[Si](c3ccccc3)(c3ccccc3)c3cccc2c3)cc1 ; c1ccc([Si]2(c3ccccc3)c3cccc(c3)N(c3ccc(-n4c5ccccc5c5ccccc54)cc3)c3cccc(c3)[Si](c3ccccc3)(c3ccccc3)c3cccc2c3)cc1] 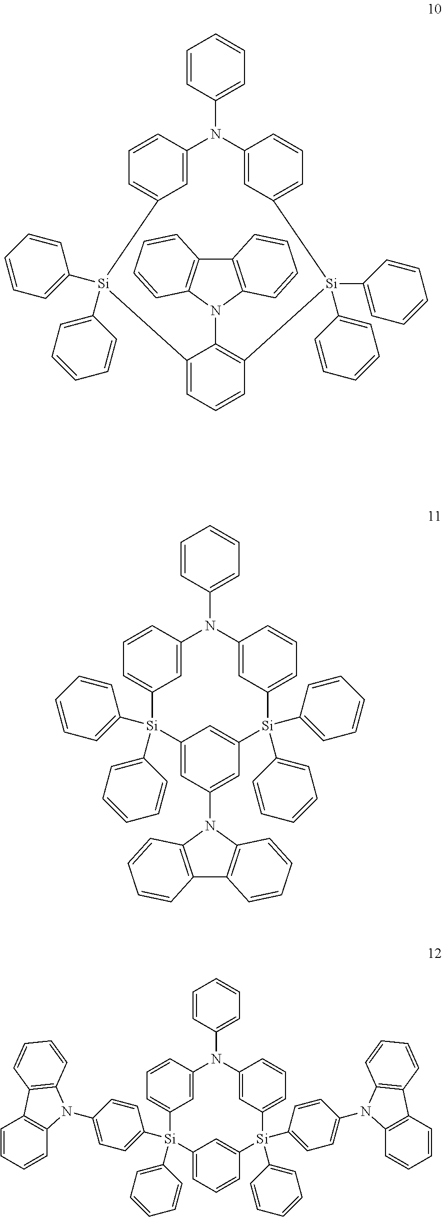 [SMILES: c1ccc(N2c3cccc(c3)[Si](c3ccccc3)(c3ccccc3)c3cccc(c3-n3c4ccccc4c4ccccc43)[Si](c3ccccc3)(c3ccccc3)c3cccc2c3)cc1 ; c1ccc(N2c3cccc(c3)[Si](c3ccccc3)(c3ccccc3)c3cc(-n4c5ccccc5c5ccccc54)cc(c3)[Si](c3ccccc3)(c3ccccc3)c3cccc2c3)cc1 ; c1ccc(N2c3cccc(c3)[Si](c3ccccc3)(c3ccc(-n4c5ccccc5c5ccccc54)cc3)c3cccc(c3)[Si](c3ccccc3)(c3ccc(-n4c5ccccc5c5ccccc54)cc3)c3cccc2c3)cc1] 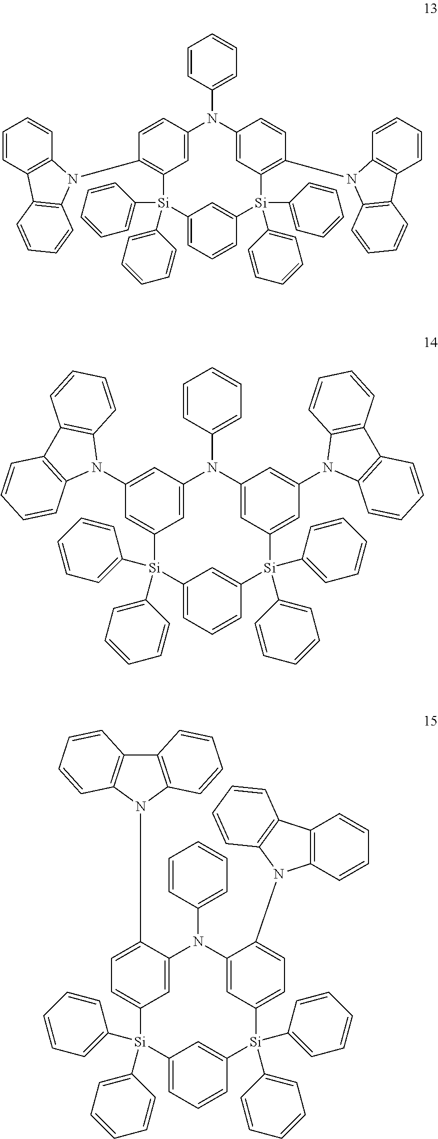 [SMILES: c1ccc(N2c3ccc(-n4c5ccccc5c5ccccc54)c(c3)[Si](c3ccccc3)(c3ccccc3)c3cccc(c3)[Si](c3ccccc3)(c3ccccc3)c3cc2ccc3-n2c3ccccc3c3ccccc32)cc1 ; c1ccc(N2c3cc(-n4c5ccccc5c5ccccc54)cc(c3)[Si](c3ccccc3)(c3ccccc3)c3cccc(c3)[Si](c3ccccc3)(c3ccccc3)c3cc2cc(-n2c4ccccc4c4ccccc42)c3)cc1 ; c1ccc(N2c3cc(ccc3-n3c4ccccc4c4ccccc43)[Si](c3ccccc3)(c3ccccc3)c3cccc(c3)[Si](c3ccccc3)(c3ccccc3)c3ccc(-n4c5ccccc5c5ccccc54)c2c3)cc1] 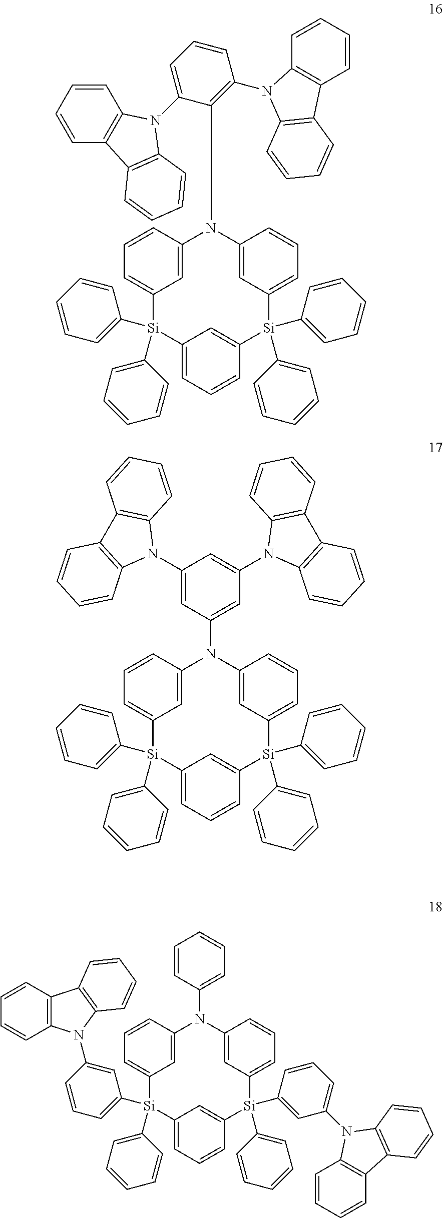 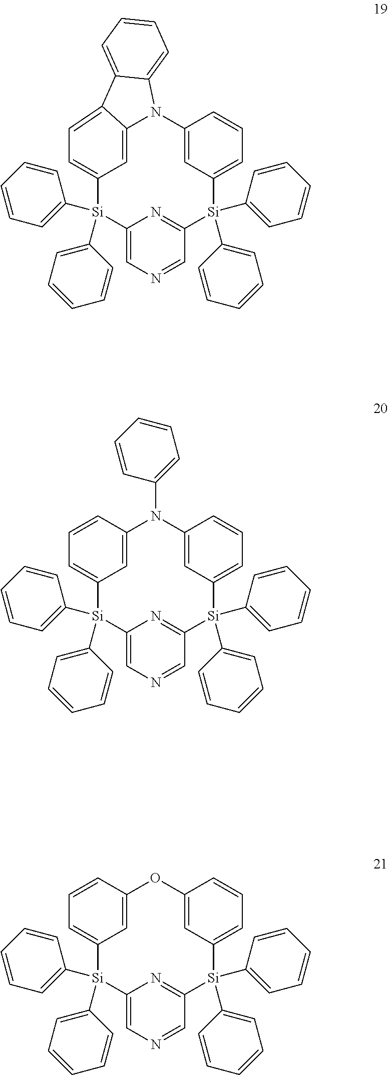 [SMILES: c1ccc([Si]2(c3ccccc3)c3cccc(c3)-n3c4ccccc4c4ccc(cc43)[Si](c3ccccc3)(c3ccccc3)c3cncc2n3)cc1 ; c1ccc(N2c3cccc(c3)[Si](c3ccccc3)(c3ccccc3)c3cncc(n3)[Si](c3ccccc3)(c3ccccc3)c3cccc2c3)cc1 ; c1ccc([Si]2(c3ccccc3)c3cccc(c3)Oc3cccc(c3)[Si](c3ccccc3)(c3ccccc3)c3cncc2n3)cc1] 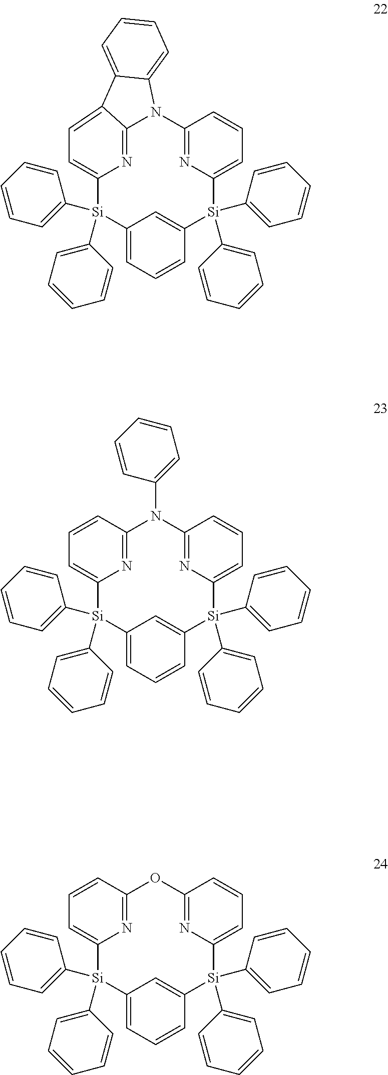 [SMILES: c1ccc([Si]2(c3ccccc3)c3cccc(c3)[Si](c3ccccc3)(c3ccccc3)c3ccc4c5ccccc5n(c4n3)-c3cccc2n3)cc1 ; c1ccc(N2c3cccc(n3)[Si](c3ccccc3)(c3ccccc3)c3cccc(c3)[Si](c3ccccc3)(c3ccccc3)c3cccc2n3)cc1 ; c1ccc([Si]2(c3ccccc3)c3cccc(c3)[Si](c3ccccc3)(c3ccccc3)c3cccc(n3)Oc3cccc2n3)cc1] 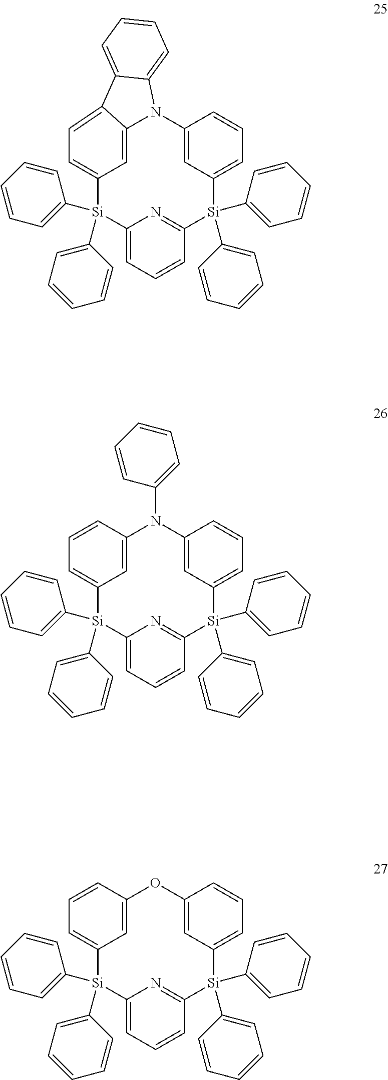 [SMILES: c1ccc([Si]2(c3ccccc3)c3cccc(c3)-n3c4ccccc4c4ccc(cc43)[Si](c3ccccc3)(c3ccccc3)c3cccc2n3)cc1 ; c1ccc(N2c3cccc(c3)[Si](c3ccccc3)(c3ccccc3)c3cccc(n3)[Si](c3ccccc3)(c3ccccc3)c3cccc2c3)cc1 ; c1ccc([Si]2(c3ccccc3)c3cccc(c3)Oc3cccc(c3)[Si](c3ccccc3)(c3ccccc3)c3cccc2n3)cc1] 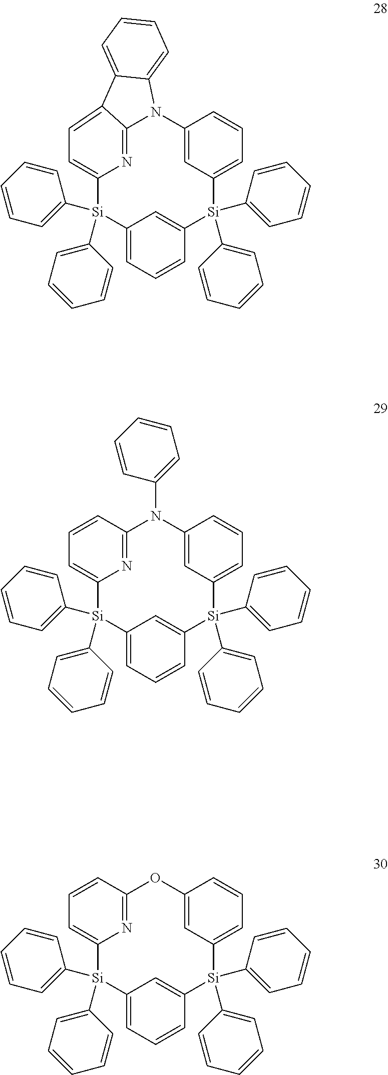 [SMILES: c1ccc([Si]2(c3ccccc3)c3cccc(c3)-n3c4ccccc4c4ccc(nc43)[Si](c3ccccc3)(c3ccccc3)c3cccc2c3)cc1 ; c1ccc(N2c3cccc(c3)[Si](c3ccccc3)(c3ccccc3)c3cccc(c3)[Si](c3ccccc3)(c3ccccc3)c3cccc2n3)cc1 ; c1ccc([Si]2(c3ccccc3)c3cccc(c3)Oc3cccc(n3)[Si](c3ccccc3)(c3ccccc3)c3cccc2c3)cc1] 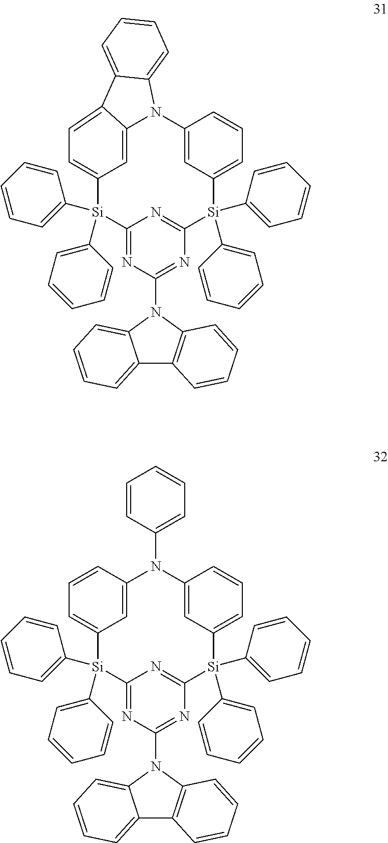 [SMILES: c1ccc([Si]2(c3ccccc3)c3cccc(c3)-n3c4ccccc4c4ccc(cc43)[Si](c3ccccc3)(c3ccccc3)c3nc(-n4c5ccccc5c5ccccc54)nc2n3)cc1 ; c1ccc(N2c3cccc(c3)[Si](c3ccccc3)(c3ccccc3)c3nc(-n4c5ccccc5c5ccccc54)nc(n3)[Si](c3ccccc3)(c3ccccc3)c3cccc2c3)cc1] 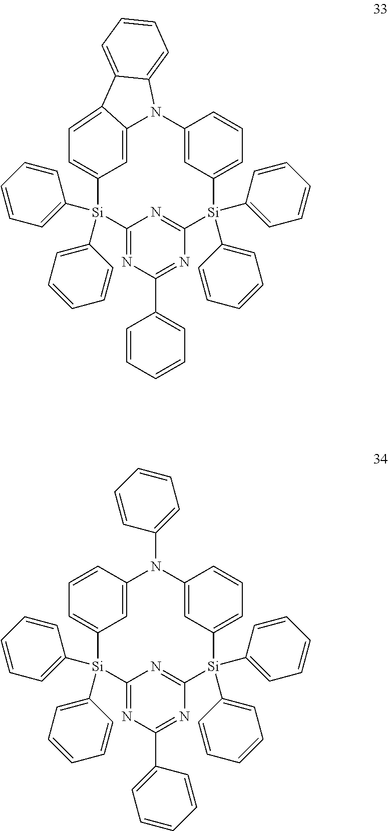 [SMILES: c1ccc(-c2nc3nc(n2)[Si](c2ccccc2)(c2ccccc2)c2ccc4c5ccccc5n(c4c2)-c2cccc(c2)[Si]3(c2ccccc2)c2ccccc2)cc1 ; c1ccc(-c2nc3nc(n2)[Si](c2ccccc2)(c2ccccc2)c2cccc(c2)N(c2ccccc2)c2cccc(c2)[Si]3(c2ccccc2)c2ccccc2)cc1] 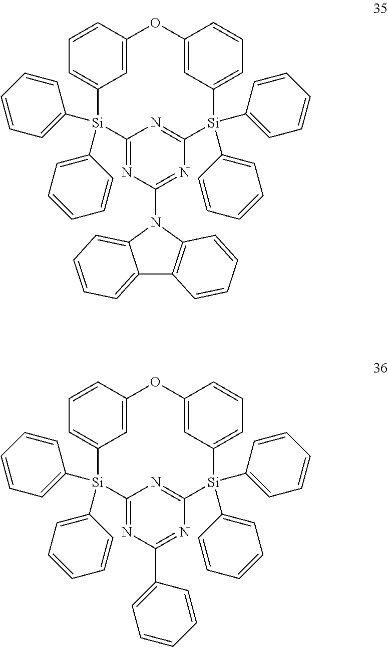 [SMILES: c1ccc([Si]2(c3ccccc3)c3cccc(c3)Oc3cccc(c3)[Si](c3ccccc3)(c3ccccc3)c3nc(-n4c5ccccc5c5ccccc54)nc2n3)cc1 ; c1ccc(-c2nc3nc(n2)[Si](c2ccccc2)(c2ccccc2)c2cccc(c2)Oc2cccc(c2)[Si]3(c2ccccc2)c2ccccc2)cc1] 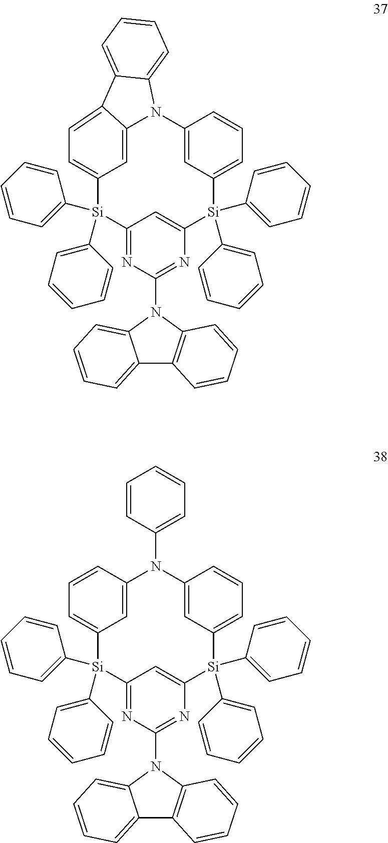 [SMILES: c1ccc([Si]2(c3ccccc3)c3cccc(c3)-n3c4ccccc4c4ccc(cc43)[Si](c3ccccc3)(c3ccccc3)c3cc2nc(-n2c4ccccc4c4ccccc42)n3)cc1 ; c1ccc(N2c3cccc(c3)[Si](c3ccccc3)(c3ccccc3)c3cc(nc(-n4c5ccccc5c5ccccc54)n3)[Si](c3ccccc3)(c3ccccc3)c3cccc2c3)cc1] 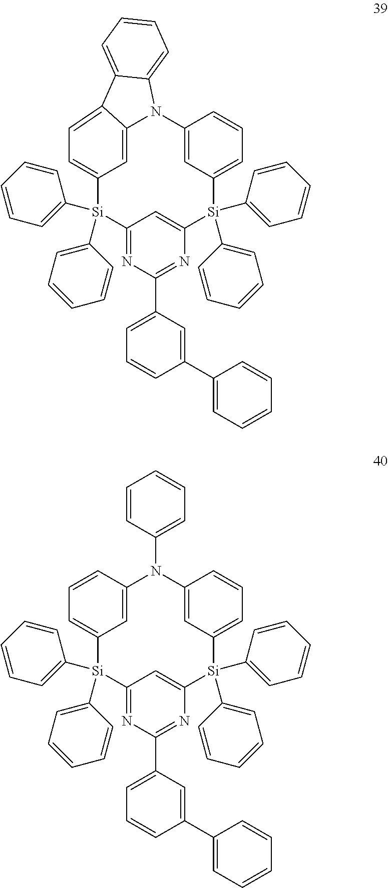 [SMILES: c1ccc(-c2cccc(-c3nc4cc(n3)[Si](c3ccccc3)(c3ccccc3)c3ccc5c6ccccc6n(c5c3)-c3cccc(c3)[Si]4(c3ccccc3)c3ccccc3)c2)cc1 ; c1ccc(-c2cccc(-c3nc4cc(n3)[Si](c3ccccc3)(c3ccccc3)c3cccc(c3)N(c3ccccc3)c3cccc(c3)[Si]4(c3ccccc3)c3ccccc3)c2)cc1] 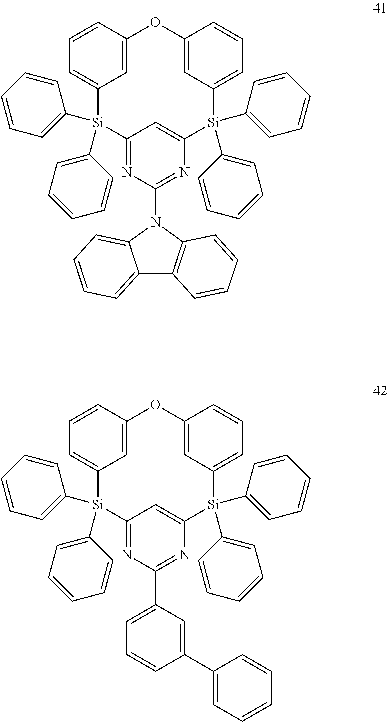 [SMILES: c1ccc([Si]2(c3ccccc3)c3cccc(c3)Oc3cccc(c3)[Si](c3ccccc3)(c3ccccc3)c3cc2nc(-n2c4ccccc4c4ccccc42)n3)cc1 ; c1ccc(-c2cccc(-c3nc4cc(n3)[Si](c3ccccc3)(c3ccccc3)c3cccc(c3)Oc3cccc(c3)[Si]4(c3ccccc3)c3ccccc3)c2)cc1] 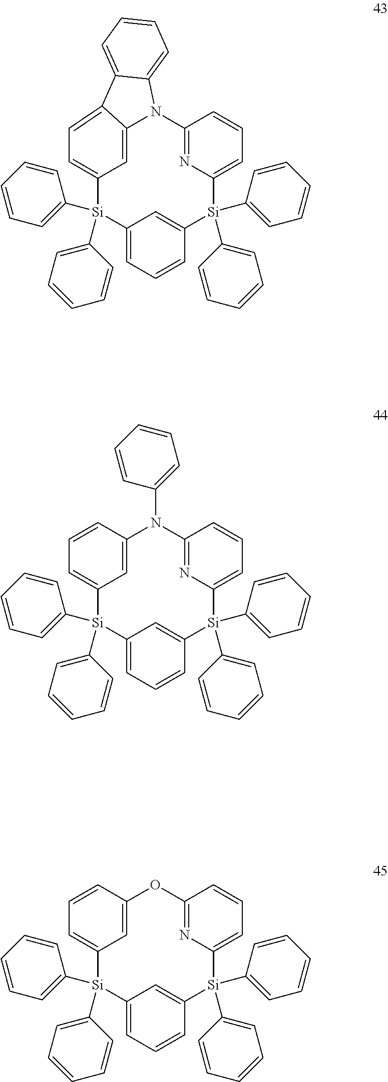 [SMILES: c1ccc([Si]2(c3ccccc3)c3cccc(c3)[Si](c3ccccc3)(c3ccccc3)c3cccc(n3)-n3c4ccccc4c4ccc2cc43)cc1 ; c1ccc(N2c3cccc(c3)[Si](c3ccccc3)(c3ccccc3)c3cccc(c3)[Si](c3ccccc3)(c3ccccc3)c3cccc2n3)cc1 ; c1ccc([Si]2(c3ccccc3)c3cccc(c3)Oc3cccc(n3)[Si](c3ccccc3)(c3ccccc3)c3cccc2c3)cc1] 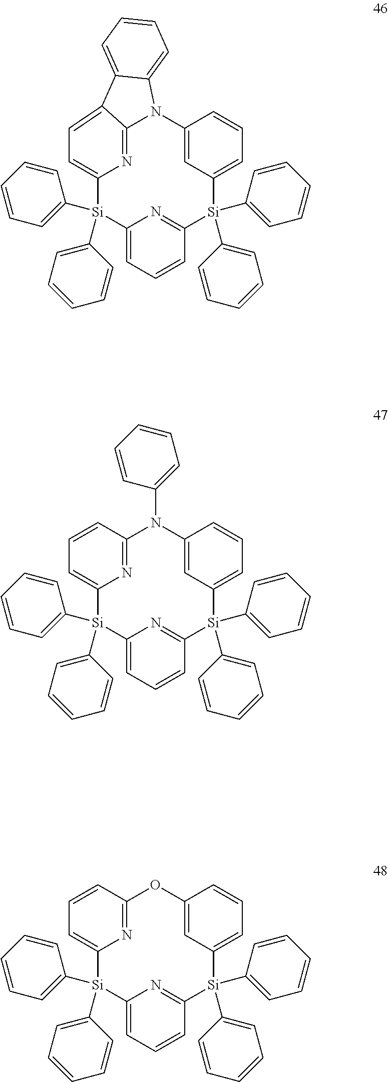 [SMILES: c1ccc([Si]2(c3ccccc3)c3cccc(c3)-n3c4ccccc4c4ccc(nc43)[Si](c3ccccc3)(c3ccccc3)c3cccc2n3)cc1 ; c1ccc(N2c3cccc(c3)[Si](c3ccccc3)(c3ccccc3)c3cccc(n3)[Si](c3ccccc3)(c3ccccc3)c3cccc2n3)cc1 ; c1ccc([Si]2(c3ccccc3)c3cccc(c3)Oc3cccc(n3)[Si](c3ccccc3)(c3ccccc3)c3cccc2n3)cc1] 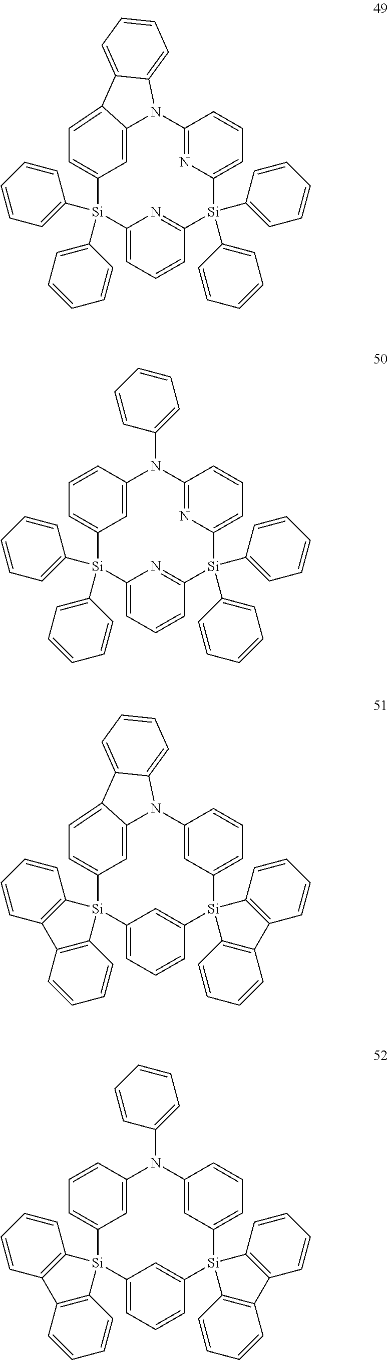 [SMILES: c1ccc([Si]2(c3ccccc3)c3ccc4c5ccccc5n(c4c3)-c3cccc(n3)[Si](c3ccccc3)(c3ccccc3)c3cccc2n3)cc1 ; c1ccc(N2c3cccc(c3)[Si](c3ccccc3)(c3ccccc3)c3cccc(n3)[Si](c3ccccc3)(c3ccccc3)c3cccc2n3)cc1 ; c1cc2cc(c1)[Si]1(c3cccc(c3)[Si]3(c4ccc5c6ccccc6n-2c5c4)c2ccccc2-c2ccccc23)c2ccccc2-c2ccccc21 ; c1ccc(N2c3cccc(c3)[Si]3(c4cccc(c4)[Si]4(c5cccc2c5)c2ccccc2-c2ccccc24)c2ccccc2-c2ccccc23)cc1] [chemical structure]
